(19) United States
(12) Patent Application Publication
(10) Pub. No.: US 2024/0349609 A1
(43) Pub. Date: Oct. 17, 2024

(54) LIGHT-EMITTING ELEMENT, POLYCYCLIC COMPOUND FOR LIGHT-EMITTING ELEMENT, AND DISPLAY DEVICE INCLUDING THE LIGHT-EMITTING ELEMENT

(71) Applicant: Samsung Display Co., Ltd., Yongin-si (KR)

(72) Inventors: TAEIL KIM, Yongin-si (KR); MINJUNG JUNG, Yongin-si (KR); JUNHA PARK, Yongin-si (KR); MinJae SUNG, Yongin-si (KR); MUN-KI SIM, Yongin-si (KR); CHANSEOK OH, Yongin-si (KR); Seonhyoung HUR, Yongin-si (KR)

(21) Appl. No.: 18/415,472

(22) Filed: Jan. 17, 2024

(30) Foreign Application Priority Data
Apr. 12, 2023 (KR) 10-2023-0048026

(51) Int. Cl. H10K 85/60; C07B 59/00; C09K 11/06; H10K 85/30; H10K 85/40; H10K 101/20

(52) U.S. Cl. CPC H10K 85/658; C07B 59/004; C09K 11/06; H10K 85/346; H10K 85/40; H10K 85/622; H10K 85/654; H10K 85/6572; H10K 85/6574; H10K 85/6576; C07B 2200/05; H10K 2101/20

(57) ABSTRACT

Provided is a light-emitting element including a first electrode, a second electrode provided on the first electrode, and an emission layer provided between the first electrode and the second electrode. The emission layer includes a first compound represented by Formula 1 below and thus the light-emitting element exhibits long-lifespan characteristics.

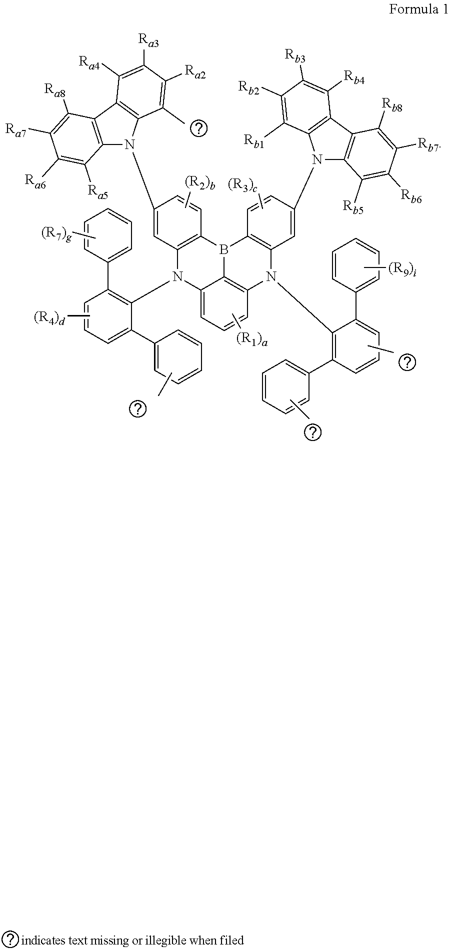

### CROSS-REFERENCE TO RELATED APPLICATIONS

The present application claims priority to and the benefit of Korean Patent Application No. 10-2023-0048026, filed on Apr. 12, 2023, in the Korean Intellectual Property Office, the entire content of which is incorporated herein by reference.

### BACKGROUND

### 1. Field

One or more aspects of embodiments of the present disclosure herein are directed toward to a light-emitting element, a polycyclic compound utilized for the same, and a display device including the light-emitting element.

### 2. Description of the Related Art

Recently, organic electroluminescence display devices and/or the like have been actively developed as image display devices. Organic electroluminescence display devices and/or the like are display devices including a self-luminous type or kind light-emitting element that recombines, in an emission layer, holes and electrons respectively injected from a first electrode and a second electrode, thereby causing a light-emitting material of the emission layer to emit light to implement displays of images.

In applying a light-emitting element to display devices, improvements in light efficiency, lifespan, etc. are required or desired, and the development of materials for a light-emitting element capable of stably or suitably achieving these improvements is continuously required or desired.

In particular, recently, in order (or in an effort) to achieve a highly efficient (or suitably efficient) light-emitting element, technologies pertaining to phosphorescence emission utilizing triplet state energy and/or delayed fluorescence emission utilizing triplet-triplet annihilation (TTA), in which singlet excitons are generated by collision of triplet excitons, are being developed or pursued, and development of a thermally activated delayed fluorescence (TADF) material utilizing a delayed fluorescence phenomenon is in progress.

### SUMMARY

One or more aspects of embodiments of the present disclosure are directed toward a light-emitting element having improved light-emitting efficiency and lifespan.

One or more aspects of embodiments of the present disclosure are also directed toward a polycyclic compound having an improved material lifespan.

One or more aspects of embodiments of the present disclosure are also directed toward a display device having excellent or suitable display quality by including a light-emitting element that has improved light-emitting efficiency and lifespan.

One or more embodiments of the present disclosure provide a polycyclic compound represented by Formula 1.

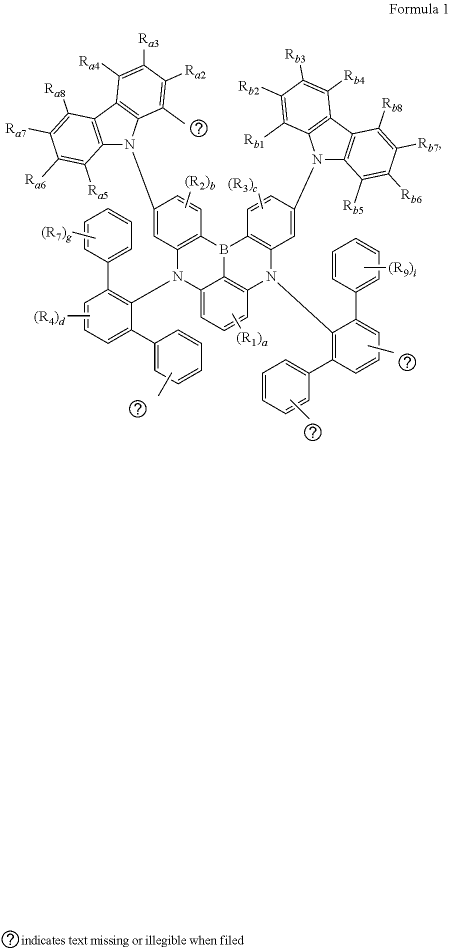

where, in Formula 1, at least one selected from among Rₐ₁ to Rₐ₈, and R_{b1} to R_{b8} is a substituted or unsubstituted aryl group having 6 to 60 ring-forming carbon atoms, or a substituted or unsubstituted heteroaryl group having 2 to 60 ring-forming carbon atoms, and the rest may each independently be a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, or a substituted or unsubstituted alkenyl group having 2 to 60 carbon atoms. a to e may each independently be an integer of 1 to 3, f to i may each independently be an integer of 1 to 5, and R₁ to R₉ may each independently be a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms.

In one or more embodiments, Formula 1 may be represented by any one of Formulae 1-1 to 1-4:

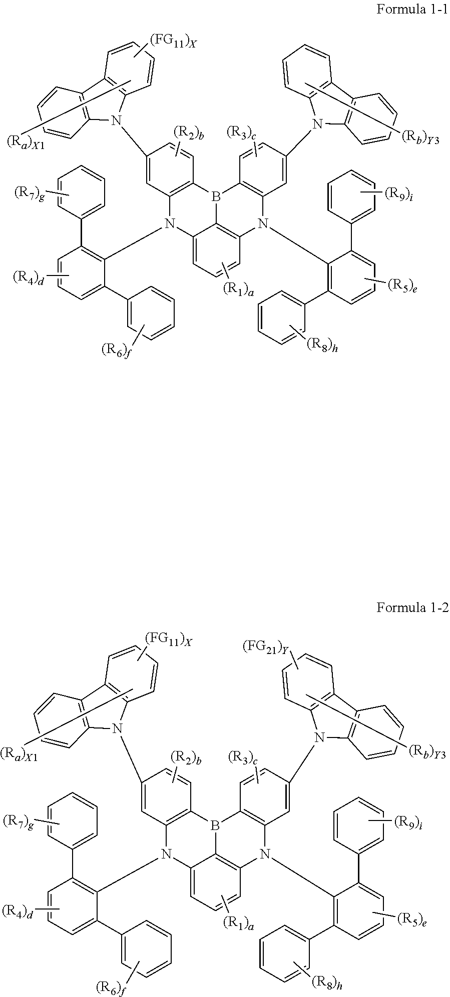

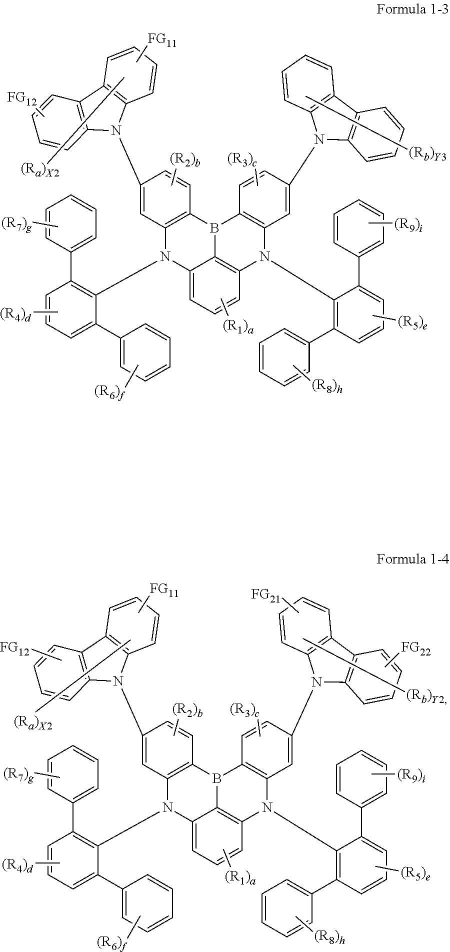

where, in Formulae 1-1 to 1-4, FG₁₁, FG₁₂, FG₂₁, and FG₂₂ may each independently be a substituted or unsubstituted aryl group having 6 to 60 ring-forming carbon atoms or a substituted or unsubstituted heteroaryl group having 2 to 60 ring-forming carbon atoms. X and Y may each independently be 1 or 2, X1 may be an integer of 1 to (8-X), Y1 may be an integer of 1 to (8-Y), X2 and Y2 may each independently be an integer of 1 to 6, and X3 and Y3 may each independently be integer of 1 to 8. Rₐ and R_{b} may each independently be a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, a substituted or unsubstituted alkenyl group having 2 to 60 carbon atoms, and a to i and R₁ to R₉ may each independently be the same as defined in Formula 1.

In one or more embodiments, in Formulae 1-1 to 1-4, FG₁₁, FG₁₂, FG₂₁, and FG₂₂ may each independently be a substituted or unsubstituted phenyl group, a substituted or unsubstituted biphenyl group, a substituted or unsubstituted terphenyl group, a substituted or unsubstituted naphthyl group, a substituted or unsubstituted phenanthrene group, a substituted or unsubstituted pyrene group, or a substituted or unsubstituted dibenzoheterol group, containing N, O, and/or S as a ring-forming atom.

In one or more embodiments, Formula 1 may be represented by Formula 2:

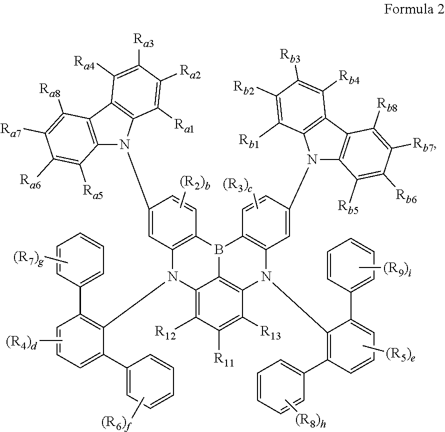

where, in Formula 2, R₁₁ may be a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms, and R₁₂ and R₁₃ may each independently be a hydrogen atom or a deuterium atom. Rₐ₁ to Rₐ₈, R_{b1} to R_{b8}, b to i, and R₂ to R₉ may each independently be the same as defined in Formula 1.

In one or more embodiments, in Formula 1, at least one selected from among Rₐ₁ to Rₐ₈, and R_{b1} to R_{b8} may be a substituted or unsubstituted aryl group having 6 to 60 ring-forming carbon atoms, or a substituted or unsubstituted heteroaryl group having 2 to 60 ring-forming carbon atoms, and the rest may each independently be a hydrogen atom or a deuterium atom.

In one or more embodiments, in Formula 1, at least one of Rₐ₁ to Rₐ₈, or R_{b1} to R_{b8} may be represented by any one of FG-a to FG-h:

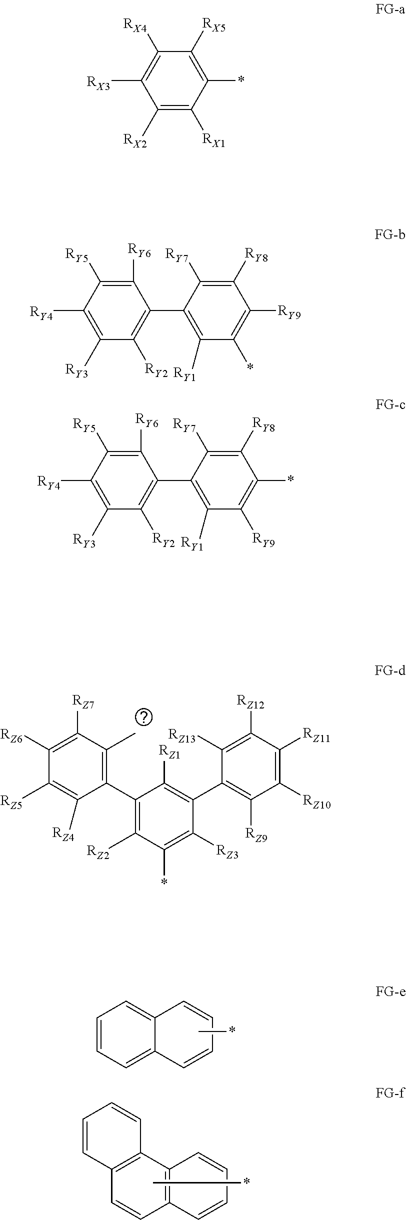

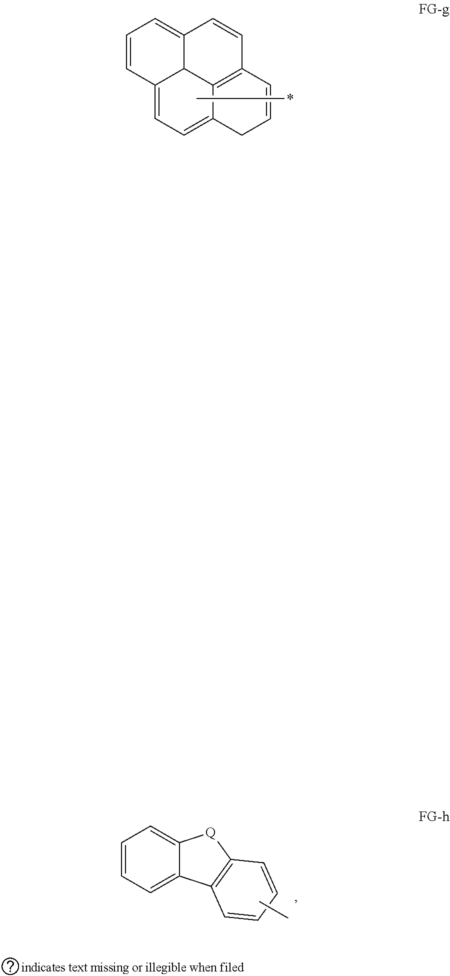

where, in FG-a to FG-d, R_{X1} to R_{X5}, R_{Y1} to R_{Y9}, and R_{Z1} to R_{Z13} may each independently be a hydrogen atom, a deuterium atom, a cyano group, a t-butyl group, and in FG-h, Q may be O, S, NH, or NPh, where Ph is a phenyl group.

In one or more embodiments, at least one hydrogen atom of Rₐ₁ to Rₐ₈, R_{b1} to R_{b8}, or R₁ to R₃ in Formula 1 may be substituted with a deuterium atom.

In one or more embodiments of the present disclosure, a light-emitting element includes a first electrode; a second electrode provided on the first electrode; and an emission layer provided between the first electrode and the second electrode and including a polycyclic compound being the first compound according to the present embodiments.

In one or more embodiments, the emission layer may further include at least one of a second compound represented by Formula HT-1, or a third compound represented by Formula ET-1:

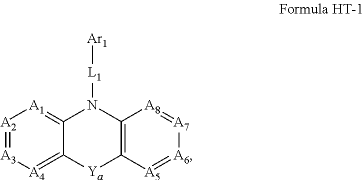

where, in Formula HT-1, A₁ to A₈ may each independently be N or CR₅₁, L₁ may be a direct linkage, a substituted or unsubstituted arylene group having 6 to 30 ring-forming carbon atoms, or a substituted or unsubstituted heteroarylene group having 2 to 30 ring-forming carbon atoms, and Yₐ may be a direct linkage, CR₅₂R₅₃, or SiR₅₄R₅₅. Ar₁ may be a substituted or unsubstituted aryl group having 6 to 30 ring-forming carbon atoms, or a substituted or unsubstituted heteroaryl group having 2 to 30 ring-forming carbon atoms, and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring:

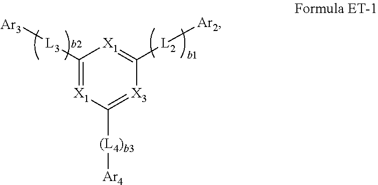

where, in Formula ET-1, at least one selected from among X₁ to X₃ may be N, the rest may be CR₅₆, and R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms. b1 to b3 may each independently be an integer of 0 to 10, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and L2 to L4 may each independently be a direct linkage, a substituted or unsubstituted arylene group having 6 to 30 ring-forming carbon atoms, or a substituted or unsubstituted heteroarylene group having 2 to 30 ring-forming carbon atoms.

In one or more embodiments, the emission layer may further include a fourth compound represented by Formula D-1:

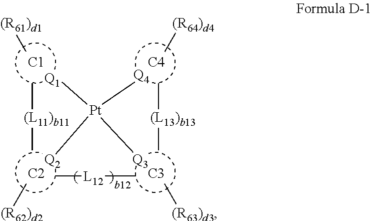

where, in Formula D-1, Q₁ to Q₄ may each independently be C or N, C1 to C4 may each independently be a substituted or unsubstituted hydrocarbon ring having 5 to 30 ring-forming carbon atoms, or a substituted or unsubstituted hetero ring having 2 to 30 ring-forming carbon atoms. L₁₁ to L₁₃ may each independently be a direct linkage,

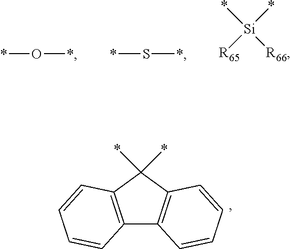

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and b11 to b13 may each independently be 0 or 1. R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and d1 to d4 may each independently be an integer of 0 to 4.

In one or more embodiments, the emission layer may include the first compound, the second compound, the third compound, and the fourth compound.

In one or more embodiments, the emission layer may be to emit delayed fluorescence.

In one or more embodiments, the emission layer may be to emit blue light.

In one or more embodiments of the present disclosure, a display device includes a base layer, a circuit layer provided on the base layer, and a display element layer provided on the circuit layer and including a light-emitting element, wherein the light-emitting element includes a first electrode, a second electrode provided on the first electrode, and a emission layer provided between the first electrode and the second electrode and including the polycyclic compound according to the embodiments.

In one or more embodiments, the light-emitting element may be to emit blue light.

In one or more embodiments, the display device may further include a light control layer including a quantum dot.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a plan view illustrating a display device according to one or more embodiments;

FIG. 2 is a cross-sectional view illustrating a section taken along line I-I′ in FIG. 1;

FIG. 3 is a cross-sectional view schematically illustrating a light-emitting element according to one or more embodiments;

FIG. 4 is a cross-sectional view schematically illustrating a light-emitting element according to one or more embodiments;

FIG. 5 is a cross-sectional view schematically illustrating a light-emitting element according to one or more embodiments;

FIG. 6 is a cross-sectional view schematically illustrating a light-emitting element according to one or more embodiments;

FIG. 7 is a cross-sectional view schematically illustrating a light-emitting element according to one or more embodiments;

FIG. 8 is a cross-sectional view illustrating a display device according to one or more embodiments;

FIG. 9 is a cross-sectional view illustrating a display device according to one or more embodiments;

FIG. 10 is a cross-sectional view illustrating a display device according to one or more embodiments;

FIG. 11 is a cross-sectional view illustrating a display device according to one or more embodiments; and

FIG. 12 is a view illustrating an inside of a vehicle in which a display device according to one or more embodiments is provided.

### DETAILED DESCRIPTION

The present disclosure may be modified in one or more suitable manners and have many forms, and thus specific embodiments will be exemplified in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of the drawings, like reference numbers are utilized for referring to like elements. In the accompanying drawings, the dimensions of each structure are exaggeratingly illustrated for clarity of the present disclosure.

It will be understood that, although the terms “first,” “second,” etc., may be utilized herein to describe one or more suitable components, these components should not be limited by these terms. These terms are only utilized to distinguish one component from another. For example, a first component could be termed a second component, and, similarly, a second component could be termed a first component, without departing from the scope of example embodiments of the present disclosure. As utilized herein, the singular forms, “a,” “an,” and “the” are intended to include the plural forms as well, unless the context clearly indicates otherwise.

In the present application, it will be understood that the terms “include,” “have” and/or the like specify the presence of features, numbers, steps, operations, component, parts, or combinations thereof disclosed in the specification, but do not exclude the possibility of presence or addition of one or more other features, numbers, steps, operations, component, parts, or combinations thereof.

In the present application, when a layer, a film, a region, and/or a plate is referred to as being “on” or “in an upper portion of another layer, film, region, and/or plate, it may be not only “directly on” the layer, film, region, or plate (e.g., without any intervening elements therebetween), but one or more intervening layers, films, regions, and/or plates may also be present. Also, when a layer, a film, a region, and/or a plate is referred to as being””, “in a lower portion of” another layer, film, region, or plate, it can be not only directly under the layer, film, region, and/or plate (e.g., without any intervening elements therebetween), but intervening layers, films, regions, and/or plates may also be present. In some embodiments, it will be understood that when a part is referred to as being “on” another part, it can be provided above the other part, or provided under the other part as well.

In the specification, the term “substituted or unsubstituted” may refer to a group that is unsubstituted or that is substituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, a heterocyclic group and combinations thereof. In some embodiments, each of the substituents exemplified above may itself be substituted or unsubstituted. For example, a biphenyl group may be interpreted as an aryl group and/or a phenyl group substituted with a phenyl group.

In the specification, the phrase “bonded to an adjacent group to form a ring” may refer to a group that is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may each independently be monocyclic or polycyclic. In some embodiments, the rings formed by being bonded to each other may be connected to another ring to form a spiro structure.

In the specification, the term “adjacent group” may refer to a pair of substituent groups where the first substituent is connected to an atom which is directly connected to another atom substituted with the second substituent; a pair of substituent groups connected to the same atom; or a pair of substituent groups where the first substituent is sterically positioned at the nearest position to the second substituent. For example, two methyl groups in 1,2-dimethylbenzene may be interpreted as “adjacent groups” to each other and two ethyl groups in 1,1-diethylcyclopentane may be interpreted as “adjacent groups” to each other. In some embodiments, two methyl groups in 4,5-dimethylphenanthrene may be interpreted as “adjacent groups” to each other.

In the specification, examples of the halogen atom may include a fluorine atom, a chlorine atom, a bromine atom, and/or an iodine atom.

In the specification, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the embodiment of the present disclosure is not limited thereto.

In the specification, a cycloalkyl group may refer to a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but the embodiment of the present disclosure is not limited thereto.

In the specification, an alkenyl group refers to a hydrocarbon group including at least one carbon double bond in the middle and/or terminal of an alkyl group having 2 or more carbon atoms. The alkenyl group may be linear or branched. The number of carbon atoms in the alkenyl group is not specifically limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, etc., but the embodiment of the present disclosure is not limited thereto.

In the specification, an alkynyl group refers to a hydrocarbon group including at least one carbon triple bond in the middle and/or terminal of an alkyl group having 2 or more carbon atoms. The alkynyl group may be linear or branched. Although the number of carbon atoms is not specifically limited, it may be 2 to 30, 2 to 20, or 2 to 10. Examples of the alkynyl group may include an ethynyl group, a propynyl group, etc., but are not limited thereto.

In the specification, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the embodiment of the present disclosure is not limited thereto.

In the specification, the fluorenyl group may be substituted, and two substituents may be bonded to each other to form a spiro structure. Examples of the substituted fluorenyl group may be as follows. However, the embodiment of the present disclosure is not limited thereto:

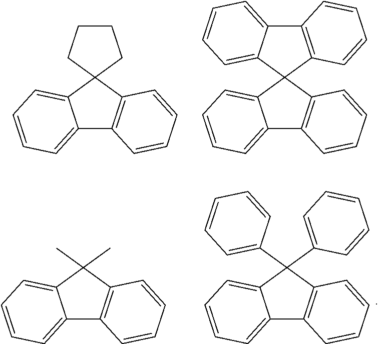

The heterocyclic group herein refers to any functional group or substituent derived from a ring containing at least one of B, O, N, P, Si, or Se as a heteroatom. The heterocyclic group includes an aliphatic heterocyclic group and/or an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. When the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but the embodiment of the present disclosure is not limited thereto.

In the specification, the heteroaryl group may contain at least one of B, O, N, P, Si, or S as a heteroatom. When the heteroaryl group contains two or more heteroatoms, the two or more heteroatoms may be the same as or different from each other. The heteroaryl group may be a monocyclic heterocyclic (e.g., heteroaryl) group or a polycyclic heterocyclic (e.g., heteroaryl) group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the embodiment of the present disclosure is not limited thereto.

In the specification, the above description of the aryl group may be applied to an arylene group except that the arylene group is a divalent group. The above description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but the embodiment of the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the present disclosure is not limited thereto:

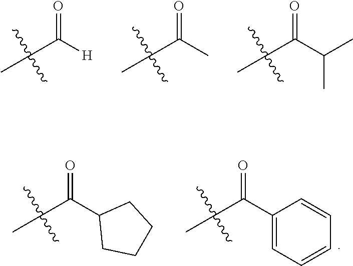

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to a group in which a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the specification, an oxy group may refer to a group in which an oxygen atom is bonded to the alkyl group or the aryl group as defined above. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but the embodiment of the present disclosure is not limited thereto.

The boron group herein may refer to a group in which a boron atom is bonded to the alkyl group or the aryl group as defined above. The boron group includes an alkyl boron group and an aryl boron group. Examples of the boron group may include a dimethylboron group, a trimethylboron group, a t-butyldimethylboron group, a diphenylboron group, a phenylboron group, etc., but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but the embodiment of the present disclosure is not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described above.

In the specification, the aryl group among an aryloxy group, an arylthio group, an arylsulfoxy group, an arylamino group, an arylboron group, an arylsilyl group, an arylamine group is the same as the examples of the aryl group described above.

In the specification, a direct linkage may refer to a single bond.

In some embodiments, in the specification, “ [symbol] ” and “ [symbol] ” refer to a position to be connected (e.g., a bonding site).

Hereinafter, embodiments of the present disclosure will be described with reference to the accompanying drawings.

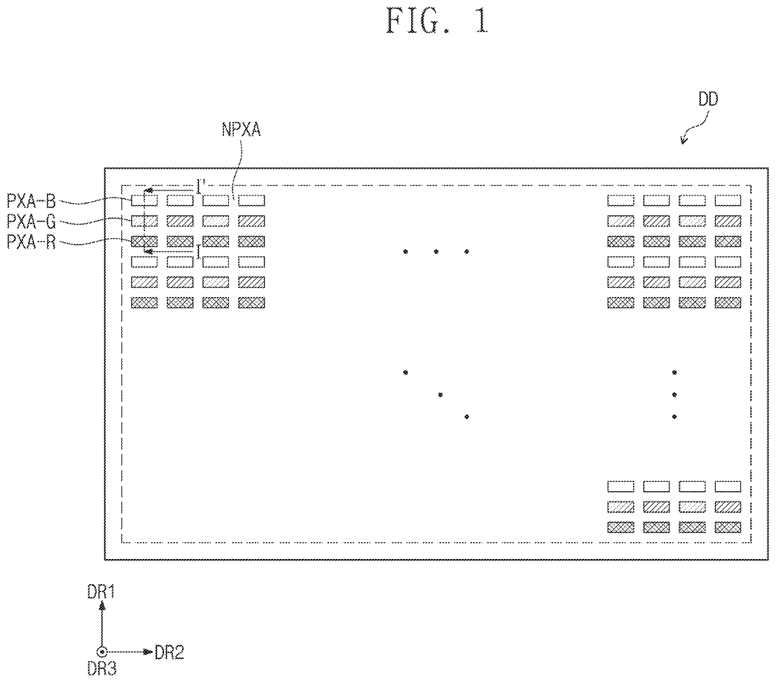

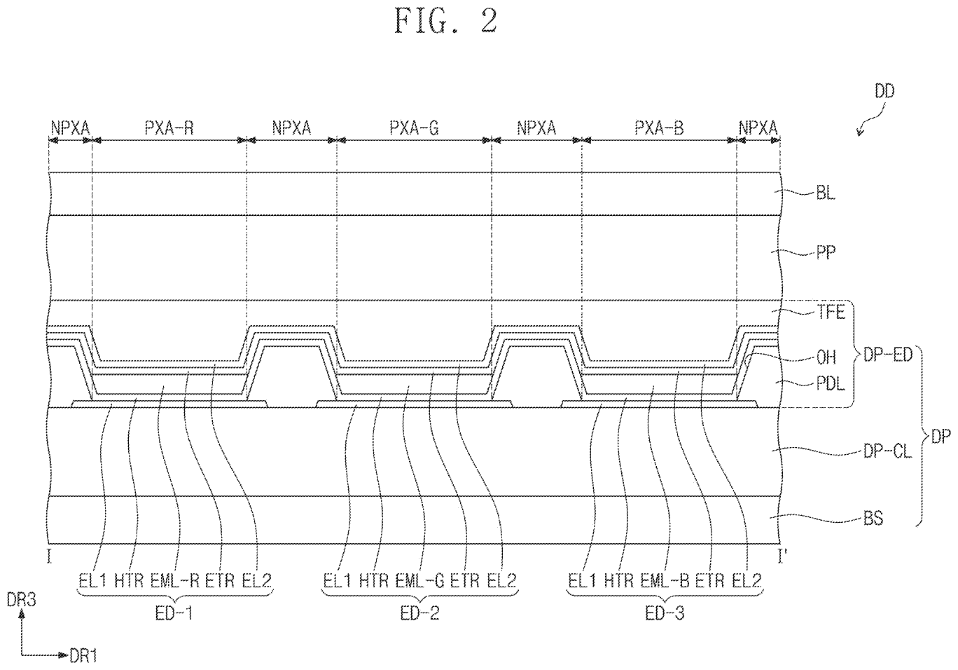

FIG. 1 is a plan view illustrating one or more embodiments of a display apparatus DD. FIG. 2 is a cross-sectional view of the display apparatus DD of the one or more embodiments. FIG. 2 is a cross-sectional view illustrating a part taken along line I-I′ of FIG. 1.

The display apparatus DD may include a display panel DP and an optical layer PP provided on the display panel DP. The display panel DP includes light emitting elements ED-1, ED-2, and ED-3. The display apparatus DD may include a plurality of light emitting elements ED-1, ED-2, and ED-3. The optical layer PP may be provided on the display panel DP to control reflected light in the display panel DP due to external light. The optical layer PP may include, for example, a polarization layer and/or a color filter layer. In some embodiments, unlike the configuration illustrated in the drawing, the optical layer PP may not be provided in the display apparatus DD of one or more embodiments.

A base substrate BL may be provided on the optical layer PP. The base substrate BL may be a member which provides a base surface on which the optical layer PP provided. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, unlike the configuration illustrated, the base substrate BL may not be provided.

The display apparatus DD according to one or more embodiments may further include a filling layer. The filling layer may be provided between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining layer PDL, the light emitting elements ED-1, ED-2, and ED-3 provided between portions of the pixel defining layer PDL, and an encapsulation layer TFE provided on the light emitting elements ED-1, ED-2, and ED-3.

The base layer BS may be a member which provides a base surface on which the display device layer DP-ED is provided. The base layer BS may be a glass substrate, a metal substrate, a plastic substrate, etc. However, the embodiment is not limited thereto, and the base layer BS may be an inorganic layer, an organic layer, or a composite material layer.

In one or more embodiments, the circuit layer DP-CL is provided on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display device layer DP-ED.

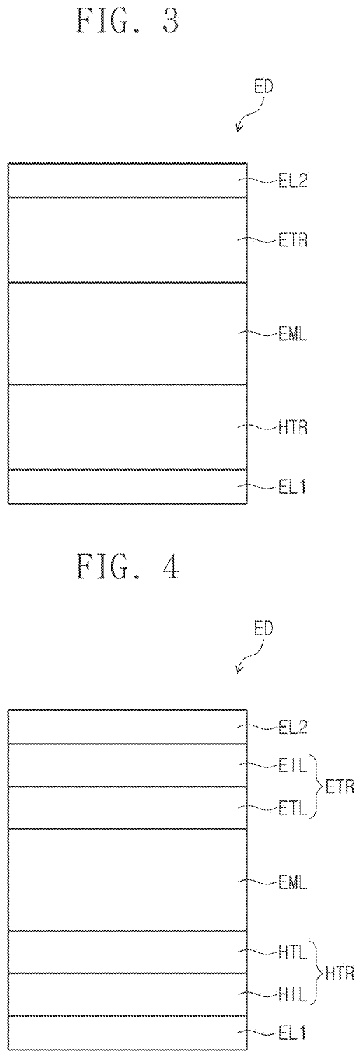

Each of the light emitting elements ED-1, ED-2, and ED-3 may have a structure of the light emitting element ED of embodiments according to FIGS. 3 to 7, which will be described in more detail hereinbelow. Each of the light emitting elements ED-1, ED-2, and ED-3 may include a first electrode EL1, a hole transport region HTR, a corresponding one of the emission layers EML-R, EML-G, and EML-B, respectively, an electron transport region ETR, and a second electrode EL2.

FIG. 2 illustrates one or more embodiments in which the emission layers EML-R, EML-G, and EML-B of the light emitting elements ED-1, ED-2, and ED-3 are provided in openings OH defined in the pixel defining layer PDL, and the hole transport region HTR, the electron transport region ETR, and the second electrode EL2 are provided as a common layer in (e.g., along) the entire light emitting elements ED-1, ED-2, and ED-3. However, the embodiment of the present disclosure is not limited thereto, and unlike the configuration illustrated in FIG. 2, the hole transport region HTR and the electron transport region ETR in one or more embodiments may be provided by being patterned inside the openings OH defined in the pixel defining layer PDL. For example, the hole transport region HTR, the emission layers EML-R, EML-G, and EML-B, and the electron transport region ETR of the light emitting elements ED-1, ED-2, and ED-3 in one or more embodiments may be provided by being patterned in an inkjet printing method.

The encapsulation layer TFE may cover the light emitting elements ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be provided on the second electrode EL2 and may be provided filling the opening OH.

Referring to FIGS. 1 and 2, the display apparatus DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2, and ED-3 is emitted. The light emitting regions PXA-R, PXA-G, and PXA-B may be spaced apart from each other on a plane (e.g., in plan view).

Each of the light emitting regions PXA-R, PXA-G, and PXA-B may be a region divided by the pixel defining layer PDL. The non-light emitting areas NPXA may be areas between the adjacent light emitting areas PXA-R, PXA-G, and PXA-B, which correspond to the pixel defining layer PDL. In some embodiments, in the specification, the light emitting regions PXA-R, PXA-G, and PXA-B may respectively correspond to pixels. The pixel defining layer PDL may divide the light emitting elements ED-1, ED-2, and ED-3. The emission layers EML-R, EML-G, and EML-B of the light emitting elements ED-1, ED-2, and ED-3 may be provided in openings OH defined in the pixel defining layer PDL and separated from each other.

The light emitting regions PXA-R, PXA-G, and PXA-B may be divided into a plurality of groups according to the color of light generated from the light emitting elements ED-1, ED-2, and ED-3. In the display apparatus DD of one or more embodiments illustrated in FIGS. 1 and 2, three light emitting regions PXA-R, PXA-G, and PXA-B, which emit red light, green light, and blue light, respectively, are exemplarily illustrated. For example, the display device DD of one or more embodiments may include the red light emitting region (e.g., a region configured to emit red light) PXA-R, the green light emitting region (e.g., a region configured to emit green light) PXA-G, and the blue light emitting region (e.g., a region configured to emit blue light) PXA-B that are separated from each other.

In the display apparatus DD according to one or more embodiments, the plurality of light emitting elements ED-1, ED-2 and ED-3 may be to emit light beams having wavelengths different from each other. For example, in one or more embodiments, the display apparatus DD may include a first light emitting element ED-1 that emits (e.g., is to emit) red light, a second light emitting element ED-2 that emits (e.g., is to emit) green light, and a third light emitting element ED-3 that emits (e.g., is to emit) blue light. For example, the red light emitting region PXA-R, the green light emitting region PXA-G, and the blue light emitting region PXA-B of the display apparatus DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2, and ED-3 may be to emit light beams in substantially the same wavelength range or at least one light emitting element may be to emit a light beam in a wavelength range different from the others. For example, the first to third light emitting elements ED-1, ED-2, and ED-3 may all emit blue light.

The light emitting regions PXA-R, PXA-G, and PXA-B in the display apparatus DD according to one or more embodiments may be arranged in a stripe form or pattern. Referring to FIG. 1, the plurality of red light emitting regions PXA-R may be arranged with each other along a second directional axis DR2, the plurality of green light emitting regions PXA-G may be arranged with each other along a second directional axis DR2, and the plurality of blue light emitting regions PXA-B may be arranged with each other along a second directional axis DR2. In some embodiments, the red light emitting region PXA-R, the green light emitting region PXA-G, and the blue light emitting region PXA-B may be alternately arranged with each other and in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2 (e.g., in a plan view).

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display apparatus DD. For example, the arrangement form of the light emitting regions PXA-R, PXA-G, and PXA-B may be a pentile (PENTILE®) arrangement form and/or a diamond (Diamond Pixel™) arrangement form (PENTILE® is a registered trademark owned by Samsung Display Co., Ltd.).

In some embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but the embodiment of the present disclosure is not limited thereto.

Hereinafter, FIGS. 3 to 7 are cross-sectional views schematically illustrating a light-emitting element according to one or more embodiments. A light-emitting element ED according to one or more embodiments may include a first electrode EL1, a hole transport region HTR, a emission layer EML, an electron transport region ETR, and a second electrode EL2, which are sequentially stacked.

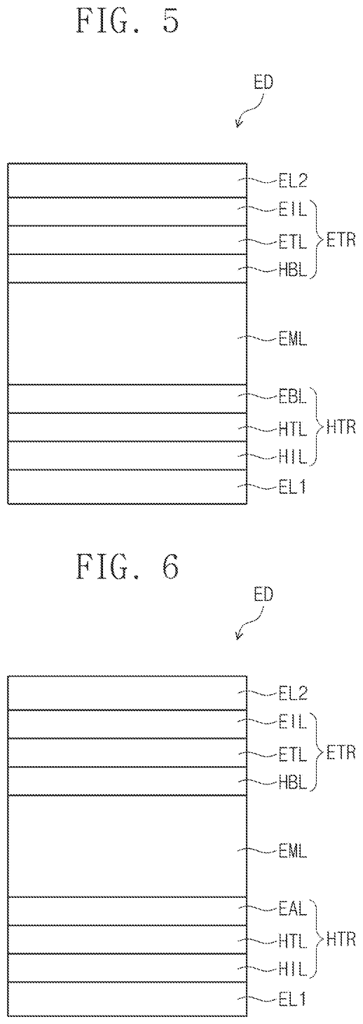

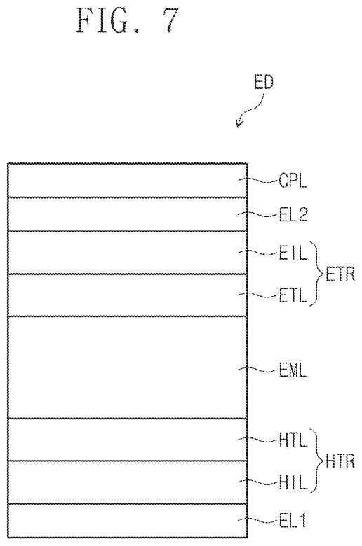

Compared with FIG. 3, FIG. 4 illustrates a cross-sectional view of a light-emitting element ED according to one or more embodiments in which a hole transport region HTR includes a hole injection layer HIL and a hole transport layer HTL, and an electron transport region ETR includes an electron injection layer EIL, and an electron transport layer ETL. In some embodiments, compared with FIG. 3, FIG. 5 illustrates a cross-sectional view of a light-emitting element ED according to one or more embodiments in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 3, FIG. 6 illustrates a cross-sectional view of a light-emitting element ED according to one or more embodiments in which a hole transport region HTR includes a hole injection layer HIL, a hole transport layer HTL, and a light-emitting auxiliary layer EAL, and an electron transport region ETR includes an electron injection layer EIL an electron transport layer ETL, and a hole blocking layer HBL. Compared with FIG. 4, FIG. 7 illustrates a cross-sectional view of a light-emitting element ED according to one or more embodiments including a capping layer CPL provided on a second electrode EL2.

The first electrode EL1 may have conductivity (e.g., may be a conductor). The first electrode EL1 may be formed of a metal material, a metal alloy, and/or a suitable conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transfiective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these (thereof), a mixture of two or more selected from among these, and an oxide thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transfiective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), UF/AI (a stacked structure of LiF and Al), Mo, Ti, W, a compound or mixture thereof (e.g., a mixture of Ag and Mg). In some embodiments, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but the embodiment of the present disclosure is not limited thereto. In some embodiments, the embodiment of the present disclosure is not limited thereto, and the first electrode EL1 may include the any of above-described metal materials, one or more combinations of at least two metal materials of the above-described metal materials, one or more oxides of the above-described metal materials, and/or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, an emission-auxiliary layer EAL, or an electron blocking layer EBL. The thickness of the hole transport region HTR may be, for example, from about 50 Å to about 15,000 Å. The light emission-auxiliary layer EAL may also be referred to as a buffer layer.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/emission-auxiliary layer EAL, a hole injection layer HIL/emission-auxiliary layer EAL, a hole transport layer HTL/emission-auxiliary layer EAL, a hole injection layer HIL/hole transport layer HTL/emission-auxiliary layer EAL, or a hole injection layer HIL/hole transport layer HTL/electron blocking layer EBL are stacked in order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1:

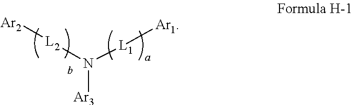

In Formula H-1 above, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of respective ones of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 above may be a monoamine compound. In some embodiments, the compound represented by Formula H-2 above may be a diamine compound in which at least one selected from among Ar₁ to Ar₃ includes the amine group as a substituent. In some embodiments, the compound represented by Formula H-1 above may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one selected from among the compounds in Compound Group H. However, the compounds listed in Compound Group H are examples, and the compounds represented by Formula H-1 are not limited to those represented by Compound Group H:

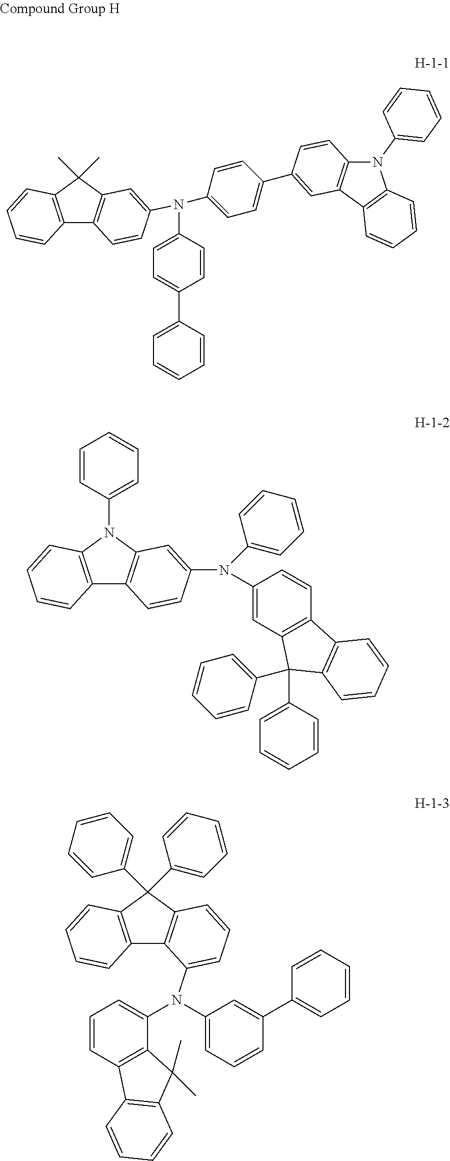 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

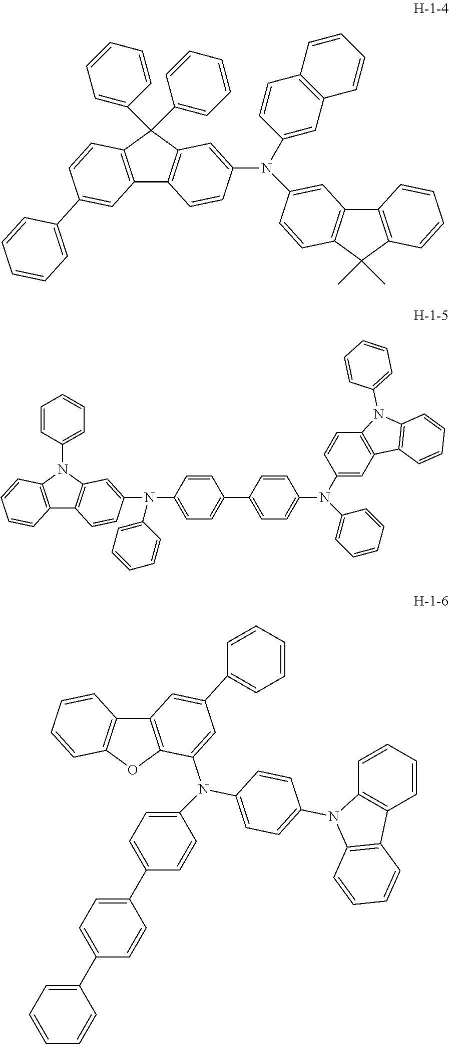 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

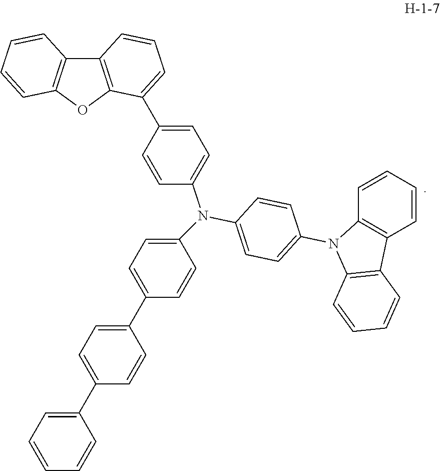 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

The hole transport region HTR may include a phthalocyanine compound (such as copper phthalocyanine); N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative (such as N-phenyl carbazole and/or polyvinyl carbazole), a fluorene-based derivative, a triphenylamine-based derivative (such as N,N′-bis(3-methylphenyl)-N,N′-diphenyl-[1,1-biphenyl]-4,4′-diamine (TPD) and/or 4,4′,4″-tris(N-carbazolyl)triphenylamine (TCTA)), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, an emission-auxiliary layer EAL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and/or the electron blocking layer EBL satisfy any of their respective above-described ranges, satisfactory or suitable hole transport properties may be achieved without a substantial increase in driving voltage.

The hole transport region HTR may further include a charge generating material to increase conductivity, in addition to the above-described materials. The charge generating material may be dispersed substantially uniformly or substantially non-uniformly in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound (such as CuI and/or RbI), a quinone derivative (such as tetracyanoquinodimethane (TCNQ) and/or 2,3,5,6-tetrafluoro-7,7′8,8-tetracyanoquinodimethane (F4-TCNQ)), a metal oxide (such as tungsten oxide and/or molybdenum oxide), a cyano group-containing compound (such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9)), etc., but the embodiment of the present disclosure is not limited thereto.

As described above, the hole transport region HTR may further include at least one of a light-emitting auxiliary layer EAL or an electron blocking layer EBL, in addition to the hole injection layer HIL and the hole transport layer HTL. The light-emitting auxiliary layer EAL may compensate for a resonance distance according to the wavelength of light emitted from the emission layer EML and may control a hole charge balance, thereby increasing light emission efficiency. In some embodiments, the light-emitting auxiliary layer EAL may also serve to prevent or reduce the injection of electrons into the hole transport region HTR. The light-emitting auxiliary layer EAL may include a material that may be included in the hole transport region HTR. The electron blocking layer EBL may be a layer that serves to prevent or reduce injection of electrons from the electron transport region ETR to the hole transport region HTR.

In the light-emitting element ED according to one or more embodiments, the emission layer EML may include a polycyclic compound according to one or more embodiments. In the light-emitting element ED according to one or more embodiments, the emission layer EML may include a first compound, which is a polycyclic compound, and at least one compound of a second compound or a third compound. In some embodiments, in the light-emitting element ED according to one or more embodiments, the emission layer EML may further include a fourth compound. The second compound may include a fused ring (or structure) of three rings, containing a nitrogen atom as at least one ring-forming atom. The third compound may include a hexagonal ring group containing at least one nitrogen atom as a ring-forming atom. The fourth compound may include an organometallic complex. The second to fourth compounds will be described in more detail hereinbelow.

As utilized herein, the first compound may be referred to as a polycyclic compound according to one or more embodiments. The polycyclic compound according to one or more embodiments includes, as a central structure, a fused ring of five rings containing two nitrogen (N) atoms and one boron (B) atom as ring-forming atoms. In some embodiments, the polycyclic compound according to one or more embodiments includes two carbazole groups and two terphenyl groups bonded to the central structure of the fused ring of five rings, and in this case, at least one carbazole group among the two carbazole groups may further include at least one aromatic group as a substituent.

For example, in the central structure of the fused ring of five rings in the polycyclic compound according to one or more embodiments, two benzene rings, each containing a carbon atom at a para-position with respect to a ring-forming boron atom, may each be substituted with a carbazole derivative. In some embodiments, two nitrogen atoms in the central structure of the fused ring of five rings may each be substituted with a terphenyl derivative. For example, in the polycyclic compound according to one or more embodiments, at least one of two carbazole derivatives substituted in the central structure of the fused ring of five rings may be substituted with an aromatic group of an aryl group and/or a heteroaryl group. The polycyclic compound according to one or more embodiments may further include an aromatic group additionally substituted in the carbazole derivative substituted in the central structure of the fused ring, and may thus exhibit characteristics of reduced energy level in a higher triplet state (Tn) through conjugation expansion.

In some embodiments, in the polycyclic compound according to one or more embodiments, material deterioration caused by high-energy triplet excitons is mitigated or reduced due to decrease in energy level in the higher triplet state (Tn), and thus improved characteristics of material stability may be exhibited. For example, the polycyclic compound according to one or more embodiments further includes an additional aromatic substituent, and thus has similar energy levels in S1 state and T1 state with a polycyclic compound having a structure in which an aromatic substituent is not added, and also exhibits relatively lower energy levels in T2 state and T3 state than a polycyclic compound having a structure in which an aromatic substituent is not added. Therefore, in the polycyclic compound according to one or more embodiments, migration between triplet states is facilitated, and therefore a speed of reverse inter system crossing (RISC), at which excitons in the T1 state change to the S1 state via the T2 or T3 state, may be improved. Therefore, the material stability of the polycyclic compound itself may be improved and a lifespan of the light-emitting element including the same may be improved due to reduction in the density of triplet excitons.

The light-emitting element ED according to one or more embodiments may include the polycyclic compound according to one or more embodiments. The polycyclic compound according to one or more embodiments may be represented by Formula 1.

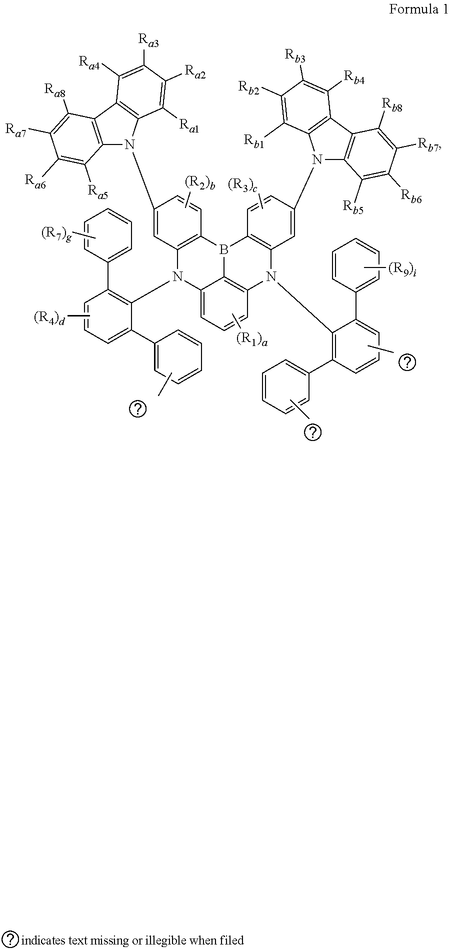

where, in Formula 1, at least one selected from among Rₐ₁ to Rₐ₈, and R_{b1} to R_{b8} may be a substituted or unsubstituted aryl group having 6 to 60 ring-forming carbon atoms or a substituted or unsubstituted heteroaryl group having 2 to 60 ring-forming carbon atoms. In some embodiments, the rest other than an aryl group or a heteroaryl group among Rₐ₁ to Rₐ₈, and R_{b1} to R_{b8}, may each independently be a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, or a substituted or unsubstituted alkenyl group having 2 to 60 carbon atoms.

For example, in one or more embodiments, at least one selected from among Rₐ₁ to Rₐ₈, and R_{b1} to R_{b8} may be a substituted or unsubstituted aryl group having 6 to 30 ring-forming carbon atoms, or a substituted or unsubstituted heteroaryl group having 2 to 30 ring-forming carbon atoms. For example, in the polycyclic compound according to one or more embodiments, at least one selected from among Rₐ₁ to Rₐ₈, and R_{b1} to R_{b8} may be a substituted or unsubstituted phenyl group, a substituted or unsubstituted biphenyl group, a substituted or unsubstituted terphenyl group, a substituted or unsubstituted naphthyl group, a substituted or unsubstituted phenanthrene group, a substituted or unsubstituted pyrene group, or a substituted or unsubstituted dibenzoheterol group, containing N, O, and/or S as a ring-forming atom. In some embodiments, in the substituted or unsubstituted phenyl group, the substituted or unsubstituted biphenyl group, the substituted or unsubstituted terphenyl group, the substituted or unsubstituted naphthyl group, the substituted or unsubstituted phenanthrene group, the substituted or unsubstituted pyrene group, or the substituted or unsubstituted dibenzoheterol group, a substituent may be a deuterium atom, a halogen atom, a cyano group, a nitro group, an alkyl group having 1 to 10 carbon atoms, a cycloalkyl group having 3 to 10 carbon atoms, and/or a substituted or unsubstituted aryl group having 6 to 20 ring-forming carbon atoms.

For example, in the polycyclic compound, represented by Formula 1, according to one or more embodiments, at least one selected from among Rₐ₁ to Rₐ₈, and R_{b1} to R_{b8} may be represented by any one among FG-a to FG-h:

where, in FG-a to FG-d, R_{X1} to R_{X5}, R_{Y1} to R_{Y9}, and R_{Z1} to R_{Z13} may each

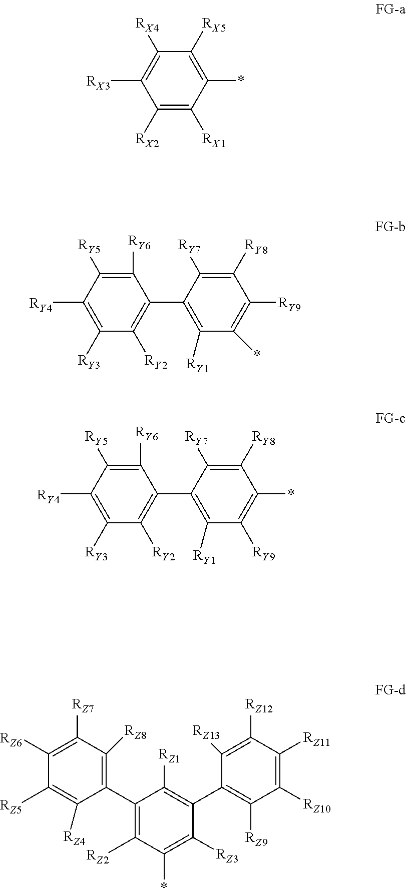

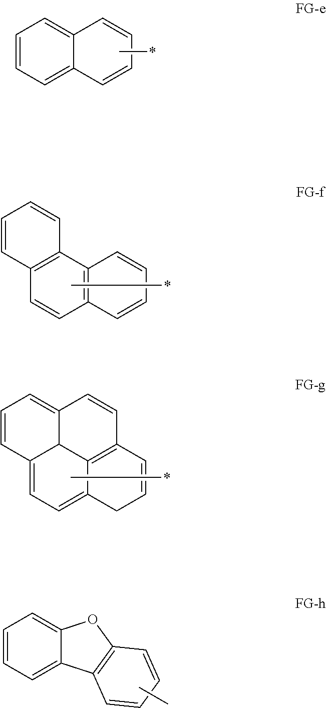

independently be a hydrogen atom, a deuterium atom, a cyano group, or a t-butyl group, and in FG-h, Q is O, S, NH, or NPh, where Ph is a phenyl group.

However, a type or kind of an aromatic substituent additionally substituted with (e.g., on) a carbazole group of the polycyclic compound according to one or more embodiments is not limited to FG-a to FG-d, and any suitable aryl group or heteroaryl group expanding a conjugation of the carbazole group in the range in which the effect on the light-emitting wavelength of the polycyclic compound according to one or more embodiments is suitably minimized or reduced may be utilized without limitation.

In some embodiments, in the polycyclic compound represented by Formula 1, according to one or more embodiments, Rₐ₁ to Rₐ₈, and R_{b1} to R_{b8} (other than an aryl group or a hetero aryl group, which is an aromatic substituent), may each independently be a hydrogen atom, a deuterium atom, a halogen atom, a cyano group, a nitro group, a substituted or unsubstituted silyl group, a substituted or unsubstituted amino group, a substituted or unsubstituted alkyl group having 1 to 10 carbon atoms, a substituted or unsubstituted cycloalkyl group having 3 to 100 carbon atoms, a substituted or unsubstituted alkoxy group having 1 to 10 carbon atoms, a substituted or unsubstituted alkenyl group having 2 to 100 carbon atoms. For example, in the polycyclic compound according to one or more embodiments, Rₐ₁ to Rₐ₈, and R_{b1} to R_{b8} other than an aryl group or a hetero aryl group, which is an aromatic substituent, may each independently be a hydrogen atom, or a deuterium atom.

In Formula 1, a to e may each independently be an integer of 1 to 3, and f to i may each independently be an integer of 1 to 5. In some embodiments, R₁ to R₉ may each independently be a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms. For example, R₁ to R₉ may each independently be a hydrogen atom, a deuterium atom, a halogen atom, a cyano group, a nitro group, a substituted or unsubstituted silyl group, a substituted or unsubstituted amino group, a substituted or unsubstituted alkyl group having 1 to 10 carbon atoms, a substituted or unsubstituted cycloalkyl group having 3 to 10 carbon atoms, a substituted or unsubstituted alkoxy group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms.

In some embodiments, when a is an integer of 2 or more, all of a plurality of R₁ may be the same or at least one thereof may be different from the others. For example, when a is 3, R₁ bonded to a carbon atom at a para-position with respect to a boron atom in the central structure of a fused ring of five rings may be a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms, and all of two of the remaining R₁ bonded to the rest (other) carbon atoms may be hydrogen atom or deuterium atom. However, one or more embodiments of the present disclosure is not limited thereto, and numbers and types (kinds) of substituted R₁ may suitably vary according to examples of a polycyclic compound.

In some embodiments, as same as described above, when b to i are integers of 2 or more, all of a plurality of R₂ to R₉ may be the same, or at least one thereof may be different from the others.

In the polycyclic compound, represented by Formula 1, according to one or more embodiments, at least one hydrogen atom may be substituted with a deuterium atom. In one or more embodiments, at least one hydrogen atom of Rₐ₁ to Rₐ₈, R_{b1} to R_{b8}, or R₁ to R₃ in Formula 1 may be substituted with a deuterium atom. For example, Rₐ₁ to Rₐ₈, and R_{b1} to R_{b8} that are not an aryl group or a heteroaryl group may be a deuterium atom or a substituent including a deuterium atom, and R₁ to R₃ may also be a deuterium atom or a substituent including a deuterium atom.

The polycyclic compound according to one or more embodiments may include an aryl group or a heteroaryl group in at least one selected from among Rₐ₁ to Rₐ₈, and R_{b1} to R_{b8}, bonded to a carbazole group. For example, one to four selected from among Rₐ₁ to Rₐ₈ and R_{b1} to R_{b8} may be an aromatic substituent of an aryl group or a heteroaryl group.

The polycyclic compound represented by Formula 1, according to one or more embodiments, may be represented by Formulae 1-1 to 1-4.

Formulae 1-1 to 1-4 represent the polycyclic compounds having different numbers of aromatic substituents and different bonding positions of the aromatic substituents substituted at the carbazole group(s) of the compound of Formula 1. In Formulae 1-1 to 1-4, FG₁₁, FG₁₂, FG₂₁, and FG₂₂ correspond to aromatic substituents substituted at a carbazole group.

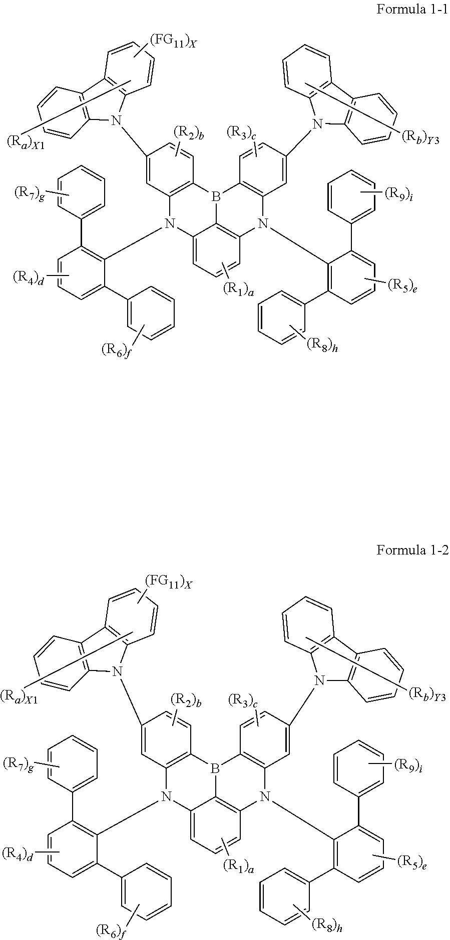

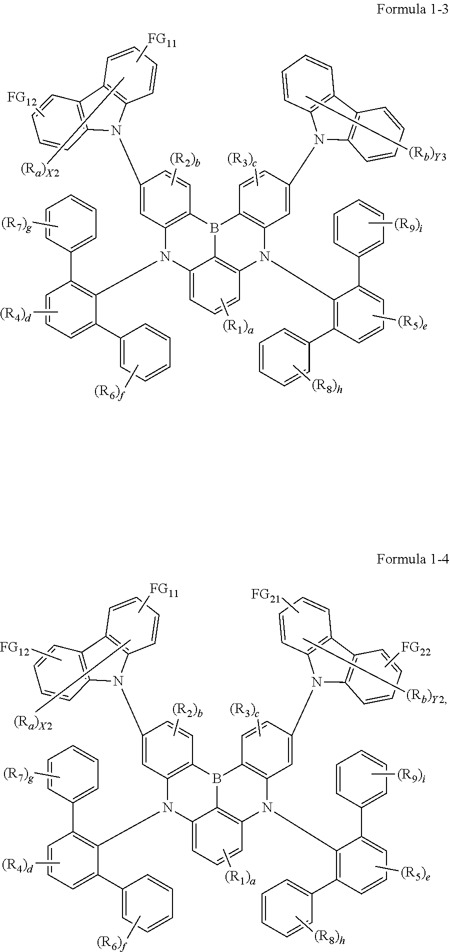

where, in Formulae 1-1 to 1-4, FG₁₁, FG₁₂, FG₂₁, and FG₂₂ may each independently be a substituted or unsubstituted aryl group having 6 to 60 ring-forming carbon atoms, or a substituted or unsubstituted heteroaryl group having 2 to 60 ring-forming carbon atoms. For example, FG₁₁, FG₁₂, FG₂₁, and FG₂₂ may each independently be a substituted or unsubstituted phenyl group, a substituted or unsubstituted biphenyl group, a substituted or unsubstituted terphenyl group, a substituted or unsubstituted naphthyl group, a substituted or unsubstituted phenanthrene group, a substituted or unsubstituted pyrene group, or a substituted or unsubstituted dibenzoheterol group, containing N, O, and/or S as a ring-forming atom.

For example, FG₁₁, FG₁₂, FG₂₁, and FG₂₂ may each independently be represented by any one selected from among FG-a to FG-h:

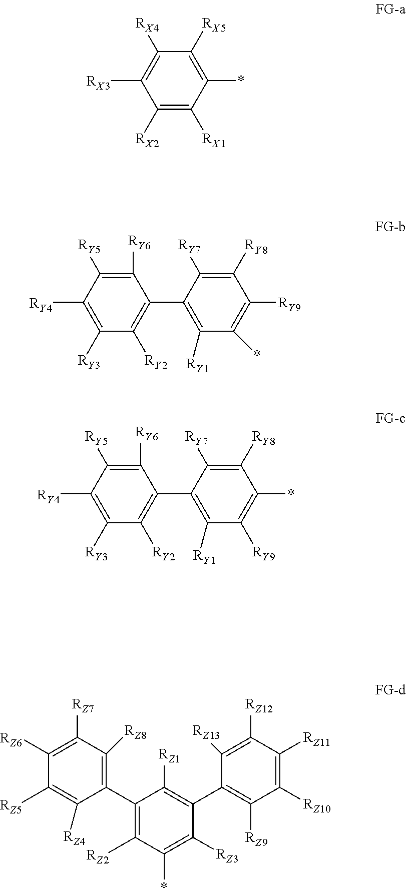

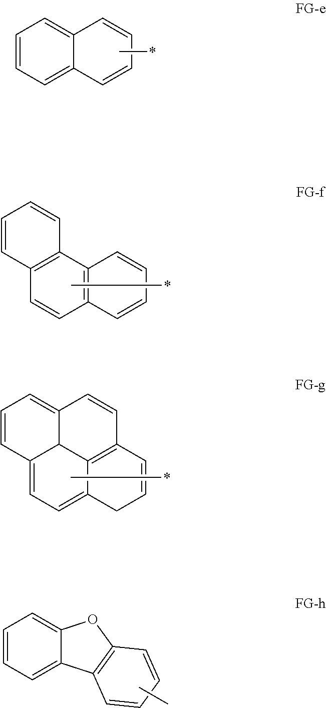

where, in FG-a to FG-d, R_{X1} to R_{X5}, R_{Y1} to R_{Y9}, and R_{Z1} to R_{Z13} may each independently be a hydrogen atom, a deuterium atom, a cyano group, a t-butyl group, and in FG-h, Q is O, S, NH, or NPh, where Ph is a phenyl group.

However, FG₁₁, FG₁₂, FG₂₁, and FG₂₂ are not limited to FG-a to FG-d, and any suitable aryl group or heteroaryl group may be utilized as long as there is suitable expansion of a conjugation of a carbazole group in a range in which the effect on the light-emitting wavelength of the polycyclic compound according to one or more embodiments is minimized or reduced.

In Formulae 1-1 to 1-4, X and Y may each be 1 or 2, X1 may be an integer of 1 to (8-X), and Y1 may be an integer of 1 to (8-Y). In some embodiments, X2 and Y2 may each independently be an integer of 1 to 6, and X3 and Y3 may each independently be an integer of 1 to 8.

For example, in Formula 1-1, when X is 1, X1 may be an integer of 1 to 7, and when X is 2, X1 may be an integer of 1 to 6. For example, the polycyclic compound represented by Formula 1-1 may include one or two FG₁₁, which is an aromatic substituent substituted at a carbazole group. In the polycyclic compound represented by Formula 1-1, when X is 2, two FG₁₁ substituents may be substituted at the same benzene ring of a carbazole group. In some embodiments, in Formula 1-1, a plurality of Rₐ bonded to other carbon atoms of the carbazole group, which is not substituted with FG₁₁, may each independently be a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, or a substituted or unsubstituted alkenyl group having 2 to 60 carbon atoms.

In some embodiments, in the polycyclic compound in Formula 1-1, Y3 may be an integer of 1 to 8, and R_{b} may each independently be a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, or a substituted or unsubstituted alkenyl group having 2 to 60 carbon atoms. When Y3 is an integer of 2 or more, all of a plurality of R_{b} may be the same, or at least one thereof may be different from the others.

In Formula 1-2, when X is 1, X1 may be an integer of 1 to 7, and when X is 2, X1 may be an integer of 1 to 6. In some embodiments, in Formula 1-2, when Y is 1, Y1 may be an integer of 1 to 7, and when Y is 2, Y1 may be an integer of 1 to 6. For example, the polycyclic compound represented by Formula 1-2 may include one or two FG₁₁, and one or two FG₂₁, which are aromatic substituents substituted at a carbazole group. In the polycyclic compound represented by Formula 1-2, when X is 2, two FG₁₁ substituents may be substituted at the same benzene ring of a carbazole group. In some embodiments, when Y is 2, two FG₂₁ substituents may be substituted at the same benzene ring of a carbazole group.

The polycyclic compound represented by Formula 1-2 according to one or more embodiments may include two to four aromatic substituents additionally substituted at a carbazole group. In some embodiments, FG₁₁ and FG₂₁ may be the same as or different from each other, and all of a plurality of FG₁₁ and a plurality of FG₂₁ may be the same or at least one thereof may be different from the others.

In some embodiments, in Formula 1-2, a plurality of Rₐ and R_{b} bonded to other carbon atoms of carbazole, which are not substituted with FG₁₁ and/or FG₂₁, may each independently be a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, or a substituted or unsubstituted alkenyl group having 2 to 60 carbon atoms.

In some embodiments, in the polycyclic compound in Formula 1-2, all of a plurality of Rₐ and a plurality of R_{b} may be the same or at least one thereof may be different from the others.

A polycyclic compound represented by Formula 1-3 according to one or more embodiments, may include FG₁₁ and FG₁₂, which are aromatic substituent substituted at a carbazole group. For example, the polycyclic compound of one or more embodiments may include two of aromatic substituents substituted at a carbazole group, and FG₁₁ and FG₁₂, which are two aromatic substituents, may be respectively substituted at different benzene rings in one carbazole group. FG₁₁ and FG₁₂ may be the same as or different from each other.

In some embodiments, in Formula 1-3, X2 may be an integer of 1 to 6. In some embodiments, Y3 may be an integer of 1 to 8. Rₐ and R_{b} may each independently be a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, a substituted or unsubstituted alkenyl group having 2 to 60 carbon atoms. When Rₐ and R_{b} are an integer of 2 or more, all of a plurality of Rₐ and R_{b} may be the same, or at least one thereof may be different from the others.

A polycyclic compound represented by Formula 1-4 according to one or more embodiments, may include FG₁₁, FG₁₂, FG₂₁, and FG₂₂, which are aromatic substituents substituted at a carbazole group. For example, the polycyclic compound according to one or more embodiments may include four aromatic substituents substituted at a carbazole group, and FG₁₁, FG₁₂, FG₂₁, and FG₂₂, which are four aromatic substituents, may be respectively substituted at different benzene rings in two carbazole groups. FG₁₁, FG₁₂, FG₂₁, and FG₂₂ may be the same as or different from each other.

In some embodiments, in Formula 1-4, X2 and Y2 may each independently be an integer of 1 to 6. In some embodiments, Rₐ and R_{b} may each independently be a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, a substituted or unsubstituted alkenyl group having 2 to 60 carbon atoms. When Rₐ and R_{b} are 2 or more, a plurality of Rₐ and R_{b} may be all the same, or at least one thereof may be different from the others.

In Formulae 1-1 to 1-4, the same descriptions as provided in Formula 1 above may be similarly applied to a to i, and R₁ to R₉.

In one or more embodiments, the polycyclic compound in Formula 1 may be represented by Formula 2.

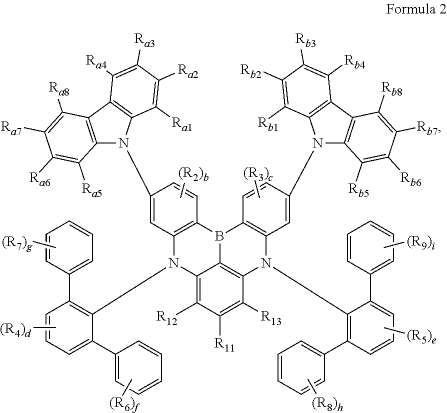

where, in Formula 2, R₁₁ may be a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, a substituted or unsubstituted alkenyl group having 2 to 60 carbon atoms, a substituted or unsubstituted aryl group of 6 to 60 ring-forming carbon atoms, or a substituted or unsubstituted heteroaryl group having 2 to 60 ring-forming carbon atoms. In some embodiments, R₁₂ and R₁₃ may each independently be a hydrogen atom or a deuterium atom.

For example, R₁₁ may be a hydrogen atom, a deuterium atom, a halogen atom, a cyano group, a nitro group, a substituted or unsubstituted silyl group, a substituted or unsubstituted amino group, a substituted or unsubstituted alkyl group having 1 to 10 carbon atoms, a substituted or unsubstituted cycloalkyl group having 3 to 10 carbon atoms, a substituted or unsubstituted alkoxy group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and R₁₂ and R₁₃ may be each independently a hydrogen atom or a deuterium atom.

In the polycyclic compound represented by Formula 2, according to one or more embodiments, the same descriptions as provided in Formula 1 above may be similarly applied to Rₐ₁ to Rₐ₈, R_{b1} to R_{b8}, b to i, and R₂ to R₉.

The polycyclic compound according to one or more embodiments may be represented by any one selected from among compounds in Compound Group 1. A light-emitting element ED according to one or more embodiments may include at least one selected from among compounds in Compound Group 1. In Compound Group 1, D is a deuterium atom.

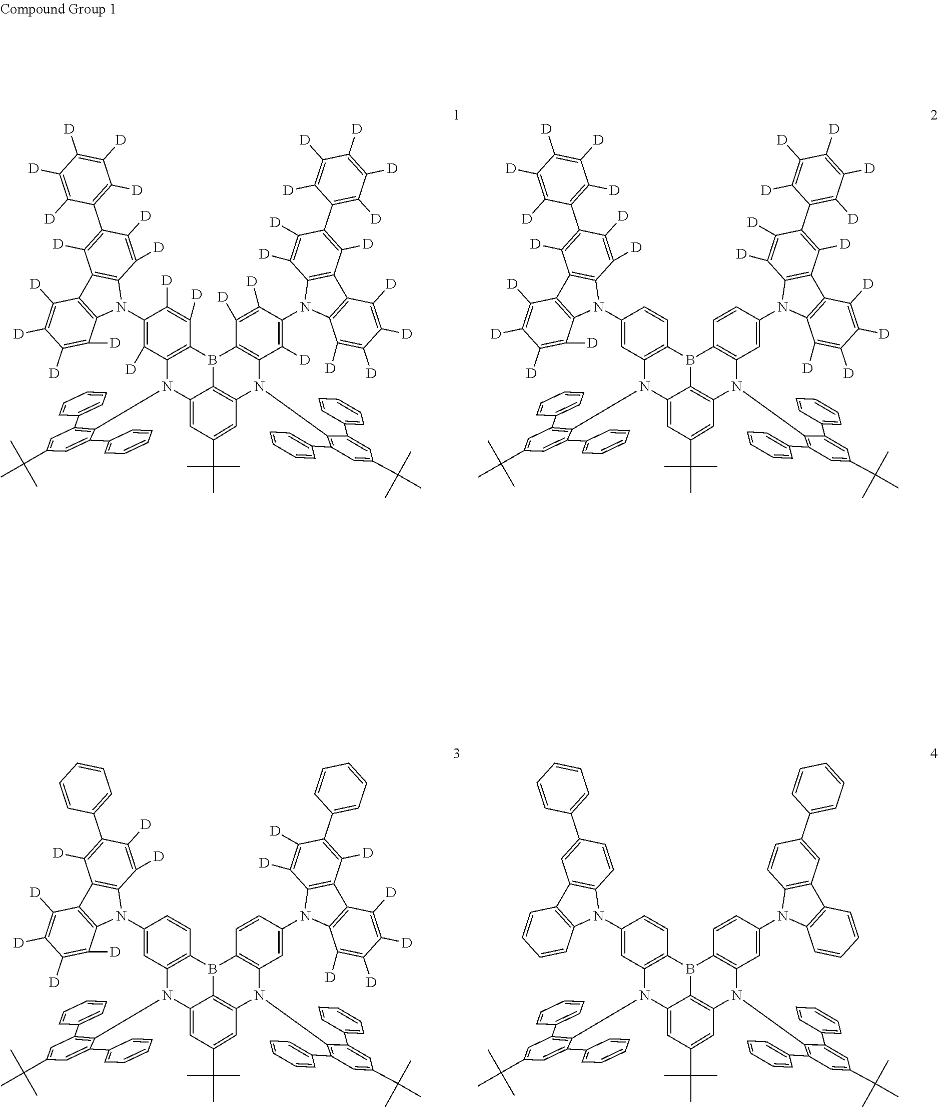

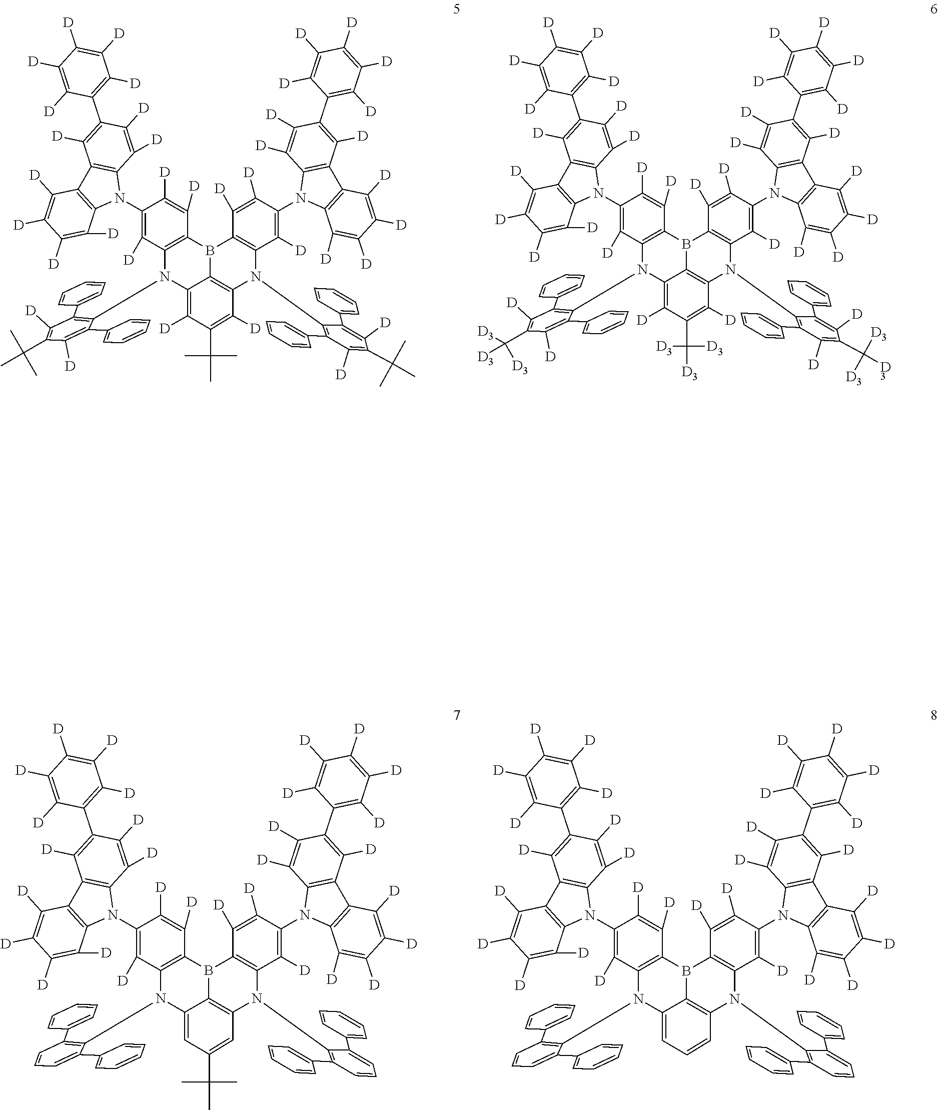

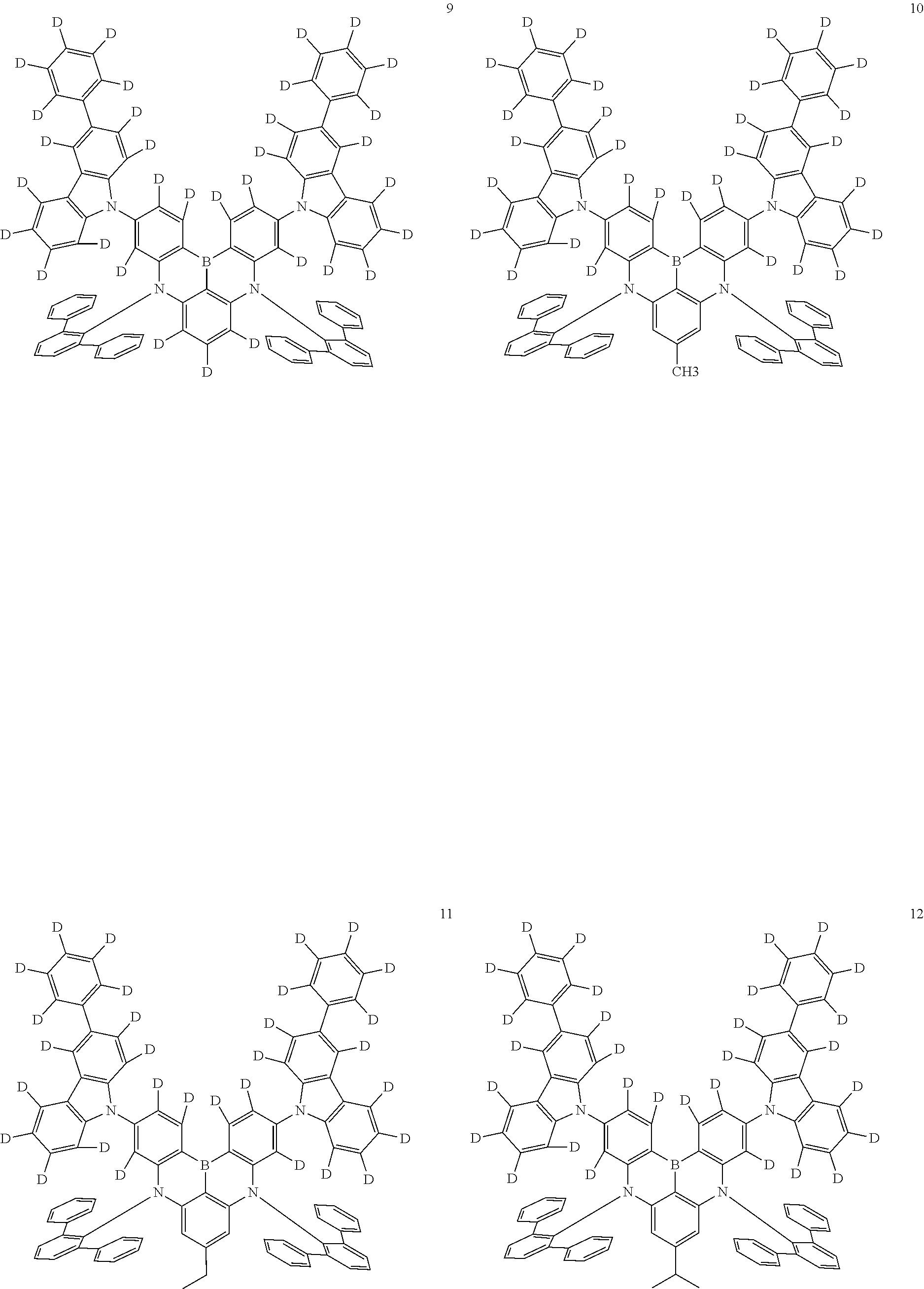

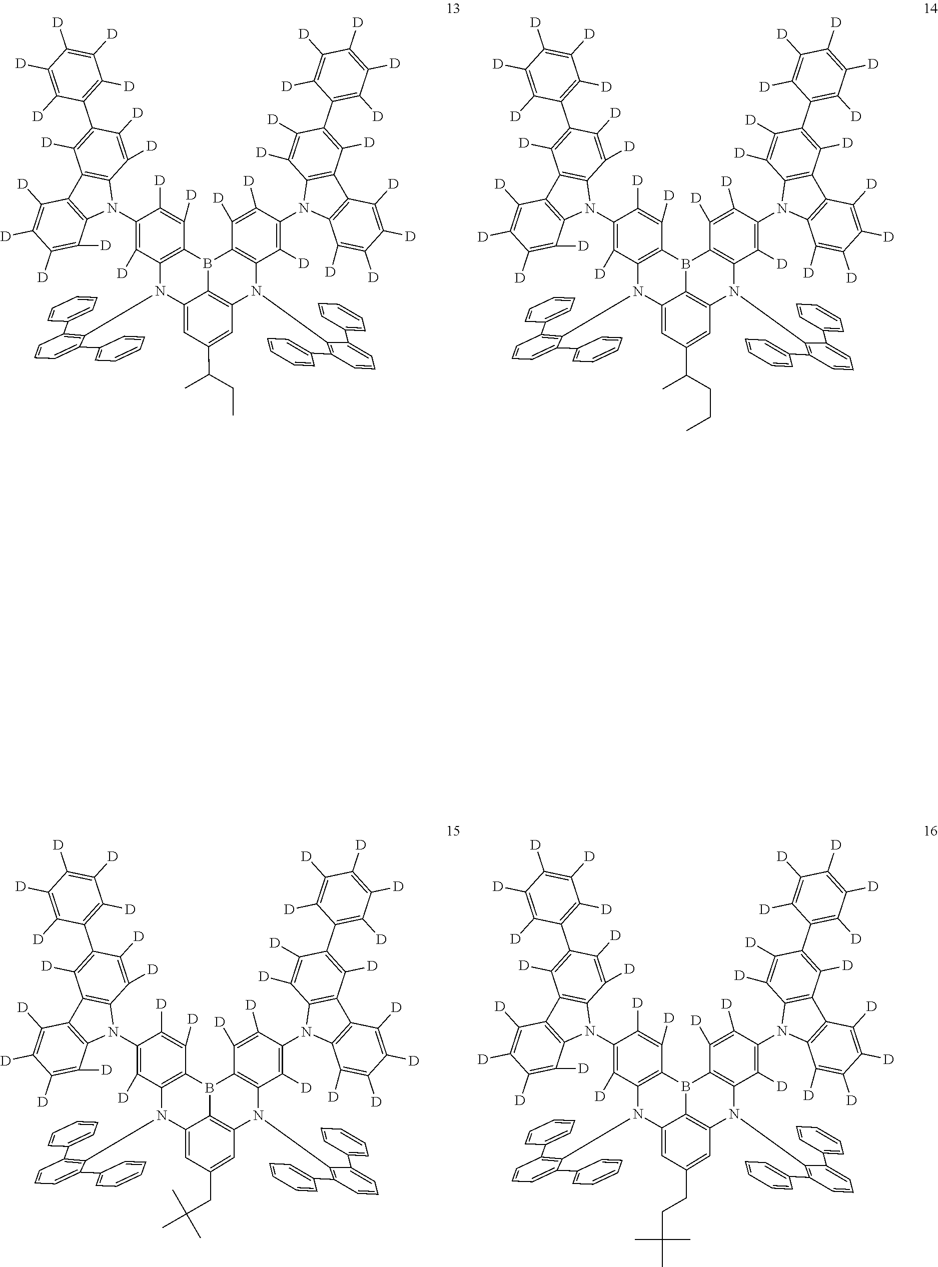

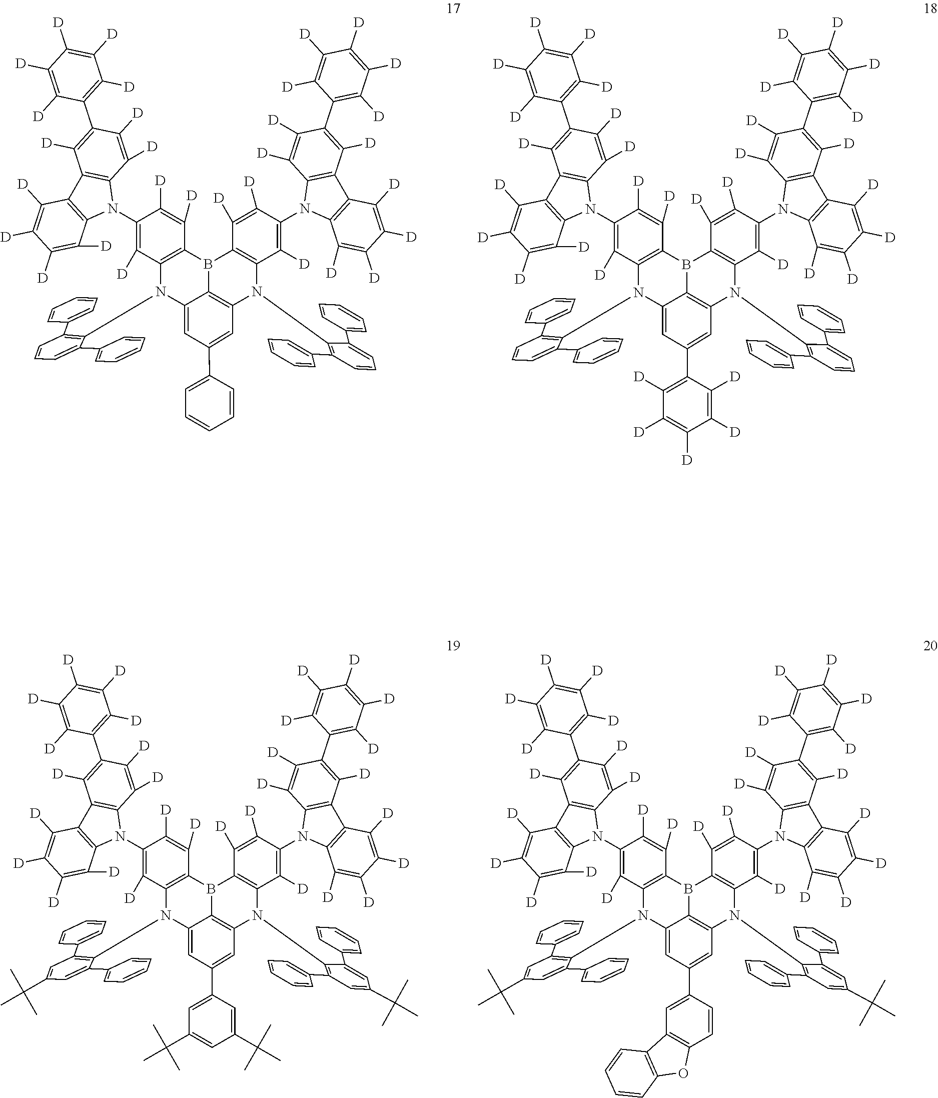

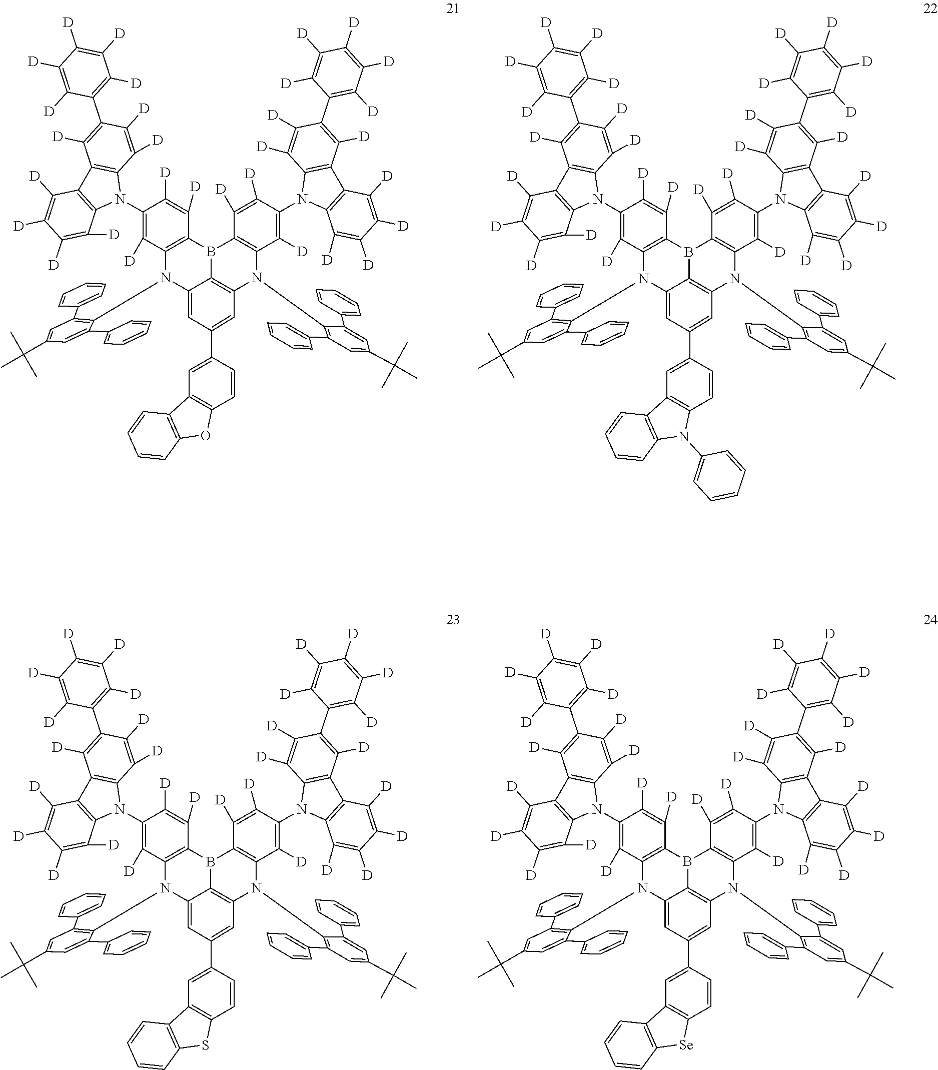

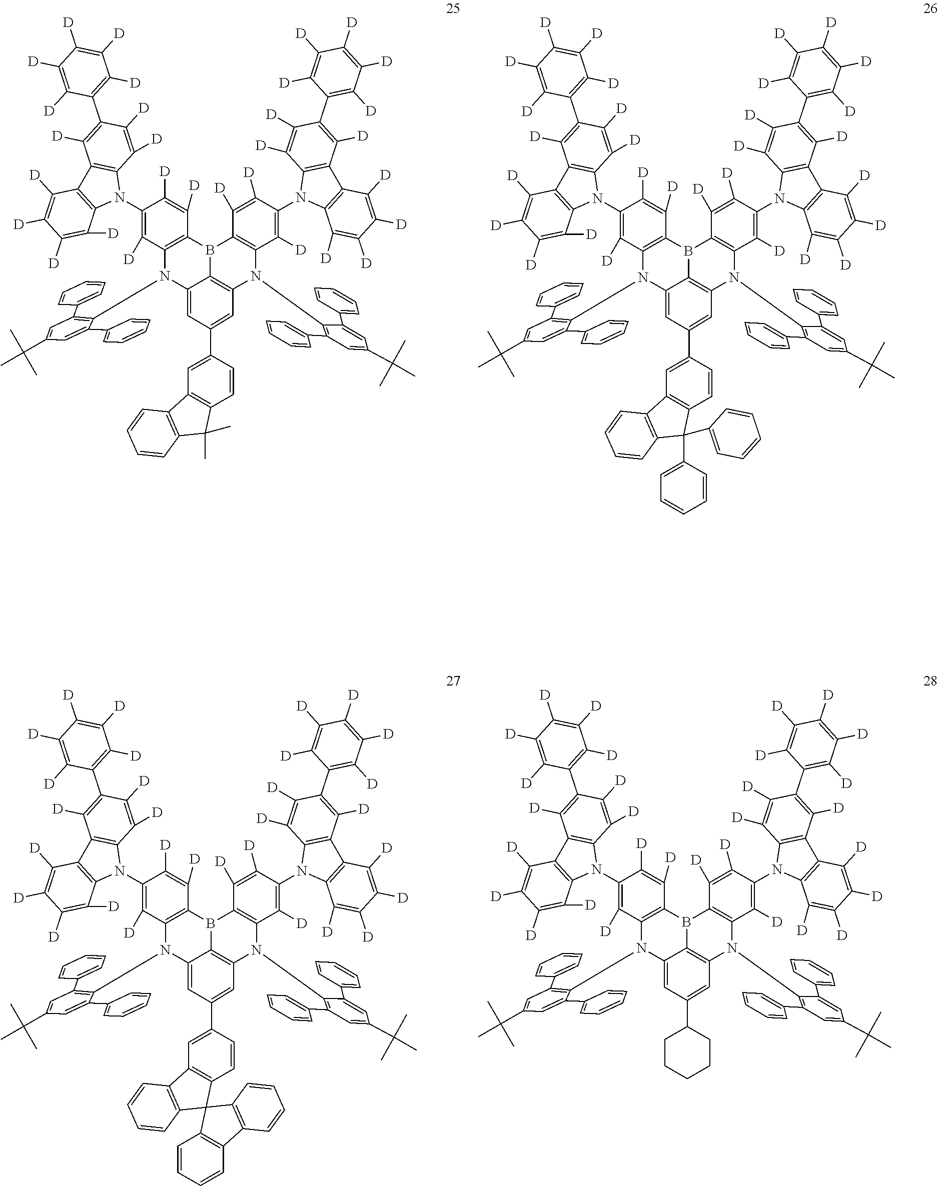

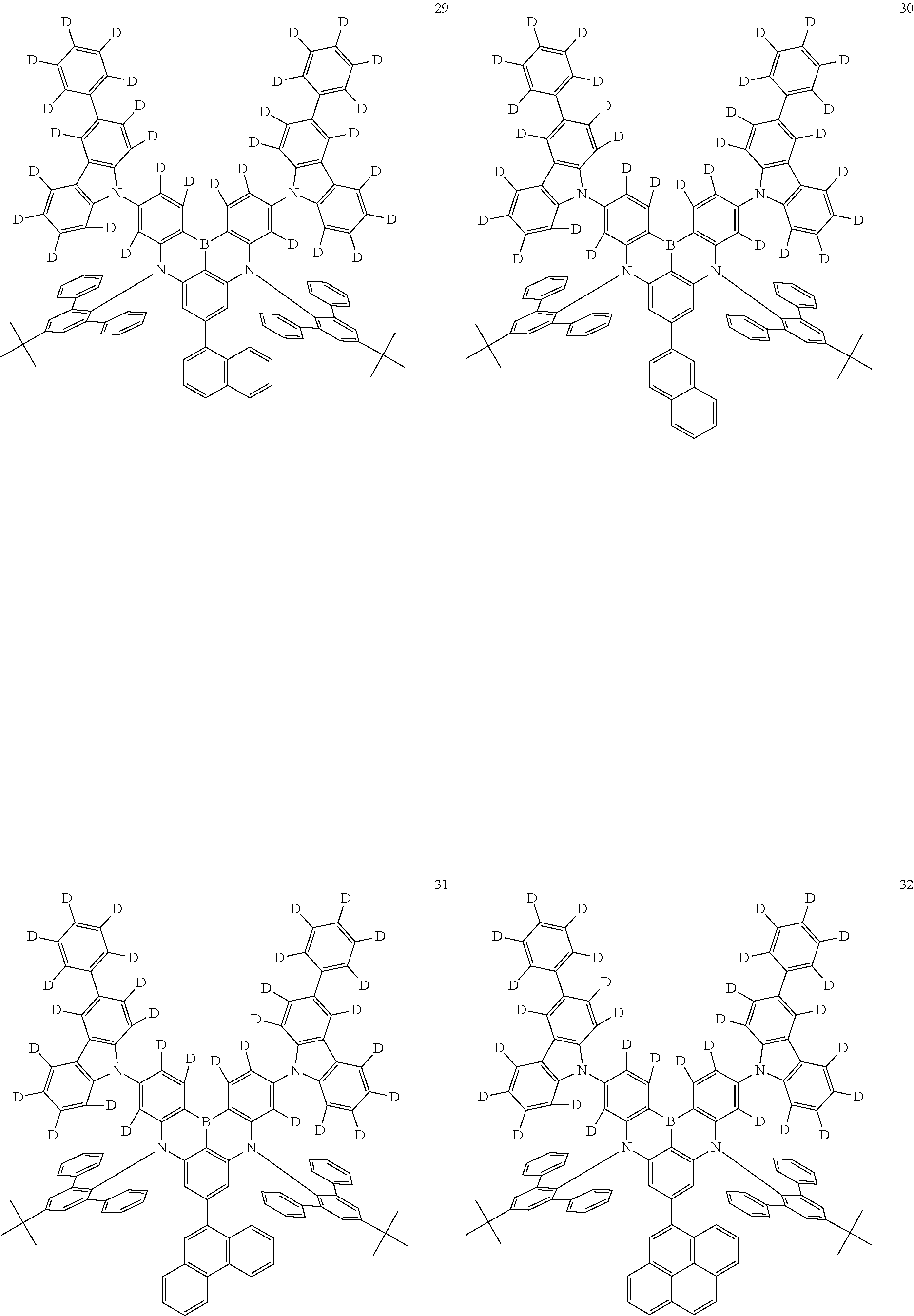

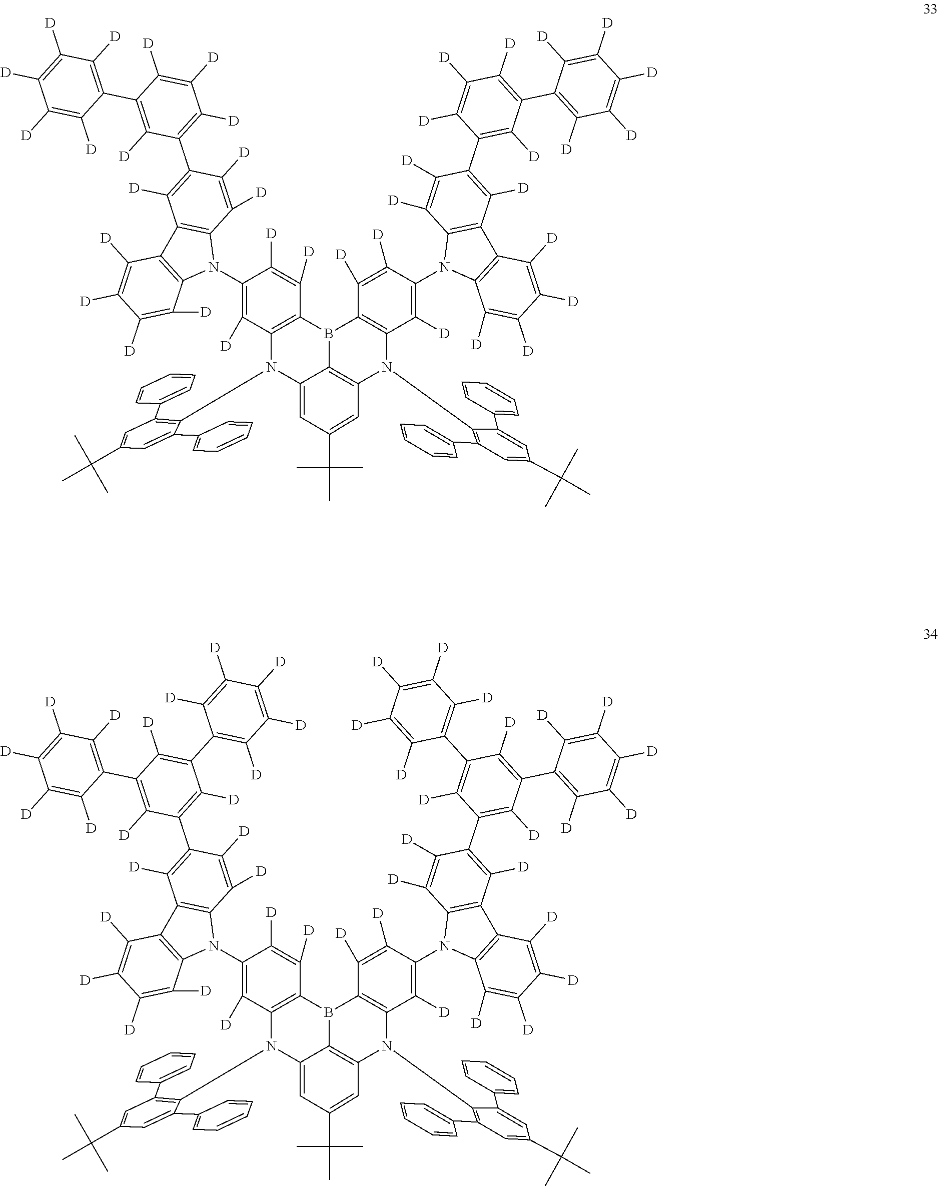

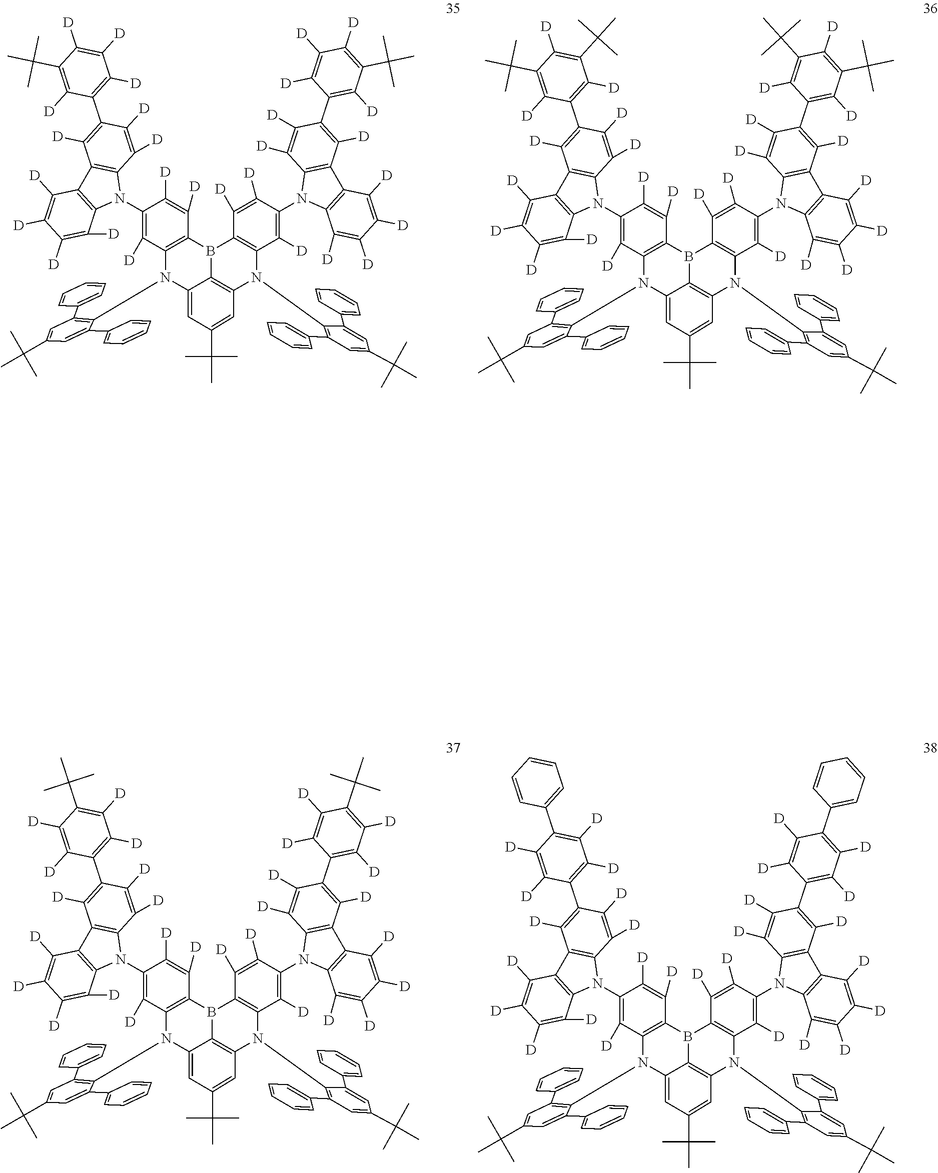

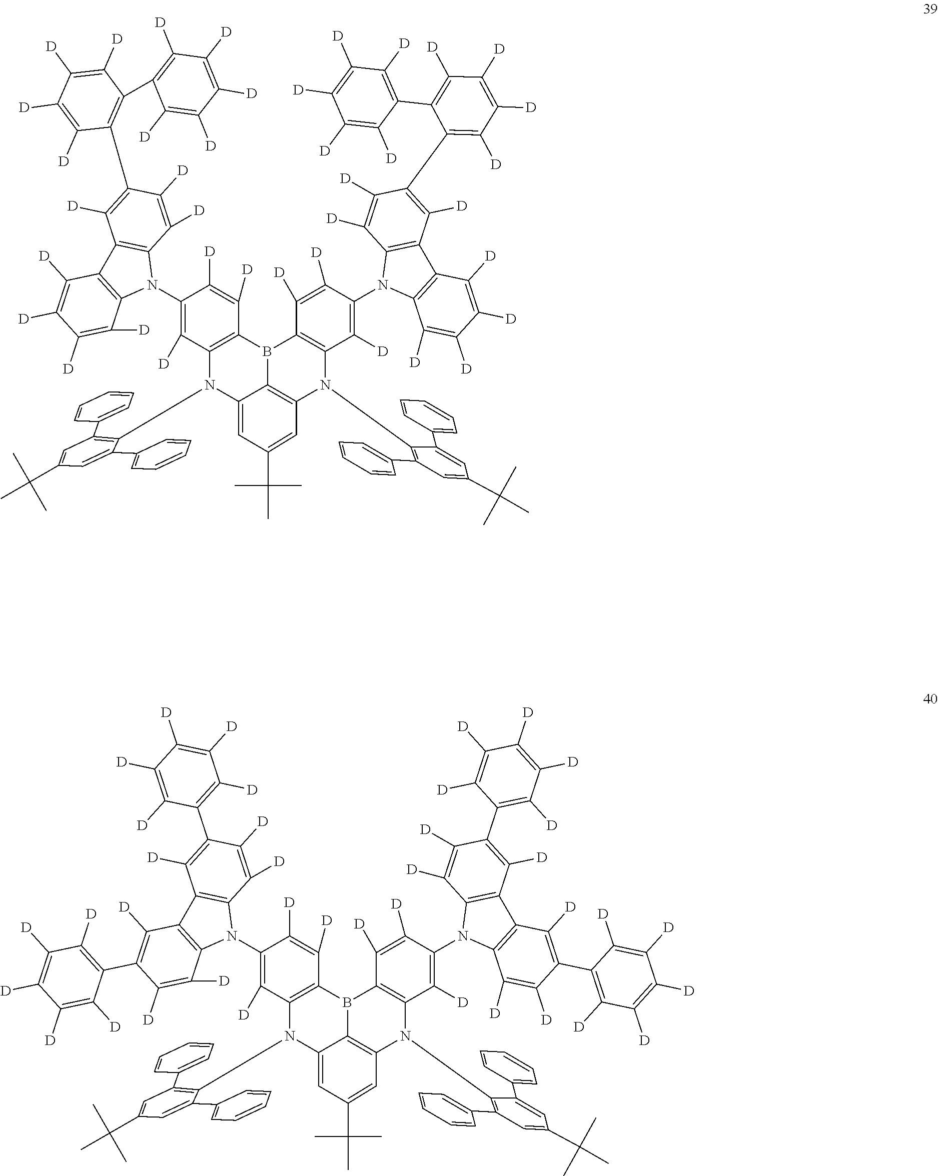

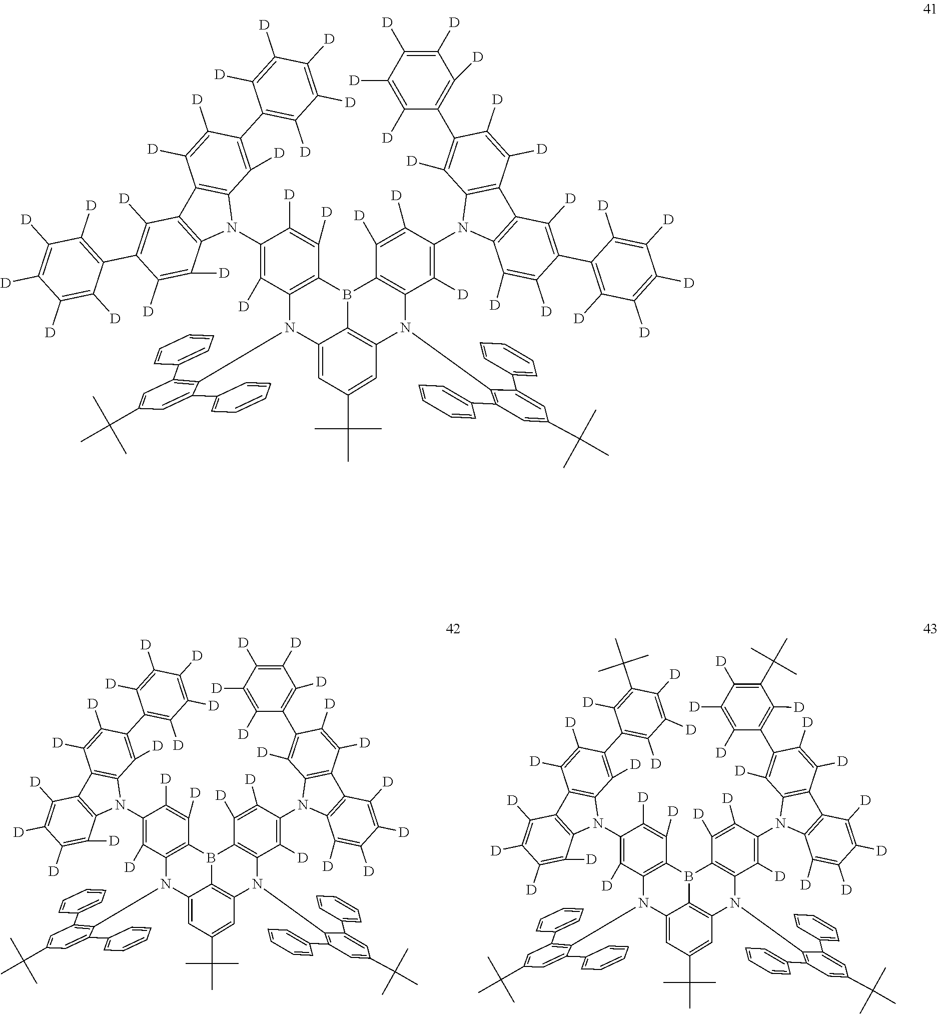

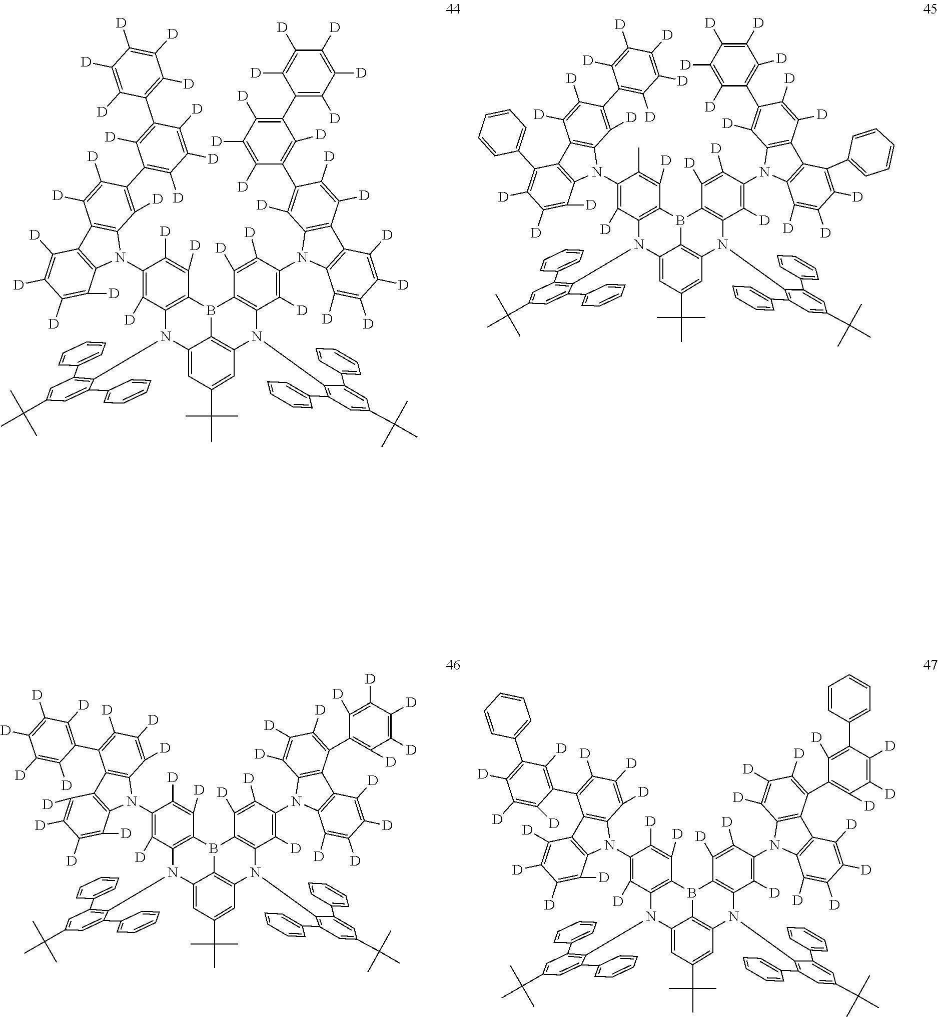

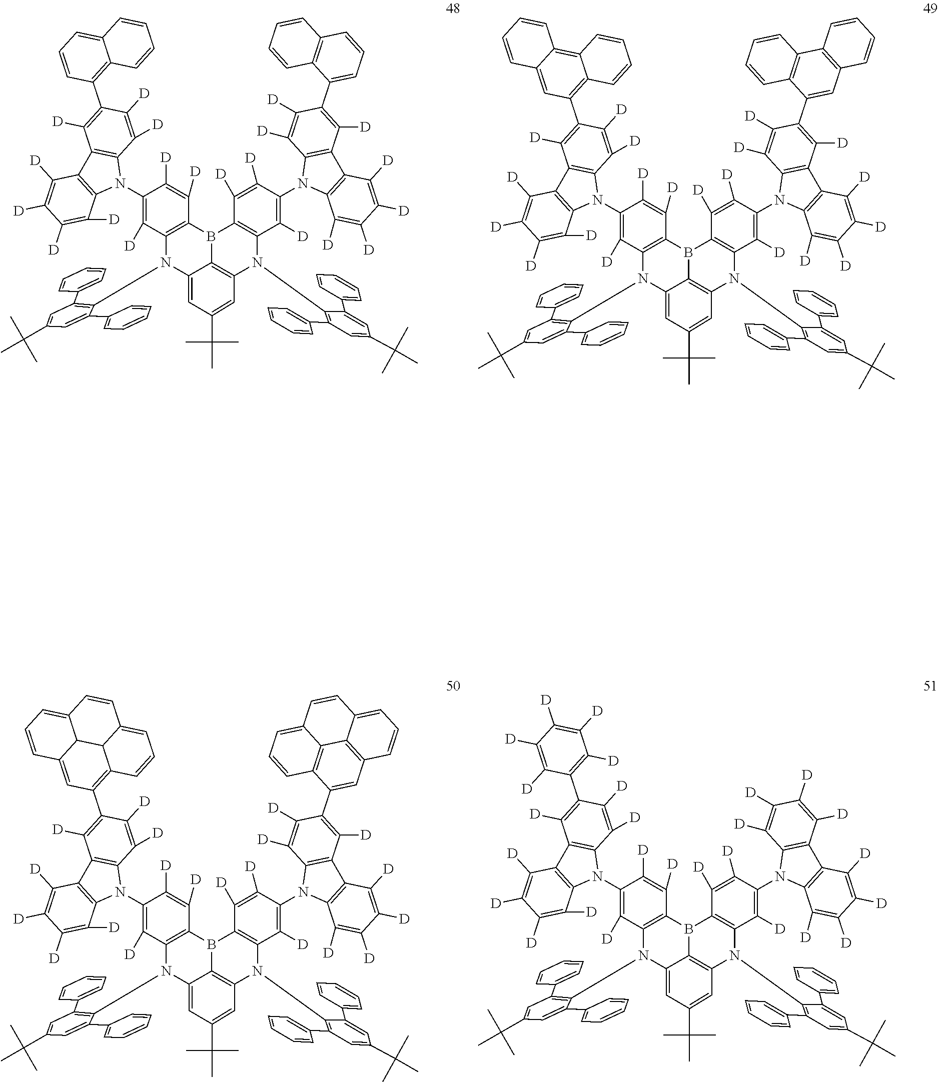

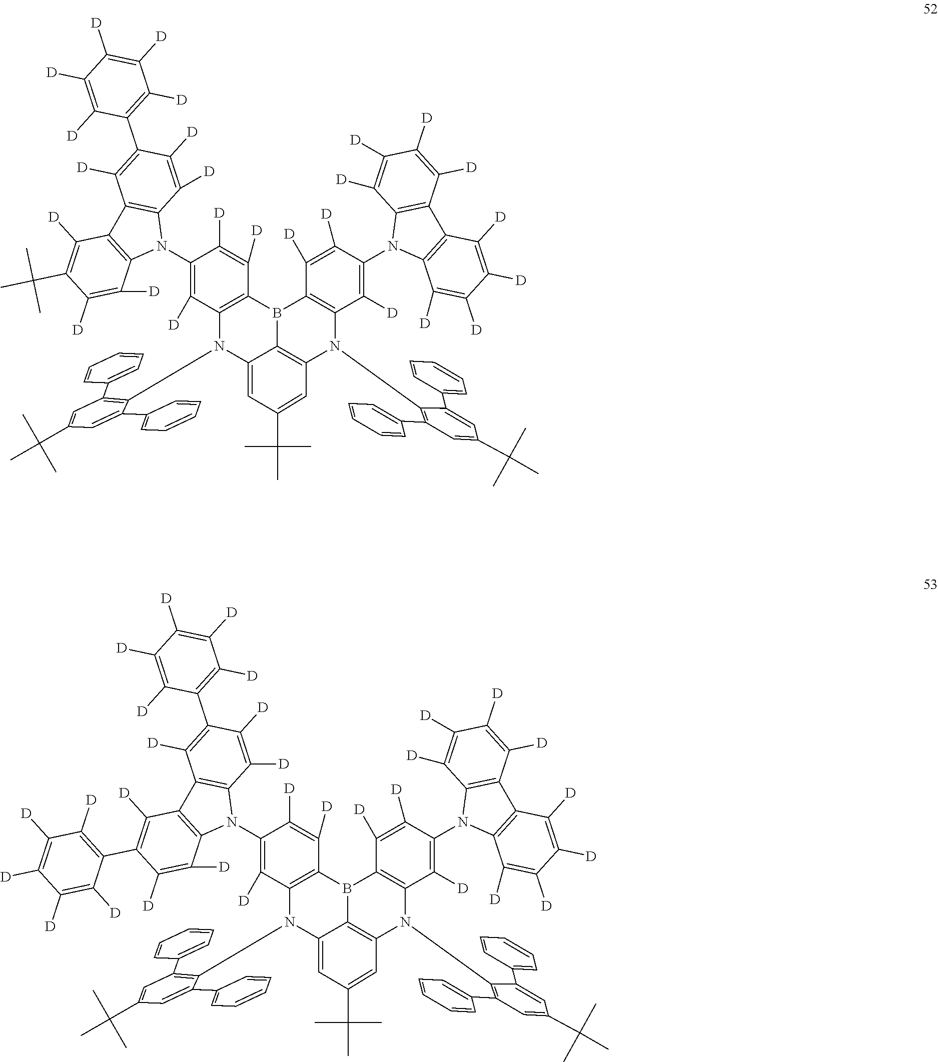

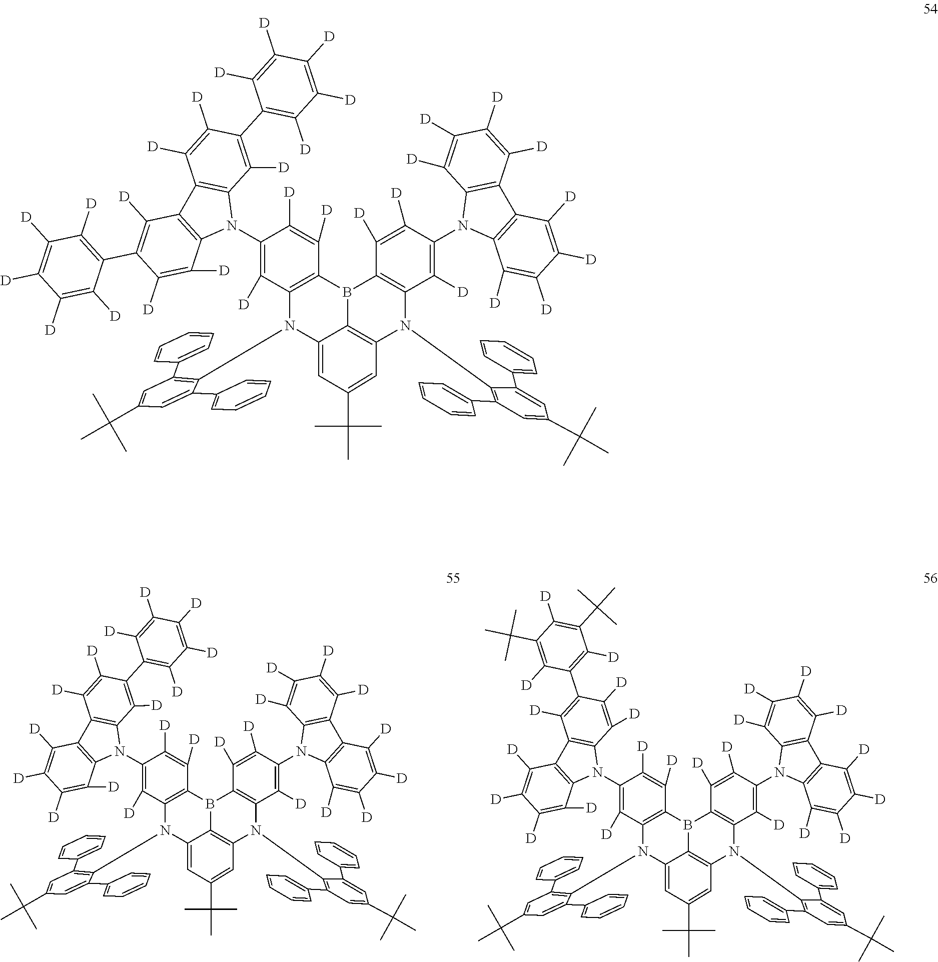

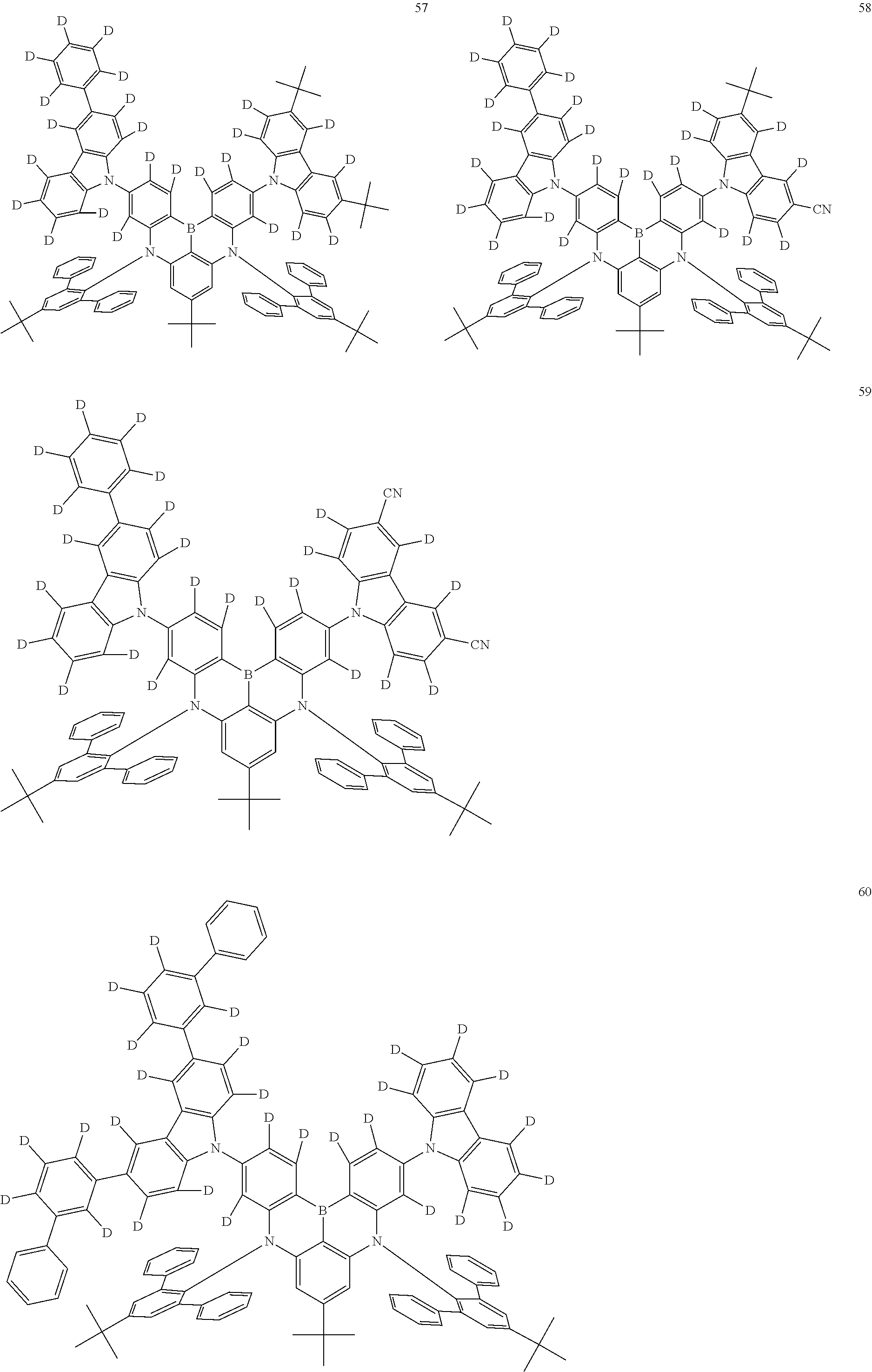

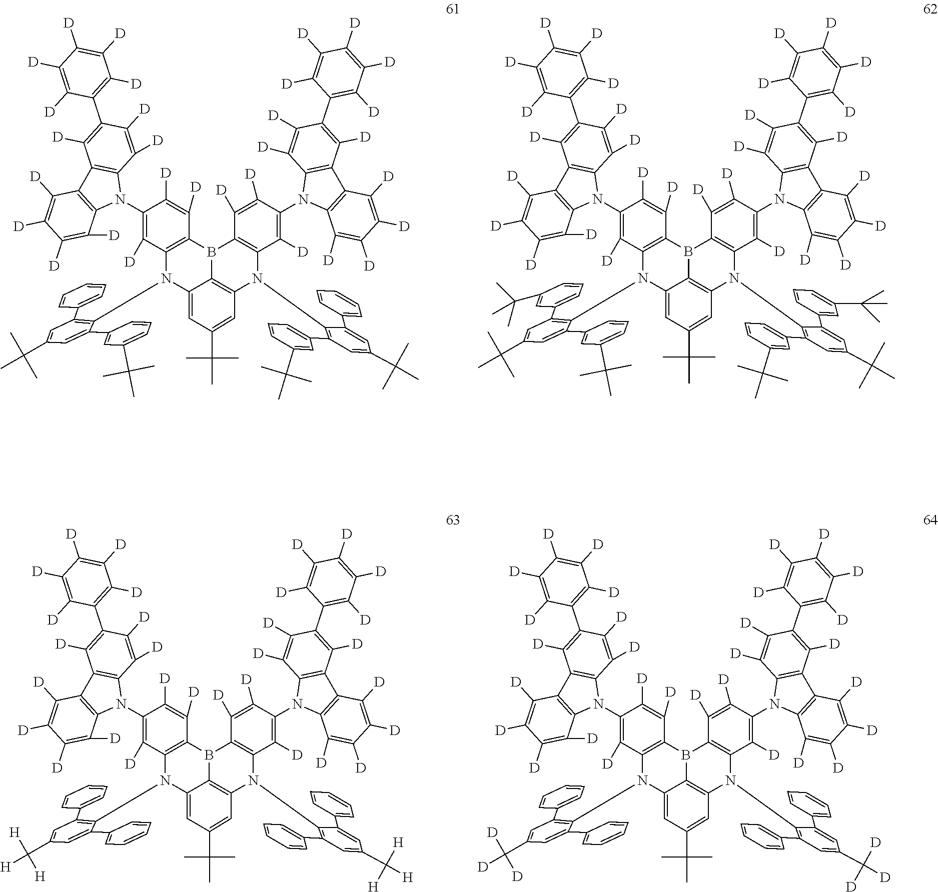

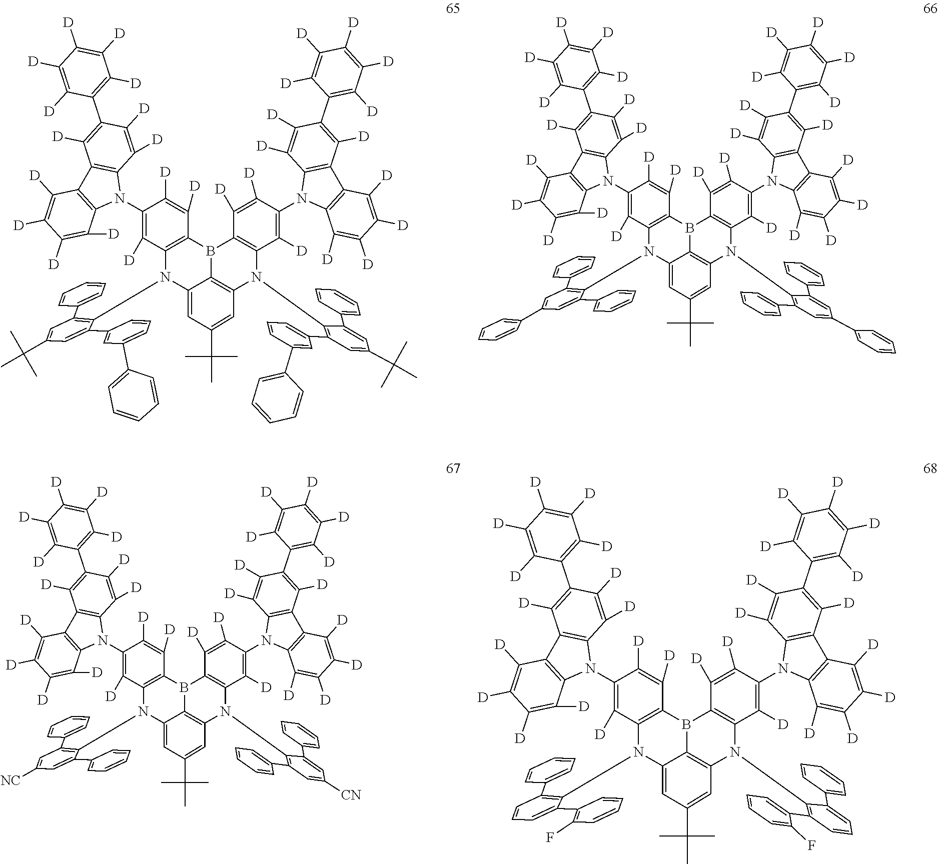

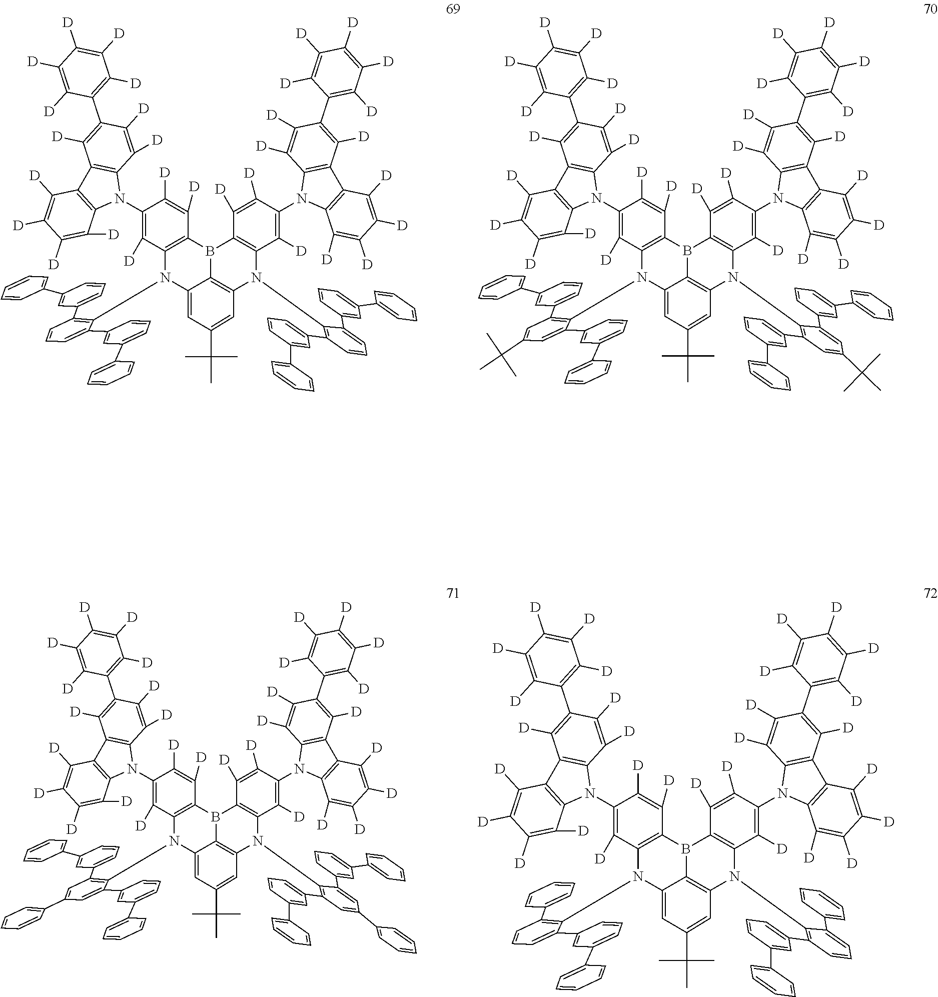

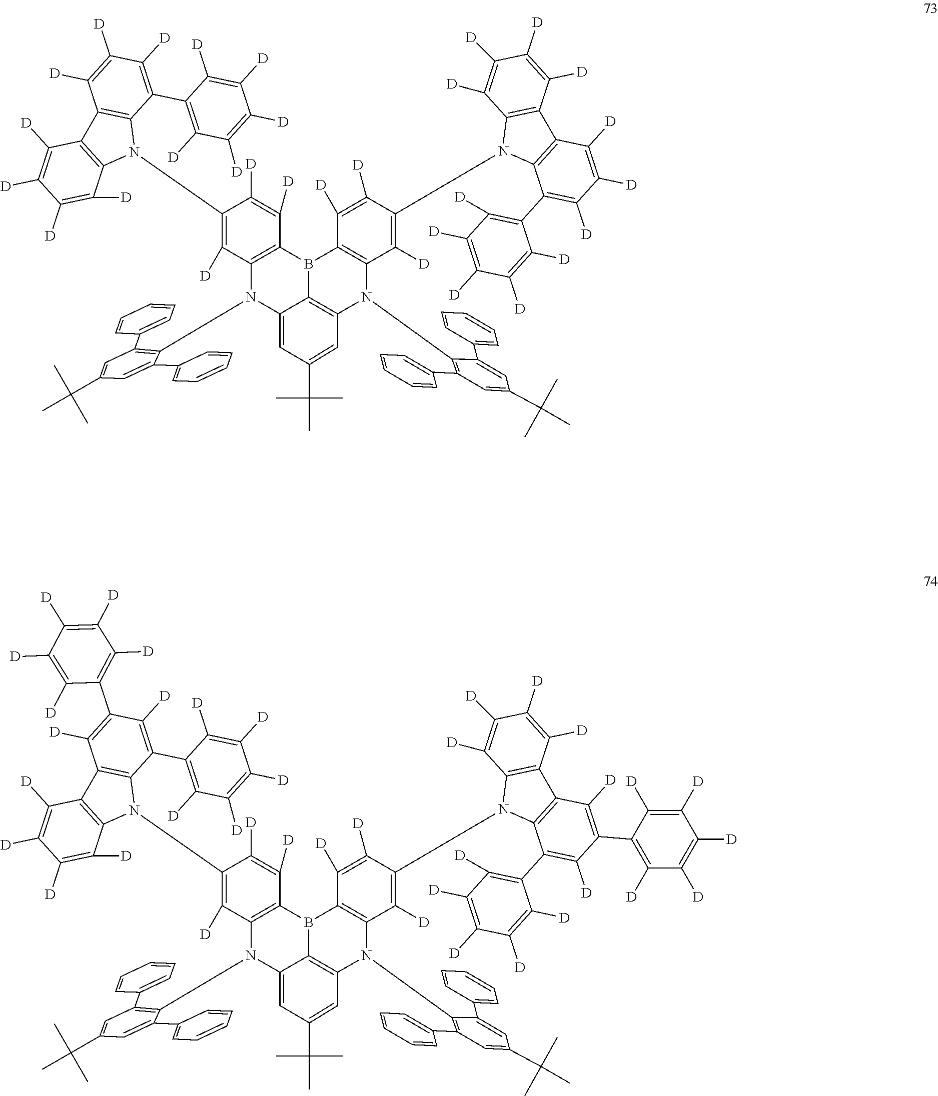

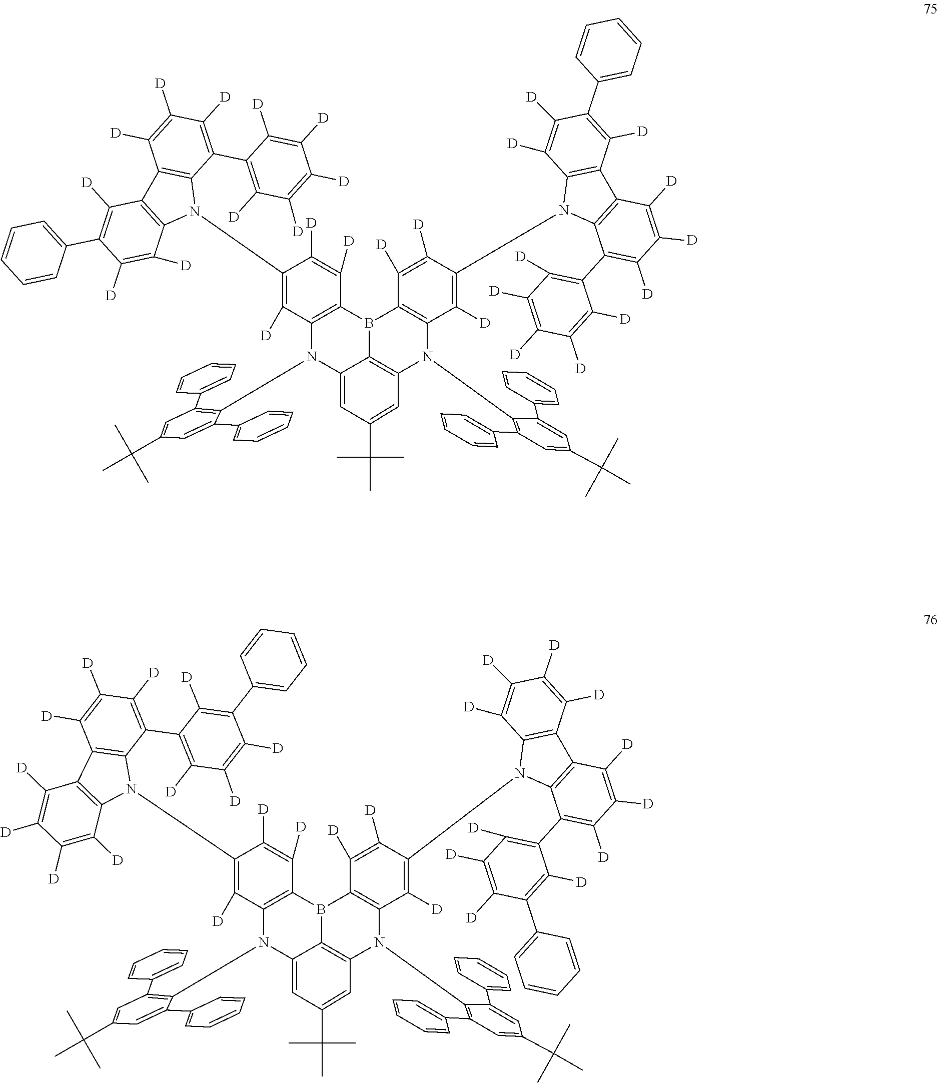

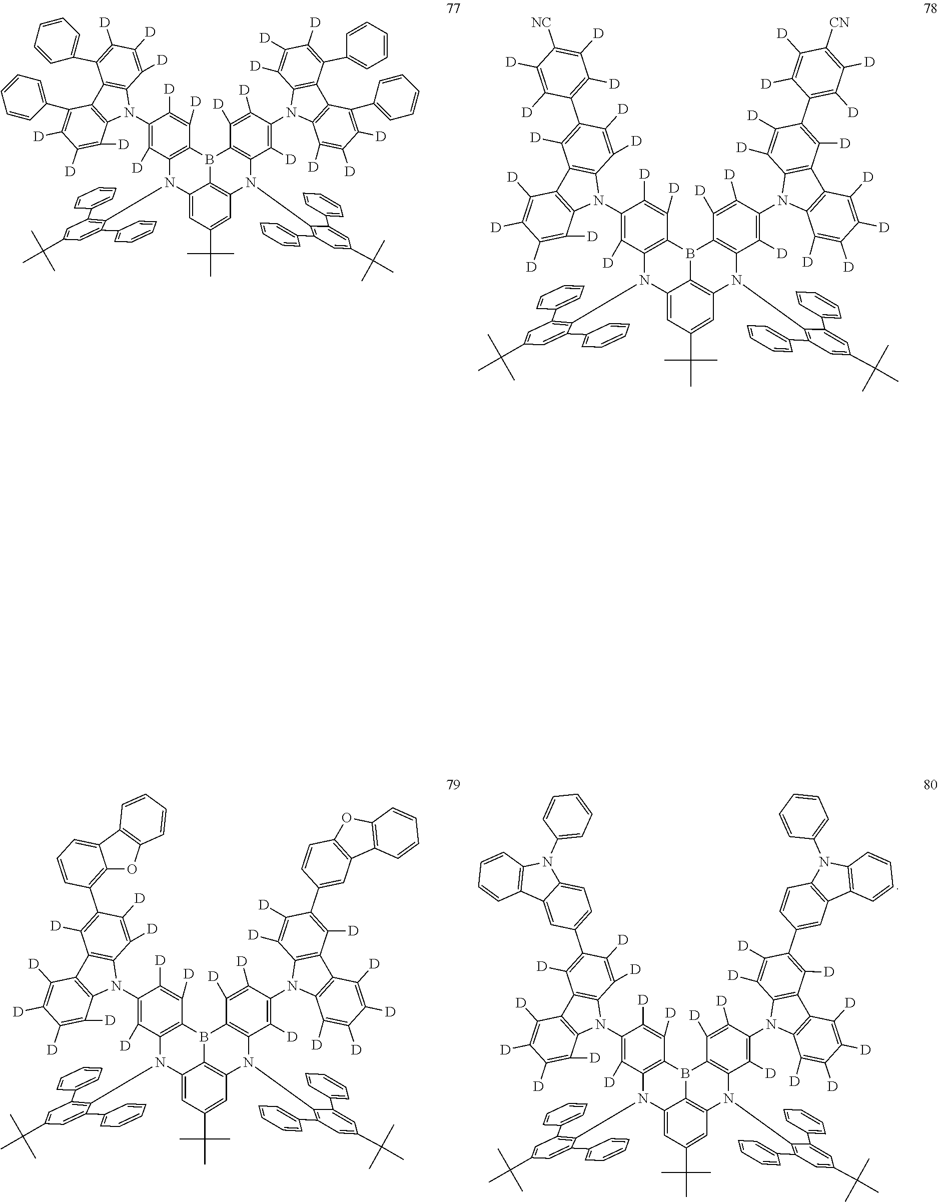

In the polycyclic compound according to one or more embodiments, an energy level difference (ΔE(S1−T1)) between a triplet (T1) state and a singlet (S1) state may be 0.2 eV or less. In the polycyclic compound according to one or more embodiments, triplet excitons may be converted to singlet excitons by RISC mechanism due to an energy level difference of 0.2 eV or less, thereby emitting light. For example, the polycyclic compound according to one or more embodiments may include a fused ring of five rings, as a central structure, containing two nitrogen atoms and one boron atom as ring-forming atoms, and may be utilized as a delayed fluorescence material. For example, the polycyclic compound according to one or more embodiments may be utilized as a thermally activated delayed fluorescence (TADF) material. In some embodiments, the polycyclic compound according to one or more embodiments may include two carbazole groups and two terphenyl groups bonded to the central structure of the fused ring, and in this case, at least one carbazole group among two carbazole groups may further include at least one aromatic group as a substituent. Therefore, the polycyclic compound may exhibit excellent or suitable material stability. The polycyclic compound according to one or more embodiments may further include an aromatic group additionally substituted at the carbazole group substituted at the central structure of the fused ring, and may thus exhibit characteristics of reduced energy level in a higher triplet state (Tn) through conjugation expansion.

In the polycyclic compound according to one or more embodiments, ΔE(T2−T3), which is an energy level difference between the higher triplet states, may be 0.05 eV or less, and ΔE(T1−T2), which is an energy level difference between the higher triplet states, may be 0.4 eV or less. In some embodiments, ΔE(S1−T2), which is an energy level difference between the higher triplet (T2) state and the singlet (S1) state, may be 0.3 eV or less. Because the characteristics of ΔE(T2−T3), ΔE(T1−T2), and ΔE(S1−T2) are exhibited, RISC may rapidly or suitably occur in the polycyclic compound according to one or more embodiments. Therefore, a material deterioration caused by the excitons may be mitigated or reduced, and thus excellent or suitable material stability may be exhibited.

In some embodiments, a light-emitting element according to one or more embodiments including the polycyclic compound according to one or more embodiments may exhibit characteristics of high efficiency and a long lifespan. For example, the light-emitting element according to one or more embodiments, in which the polycyclic compound according to one or more embodiments with improved material stability is included in the emission layer, may exhibit excellent or suitable long-lifespan characteristics.

In the light-emitting element according to one or more embodiments, the emission layer EML may be a delayed fluorescence emission layer including a host and a dopant. For example, the emission layer EML may be to emit thermally activated delayed fluorescence (TADF). The polycyclic compound according to one or more embodiments may be a thermally activated delayed fluorescence dopant.

The emission layer EML may include a polycyclic compound according to one or more embodiments as a dopant. The polycyclic compound according to one or more embodiments may be to emit blue light. For example, the polycyclic compound according to one or more embodiments may be a light-emitting material having a center light-emitting wavelength in a wavelength range of about 430 nm to about 490 nm. For example, the polycyclic compound according to one or more embodiments may be a light-emitting material having a center light-emitting wavelength in a wavelength range of about 450 nm to about 470 nm.

In one or more embodiments, the emission layer EML may include a polycyclic compound according to one or more embodiments and may include at least one selected from among second to fourth compounds. In one or more embodiments, the emission layer EML may include the second compound represented by Formula HT-1. For example, the second compound may be utilized as a hole transporting host material.

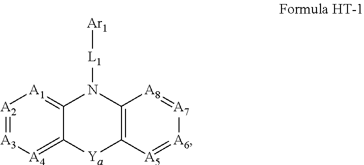

where, in Formula HT-1, A₁ to A₈ may each independently be N or CR₅₁. For example, all A₁ to A₈ may be CR₅₁. In some embodiments, one of A₁ to A₈ may be N, and the rest may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, or a substituted or unsubstituted divalent carbazole group, but the embodiment of the present disclosure is not limited thereto.

In Formula HT-1, Yₐ may be a direct linkage, CR₅₂R₅₃, or SiR₅₄R₅₅. For example, in Formula HT-1, two benzene rings being connected to a nitrogen atom in Formula HT-1 may refer to being connected via direct linkages,

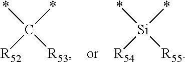

In Formula HT-1, when Yₐ is a direct linkage, a second compound represented by Formula HT-1 may include a carbazole moiety.

In Formula HT-1, Ar₁ may be a substituted or unsubstituted aryl group having 6 to 30 ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, or a substituted or unsubstituted biphenyl group, but the embodiment of the present disclosure is not limited thereto.

In Formula HT-1 R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, R₅₁ to R₅₅ may each independently be bonded to an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In one or more embodiments, the second compound represented by Formula HT-1 may be represented by any one selected from among compounds in Compound Group 2. The emission layer EML may include at least one selected from among compounds represented in Compound Group 2 as a hole transporting host material.

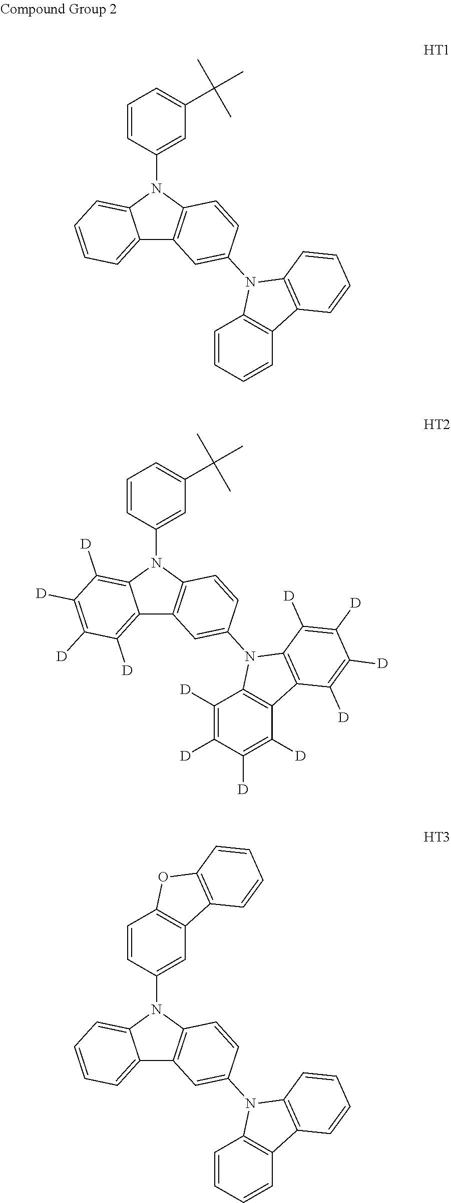 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

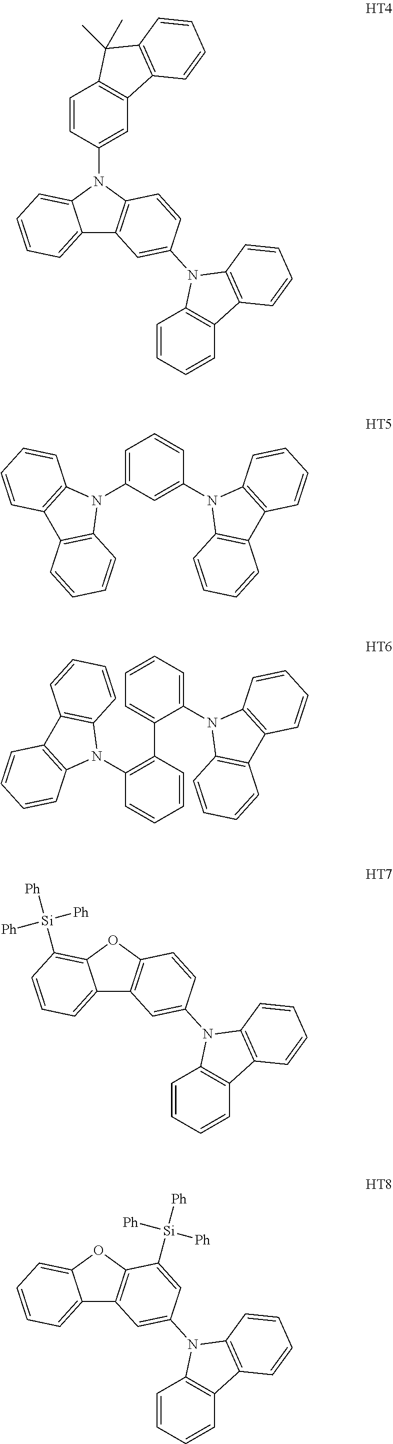 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

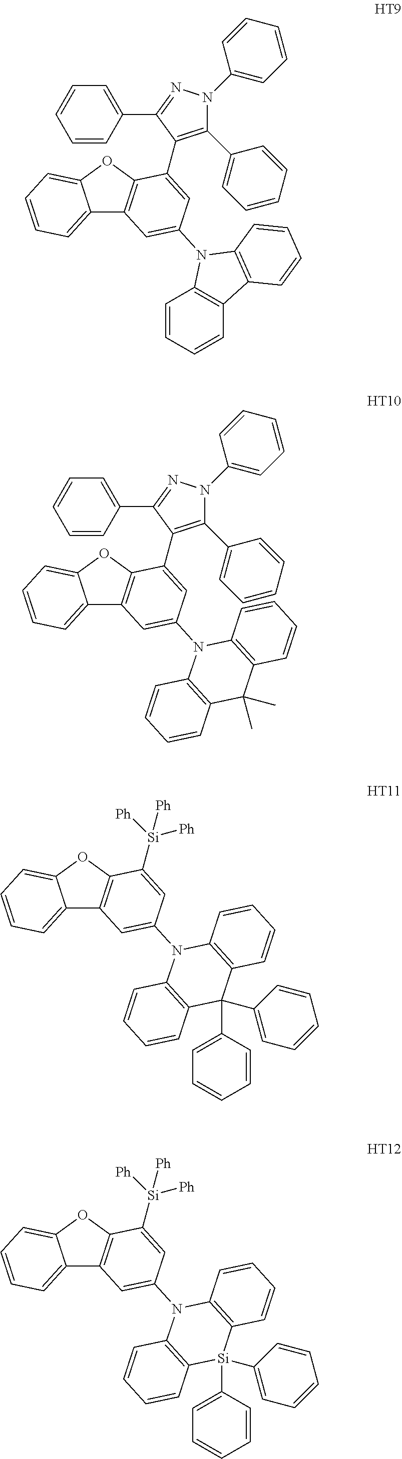 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

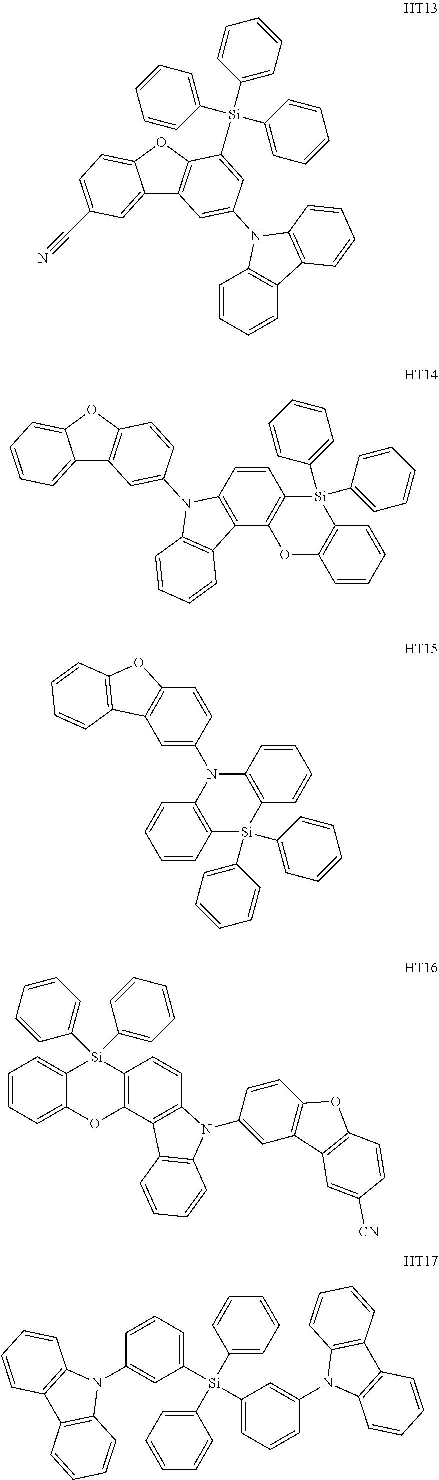 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1]

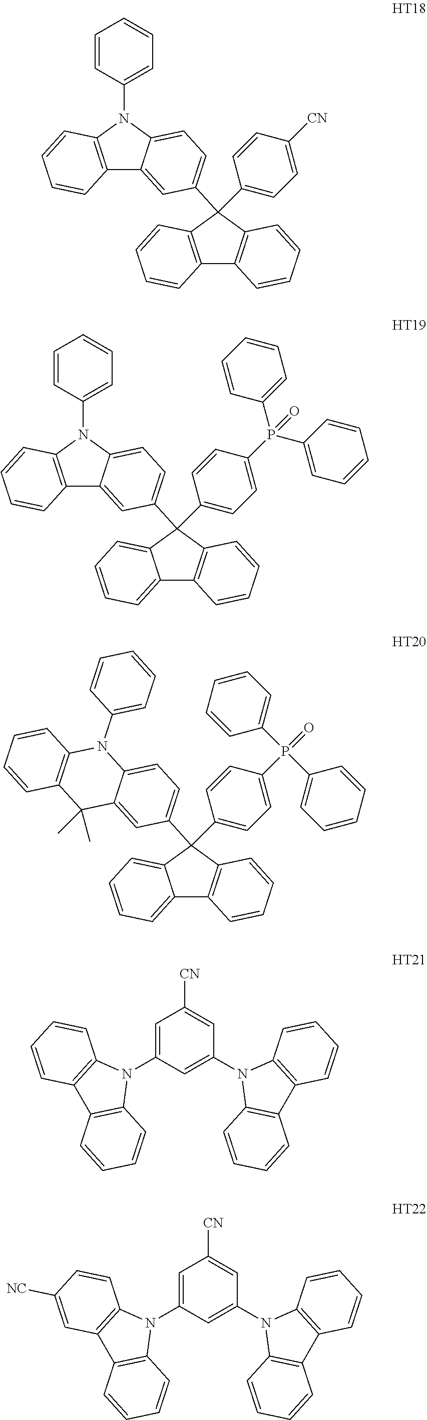 [SMILES: N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

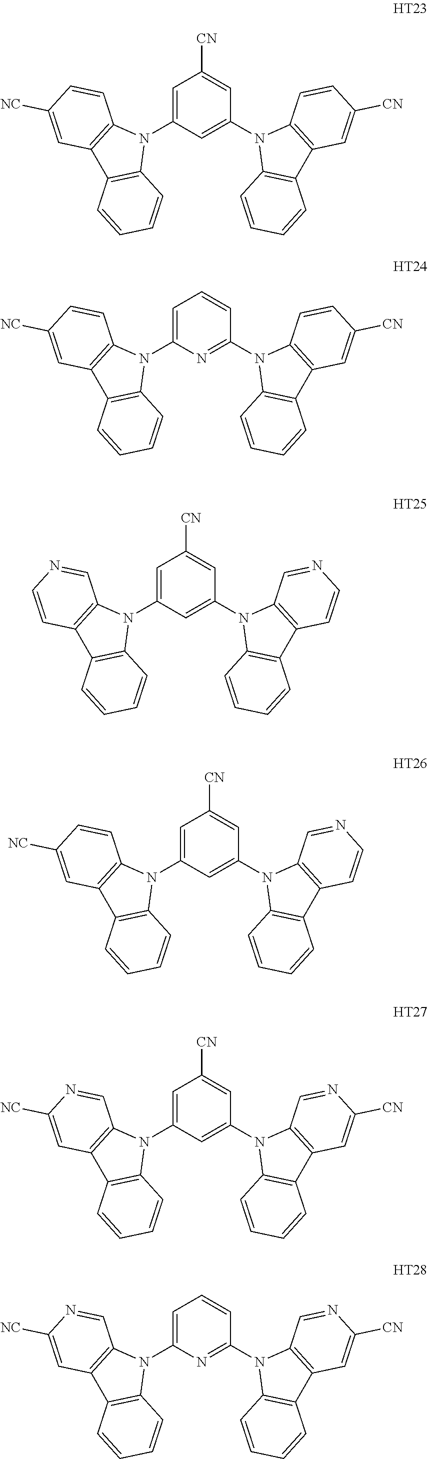 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

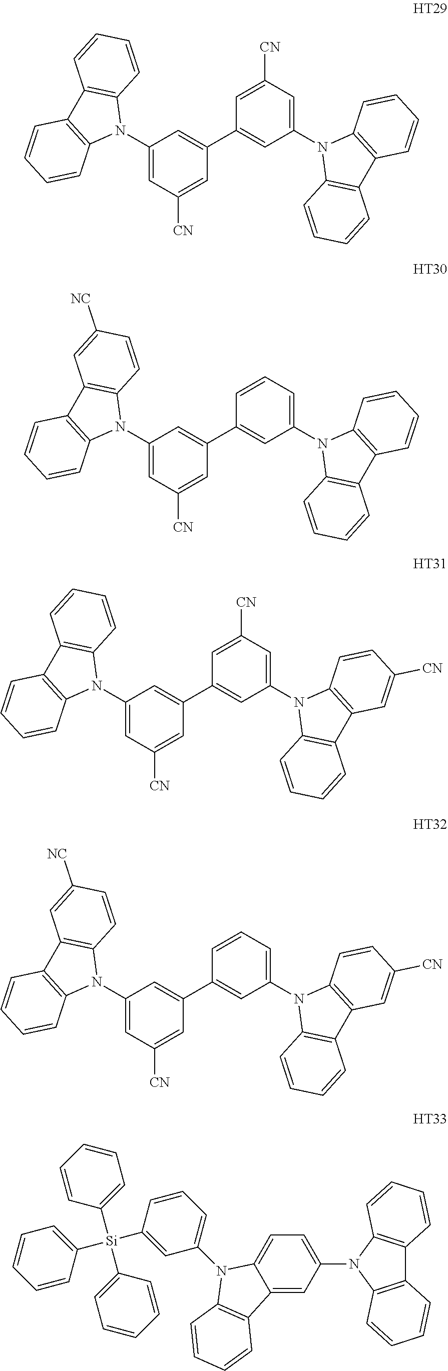 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cc(C#N)cc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

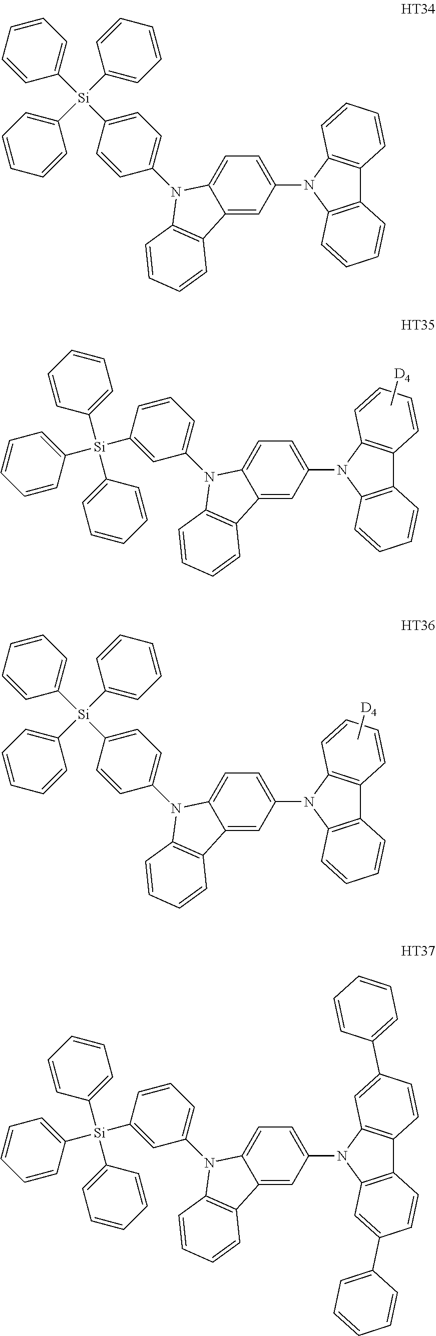

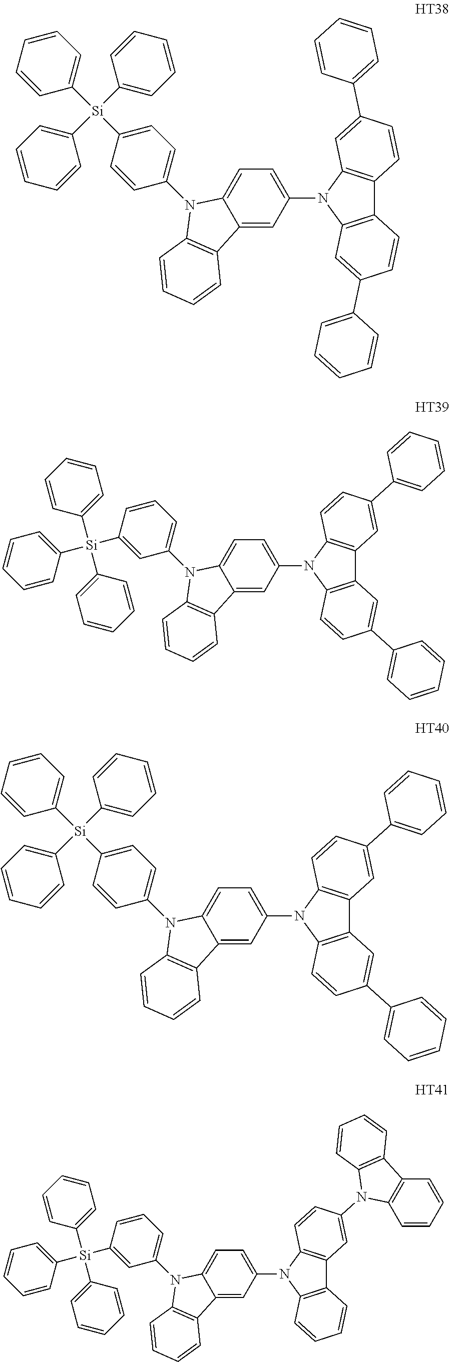 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1]

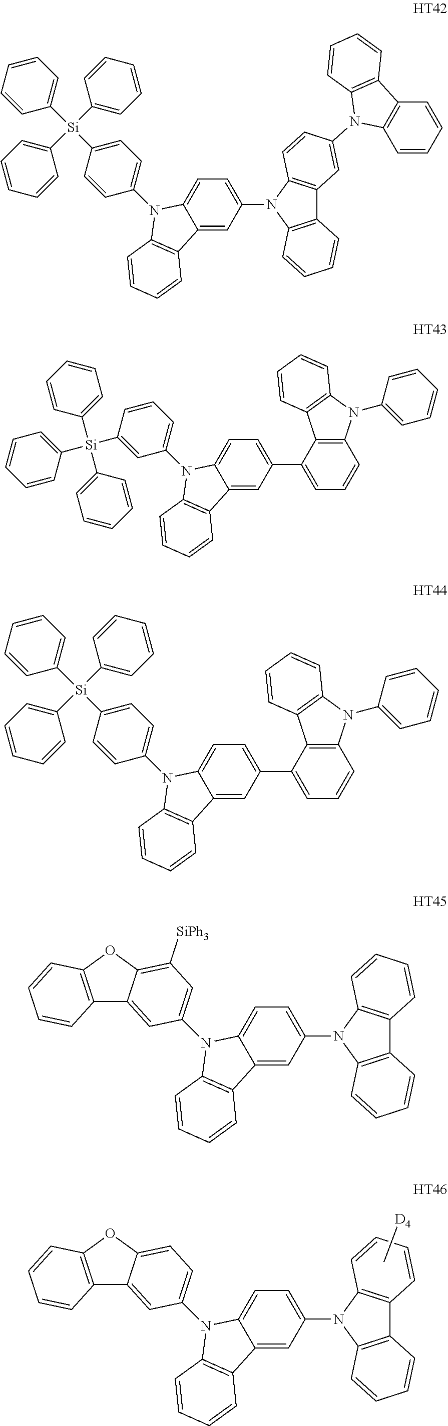

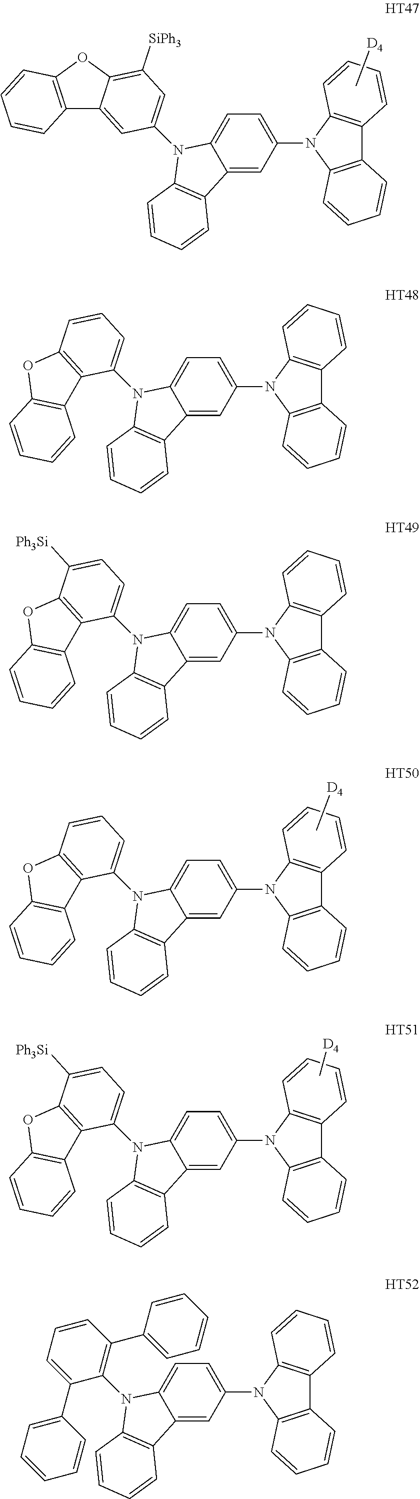

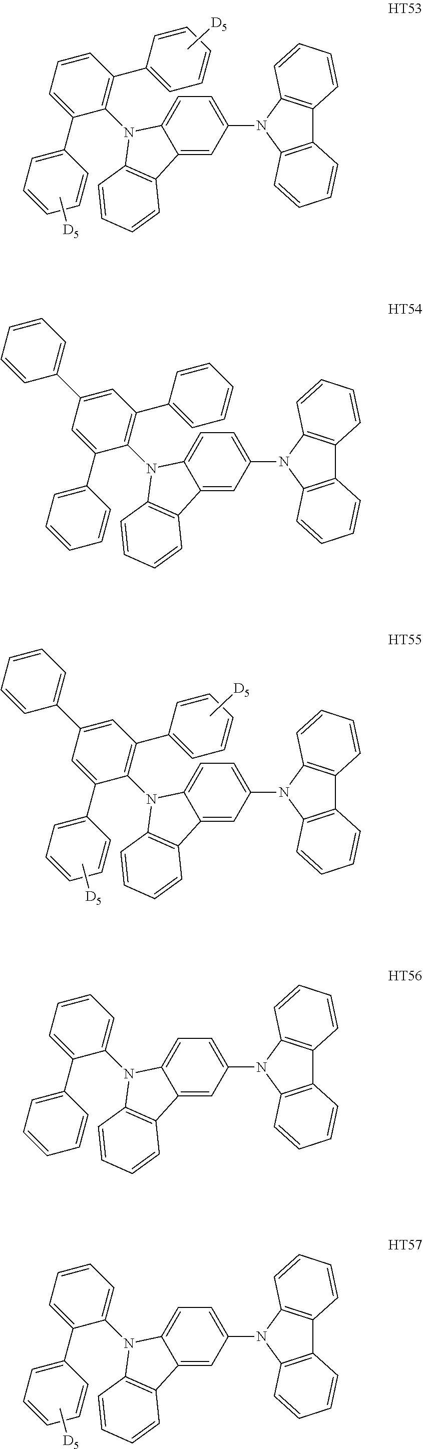

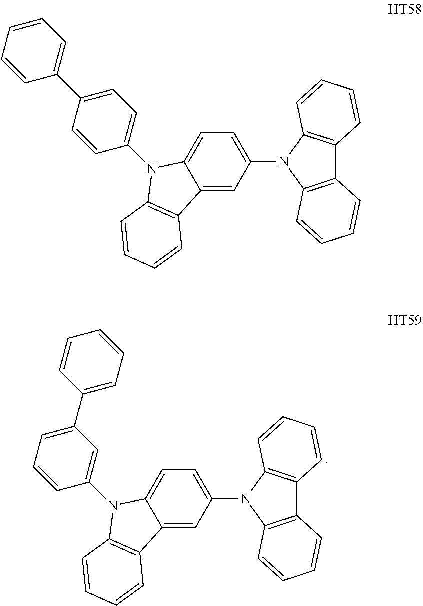 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In the compounds presented in Compound Group 2 “D” may refer to a deuterium atom, and “Ph” may refer to a substituted or unsubstituted phenyl group. For example, in the example compounds presented in Compound Group 2, “Ph” may be an unsubstituted phenyl group.

In one or more embodiments, the emission layer EML may include a third compound represented by Formula ET-1. For example, the third compound may be utilized as an electron transporting host material in the emission layer EML.

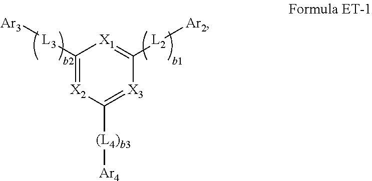

where, in Formula ET-1, at least one selected from among X₁ to X₃ may be N, and the rest may be CR₅₆. For example, any one selected from among X₁ to X₃ may be N, and the rest two may each independently be CR₅₆. In this case, the third compound represented by Formula ET-1 may include a pyridine moiety. In some embodiments, two selected from among X₁ to X₃ may be N, and the remaining one may be CR₅₆. In this case, the third compound represented by Formula ET-1 may include a pyrimidine moiety. In some embodiments, all X₁ to X₃ may be N. In this case, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b₁ to b₃ may each independently be an integer of 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when b1 to b3 are integers of 2 or more, L₂ to L₄ may each independently be a substituted or unsubstituted arylene group having 6 to 30 ring-forming carbon atoms, or a substituted or unsubstituted heteroarylene group having 2 to 30 ring-forming carbon atoms.

In one or more embodiments, a third compound may be represented by any one selected from among compounds in Compound Group 3. A light-emitting element ED according to one or more embodiments may include any one selected from among compounds in Compound Group 3.

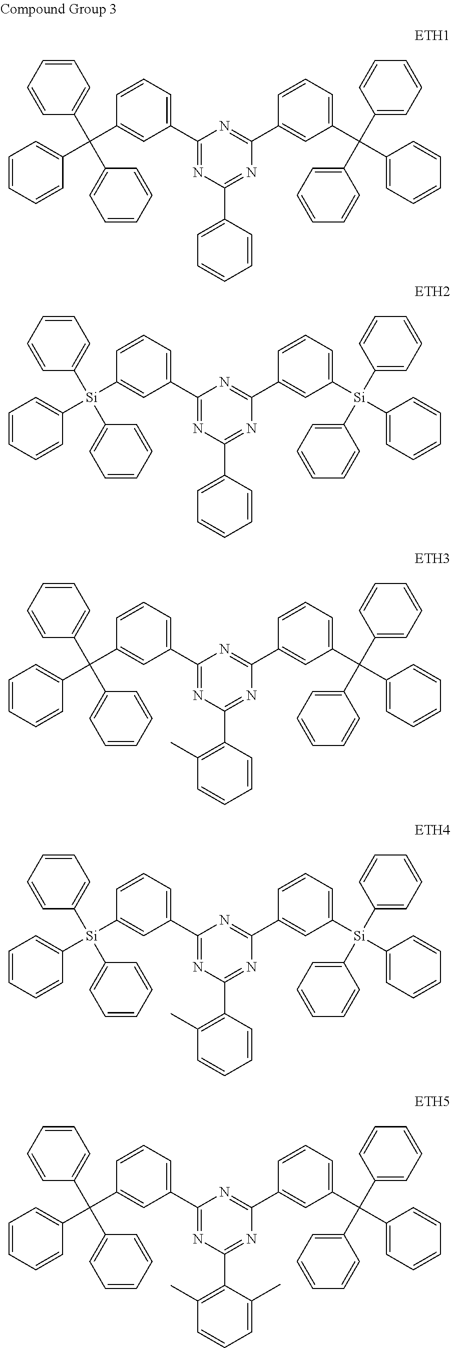

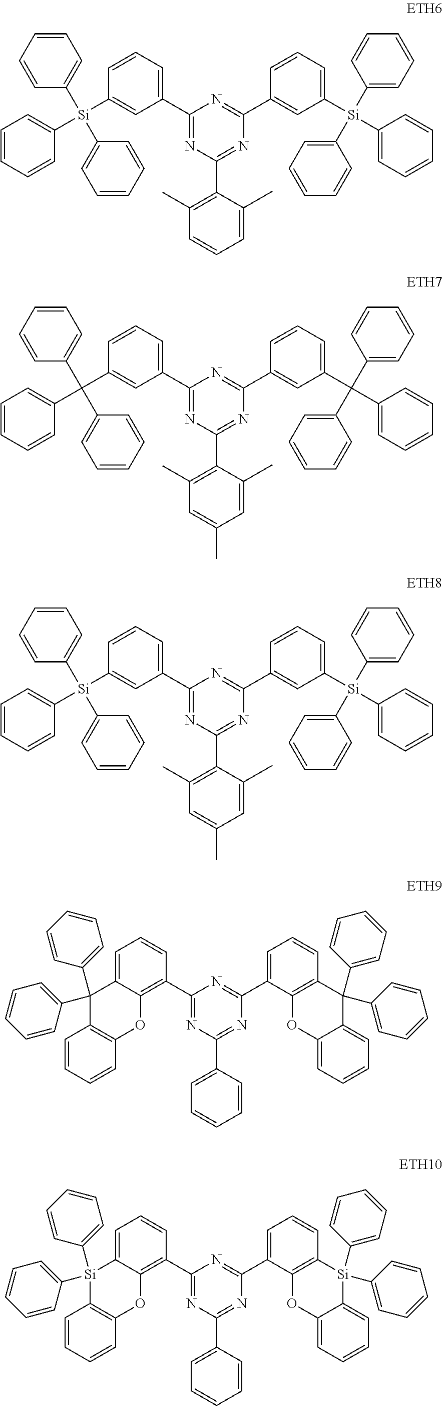

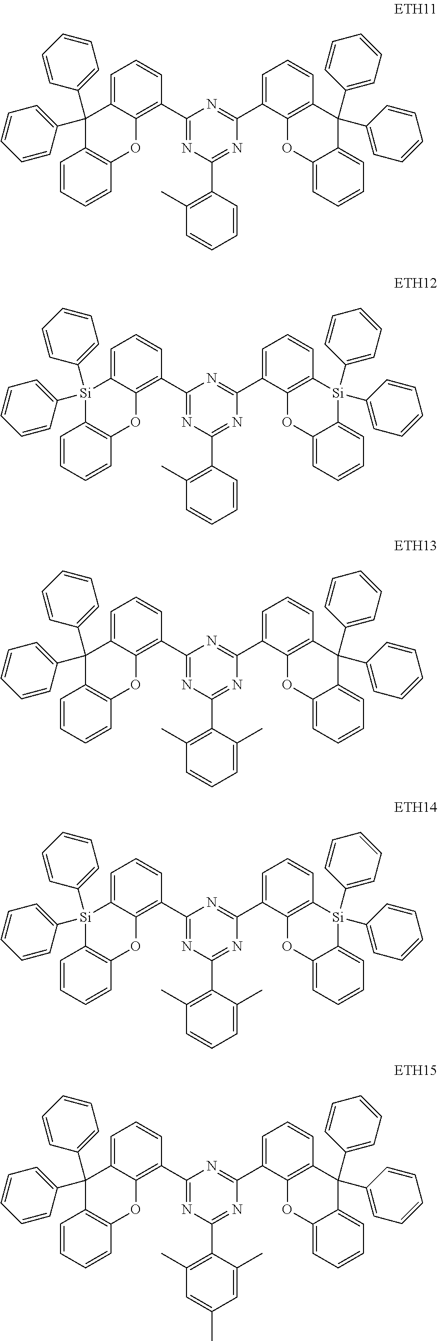

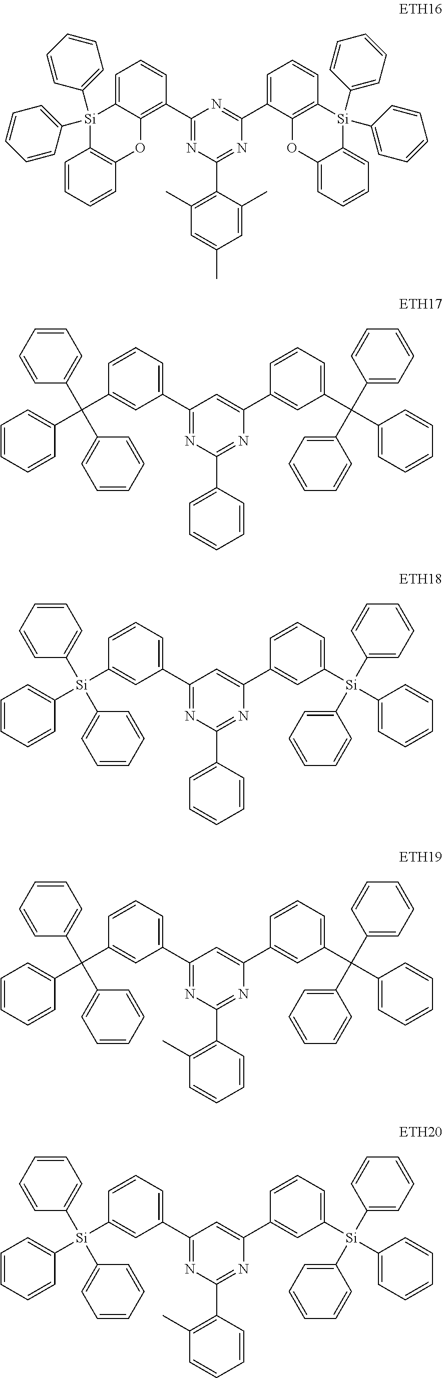

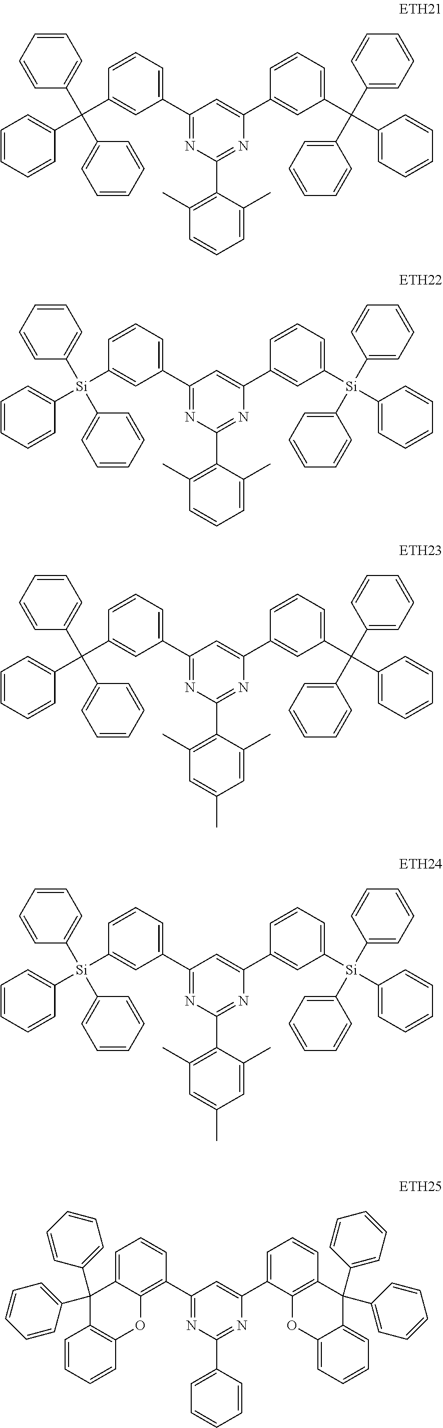

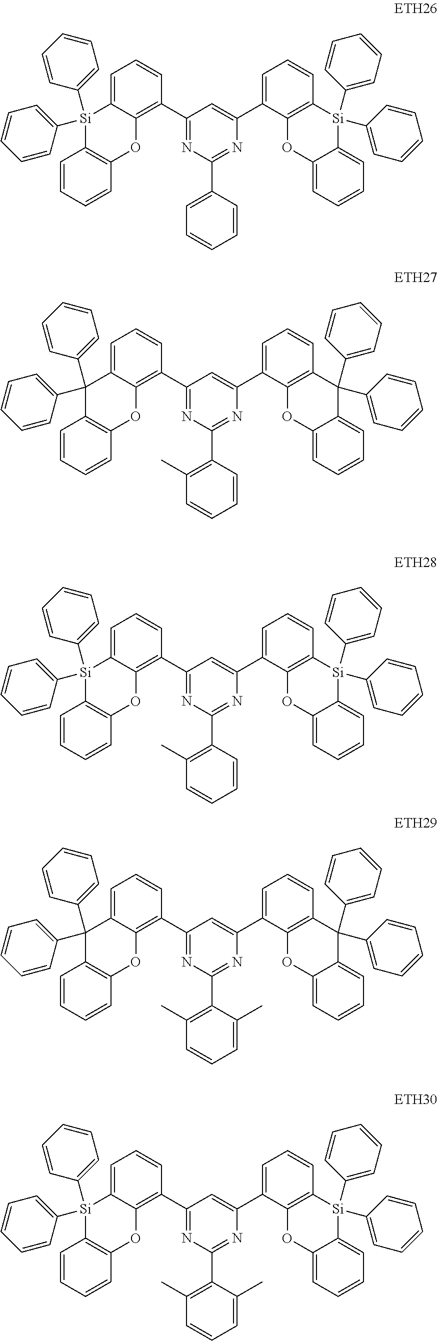

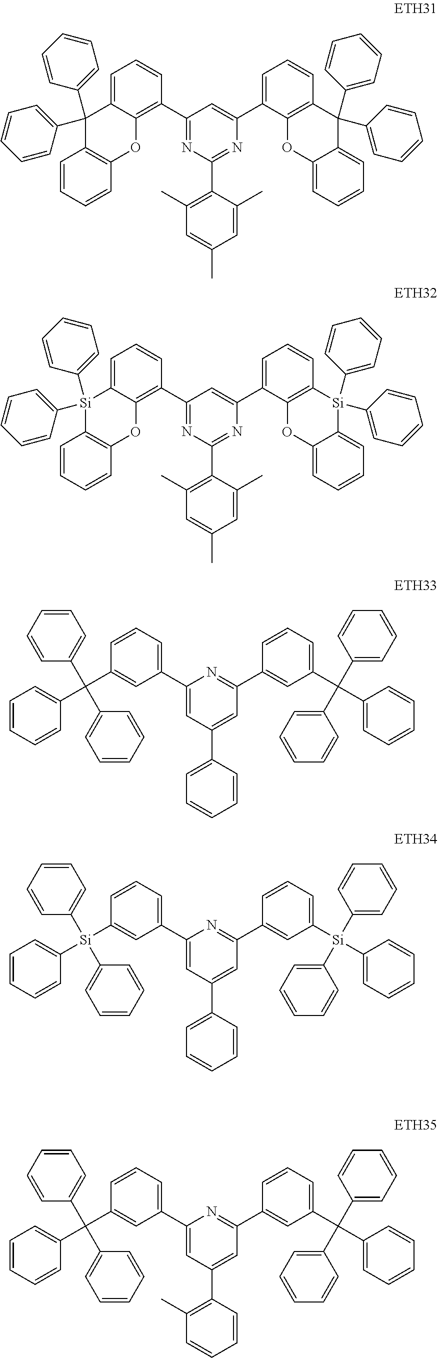

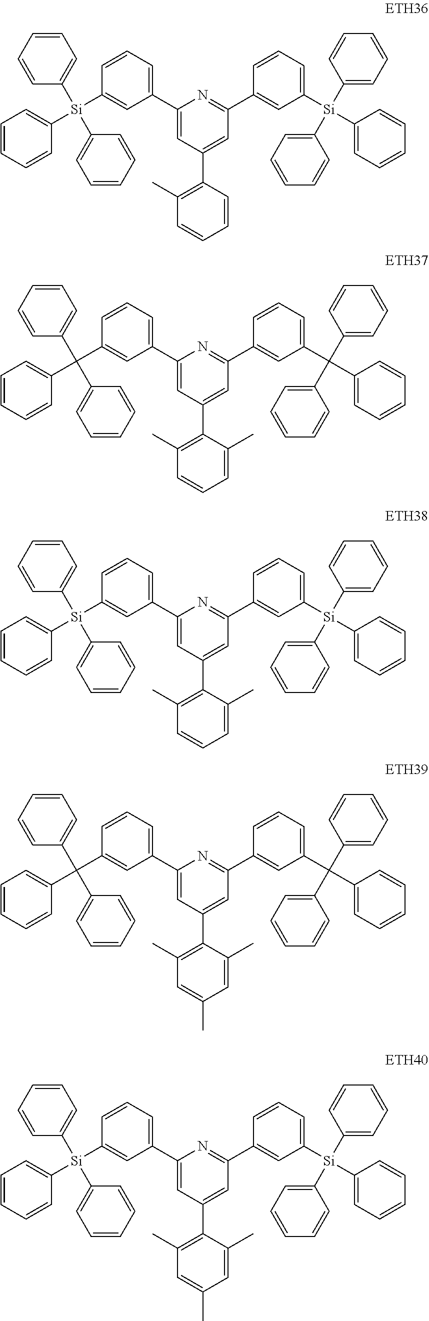

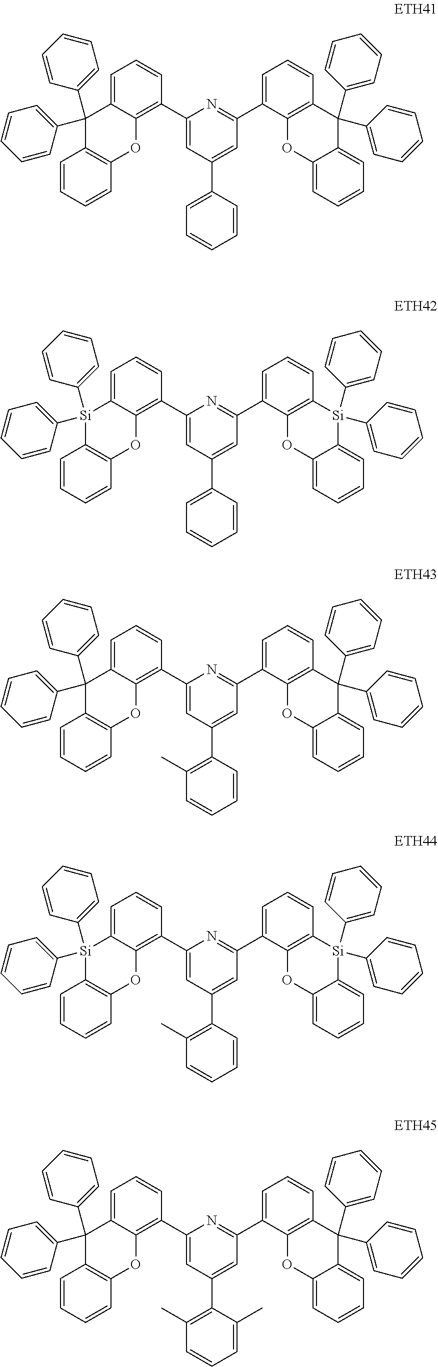

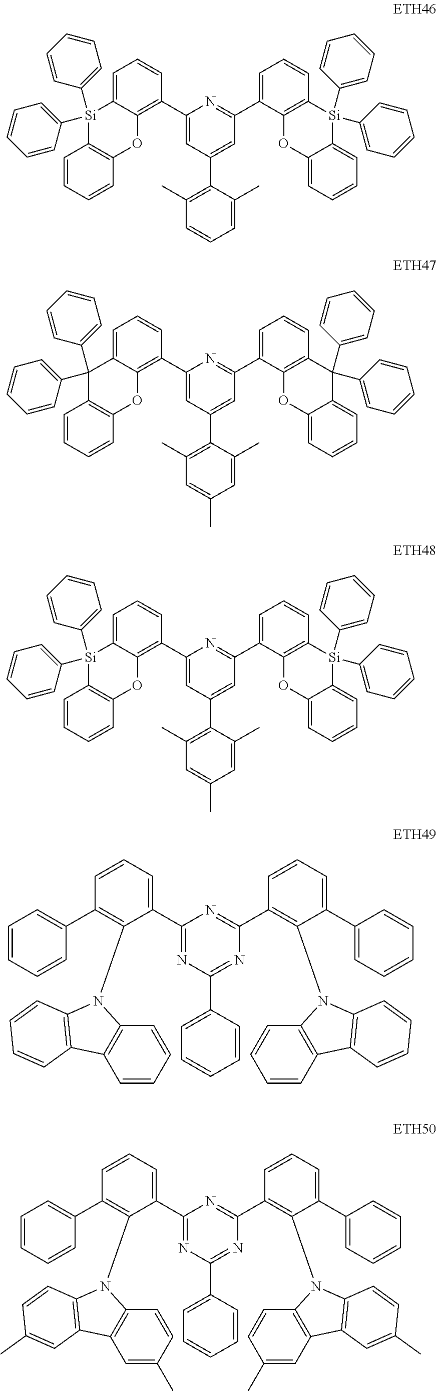

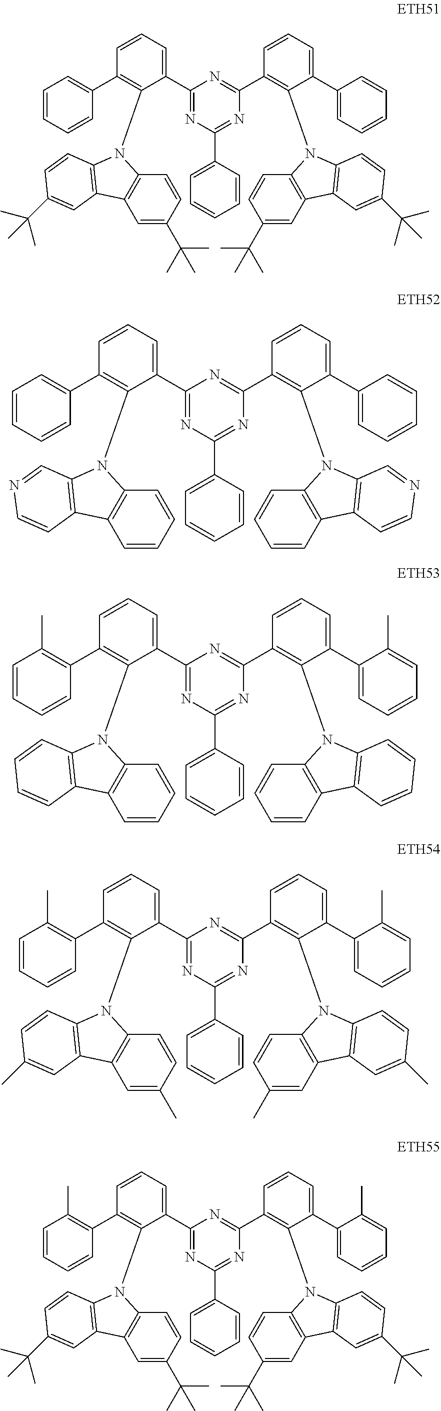

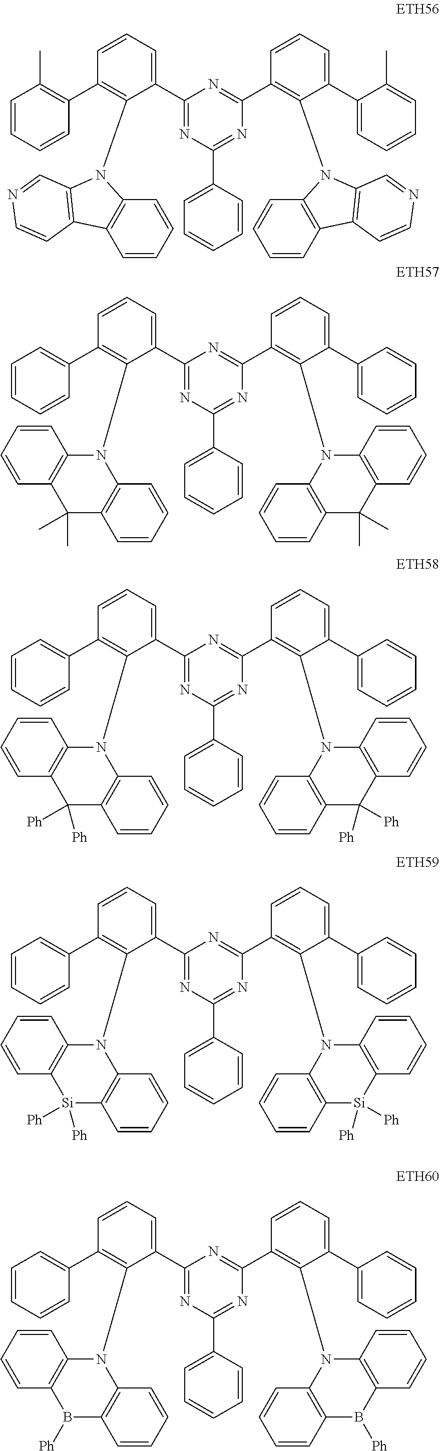

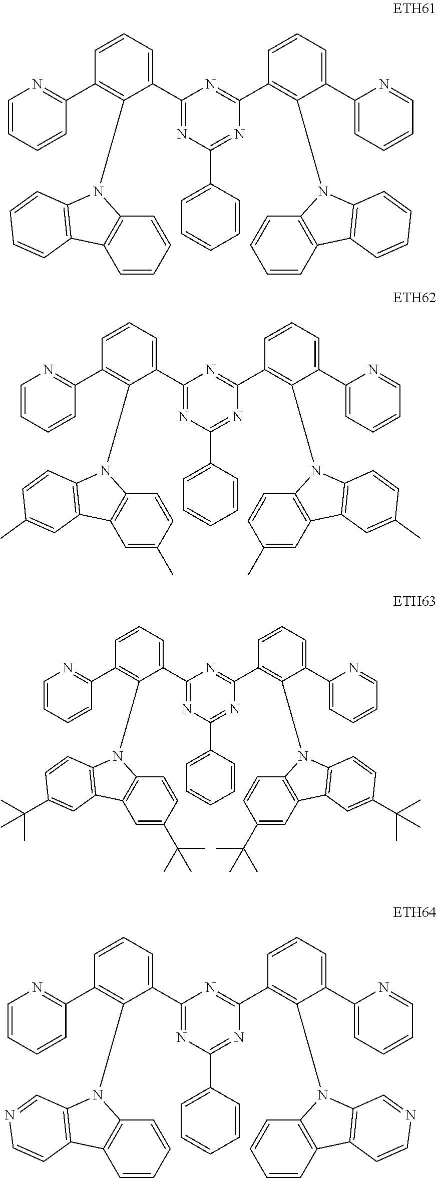

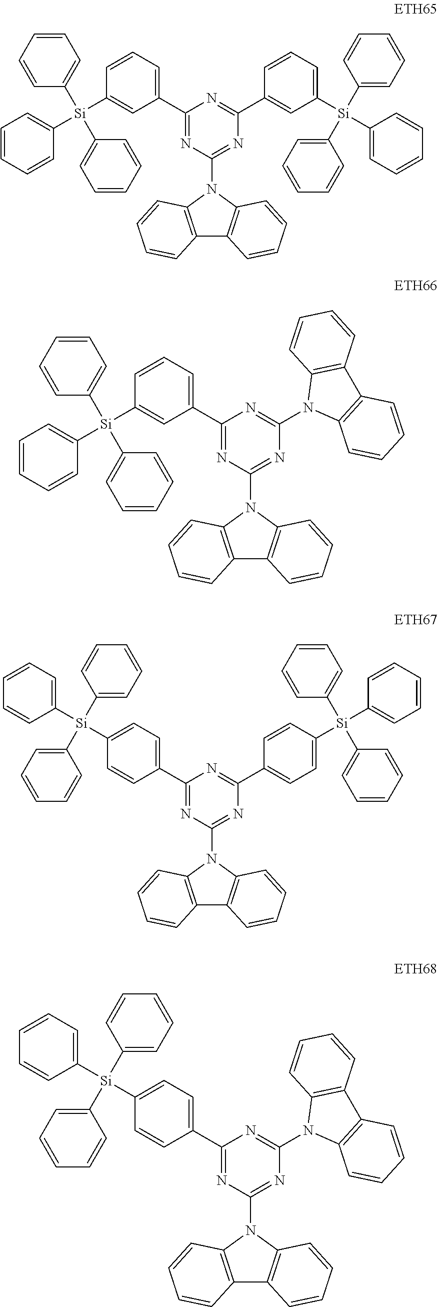 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

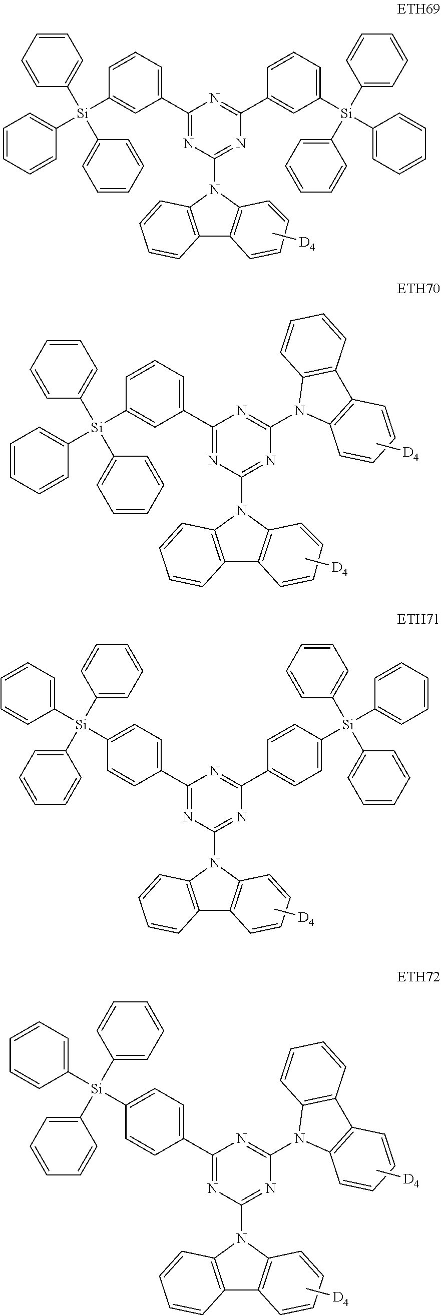

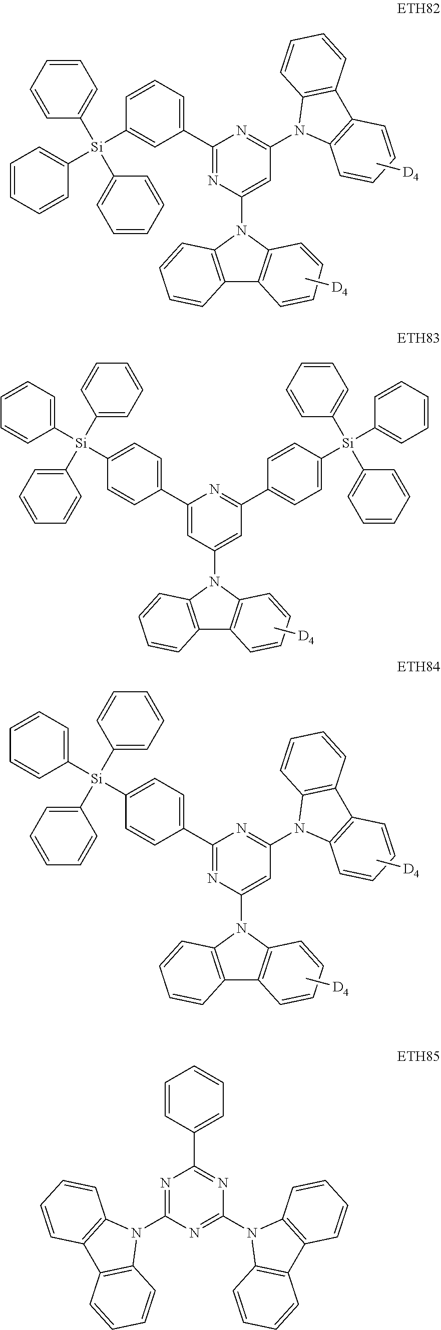

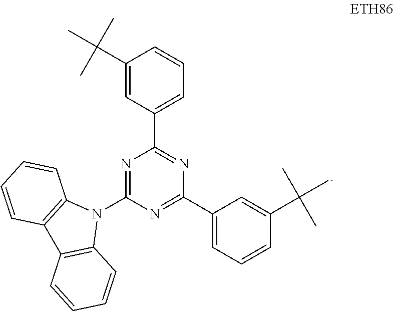 [SMILES: CC(C)(C)c1cccc(-c2nc(-c3cccc(C(C)(C)C)c3)nc(-n3c4ccccc4c4ccccc43)n2)c1]

In the compounds presented in Compound Group 3, “D” may refer to a deuterium atom, and “Ph” may refer to an unsubstituted phenyl group.

The emission layer EML may include the second compound and the third compound, and the second compound and the third compound may form an exciplex. In the emission layer EML, the exciplex may be formed by a hole transporting host and an electron transporting host. In this case, the triplet energy of the exciplex formed by the hole transporting host and the electron transporting host may correspond to a difference between a lowest unoccupied molecular orbital (LUMO) energy level of the electron transporting host and a highest occupied molecular orbital (HOMO) energy level of the hole transporting host.

For example, an absolute value of the triplet (T1) energy level of the exciplex formed by the hole transporting host and the electron transporting host may be about 2.4 eV to about 3.0 eV. In some embodiments, the triplet energy of the exciplex may be a smaller value than an energy gap of each host material. The exciplex may have a triplet energy of 3.0 eV or less, which may be an energy gap between the hole transporting host and the electron transporting host.

In one or more embodiments, the emission layer EML may further include a fourth compound, in addition to the first to third compounds according to the present embodiments. The fourth compound may be utilized as a phosphorescent sensitizer of the emission layer EML. Energy transfer from the fourth compound to the first compound may cause (e.g., facilitate) light to be emitted.

For example, the emission layer EML may include, as the fourth compound, an organometallic complex including platinum (Pt) as a central metal atom and including ligands bonded to the central metal atom. In the light-emitting element ED according to one or more embodiments, the emission layer EML may include a compound represented by Formula D-1 as the fourth compound.

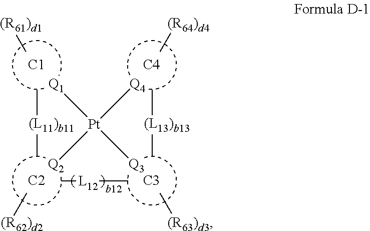

wherein, in Formula D-1, Q₁ to Q₄ may each independently be C or N. C1 to C4 may each independently be a substituted or unsubstituted hydrocarbon ring having 5 to 30 ring-forming carbon atoms or a substituted or unsubstituted hetero ring having 2 to 30 ring-forming carbon atoms.

In Formula D-1, L₁₁ to L₁₃ may each independently be a direct linkage,

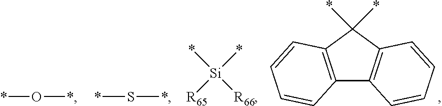

a substituted or unsubstituted divalent alkyl group having 1 to 20 carbon atoms, a substituted or unsubstituted arylene group having 2 to 30 carbon atoms, or a substituted or unsubstituted heteroarylene group having 2 to 30 ring-forming carbon atoms. In L₁₁ to L₁₃, “ [symbol] ” refers to a position connected with the respective ones of C₁ to C₄.

In Formula D-1, b11 to b13 may each independently be 0 or 1. When b11 is 0, C1 may not be connected (e.g., may not be bonded) with C2. When b12 is 0, C2 may not be connected (e.g., may not be bonded) with C3. When b13 is 0, C3 may not be connected (e.g., may not be bonded) with C4.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, R₆₁ to R₆₆ may be each independently combined with an adjacent group to form a ring. R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, when d1 to d4 are each 0, the fourth compound may be unsubstituted with R₆₁ to R₆₄. The case where d1 to d4 are each 4 and R₆₁ to R₆₄ are each a hydrogen atom may be the same as the case where d1 to d4 are each 0. When d1 to d4 are each an integer of 2 or more, R₆₁ to R₆₄ provided in plural may each be the same as each other, or at least one thereof may be different from the others.

In Formula D-1, C1 to C4 may each independently be a substituted or unsubstituted hydrocarbon ring or a substituted or unsubstituted hetero ring represented by any one selected from among C-1 to C4:

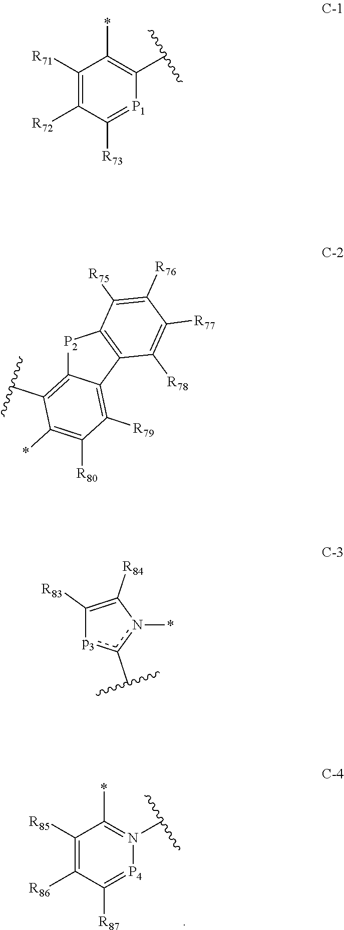

In C-1 to C-4, P₁ may be [symbol] or CR₇₄, P₂ may be [symbol] or NR₈₁, P₃ may be [symbol] or NR₈₂, and P₄ may be [symbol] or CR₈₈. R₇₁ to R₈₈ may each independently be substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In some embodiments, in C-1 to C-4, “ [symbol] ” is a portion connected to Pt, which is a central metal atom in Formula D-1, and “ [symbol] ” is a portion connected to a neighboring ring (C1 to C4) and/or a linker (L₁₁ to L₁₃).

The emission layer EML according to one or more embodiments may include the first compound, which is a polycyclic compound, and at least one selected from among second to fourth compounds. For example, the emission layer EML may include the first compound, the second compound, and the third compound. The second compound and the third compound may form an exciplex in the emission layer EML, and energy transfer from the exciplex to the first compound may cause (e.g., facilitate) light to be emitted.

In some embodiments, the emission layer EML may include the first compound, the second compound, the third compound, and the fourth compound. The second compound and the third compound may form an exciplex in the emission layer EML, and energy transfer from the exciplex to the fourth and first compounds may cause (e.g., facilitate) light to be emitted. In one or more embodiments, the fourth compound may be a sensitizer. In the light-emitting element ED according to one or more embodiments, the fourth compound included in the emission layer EML may serve as the sensitizer to play a role in transferring energy from a host to the first compound which is an emission dopant. For example, the fourth compound that serves as an auxiliary dopant may accelerate energy transfer to the first compound, which is the emission dopant, thereby increasing in an emission rate of the first compound. Therefore, the emission layer EML according to one or more embodiments may have improved light emission efficiency. In some embodiments, when energy transfer to the first compound increases, excitons formed in the emission layer EML are not accumulated inside the emission layer EML and may cause (e.g., facilitate) light to be emitted rapidly, thereby mitigating or reducing the deterioration of the light-emitting element. Therefore, the light-emitting element ED according to one or more embodiments may have an improved lifespan.

The light-emitting element ED according to one or more embodiments includes all of the first compound, the second compound, the third compound, and the fourth compound, and thus the emission layer EML may include a combination of two host materials and two dopant materials. In the light-emitting element ED according to one or more embodiments, the emission layer EML may include the second compound and the third compound, which are two different hosts, the first compound emitting (e.g., configured to emit) delayed fluorescence, and the fourth compound including an organometallic complex at the same time, thereby exhibiting excellent or suitable light emission efficiency characteristics.

In one or more embodiments, the fourth compound represented by Formula D-1 may be represented by at least one selected from among compounds represented in Compound Group 4. The emission layer EML may include, as a sensitization material, at least one of compounds represented in Compound Group 4.

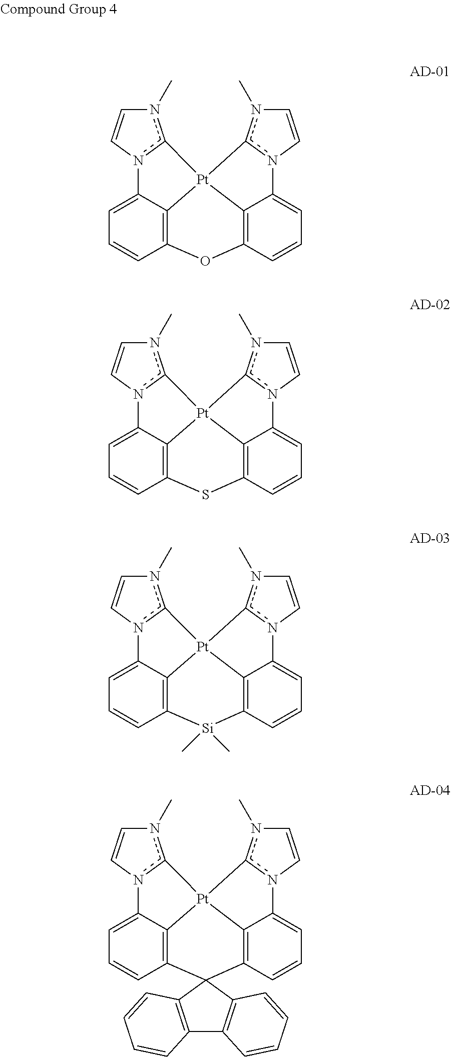

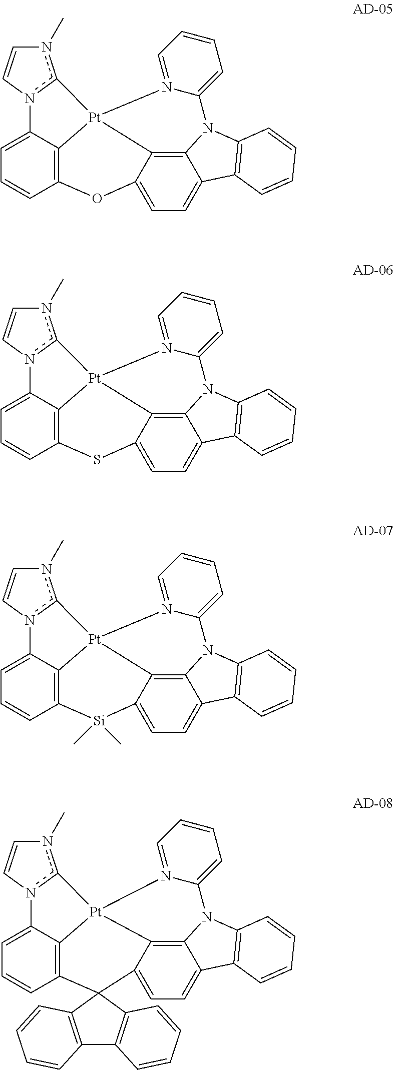

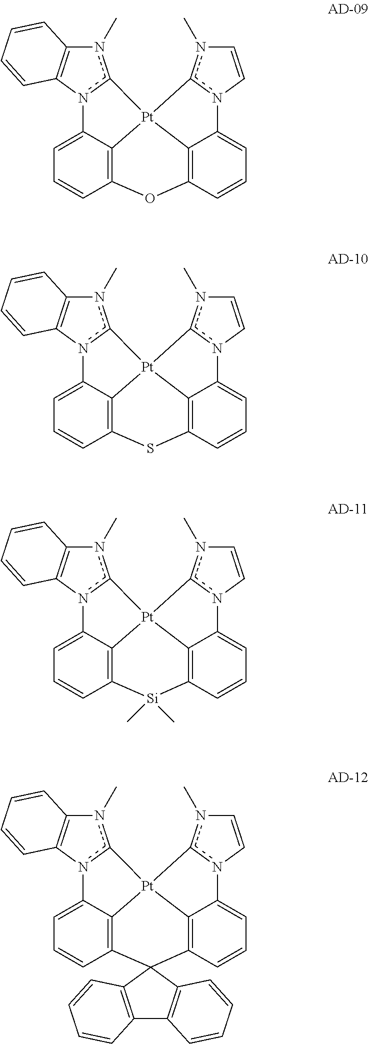

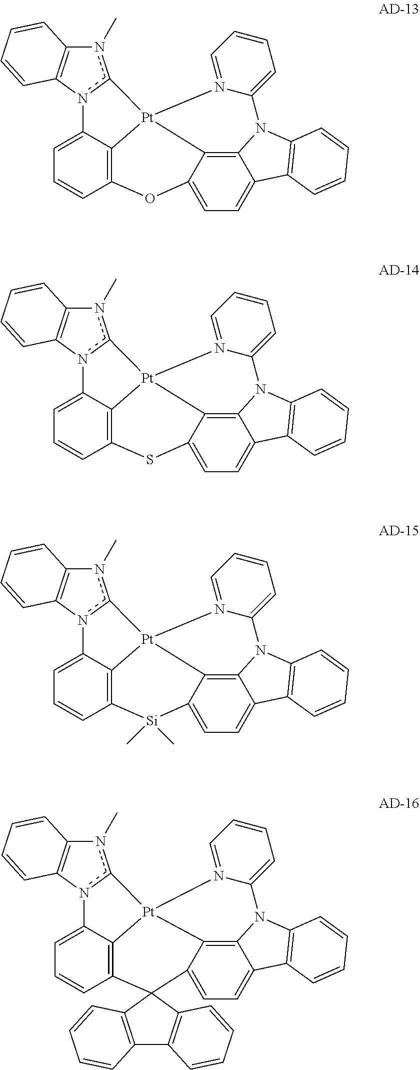

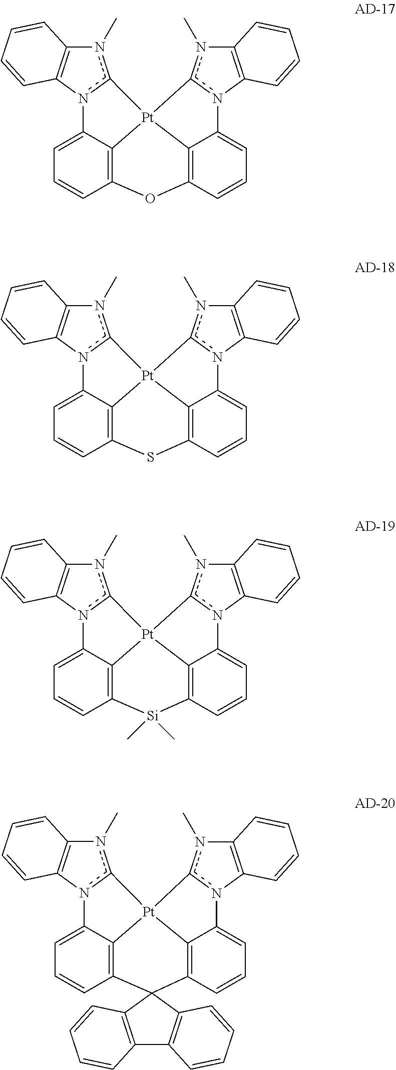

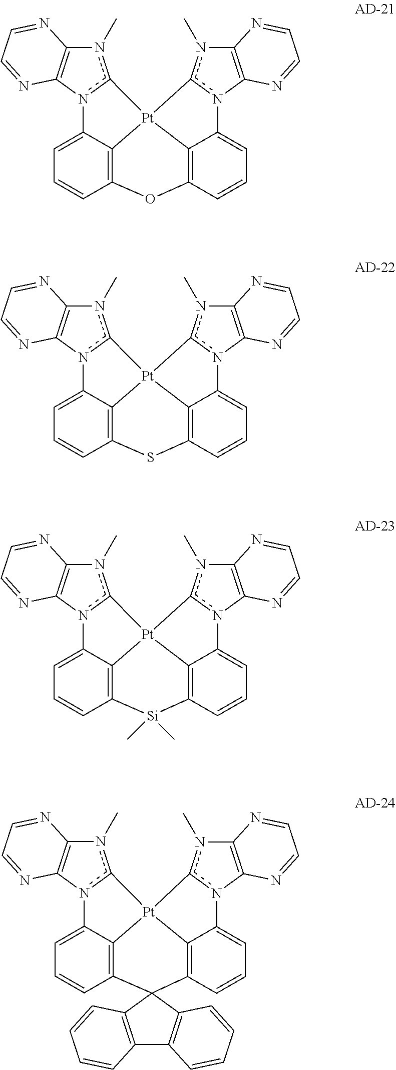

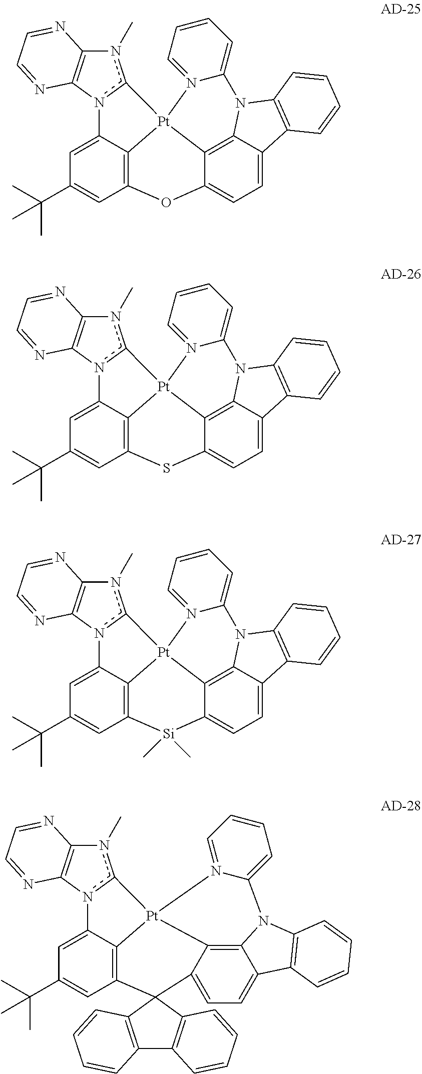

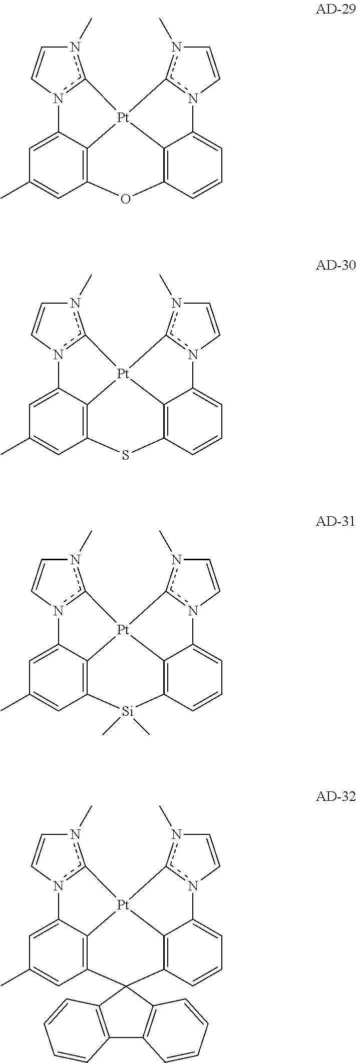

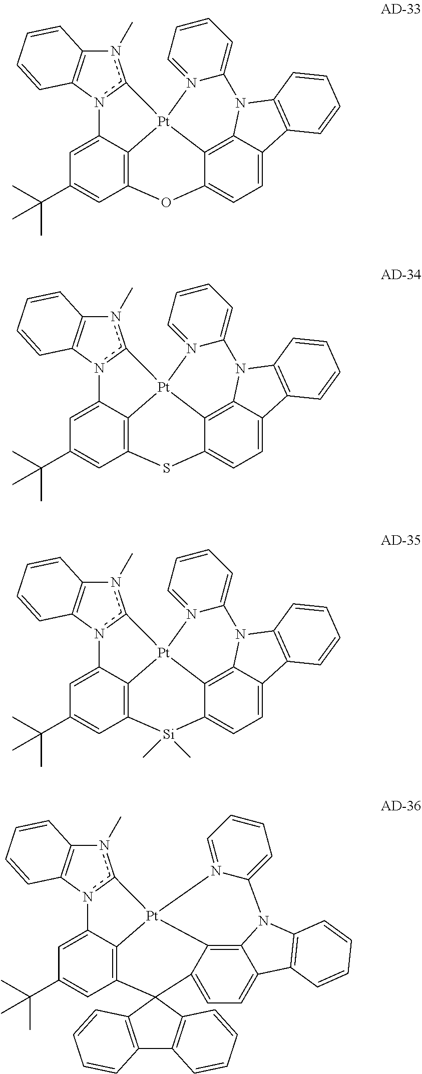

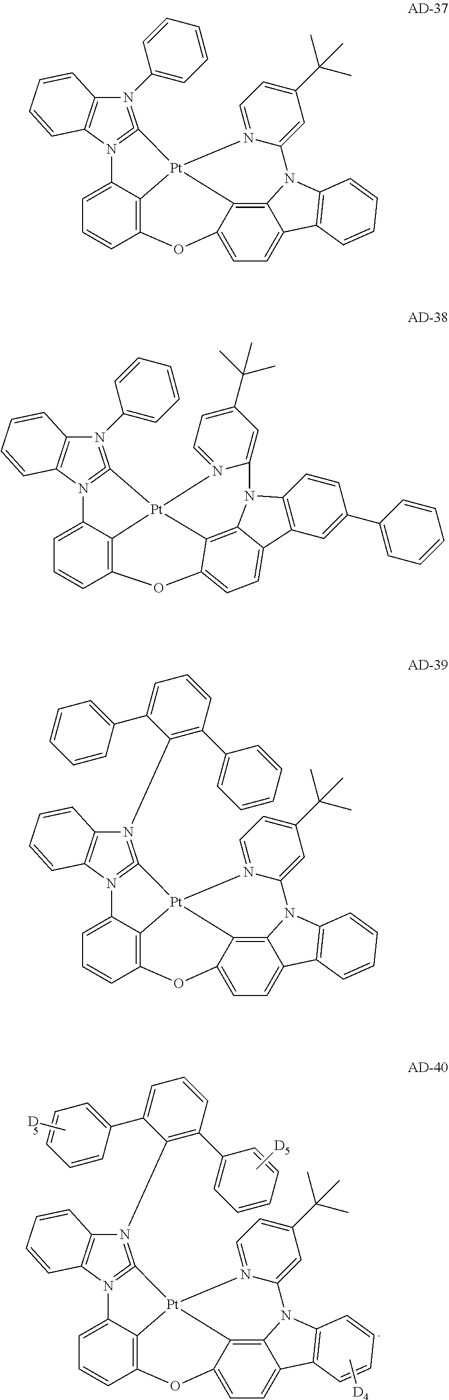

In the compounds presented in Compound Group 4, “D” may refer to a deuterium atom.

In the light-emitting element ED according to one or more embodiments, when the emission layer EML includes all the first compound, the second compound, and the third compound according to the present embodiments, an amount of the first compound may be 0.1 wt % to 5 wt % with respect to a total weight of the first compound, the second compound, and the third compound. However, one or more embodiments of the present disclosure is not limited thereto. When the amount of the first compound falls within a ratio (e.g., amount) as defined herein, the energy transfer from the second compound and the third compound to the first compound may increase, and thus light emission efficiency and the element lifespan may increase.

The amounts of the second compound and the third compound in the emission layer EML may be a remaining weight except for the weight of the first compound. For example, the amounts of the second compound and the third compound in the emission layer EML may be 65 wt % to 95 wt % with respect to the total weight of the first compound, the second compound, and the third compound.

A weight ratio of the second compound to the third compound may be about 3:7 to about 7:3 in the total weight of the second compound and the third compound.

When the amounts of the second compound and the third compound fall within the corresponding ratios described herein, charge balance characteristics in the emission layer EML may be improved, and thus light emission efficiency and the element lifespan may increase. When the amounts of the second compound and the third compound are out of the recited ranges, the charge balance in the emission layer EML may be lost to result in a decease in the light emission efficiency, and the element may relatively easily deteriorate.

When the emission layer EML includes the fourth compound, an amount of the fourth compound may be 10 wt % to 30 wt % with respect to the total weight of the first compound, the second compound, the third compound, and the fourth compound in the emission layer EML. However, one or more embodiments of the present disclosure is not limited thereto. When the amount of the fourth compound falls within the amount according to the present embodiments, the energy transfer from the host to the first compound, which is the light-emitting dopant, may increase, thus an emission rate may be improved, and accordingly, the light emission efficiency of the emission layer EML may be improved. When the amounts of the first compound, the second compound, the third compound, and the fourth compound fall within content (e.g., amount) of the ratio ranges according to the present embodiments, excellent or suitable light emission efficiency and a long lifespan may be achieved.

The emission layer EML may have a thickness of, for example, about 100 Å to about 1000 Å, or about 100 Å to about 300 Å. The emission layer EML may have a single layer formed of a single material, a single layer formed of a plurality of different materials or a multilayer structure having a plurality of layers formed of a plurality of different materials.

Emission layers EML in light-emitting elements ED according to one or more embodiments, illustrated in FIGS. 3 to 7, may each include, as a dopant, a polycyclic compound according to the present embodiments. In some embodiments, the emission layers EML in the light-emitting elements ED according to embodiments, illustrated in FIGS. 3 to 7, may each include a first compound, which is a polycyclic compound according to one or more embodiments, and at least one of a second compound represented by Formula HT-1 or a third compound represented by Formula ET-1. In some embodiments, the emission layers EML in the light-emitting elements ED according to the embodiments, illustrated in FIGS. 3 to 7, may each include a first compound, which is a polycyclic compound according to one or more embodiments, a second compound represented by Formula HT-1, a third compound represented by Formula ET-1, and a fourth compound represented by Formula D-1.

In the light emitting element ED of one or more embodiments, the emission layer EML may further include an anthracene derivative, a pyrene derivative, a fluoranthene derivative, a chrysene derivative, a dehydrobenzanthracene derivative, and/or a triphenylene derivative. For example, the emission layer EML may include the anthracene derivative and/or the pyrene derivative.

In each light emitting element ED of embodiments illustrated in FIGS. 3 to 7, the emission layer EML may further include a suitable host and dopant, besides the above-described host and dopant, and for example the emission layer EML may include a compound represented by Formula E-1. The compound represented by Formula E-1 may be utilized as a fluorescent host material.

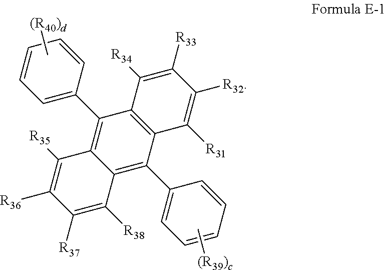

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer of 0 to 5.

Formula E-1 may be represented by any one selected from among Compound E1 to Compunds E19:

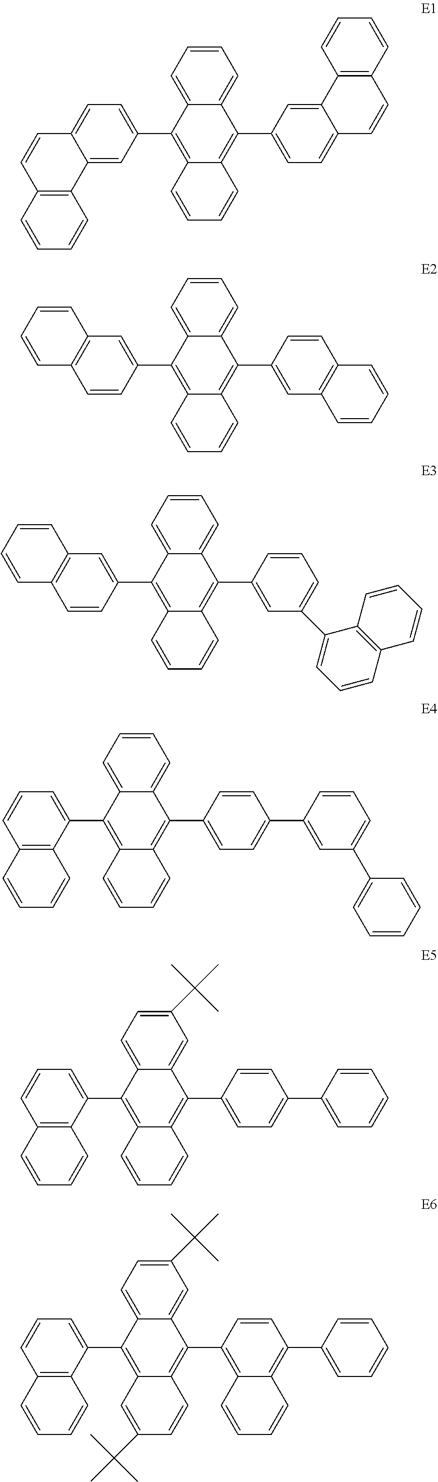

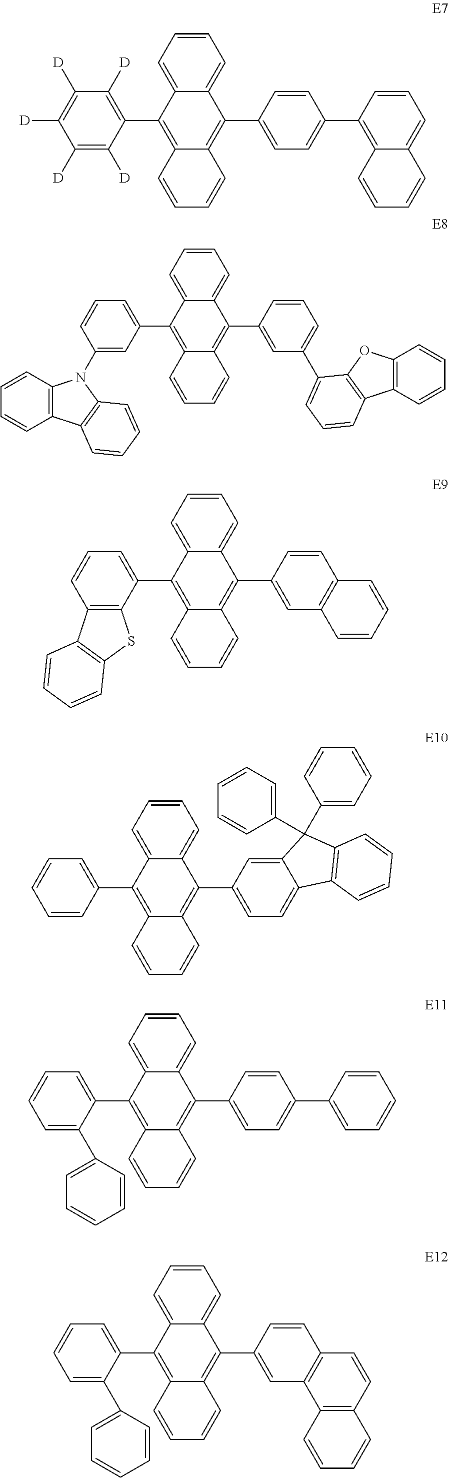

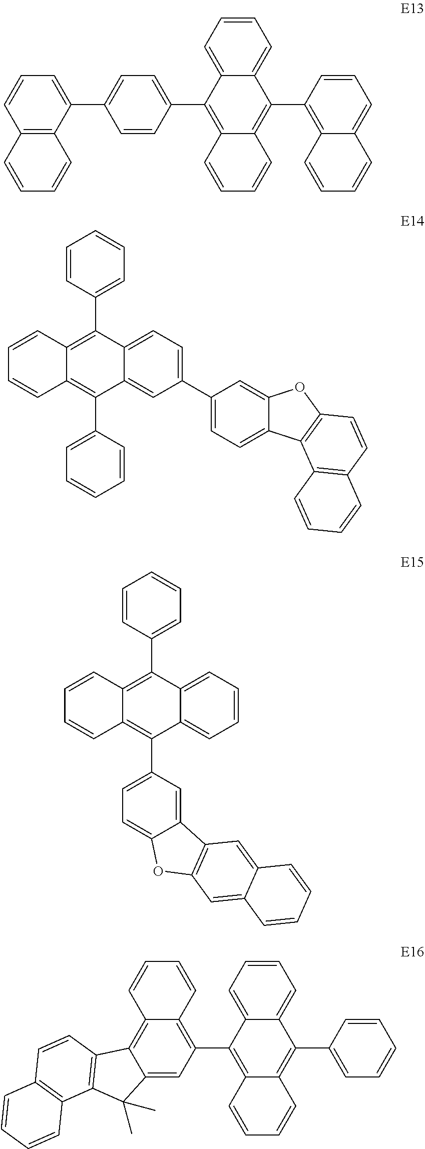

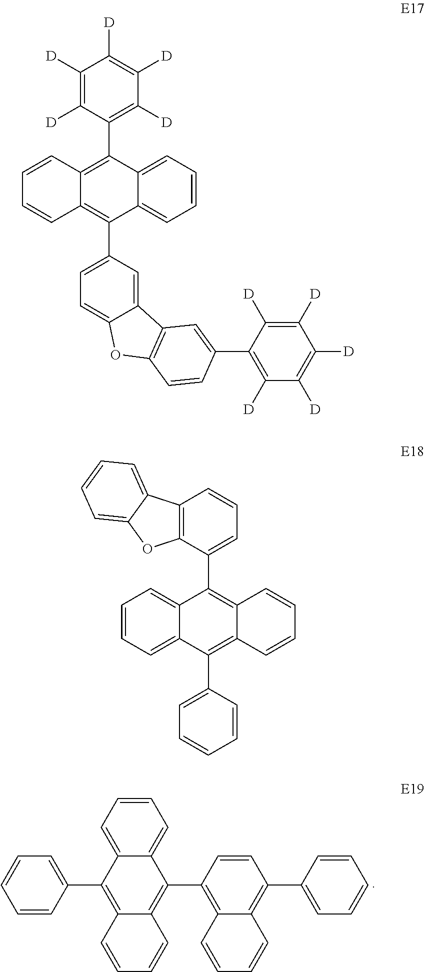

In one or more embodiments, the emission layer EML may include a compound represented by Formula E-2a or Formula E-2b. The compound represented by Formula E-2a or Formula E-2b may be utilized as a phosphorescent host material:

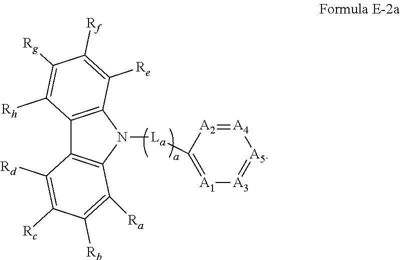

In Formula E-2a, a may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of Lₐ's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Rₐ to Rᵢ may be bonded to an adjacent group to form a hydrocarbon ring or a heterocycle containing N, O, S, etc., as a ring-forming atom.

In some embodiments, in Formula E-2a, two or three selected from among A₁ to A₅ may be N, and the rest may be CRᵢ.

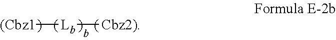

In Formula E-2b, Cbz1 and Cbz2 may each independently be an unsubstituted carbazole group, or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, b may be an integer of 0 to 10, and when b is an integer of 2 or more, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among the compounds of Compound Group E-2. However, the compounds listed in Compound Group E-2 are example, and the compound represented by Formula E-2a or Formula E-2b is not limited to those represented in Compound Group E-2.

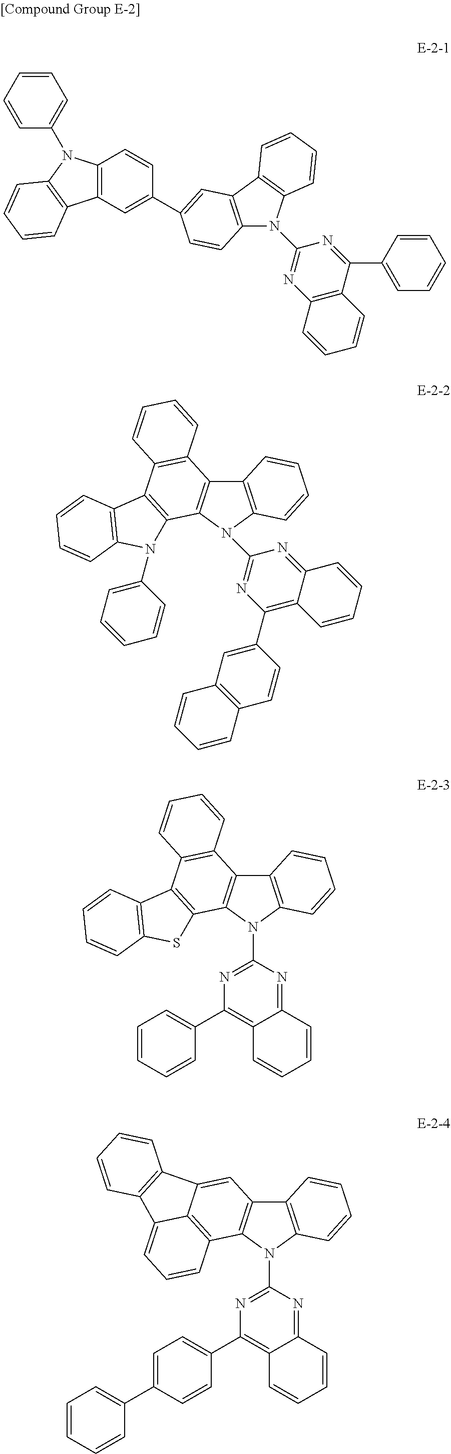

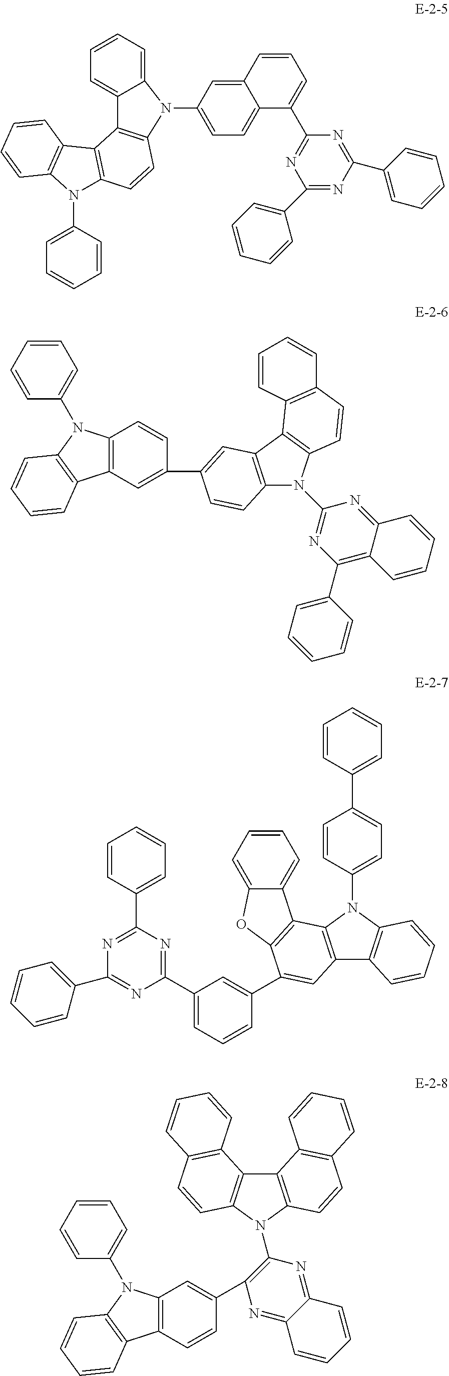 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

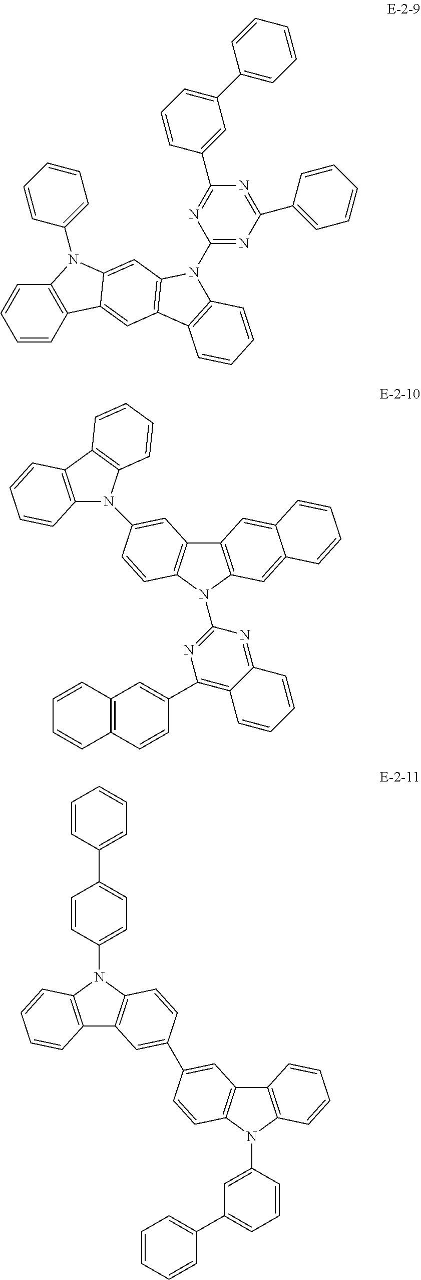

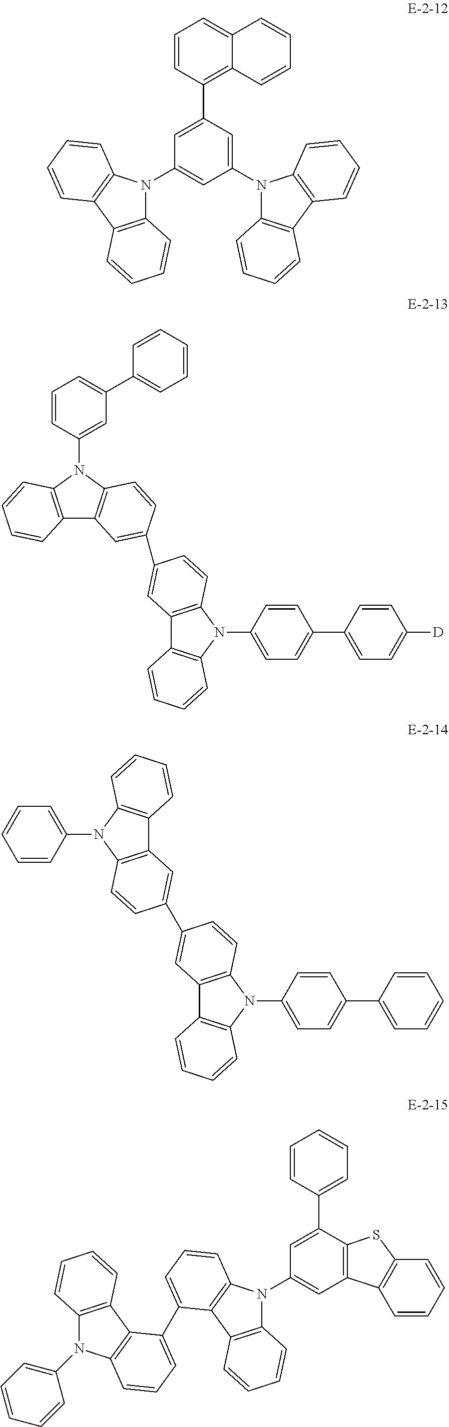 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

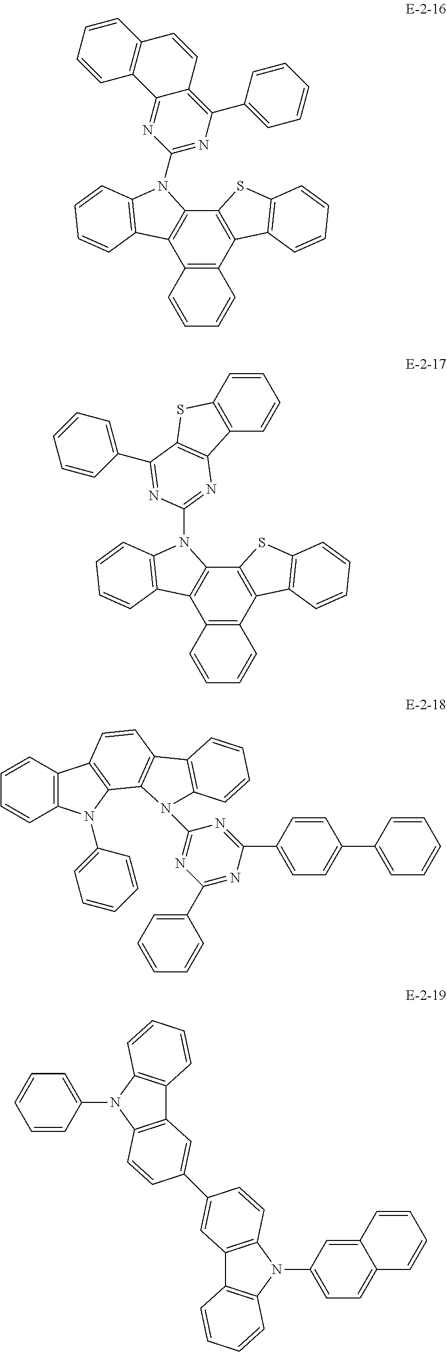 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

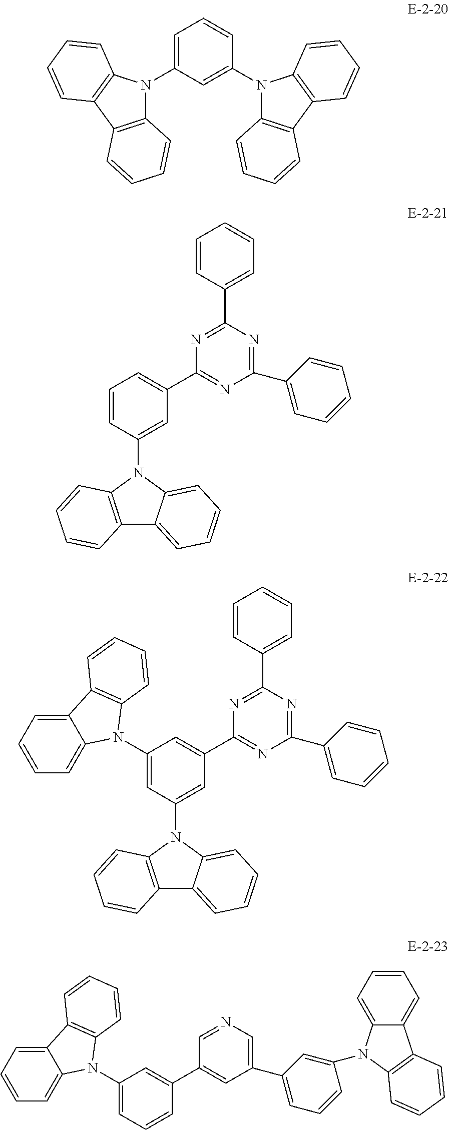 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

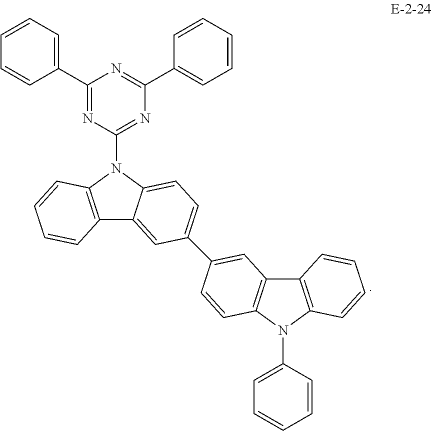 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may include the compound represented by Formula M-a. The compound represented by Formula M-a may be utilized as a phosphorescent dopant material:

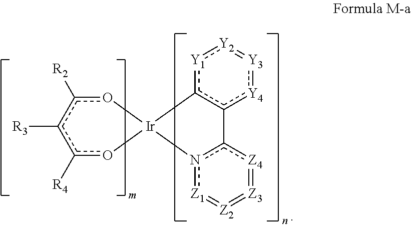

In Formula M-a, Y1 to Y4 and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be utilized as a phosphorescent dopant.

The compound represented by Formula M-a may be represented by any one selected from among Compound M-a1 to Compound M-a25. However, Compounds M-a1 to M-a25 are examples, and the compound represented by Formula M-a is not limited to those represented by Compounds M-a1 to M-a25:

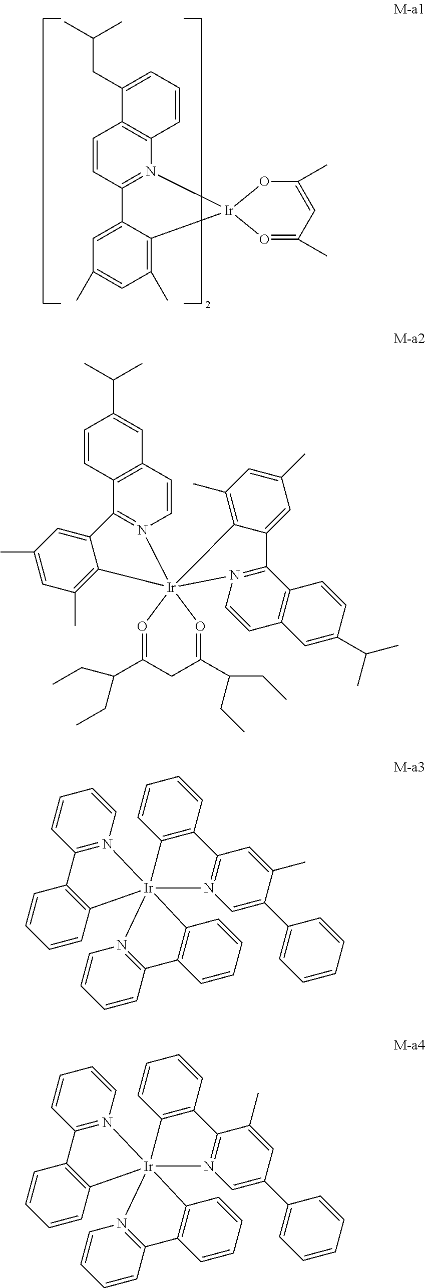

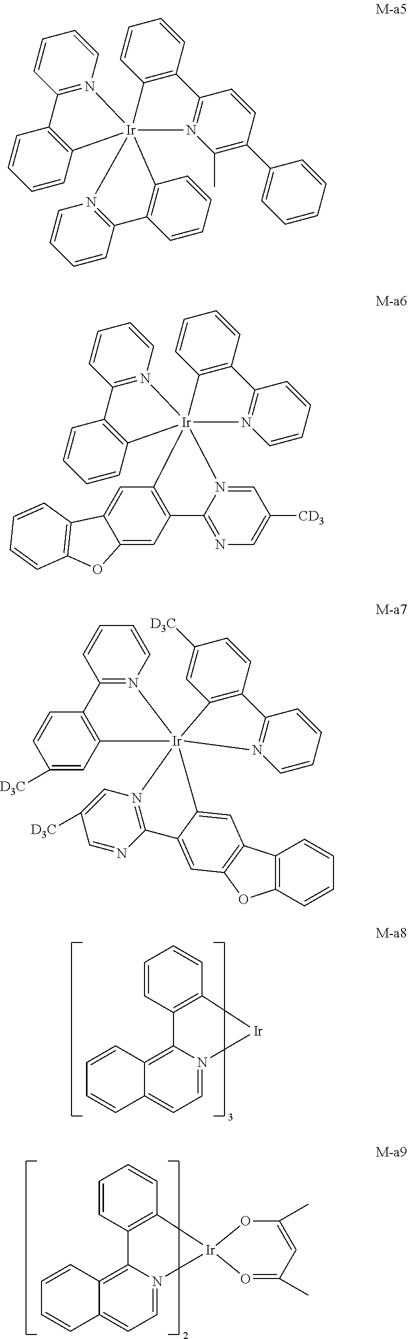

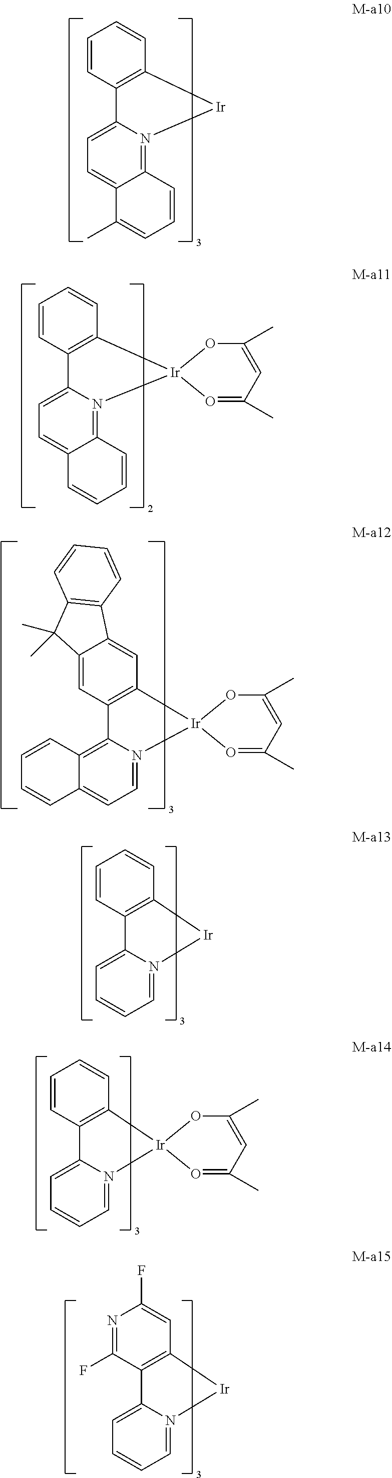

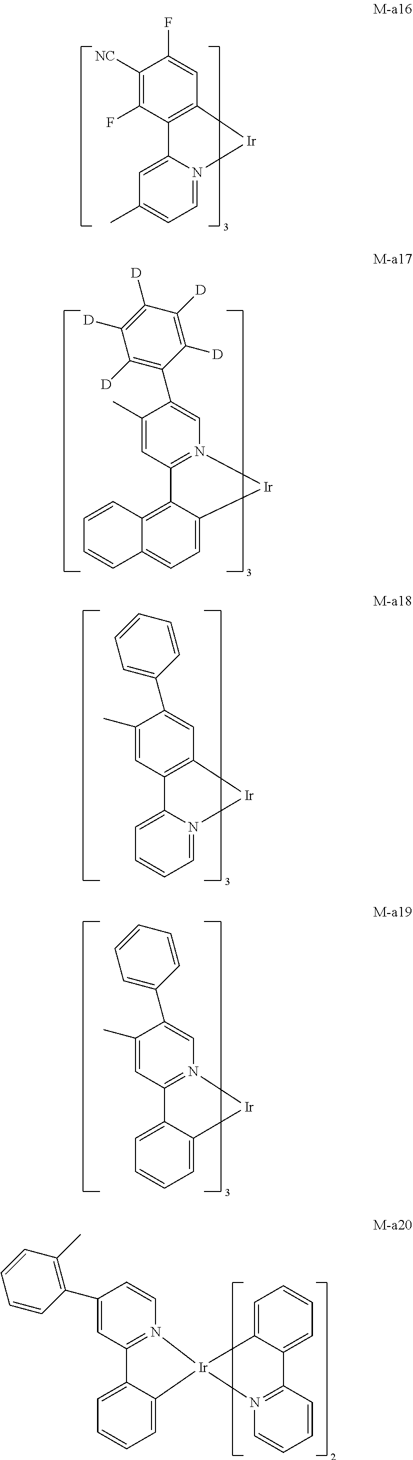

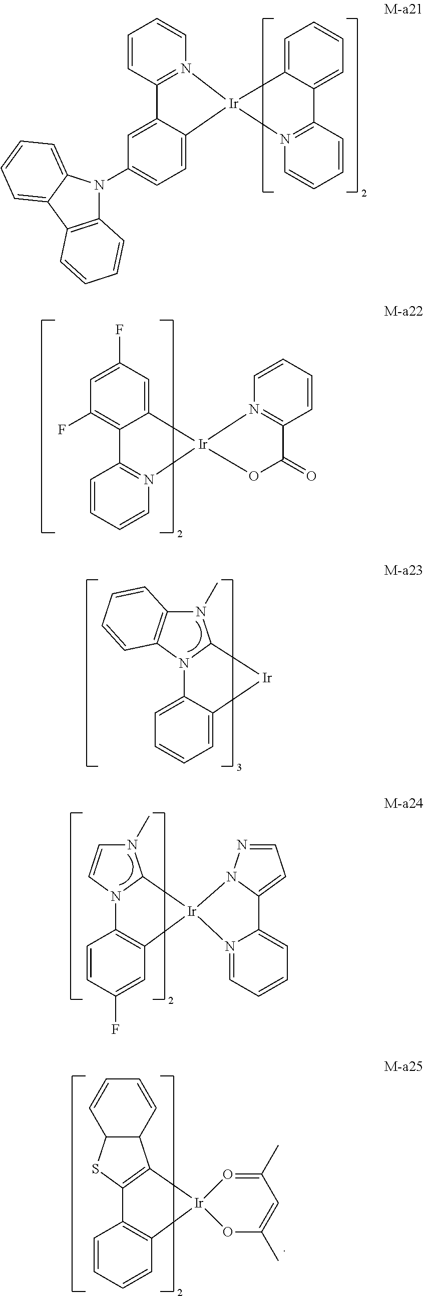

The emission layer EML may include a compound represented by any one selected from among Formula F-a to Formula F-c. The compound represented by Formula F-a to Formula F-c may be utilized as a fluorescence dopant material:

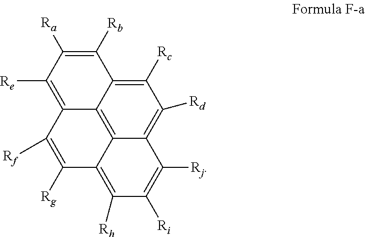

In Formula F-a, two selected from among Rₐ to Rⱼ may each independently be substituted with [symbol] NAr₁Ar₂. The others, which are not substituted with [symbol] NAr₁Ar₂ among Rₐ to Rⱼ, may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In [symbol] NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

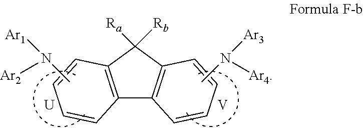

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms. At least one selected from among Ar₁ to Ar₄ may be a heteroaryl group containing O or S as a ring-forming atom.

In Formula F-b, the number of rings represented by U and V may each independently be 0 or 1. For example, in Formula F-b, when the number of U or V is 1, one ring constitutes a fused ring at a portion indicated by U or V, and when the number of U or V is 0, a ring indicated by U or V does not exist. For example, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

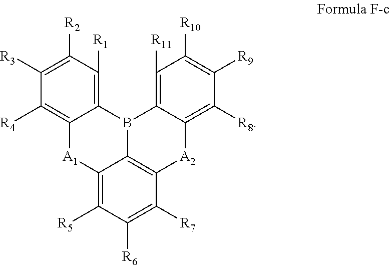

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring.

In Formula F-c, A₁ and A₂ may each independently be bonded to substituents of an adjacent ring to form a fused ring. For example, when A₁ and A₂ may each independently be NRₘ, A₁ may be bonded to R₄ or R₅ to form a ring. In some embodiments, A₂ may be bonded to R₇ or R₈ to form a ring.

In one or more embodiments, the emission layer EML may further include, as a suitable dopant material, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and/or N-(4-((E)-2-(6-((E)-4-(diphenylamino)styryl)naphthalen-2-yl)vinyl)phenyl)-N-phenylbenzenamine (N-BDAVBi)), 4,4′-bis[2-(4-(N,N-diphenylamino)phenyl)vinyl]biphenyl (DPAVBi), perylene and/or a derivative thereof (e.g., 2,5,8,11-tetra-t-butylperylene (TBP)), pyrene and/or a derivative thereof (e.g., 1,1-dipyrene, 1,4-dipyrenylbenzene, 1,4-bis(N,N-diphenylamino)pyrene), etc.

The emission layer EML may further include a suitable phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), and/or thulium (Tm) may be utilized as a phosphorescent dopant. For example, iridium(III) bis(4,6-difluorophenylpyridinato-N,C2) (FIrpic), bis(2,4-difluorophenylpyridinato)-tetrakis(1-pyrazolyl)borate iridium(III) (Fir6), and/or platinum octaethyl porphyrin (PtOEP) may be utilized as a phosphorescent dopant. However, the embodiment of the present disclosure is not limited thereto.

The emission layer EML may include a quantum dot material. The core of the quantum dots may be selected from among a Group II-VI compound, a Group I-II-VI compound, a Group II-IV-VI compound, a Group I-II-IV-VI compound, a Group II-IV-V compound, a Group III-VI compound, a Group I-III-VI compound, a Group III-V compound, a Group III-II-V compound, a Group IV-VI compound, a Group IV element, a Group IV compound, and combinations thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and mixtures thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and mixtures (or combinations) thereof.

The Group III-VI compound may include a binary compound such as In₂S₃ and/or In₂Se₃, a ternary compound such as InGaS₃ and/or InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and mixtures thereof, and/or a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In some embodiments, the Group III-V compound may further include a Group II metal. For example, InZnP, etc., may be selected as a Group III-II-V compound.

The Group IV-VI compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The Group IV element may be selected from the group consisting of Si, Ge, and mixtures thereof. The Group IV compound may be a binary compound selected from the group consisting of SiC, SiGe, and mixtures thereof.

Each element included in a polynary compound such as the binary compound, the ternary compound, and/or the quaternary compound may be present in a particle with a substantially uniform or non-substantially uniform concentration distribution. For example, the formulae refer to the types (kinds) of elements included in the compounds, and the elemental ratio in the compound may be different. For example, AgInGaS₂ may refer to AgInₓGa₁₋ₓS₂ (where x is a real number of 0 to 1).

In some embodiments, the quantum dot may have a single structure or a double structure of core-shell in which the concentration of each element included in the quantum dot is substantially uniform. For example, the material included in the core may be different from the material included in the shell.

The shell of the quantum dot may serve as a protection layer to prevent or reduce the chemical deformation of the core to maintain semiconductor properties, and/or a charging layer to impart electrophoresis properties to the quantum dot. The shell may be a single layer or a multilayer. An interface between the core and the shell may have a concentration gradient in which the concentration of an element present in the shell becomes lower towards the center.

An example of the shell of the quantum dots may include a metal oxide, a non-metal oxide, a semiconductor compound, or a combination thereof. For example, the metal oxide and the non-metal oxide may be a binary compound (such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO), and/or a ternary compound (such as MgAl₂O₄, CoFe₂O₄, NiFe₂O₄, and/or CoMn₂O₄), but the embodiment of the present disclosure is not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the embodiment of the present disclosure is not limited thereto.

Each element included in a polynary compound such as the binary compound and/or the ternary compound may be present in a particle with a substantially uniform or non-substantially uniform concentration distribution. For example, the formulae refer to the types (kinds) of elements included in the compounds, and the elemental ratio in the compound may be different.

The quantum dot may have a full width of half maximum (FWHM) of an emission wavelength spectrum of about 45 nm or less, about 40 nm or less, and more about 30 nm or less, and color purity and/or color reproducibility may be improved in the above range. In some embodiments, light emitted through such a quantum dot is emitted in all directions, and thus a wide viewing angle may be improved.

In some embodiments, although the form of the quantum dot is not particularly limited as long as it is a suitable form in the art, for example, the quantum dot in the form of spherical, pyramidal, multi-arm, and/or cubic nanoparticles, nanotubes, nanowires, nanofibers, nanoplate particles, etc. may be utilized.

As the size of the quantum dot is adjusted and/or the elemental ratio in the quantum dot compound is adjusted, it is possible to control the energy band gap, and thus light in one or more suitable wavelength ranges may be obtained in the quantum dot emission layer. Therefore, the quantum dot as above (utilizing different sizes of quantum dots and/or different elemental ratios in the quantum dot compound) is utilized, and thus the light emitting element, which emits light in one or more suitable wavelengths, may be implemented. For example, the adjustment of the size of the quantum dot and/or the elemental ratio in the quantum dot compound may be selected to emit red, green, and/or blue light. In some embodiments, the quantum dots may be configured to emit white light by combining one or more suitable colors of light.

In each of the light emitting devices ED of embodiments illustrated in FIGS. 3 to 7, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but the embodiment of the present disclosure is not limited thereto. The electron transport region ETR may have a thickness, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-2:

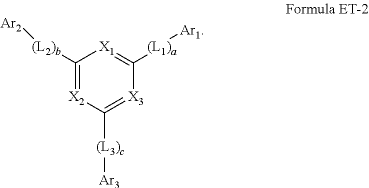

In Formula ET-2, at least one selected from among X₁ to X₃ is N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c may each independently be an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alqa), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyrdin-3-yl)phenyl]benzene (BmPyPhB), or a mixture thereof.

The electron transport region ETR may include at least one selected from among Compound ET1 to Compound ET36:

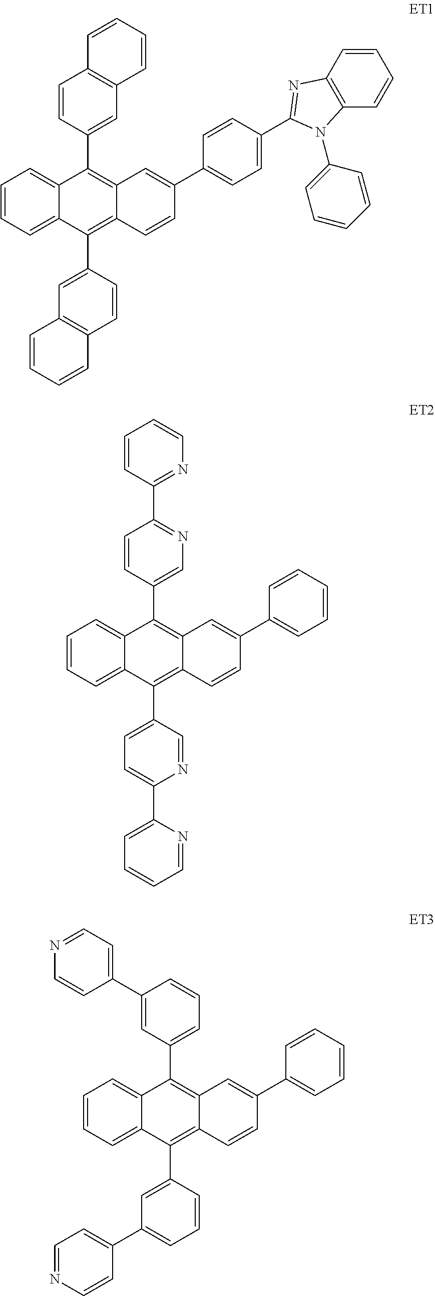 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

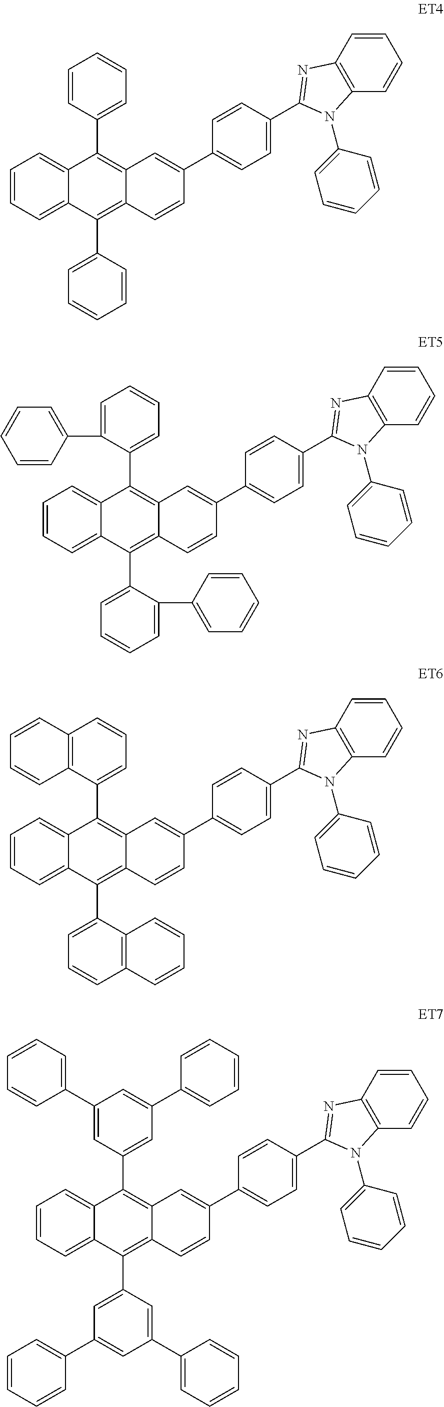 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

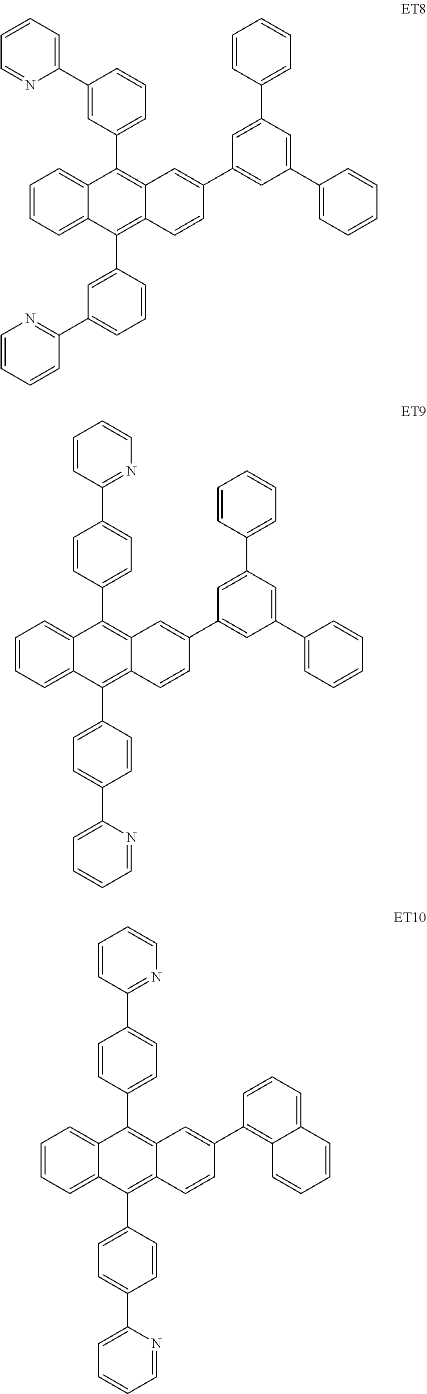 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

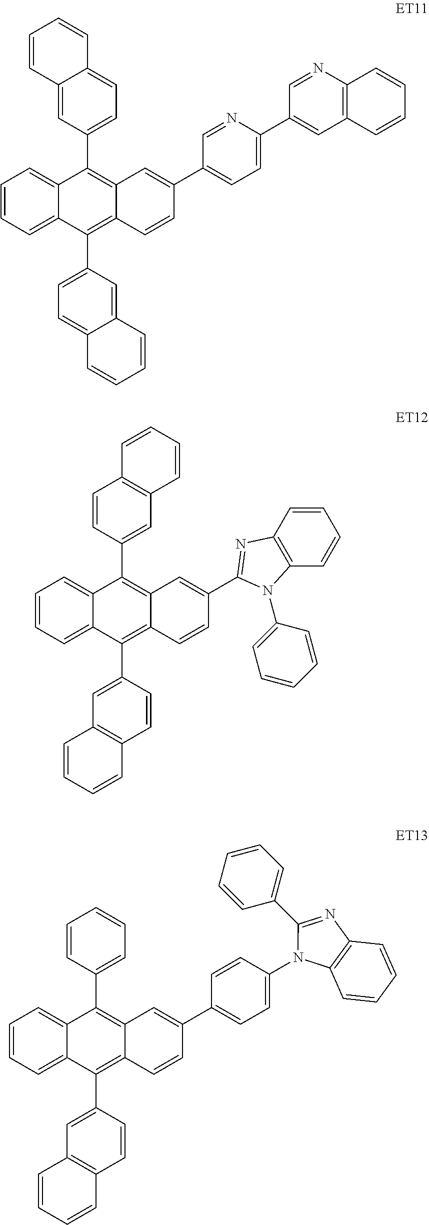 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

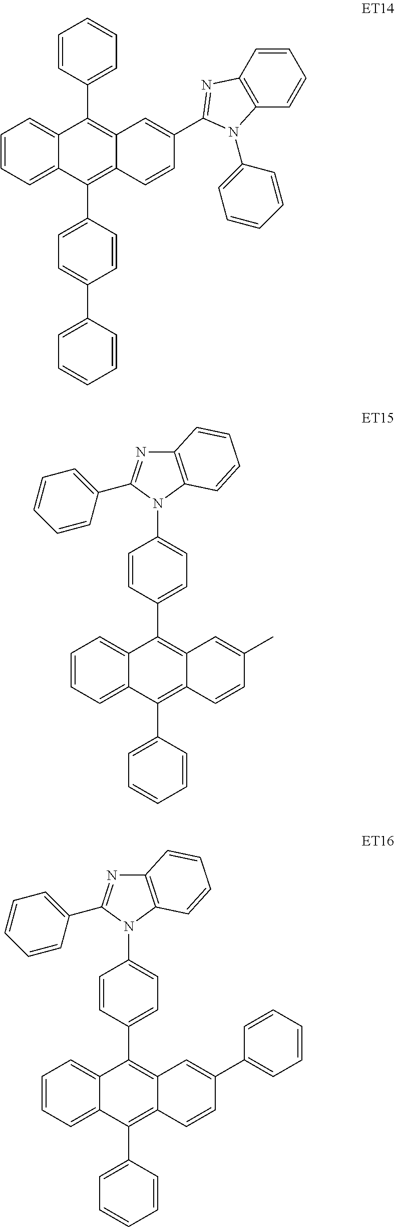 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

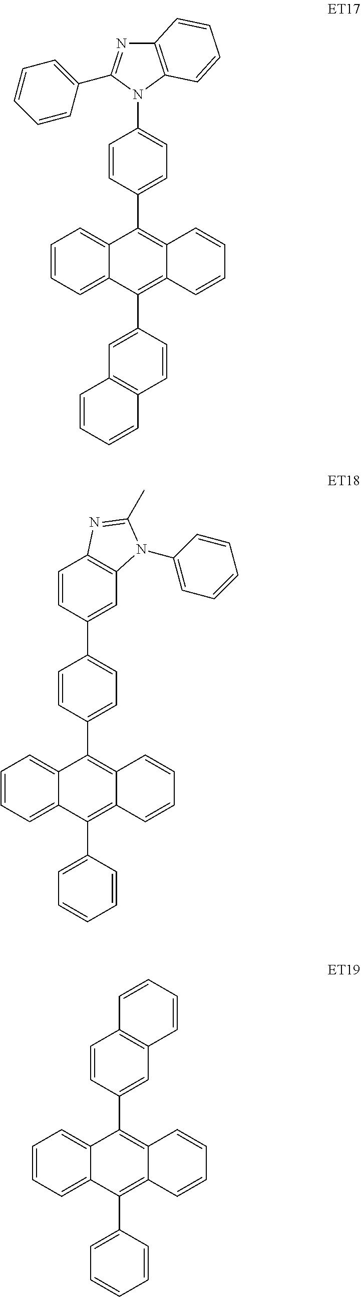

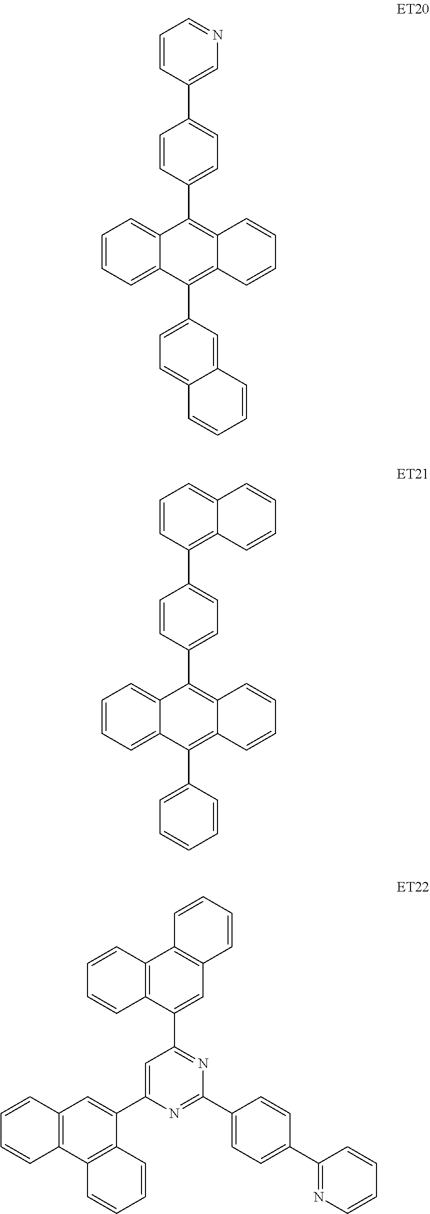

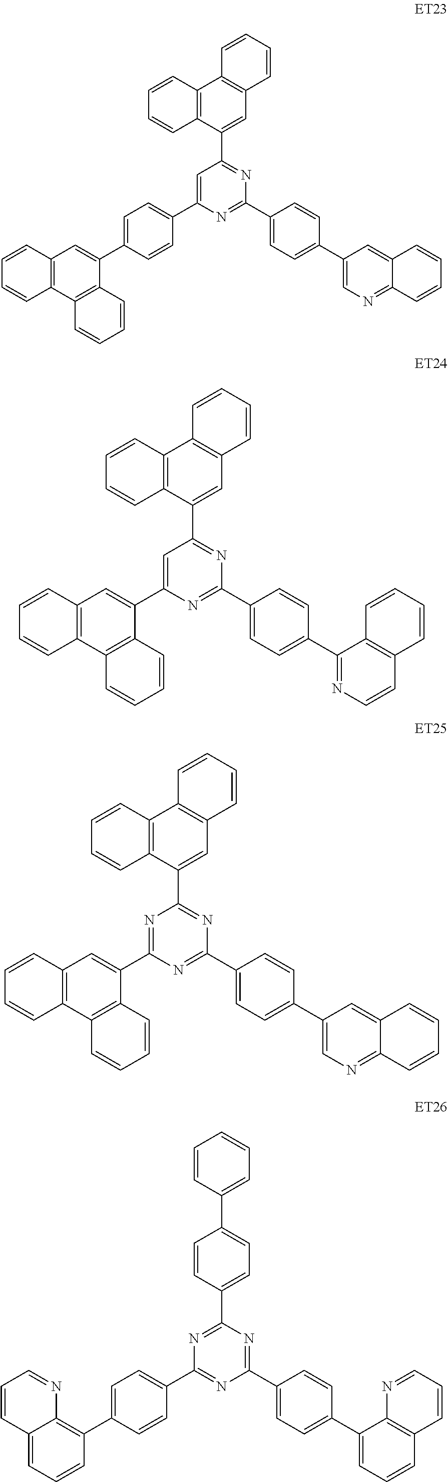 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

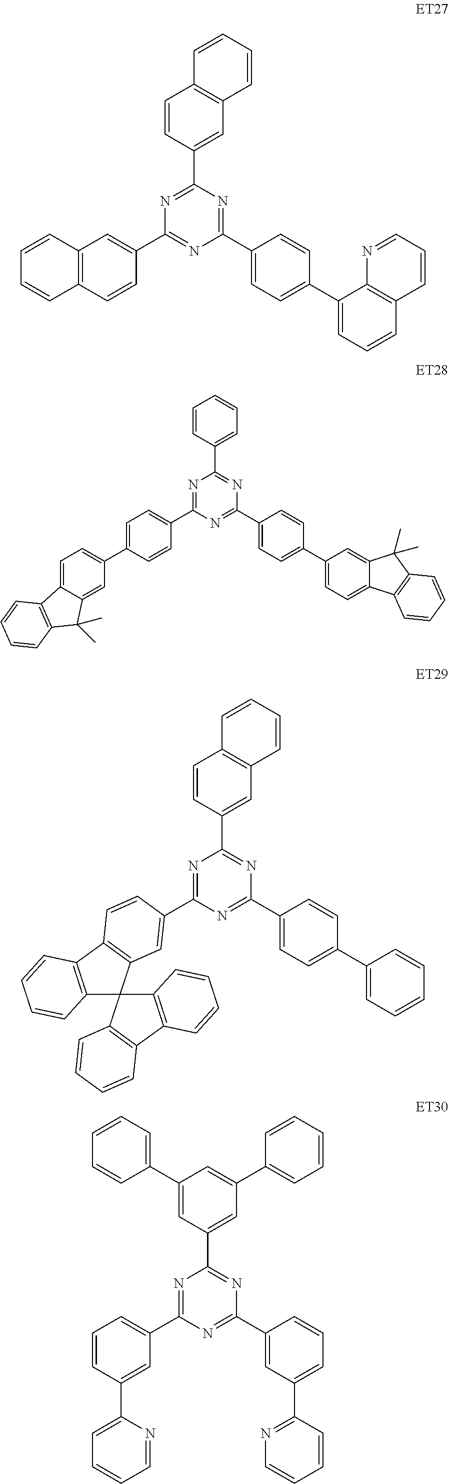

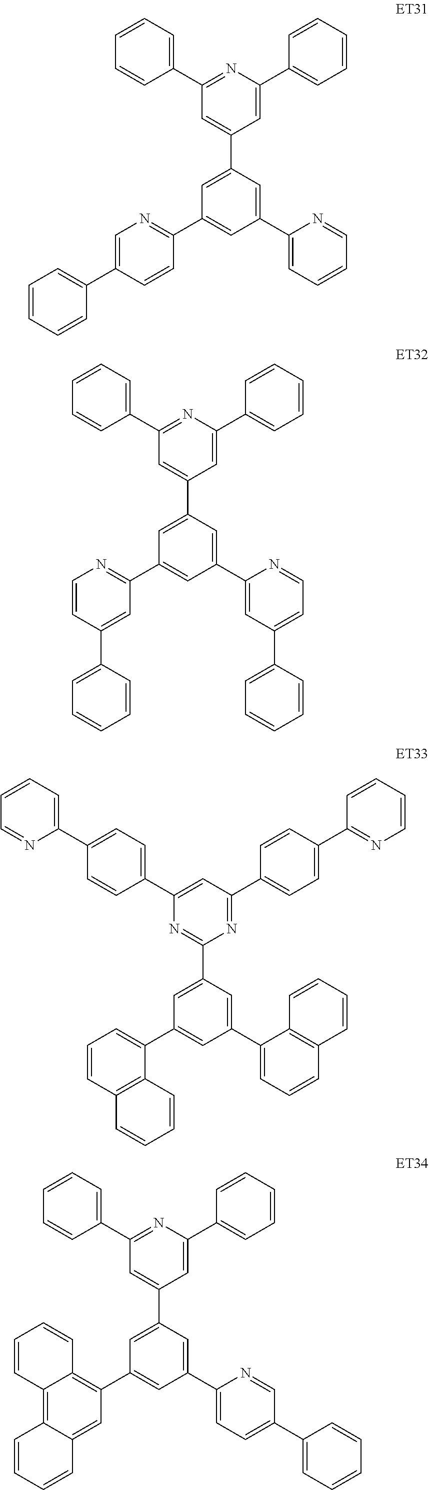 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

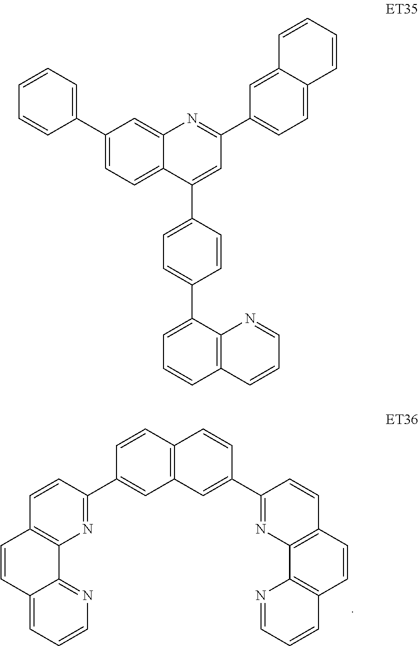

In some embodiments, the electron transport region ETR may include a metal halide such as LiF, NaCl, CsF, RbCl, RbI, CuI, and/or KI; a lanthanide metal such as Yb; and/or a co-deposited material of the metal halide and the lanthanide metal. For example, the electron transport region ETR may include KI:Yb, RbI:Yb, LiF:Yb, etc., as a co-deposited material. In some embodiments, the electron transport region ETR may be formed utilizing a metal oxide such as Li₂O and/or BaO, and/or 8-hydroxyl-lithium quinolate (Liq), etc., but the embodiment of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, and/or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen), in addition to the above-described materials, but the embodiment of the present disclosure is not limited thereto.

The electron transport region ETR may include the above-described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies any of the aforementioned ranges, satisfactory or suitable electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies any of the above-described ranges, satisfactory or suitable electron injection characteristics may be obtained without a substantial increase in driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LF/Al, Mo, Ti, Yb, W, or a compound or mixture thereof (e.g., AgMg, AgYb, or MgAg). In some embodiments, the second electrode EL2 may have a multilayer structure including a reflective film or a transflective film formed of any of the above-described materials, and a transparent conductive film formed of ITO, IZO, ZnO, ITZO, etc. For example, the second electrode EL2 may include any of the above-described metal materials, one or more combinations of at least two metal materials of the above-described metal materials, one or more oxides of the above-described metal materials, and/or the like.

The second electrode EL2 may be connected with an auxiliary electrode. When the second electrode EL2 is connected with the auxiliary electrode, the resistance of the second electrode EL2 may be decreased.

In some embodiments, a capping layer CPL may further be provided on the second electrode EL2 of the light emitting element ED of one or more embodiments. The capping layer CPL may include a multilayer or a single layer.

In one or more embodiments, the capping layer CPL may be an organic layer and/or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., an epoxy resin, and/or acrylate such as methacrylate. However, the embodiment of the present disclosure is not limited thereto, and the capping layer CPL may include at least one selected from among Compounds P1 to P5:

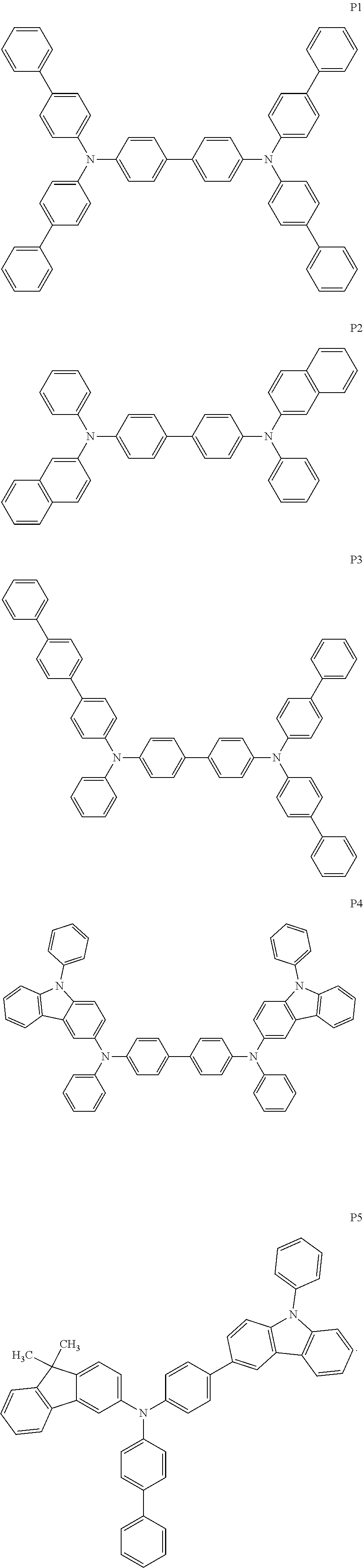 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL may be about 1.6 or more with respect to light in a wavelength range of about 550 nm to about 660 nm.

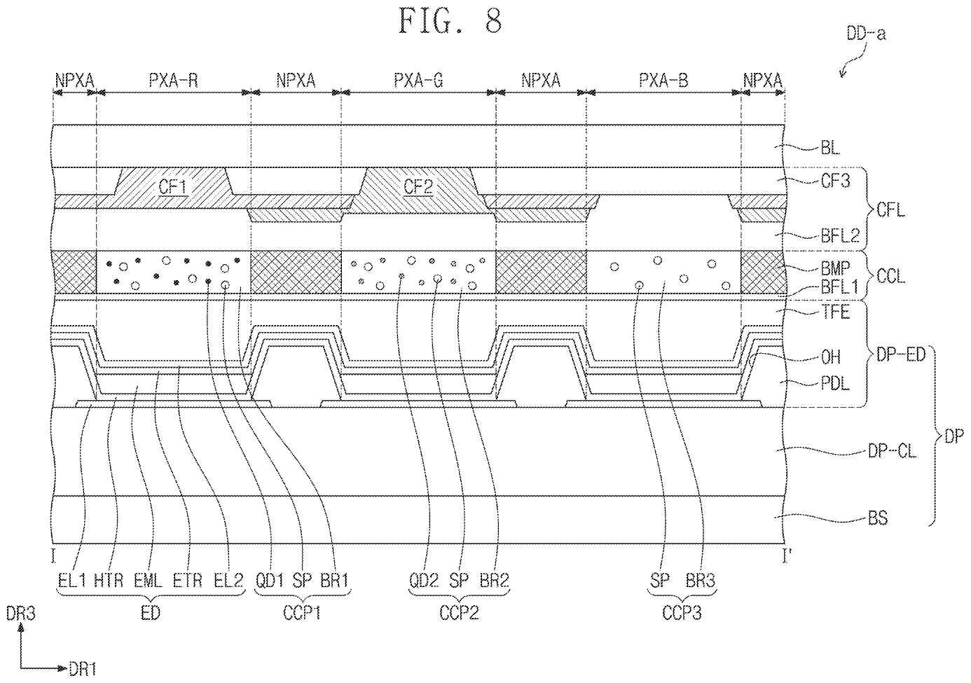

Each of FIGS. 8 to 11 is a cross-sectional view of a display apparatus according to one or more embodiments of the present disclosure. Hereinafter, in describing the display apparatuses of embodiments with reference to FIGS. 8 to 11, the duplicated features which have been described in FIGS. 1 to 7 are not described again, but their differences will be mainly described.

Referring to FIG. 8, the display apparatus DD-a according to one or more embodiments may include a display panel DP including a display device layer DP-ED, a light control layer CCL provided on the display panel DP, and a color filter layer CFL. In one or more embodiments illustrated in FIG. 8, the display panel DP may include a base layer BS, a circuit layer DP-CL provided on the base layer BS, and the display device layer DP-ED, and the display device layer DP-ED may include a light emitting element ED.

The light emitting element ED may include a first electrode EL1, a hole transport region HTR provided on the first electrode EL1, an emission layer EML provided on the hole transport region HTR, an electron transport region ETR provided on the emission layer EML, and a second electrode EL2 provided on the electron transport region ETR. In some embodiments, the structures of the light emitting elements of FIGS. 3 to 7 as described above may be equally applied to the structure of the light emitting element ED illustrated in FIG. 8.

A light-emitting element ED illustrated in FIG. 8 may include the polycyclic compound according to one or more embodiments, and at least one selected from among second to fourth compounds. Therefore, the light-emitting element ED may exhibit characteristics of high efficiency and long lifespan.

Referring to FIG. 8, the emission layer EML may be provided in an opening OH defined in a pixel defining layer PDL. For example, the emission layer EML which is divided by the pixel defining layer PDL and provided corresponding to each light emitting regions PXA-R, PXA-G, and PXA-B may be to emit light in substantially the same wavelength range. In the display apparatus DD-a of one or more embodiments, the emission layer EML may be to emit blue light. In some embodiments, the emission layer EML may be provided as a common layer in (e.g., along or over) the entire light emitting regions PXA-R, PXA-G, and PXA-B.

The light control layer CCL may be provided on the display panel DP. The light control layer CCL may include a light conversion body. The light conversion body may be a quantum dot, a phosphor, and/or the like. The light conversion body may be to emit provided light by converting the wavelength thereof. For example, the light control layer CCL may a layer containing the quantum dot and/or a layer containing the phosphor.

The light control layer CCL may include a plurality of light control parts CCP1, CCP2 and CCP3. The light control parts CCP1, CCP2, and CCP3 may be spaced apart from each other.

Referring to FIG. 8, divided patterns BMP may be provided between the light control parts CCP1, CCP2 and CCP3 which are spaced apart from each other, but the embodiment of the present disclosure is not limited thereto. FIG. 8 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts (e.g., is configured to convert) first color light provided from the light emitting element ED into second color light, a second light control part CCP2 containing a second quantum dot QD2 which converts (e.g., is configured to convert) the first color light into third color light, and a third light control part CCP3 which transmits (e.g., is configured to transmit) the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The same description of the quantum dot as provided above may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may respectively include base resins BR1, BR2, and BR3 in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In one or more embodiments, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the light control parts CCP1, CCP2 and CCP3 from being exposed to moisture/oxygen. In some embodiments, the barrier layer BFL1 may cover the light control parts CCP1, CCP2, and CCP3. In some embodiments, the barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, and/or a metal thin film which secures a transmittance, etc. In some embodiments, the barrier layers BFL1 and BFL2 may further include an organic film. The barrier layers BFL1 and BFL2 may be formed of a single layer or a plurality of layers.

In the display apparatus DD-a of one or more embodiments, the color filter layer CFL may be provided on the light control layer CCL. For example, the color filter layer CFL may be directly provided on the light control layer CCL. In this case, the barrier layer BFL2 may not be provided.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment and/or dye. The first filter CF1 may include a red pigment and/or dye, the second filter CF2 may include a green pigment and/or dye, and the third filter CF3 may include a blue pigment and/or dye.

In some embodiments, the embodiment of the present disclosure is not limited thereto, and the third filter CF3 may not include (e.g., may exclude) a pigment or dye. The third filter CF3 may include a polymeric photosensitive resin and may not include (e.g., may exclude) a pigment or dye. The third filter CF3 may be transparent. The third filter CF3 may be formed of a transparent photosensitive resin.

Furthermore, in one or more embodiments, the first filter CF1 and the second filter CF2 may be a yellow filter. The first filter CF1 and the second filter CF2 may not be separated, but may be provided as one filter.

In some embodiments, the color filter layer CFL may further include a light shielding part. The light shielding part may be a black matrix. The light shielding part may include an organic light shielding material and/or an inorganic light shielding material containing a black pigment and/or dye. The light shielding part may prevent or reduce light leakage, and may separate boundaries between the adjacent filters CF1, CF2, and CF3. Also, in one or more embodiments, the light shielding part may be formed of a blue filter.

The first to third filters CF1, CF2, and CF3 may be provided corresponding to the red light emitting region PXA-R, the green light emitting region PXA-G, and the blue light emitting region PXA-B, respectively.

A base substrate BL may be provided on the color filter layer CFL. The base substrate BL may be a member which provides a base surface in which the color filter layer CFL, the light control layer CCL, and/or the like are provided. The base substrate BL may be a glass substrate, a metal substrate, a plastic substrate, etc. However, the embodiment of the present disclosure is not limited thereto, and the base substrate BL may be an inorganic layer, an organic layer, or a composite material layer (e.g., including an organic material and an inorganic material). In some embodiments, the base substrate BL may not be provided.

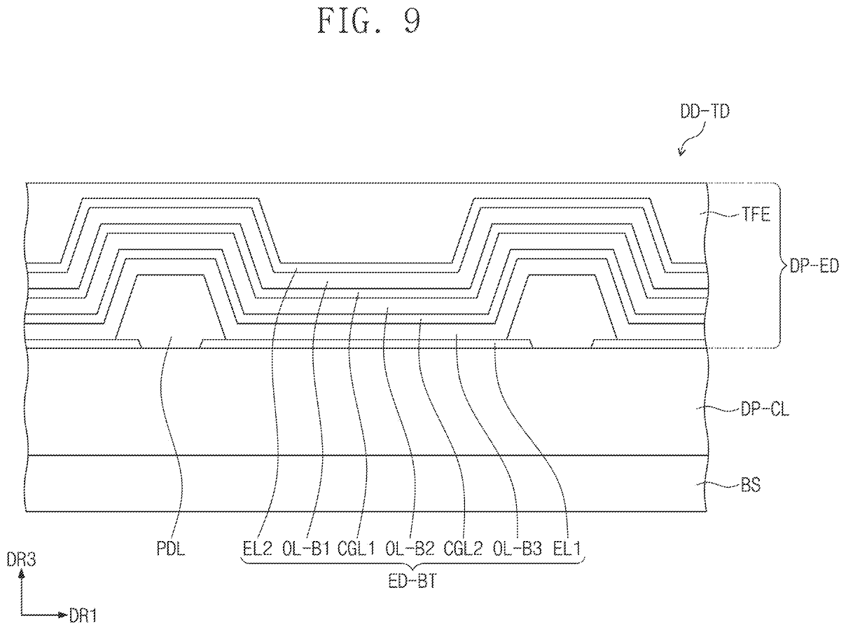

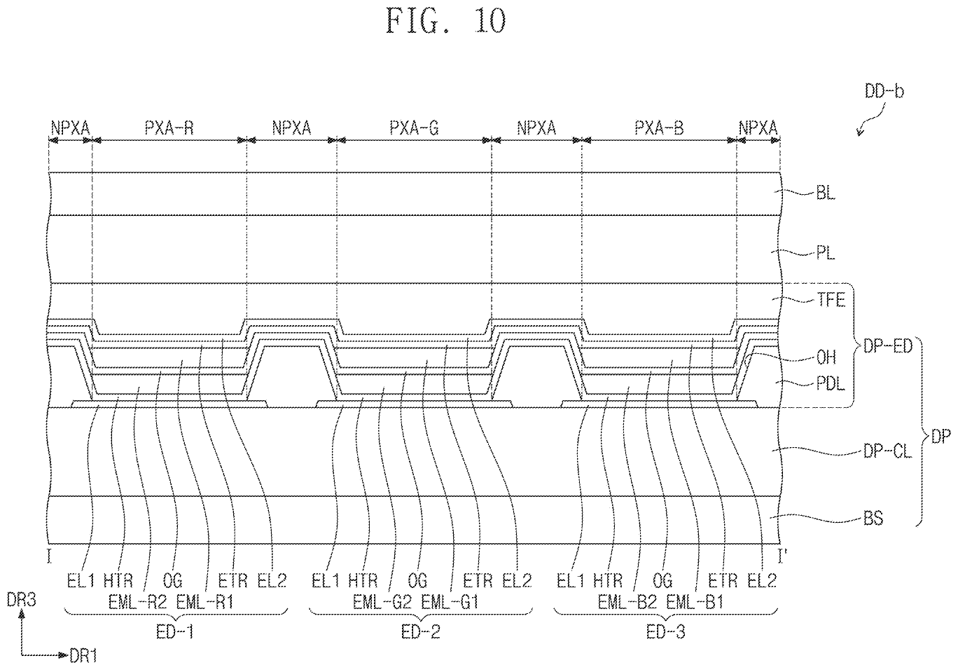

FIG. 9 is a cross-sectional view illustrating a portion of a display device according to one or more embodiments. In a display device DD-TD according to one or more embodiments, a light-emitting element ED-BT may include a plurality of light-emitting structures OL-B1, OL-B2, and OL-B3. At least one selected from among the plurality of light-emitting structures OL-B1, OL-B2, and OL-B3 may include the polycyclic compound according to one or more embodiments, and at least one selected from among the second to fourth compounds. Therefore, the light-emitting element ED-BT may exhibit characteristics of high efficiency and a long lifespan.

The light emitting element ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 8), and a hole transport region HTR and an electron transport region ETR with the emission layer EML (FIG. 8) located therebetween. For example, the light emitting element ED-BT included in the display apparatus DD-TD of one or more embodiments may be a light emitting element having a tandem structure and including a plurality of emission layers.

In one or more embodiments illustrated in FIG. 9, all light beams respectively emitted from the light emitting structures OL-B1, OL-B2, and OL-B3 may be blue light. However, the embodiment of the present disclosure is not limited thereto, and the light beams respectively emitted from the light emitting structures OL-B1, OL-B2, and OL-B3 may have wavelength ranges different from each other. For example, the light emitting element ED-BT including the plurality of light emitting structures OL-B1, OL-B2, and OL-B3 which emit light beams having wavelength ranges different from each other may be to emit white light.

A charge generating layer CGL1 and CGL2 may be provided between the neighboring light-emitting structures OL-B1, OL-B2 and OL-B3. The charge generating layer CGL1 and CGL2 may include a p-type or kind charge generating layer and/or an n-type or kind charge generating layer. For example, the charge generating layer CGL1 and CGL2 may include a first charge generating layer CGL1 and a second charge generating layer CGL2.

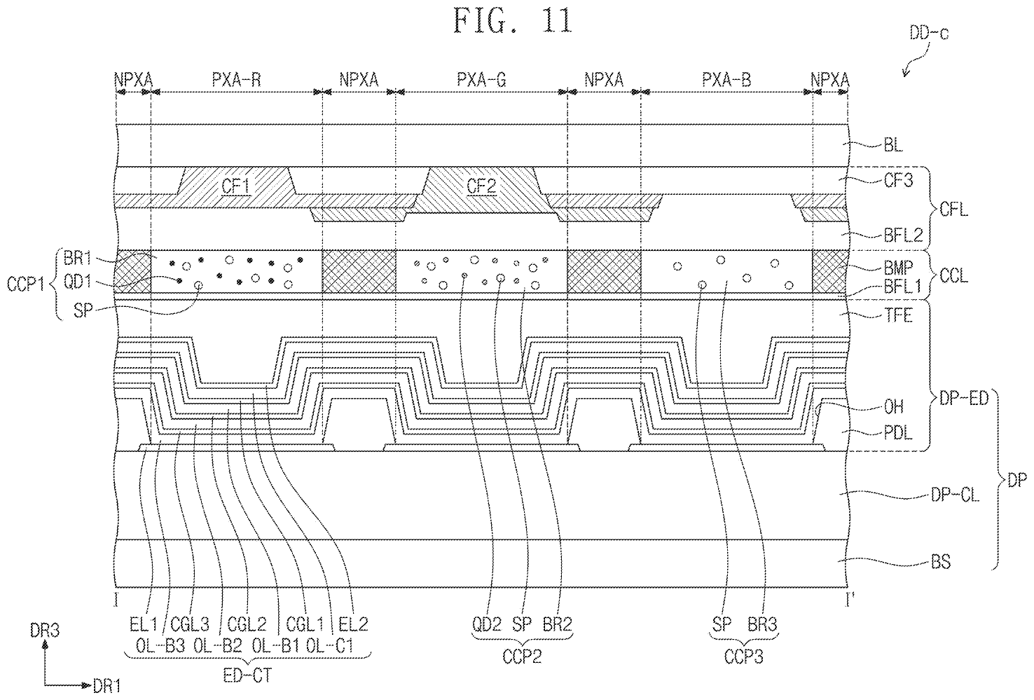

Referring to FIG. 10, a display device DD-b according to one or more embodiments may include light-emitting elements ED-1, ED-2, and ED-3, in which two emission layers are stacked. At least one of the light-emitting elements ED-1, ED-2, or ED-3 may include the polycyclic compound according to one or more embodiments, and at least one selected from among the second to fourth compounds. Therefore, the light-emitting element ED-BT may exhibit characteristics of high efficiency and a long lifespan.

Compared with the display apparatus DD of one or more embodiments illustrated in FIG. 2, the display apparatus DD-b illustrated in FIG. 10 has a difference in that the first to third light emitting elements ED-1, ED-2, and ED-3 each include two emission layers stacked in the thickness direction. In each of the first to third light emitting elements ED-1, ED-2, and ED-3, the two emission layers may be to emit light in substantially the same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. An emission auxiliary part OG may be provided between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked. The emission auxiliary part OG may be provided as a common layer in the whole of the first to third light emitting elements ED-1, ED-2, and ED-3. However, the embodiment of the present disclosure is not limited thereto, and the emission auxiliary part OG may be provided by being patterned within the openings OH defined in the pixel defining layer PDL.

The first red emission layer EML-R1, the first green emission layer EML-G1, and the first blue emission layer EML-B1 may be provided between the electron transport region ETR and the emission auxiliary part OG. The second red emission layer EML-R2, the second green emission layer EML-G2, and the second blue emission layer EML-B2 may be provided between the emission auxiliary part OG and the hole transport region HTR.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be provided on the display device layer DP-ED. The optical auxiliary layer PL may include a polarizing layer. The optical auxiliary layer PL may be provided on the display panel DP and control reflected light in the display panel DP due to external light. In some embodiments, the optical auxiliary layer PL in the display apparatus according to one or more embodiments may not be provided.

Compared to FIGS. 9 and 10, FIG. 11 illustrates that a display device DD-c includes four light-emitting structures OL-B1, OL-B2, OL-B3, and OL-C1. A light-emitting element ED-CT may include a first electrode EL1 and a second electrode EL2, which face each other, and the first to fourth light-emitting structures OL-B1, OL-B2, OL-B3, and OL-C1, which are sequentially stacked between the first electrode EL1 and the second electrode EL2 in a thickness direction. At least one selected from among the first to fourth light-emitting structures OL-B1, OL-B2, OL-B3, and OL-C1 may include the polycyclic compound according to one or more embodiments, and at least one selected from among the second to fourth compounds. Therefore, the light-emitting element ED-BT may exhibit characteristics of high efficiency and a long lifespan.

Charge generation layers CGL1, CGL2, and CGL3 may be provided between the first to fourth light emitting structures OL-B1, OL-B2, OL-B3, and OL-C1. Among the four light emitting structures, the first to third light emitting structures OL-B1, OL-B2, and OL-B3 may be to emit blue light, and the fourth light emitting structure OL-C1 may be to emit green light. However, the embodiment of the present disclosure is not limited thereto, and the first to fourth light emitting structures OL-B1, OL-B2, OL-B3, and OL-C1 may be to emit light beams in different wavelength regions. The charge generation layers CGL1, CGL2, and CGL3 provided between adjacent light emitting structures OL-B1, OL-B2, OL-B3, and OL-C1 may include a p-type or kind charge generation layer and/or an n-type or kind charge generation layer.

In one or more embodiments, the electronic apparatus may include a display apparatus including a plurality of light emitting elements, and a control part which controls the display apparatus. The electronic apparatus of one or more embodiments may be a device that is activated according to an electrical signal. The electronic apparatus may include display apparatuses of one or more suitable embodiments. For example, the electronic apparatus may include not only large-sized electronic apparatuses such as a television set, a monitor, and/or an outdoor billboard, but also include small- and medium-sized electronic apparatuses such as a personal computer, a laptop computer, a personal digital terminal, a display apparatus for a vehicle, a game console, a portable electronic device, and/or a camera.

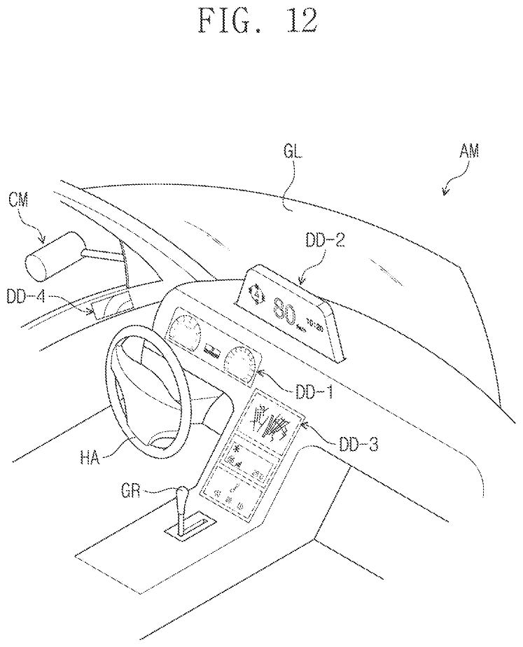

FIG. 12 is a view illustrating a vehicle AM in which first to fourth display apparatuses DD-1, DD-2, DD-3, and DD-4 are provided. At least one selected from among the first to fourth display apparatuses DD-1, DD-2, DD-3, and DD-4 may include the same configuration as the display apparatuses DD, DD-TD, DD-a, DD-b, and DD-c as described with reference to FIGS. 1, and 2, and 8 to 11.

FIG. 12 illustrates a vehicle AM, but this is an example, and the first to fourth display apparatuses DD-1, DD-2, DD-3, and DD-4 may be provided in another transportation device or equipment such as bicycles, motorcycles, trains, ships, and/or airplanes. In some embodiments, at least one selected from among the first to fourth display apparatuses DD-1, DD-2, DD-3, and DD-4 including the same configuration as the display apparatuses DD, DD-TD, DD-a, DD-b, and/or DD-c of one or more embodiments may be employed in a personal computer, a laptop computer, a personal digital terminal, a game console, a portable electronic device, a television, a monitor, an outdoor billboard, and/or the like. In some embodiments, these are merely provided as embodiments, and thus may be employed in other suitable electronic apparatuses within the spirit of the present disclosure.

At least one selected from among a first to fourth display devices DD-1, DD-2, DD-3, and DD-4 may include the light-emitting element ED described with reference to FIGS. 3 to 7. At least one selected from among the first to fourth display devices DD-1, DD-2, DD-3, and DD-4 may include the polycyclic compound according to one or more embodiments, and at least one selected from among the second to fourth compounds. Accordingly, the first to fourth display devices DD-1, DD-2, DD-3, and DD-4 including the polycyclic compound, and at least one selected from among the second to fourth compounds may have improved display efficiency and a display lifespan.

Referring to FIG. 12, the vehicle AM may include a steering wheel HA and a gear GR for driving the vehicle AM. In some embodiments, the vehicle AM may include a front window GL provided so as to face the driver.

The first display apparatus DD-1 may be provided in a first region overlapping the steering wheel HA. For example, the first display apparatus DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, etc. A first scale and a second scale may be indicated (e.g., provided) as a digital image.

The second display apparatus DD-2 may be provided in a second region facing the driver's seat and overlapping the front window GL. The driver's seat may be a seat in which the steering wheel HA is provided. For example, the second display apparatus DD-2 may be a head up display (HUD) which displays second information of the vehicle AM. The second display apparatus DD-2 may be optically transparent. The second information may include digital numbers which indicate a driving speed, and may further include information such as the current time. In some embodiments, the second information of the second display apparatus DD-2 may be projected to the front window GL to be displayed.

The third display apparatus DD-3 may be provided in a third region adjacent to the gear GR. For example, the third display apparatus DD-3 may be provided between the driver's seat and the passenger seat and may be a center information display (CID) for a vehicle for displaying third information. The passenger seat may be a seat spaced apart from the driver's seat with the gear GR provided therebetween. The third information may include information about traffic (e.g., navigation information), playing music and/or radio and/or a video (e.g., an image), temperatures inside the vehicle AM, etc.

The fourth display apparatus DD-4 may be spaced apart from the steering wheel HA and the gear GR, and may be provided in a fourth region adjacent to the side of the vehicle AM. For example, the fourth display apparatus DD-4 may be a digital side-view mirror which displays fourth information. The fourth display apparatus DD-4 may display an image outside the vehicle AM taken by a camera module CM provided outside the vehicle AM. The fourth information may include an image outside the vehicle AM.

The above-described first to fourth information may be examples, and the first to fourth display apparatuses DD-1, DD-2, DD-3, and DD-4 may further display information about the inside and outside of the vehicle AM. The first to fourth information may include different information. However, the embodiment of the present disclosure is not limited thereto, and a part of the first to fourth information may include the same information as one another.

Hereinafter, a polycyclic compound according to one or more embodiments of the present disclosure and a light-emitting element of one or more embodiments will be further explained by referring to Examples and Comparative Examples. In some embodiments, it should be understood that embodiments described are only illustrations to assist the understanding of the present disclosure, and the scope of the present disclosure is not limited thereto. thereto.

### EXAMPLES

### 1. Synthesis of Polycyclic Compound According to One or More Embodiments

The synthetic method of the polycyclic compound according to one or more embodiments of the present disclosure will be described in particular by exemplifying the synthetic methods of Compounds 1, 19, 20, 33, 34, 36, 42, 44, 46, 49, 51, 53, 62, and 80. In some embodiments, the synthetic methods of the-described polycyclic compounds are examples, and the synthetic method of the compound according to one or more embodiments of the present disclosure is not limited to the examples.

### (1) Synthesis of Compound 1

A polycyclic compound according to one or more embodiments may be synthesized by, for example, steps (e.g., by acts and/or by reactions) of Reaction Formula 1.

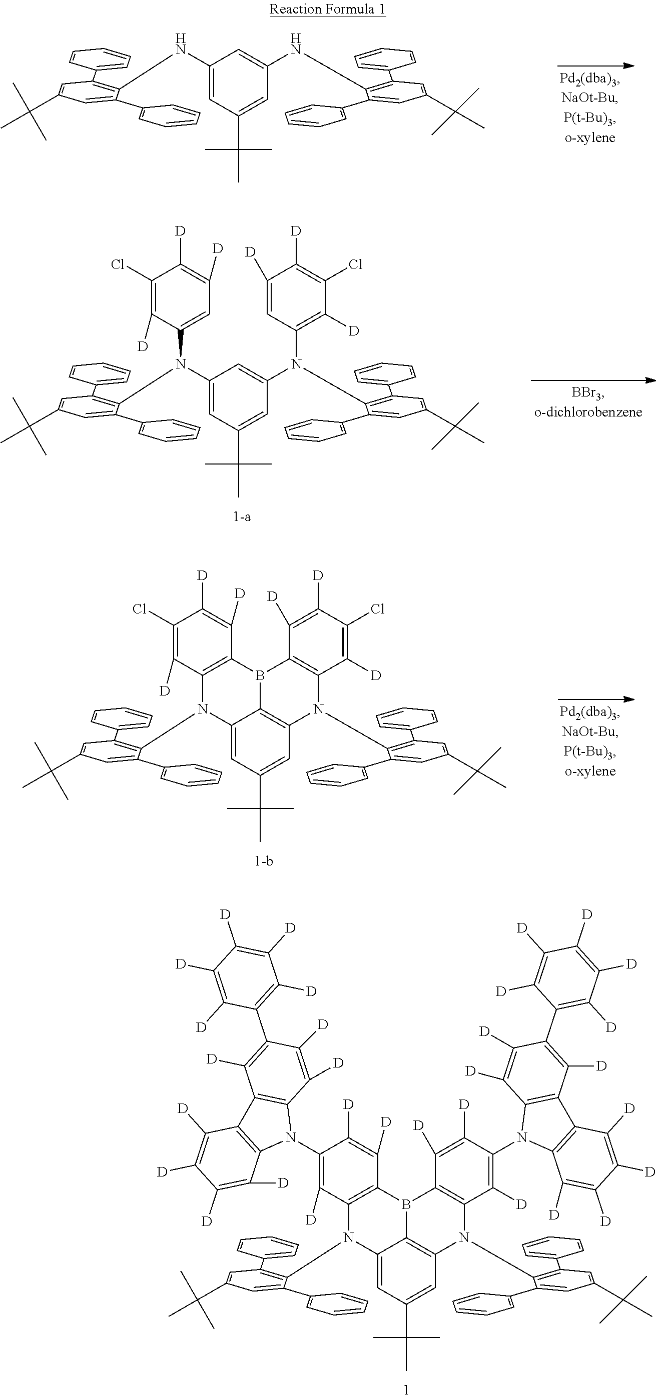

### Synthesis of Intermediate 1-a

In an argon atmosphere, 5-(tert-butyl)-N1,N3-bis(5′-(tert-butyl)-[1,1′:3′,1″-terphenyl]-2′-yl)benzene-1,3-diamine (10 g, 13.5 mmol), 1-chloro-3-iodobenzene-2,4,5,6-d4 (6.6 g, 27 mmol), Pd₂(dba)₃ (1.6 g, 1.9 mmol), tris-tert-butyl phosphine (1.6 mL, 3.8 mmol), and sodium tert-butoxide (11.5 g, 120 mmol) were put into a 2 L flask and dissolved in 300 mL of o-xylene, and then a reaction solution was stirred at 140° C. for 2 hours. After cooling, an organic layer was collected by adding 1 L of water and 300 mL of ethyl acetate and extracting, then dried over MgSO₄ and then filtered. A solvent was removed from the filtered solution under a reduced pressure, and the obtained solid was purified and separated by column chromatography utilizing silica gel with CH₂Cl₂ and hexane as a developing solvent to obtain Intermediate 1-a (10 g, yield of 77%), which is a white solid. A mass spectroscopic analysis data of the obtained compound is as follows.

ESI-LCMS: [M]⁺: C66H56D6Cl2N2. 958.4711.

### Synthesis of Intermediate 1-b

In an argon atmosphere, the Intermediate 1-a (10 g, 10 mmol) was put in a 1 L flask, and dissolved in 100 mL of o-dichlorobenzene, and then BBr₃ (1.5 equiv.) was added. A reaction solution was stirred for 12 hours at 140° C. After cooling, the reaction was quenched by adding triethylamine, and a solvent was removed under a reduced pressure. Then, the obtained solid was purified and separated by column chromatography utilizing silica gel with CH₂Cl₂ and hexane as a developing solvent, to obtain Intermediate 1-b (2.4 g, yield of 24%), which is a yellow solid. A mass spectroscopic analysis data of the obtained compound is as follows.

ESI-LCMS: [M]⁺: C66H53D6BCl2N2. 966.4532

### Synthesis of Compound 1

In an argon atmosphere, Intermediate 1-b (2.4 g, 2.5 mmol), 3-(phenyl-d5)-9H-carbazole-1,2,4,5,6,7,8-d7 (1.3 g, 5 mmol), Pd₂(dba)₃ (0.06 g, 0.12 mmol), tris-tert-butyl phosphine (0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 100° C. After cooling, an organic layer was collected by adding 1 L of water and 300 mL of ethyl acetate and extracting, then dried over MgSO₄, and then filtered. A solvent was removed under reduced pressure in a filtered solution. Then, the obtained solid was purified and separated by column chromatography utilizing silica gel with CH₂Cl₂ and hexane as a developing solvent, to obtain Compound 1 (1.7 g, yield of 72%), which is a yellow solid. Compound 1 obtained was identified by analysis data.

ESI-LCMS: [M]⁺: C102H53D30BN4. 1404.8667

1H-NMR (CDCl3): δ=7.41 (s, 4H), 7.15 (m, 12H), 7.05 (m, 8H), 6.88 (s, 2H), 1.32 (s, 18H), 1.12 (s, 9H)

### (2) Synthesis of Compound 4

Polycyclic Compound 4 according to one or more embodiments may be synthesized by, for example, steps of Reaction Formula 2.

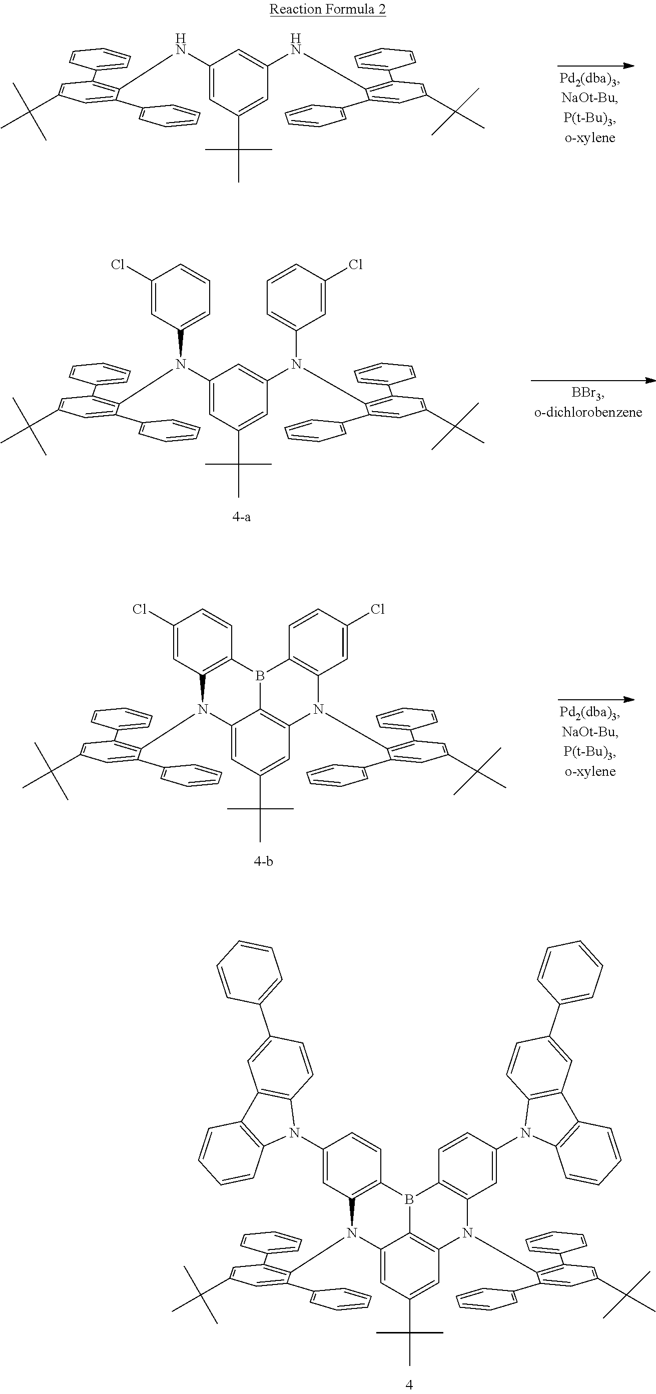

### Synthesis of Intermediate 4-a

In an argon atmosphere, 5-(tert-butyl)-N1,N3-bis(5′-(tert-butyl)-[1,1′:3′,1″-terphenyl]-2′-yl)benzene-1,3-diamine (10 g, 13.5 mmol), 1-chloro-3-iodobenzene (6.6 g, 27 mmol), Pd₂(dba)₃ (1.6 g, 1.9 mmol), tris-tert-butyl phosphine (1.6 mL, 3.8 mmol), and sodium tert-butoxide (11.5 g, 120 mmol) were put into 2 L flask and dissolved in 300 mL of o-xylene, and then a reaction solution was stirred at 140° C. for 2 hours. After cooling, an organic layer was collected by adding 1 L of water and 300 mL of ethyl acetate and extracting, then dried over MgSO₄ and then filtered. A solvent was removed under a reduced pressure in the filtered solution, and then the obtained solid was purified and separated by column chromatography utilizing silica gel with CH₂Cl₂ and hexane as a developing solvent, to obtain Intermediate 4-a (9.76 g, yield of 75%), which is a white solid. A mass spectroscopic analysis data of the obtained compound is as follows.

ESI-LCMS: [M]⁺: C66H62C12N2. 954.1434.

### Synthesis of Intermediate 4-b

In an argon atmosphere, the Intermediate 4-a (9.5 g, 10 mmol) was put into a 1 L flask, and dissolved in 100 mL of o-dichlorobenzene, and then BBr₃ (1.5 equiv.) was added. A reaction solution was stirred for 12 hours at 140° C. After cooling, the reaction was quenched by adding triethylamine, and a solvent was removed under a reduced pressure. Then, the obtained solid was purified and separated by column chromatography utilizing silica gel with CH₂Cl₂ and hexane as a developing solvent to obtain Intermediate 4-b (2.0 g, yield of 21%), which is a yellow solid. A mass spectroscopic analysis data of the obtained compound is as follows.

ESI-LCMS: [M]⁺: C66H59BCl2N2. 961.9210

### Synthesis of Compound 4

In an argon atmosphere, Intermediate 4-b (2 g, 2 mmol), 3-phenyl-9H-carbazole (1.11 g, 4.5 mmol), Pd₂(dba)₃ (0.06 g, 0.12 mmol), tris-tert-butyl phosphine (0.06 mL, 0.24 mmol), and sodium tert-butoxide (0.5 g, 5.1 mmol) were put into a 1 L flask and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄ and then filtered. A solvent was removed under reduced pressure in the filtered solution. Then, the obtained solid was purified and separated by column chromatography utilizing silica gel with CH₂Cl₂ and hexane as a developing solvent, to obtain Compound 4 (2.2 g, yield of 77%), which is a yellow solid. Compound 4 obtained was identified by analysis data.

ESI-LCMS: [M]⁺: C102H83BN4. 1375.6102

1H-NMR (CDCl3): δ=8.88 (d, 2H), 8.55 (d, 2H), 8.12 (d, 2H), 7.94 (d, 2H), 7.89 (s, 2H), 7.71 (t, 2H), 7.55 (m, 6H), 7.41 (s, 4H), 7.30 (d, 2H), 7.11 (m, 18H), 7.23 (s, 2H), 7.08 (m, 10H), 6.91 (s, 2H), 1.34 (s, 18H), 1.15 (s, 9H)

### (3) Synthesis of Compound 19

Polycyclic Compound 19 according to one or more embodiments may be synthesized by, for example, steps of Reaction Formula 3.

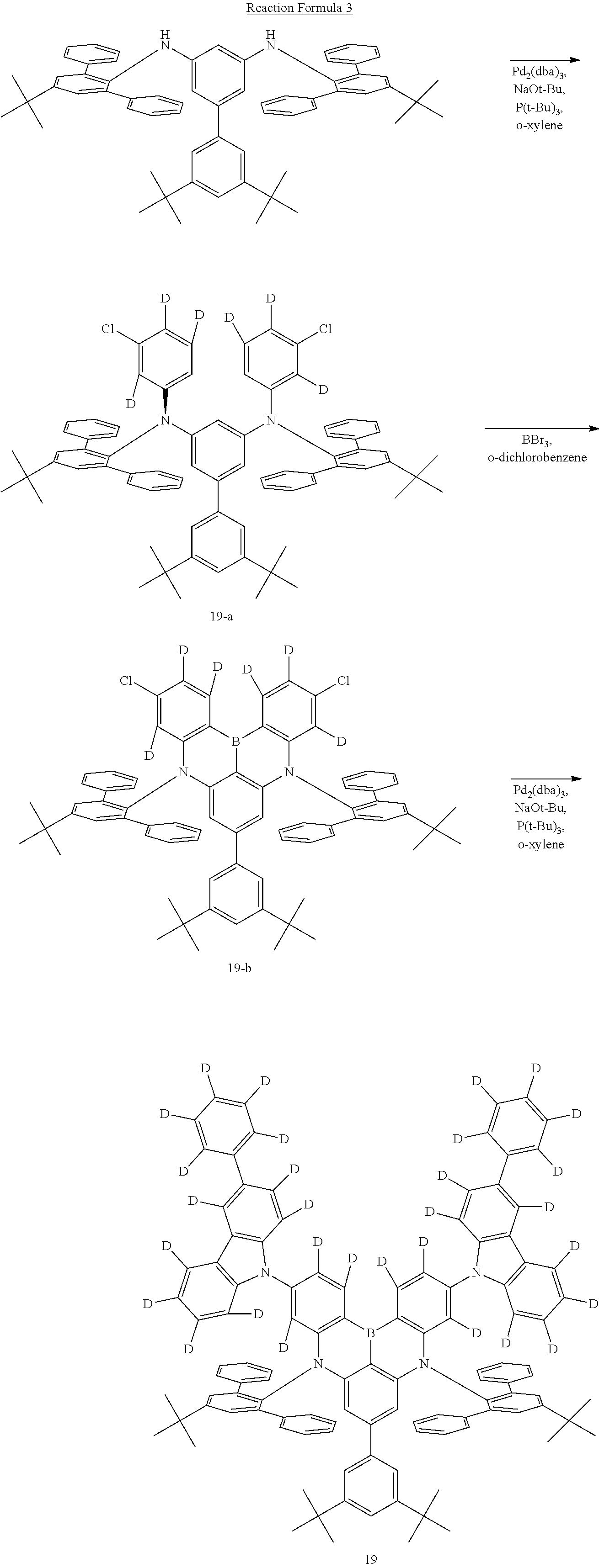

### Synthesis of Intermediate 19-a

In an argon atmosphere 3′,5′-di-tert-butyl-N3,N5-bis(5′-(tert-butyl)-[1,1′:3′,1″-terphenyl]-2′-yl)-[1,1′-biphenyl]-3,5-diamine (10 g, 11.5 mmol), 1-chloro-3-iodobenzene-2,4,5,6-d4 (5.6 g, 22 mmol), Pd₂(dba)₃ (1.6 g, 1.9 mmol), tris-tert-butyl phosphine (1.6 mL, 3.8 mmol), and sodium tert-butoxide (2.85 g, 30 mmol) were put into 2 L flask, and dissolved in 300 mL of o-xylene, and then the reaction solution was stirred at 140° C. for 2 hours. After cooling, an organic layer was collected by adding 1 L of water and 300 mL of ethyl acetate and extracting, then dried over MgSO₄ and then filtered. A solvent was removed under a reduced pressure in a filtered solution, and the obtained solid was purified and separated by column chromatography utilizing silica gel with CH₂Cl₂ and hexane as a developing solvent, to obtain Intermediate 19-a (9.5 g, yield of 75%), which is a white solid. A mass spectroscopic analysis data of an obtained compound is as follows.

ESI-LCMS: [M]⁺: C76H68D6Cl2N2. 1090.5654

### Synthesis of Intermediate 19-b

In an argon atmosphere, the Intermediate 19-a (9.5 g, 8.7 mmol) was put into a 1 L flask, and dissolved in 100 mL of o-dichlorobenzene, and then BBr₃ (1.5 equiv.) was added. A reaction solution was stirred for 12 hours at 140° C. After cooling, the reaction was quenched by adding triethylamine, and a solvent was removed under a reduced pressure. Then, the obtained solid was purified and separated by column chromatography utilizing silica gel with CH₂Cl₂ and hexane as a developing solvent, to obtain Intermediate 19-b (2.3 g, yield of 24%), which is a yellow solid. A mass spectroscopic analysis data of an obtained compound is as follows.

ESI-LCMS: [M]⁺: C76H65D6BCl2N2. 1098.4055

### Synthesis of Compound 19

In an argon atmosphere, Intermediate 19-b (2.4 g, 2.2 mmol), 3-(phenyl-d5)-9H-carbazole-1,2,4,5,6,7,8-d7 (1.11 g, 4.5 mmol), Pd₂(dba)₃ (0.06 g, 0.12 mmol), tris-tert-butyl phosphine (0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄, and then filtered. A solvent was removed from the filtered solution under reduced pressure. Then, the obtained solid was purified and separated by column chromatography utilizing silica gel with CH₂Cl₂ and hexane as a developing solvent, to obtain Compound 19 (2.2 g, yield of 77%), which is a yellow solid. Compound 19 obtained was identified by analysis data.

ESI-LCMS: [M]⁺: C112H65D30BN4. 1536.9440

1H-NMR (CDCl3): δ=7.41 (s, 4H), 7.28 (s, 2H), 7.24 (s, 1H), 7.08 (m, 12H), 7.00 (m, 8H), 6.93 (s, 2H), 1.32 (s, 18H), 1.22 (s, 18H)

### (4) Synthesis of Compound 20

Polycyclic Compound 20 according to one or more embodiments may be synthesized by, for example, steps of Reaction Formula 4.

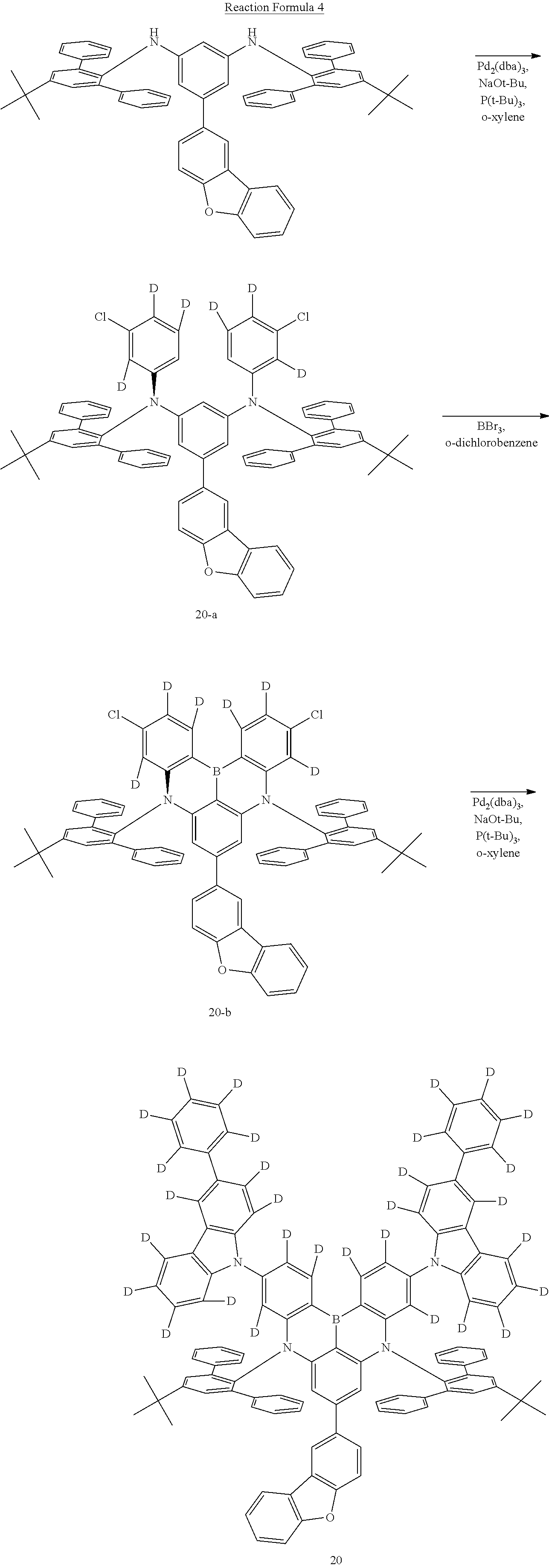

### Synthesis of Intermediate 20-a

In an argon atmosphere, N1,N3-bis(5′-(tert-butyl)-[1,1′:3′,1″-terphenyl]-2′-yl)-5-(dibenzo[b,d]furan-2-yl)benzene-1,3-diamine (10 g, 11.8 mmol), 1-chloro-3-iodobenzene-2,4,5,6-d4 (5.6 g, 22 mmol), Pd₂(dba)₃(1.6 g, 1.9 mmol), tris-tert-butyl phosphine (1.6 mL, 3.8 mmol), and sodium tert-butoxide (2.85 g, 30 mmol) were put into 2 L flask and dissolved in 300 mL of o-xylene, and then the reaction solution was stirred at 140° C. for 2 hours. After cooling, an organic layer was collected by adding 1 L of water and 300 mL of ethyl acetate and extracting, then dried over MgSO₄, and then filtered. A solvent was removed from the filtered solution under reduced pressure, and the obtained solid was purified and separated by column chromatography utilizing silica gel with CH₂Cl₂ and hexane as a developing solvent to obtain Intermediate 20-a (9.75 g, yield of 75%), which is a white solid. A mass spectroscopic analysis data of an obtained compound is as follows.

ESI-LCMS: [M]⁺: C74H54D6Cl2N2O. 1068.4543

### Synthesis of Intermediate 20-b

In an argon atmosphere, the Intermediate 20-a (9.5 g, 9 mmol) was put into a 1 L flask, and dissolved in 100 mL of o-dichlorobenzene, and then BBr₃ (1.5 equiv.) was added. A reaction solution was stirred for 12 hours at 140° C. After cooling, the reaction was quenched by adding triethylamine, and a solvent was removed under a reduced pressure. Then, the obtained solid was under a reduced pressure to remove a solvent, and the obtained solid was purified and separated by column chromatography utilizing silica gel with CH₂Cl₂ and hexane as a developing solvent to obtain Intermediate 20-b (2.1 g, yield of 22%), which is a yellow solid. A mass spectroscopic analysis data of an obtained compound is as follows.

ESI-LCMS: [M]⁺: C74H51D6BCl2N2O. 1076.0943

### Synthesis of Compound 20

In an argon atmosphere, Intermediate 20-b (2.4 g, 2.2 mmol), 3-(phenyl-d5)-9H-carbazole-1,2,4,5,6,7,8-d7 (1.11 g, 4.5 mmol), Pd₂(dba)₃ (0.06 g, 0.12 mmol), tris-tert-butyl phosphine (0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄, and filtered. A solvent was removed from the filtered solution under reduced pressure. Then, the obtained solid was purified and separated by column chromatography utilizing silica gel with CH₂Cl₂ and hexane as a developing solvent, to obtain Compound 20 (2.5 g, yield of 76%), which is a yellow solid.

ESI-LCMS: [M]⁺: C110H51D30BN4O. 1514.1188

1H-NMR (CDCl3): δ=7.68 (m, 3H), 7.54 (d, 1H), 7.45 (s, 4H), 7.39 (m, 2H), 7.33 (m, 13H), 7.05 (m, 12H), 6.93 (s, 2H), 1.33 (s, 18H)

### (4) Synthesis of Compound 33

Polycyclic compound 33 according to one or more embodiments may be synthesized by, for example, steps of Reaction Formula 5.

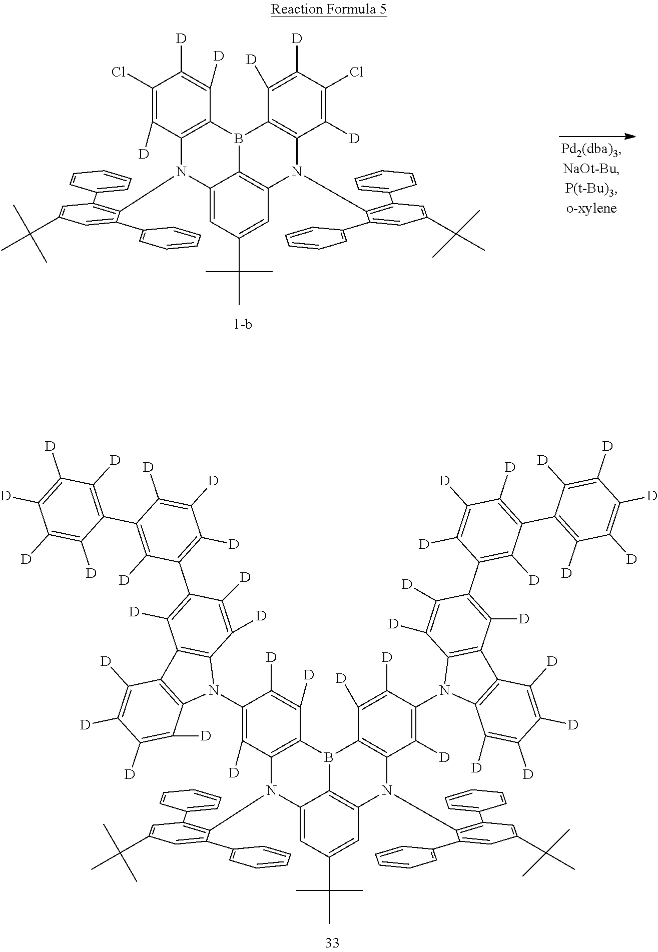

### Synthesis of Compound 33

In an argon atmosphere, Intermediate 1-b (2 g, 2 mmol), 3-([1,1′-biphenyl]-3-yl-d9)-9H-carbazole-1,2,4,5,6,7,8-d7 (1.4 g, 4.1 mmol), Pd₂(dba)₃ (0.06 g, 0.12 mmol), tris-tert-butyl phosphine (0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄, and then filtered. A solvent was removed from the filtered solution under reduced pressure. Then, the obtained solid was purified and separated by column chromatography utilizing silica gel with CH₂Cl₂ and hexane as a developing solvent to obtain Compound 33 (2.5 g, yield of 78%), which is a yellow solid. Compound 33 obtained was identified through analysis data.

ESI-LCMS: [M]⁺: C110H51D30BN4O. 1514.1188

1H-NMR (CDCl3): δ=7.45 (s, 4H), 7.18 (m, 12H), 7.07 (m, 8H), 7.00 (s, 1H), 1.46 (s, 18H), 1.22 (s, 9H)

### (6) Synthesis of Compound 34

Polycyclic compound 34 according to one or more embodiments may be synthesized by, for example, steps of Reaction Formula 6.

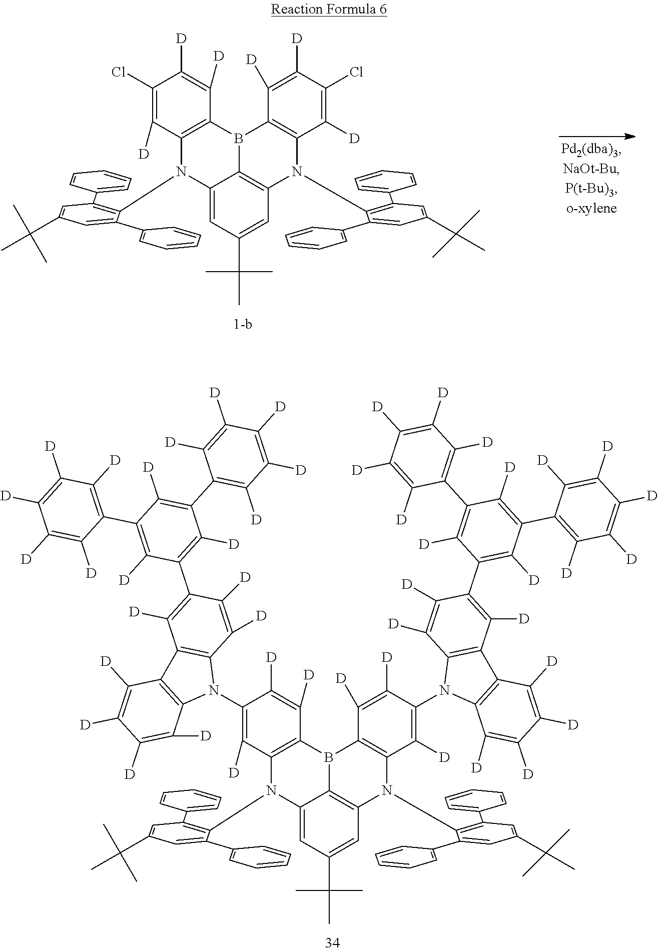

### Synthesis of Compound 34

In an argon atmosphere, Intermediate 1-b (2 g, 2 mmol), 3-([1,1′:3′,1″-terphenyl]-5′-yl-d13)-9H-carbazole-1,2,4,5,6,7,8-d7 (1.7 g, 4.1 mmol), Pd₂(dba)₃(0.06 g, 0.12 mmol), tris-tert-butyl phosphine (0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄, and then filtered. A solvent was removed from the filtered solution under reduced pressure. Then, the obtained solid was purified and separated by column chromatography utilizing silica gel with CH₂Cl₂ and hexane as a developing solvent, to obtain Compound 34 (2.53 g, yield of 71%), which is a yellow solid. Compound 34 obtained was identified through analysis data.

ESI-LCMS: [M]⁺: C126H53D46BN4. 1725.0901

1H-NMR (CDCl3): δ=7.47 (s, 4H), 7.21 (m, 12H), 7.09 (m, 8H), 6.98 (s, 1H), 1.49 (s, 18H), 1.21 (s, 9H)

### (7) Synthesis of Compound 36

Polycyclic compound 36 according to one or more embodiments may be synthesized by, for example, steps of Reaction Formula 7.

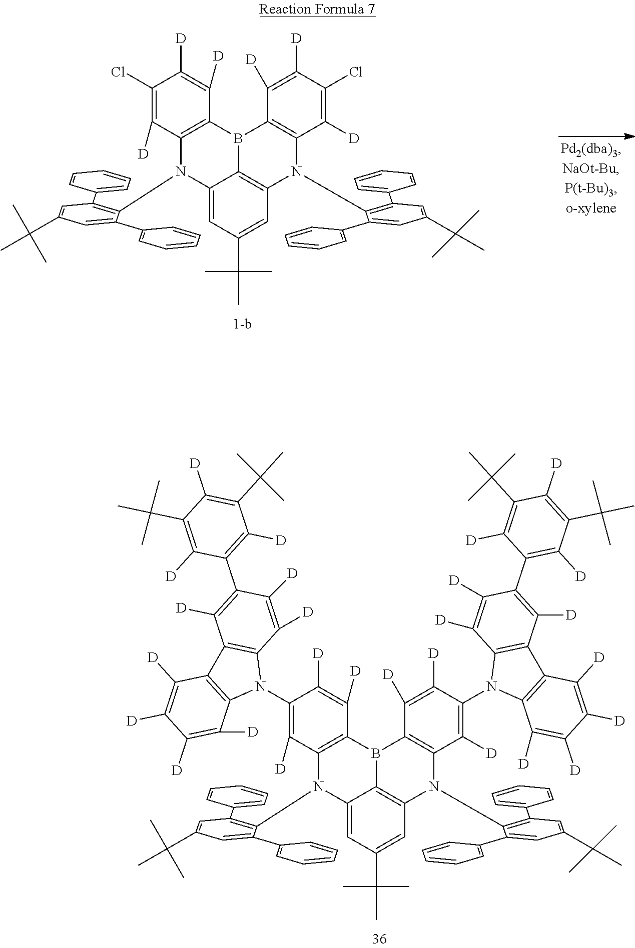

### Synthesis of Compound 36

In an argon atmosphere, Intermediate 1-b (2 g, 2 mmol), 3-(3,5-di-tert-butylphenyl-2,4,6-d3)-9H-carbazole-1,2,4,5,6,7,8-d7 (1.46 g, 4 mmol), Pd₂(dba)₃(0.06 g, 0.12 mmol), tris-tert-butyl phosphine (0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄, and then filtered. A solvent was removed from the filtered solution under reduced pressure. Then, the obtained solid was purified and separated by column chromatography utilizing silica gel with CH₂Cl₂ and hexane as a developing solvent, to obtain Compound 36 (2.4 g, yield of 74%), which is a yellow solid. The obtained Compound 36 was identified through analysis data.

ESI-LCMS: [M]⁺: C118H89D26BN4. 1625.7448

1H-NMR (CDCl3): δ=7.41 (s, 4H), 7.23 (m, 12H), 7.05 (m, 8H), 6.92 (s, 1H), 1.49 (s, 18H), 1.33 (s, 36H), 1.21 (s, 9H)

### (8) Synthesis of Compound 42

Polycyclic compound 42 according to one or more embodiments may be synthesized by, for example, steps of Reaction Formula 8.

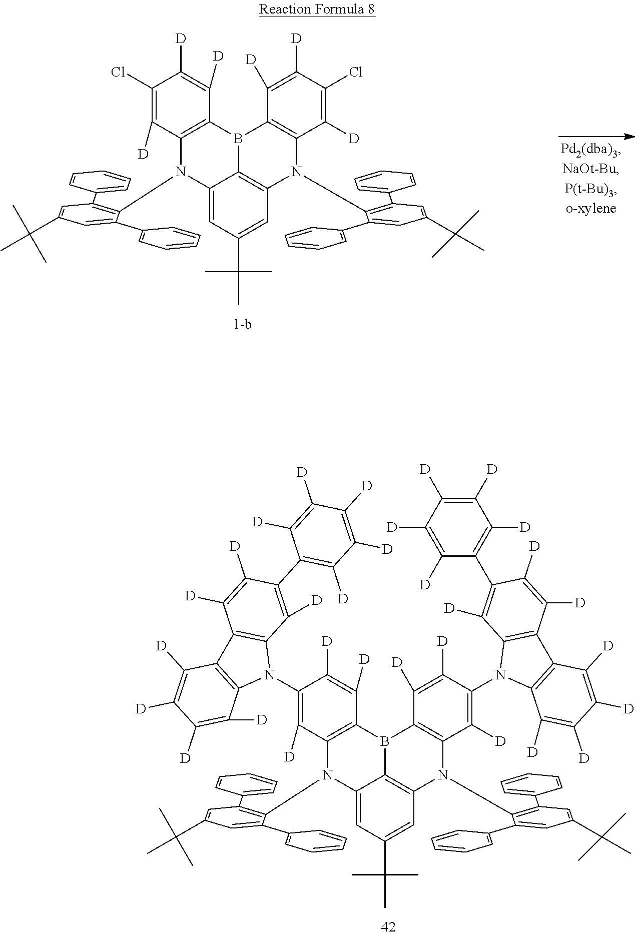

### Synthesis of Compound 42

In an argon atmosphere, Intermediate 1-b (2 g, 2 mmol), 2-(phenyl-d5)-9H-carbazole-1,3,4,5,6,7,8-d7 (1.02 g, 4 mmol), Pd₂(dba)₃ (0.06 g, 0.12 mmol), tris-tert-butyl phosphine (0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄, and then filtered. A solvent was removed from the filtered solution under reduced pressure. Then, the obtained solid was purified and separated by column chromatography utilizing silica gel with CH₂Cl₂ and hexane as a developing solvent, to obtain Compound 42 (2.4 g, yield of 74%), which is a yellow solid. Compound 42 obtained was identified by analysis data.

ESI-LCMS: [M]⁺: C102H53D30BN4. 1404.8667

1H-NMR (CDCl3): δ=7.39 (s, 4H), 7.22 (m, 12H), 7.11 (m, 8H), 6.94 (s, 1H), 1.45 (s, 18H), 1.21 (s, 9H)

### (9) Synthesis of Compound 44

Polycyclic Compound 44 according to one or more embodiments may be synthesized by, for example, steps of Reaction Formula 9.

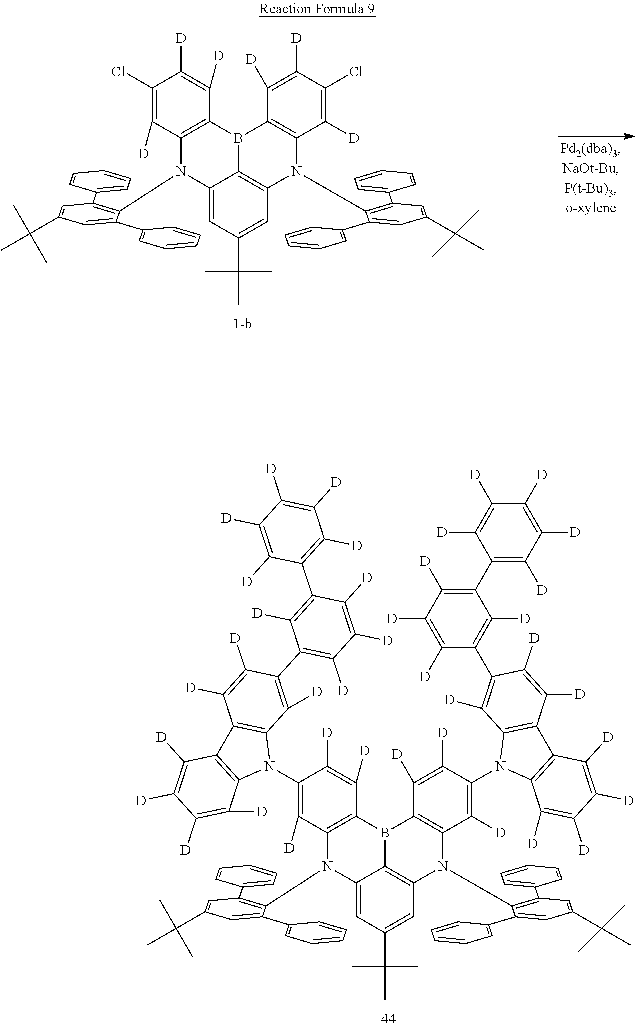

### Synthesis of Compound 44

In an argon atmosphere, Intermediate 1-b (2 g, 2 mmol), 2-([1,1′-biphenyl]-3-yl-d9)-9H-carbazole-1,3,4,5,6,7,8-d7 (1.34 g, 4 mmol), Pd₂(dba)₃(0.06 g, 0.12 mmol), tris-tert-butyl phosphine (0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄, and then filtered. A solvent was removed from the filtered solution under reduced pressure. Then, the obtained solid was purified and separated by column chromatography utilizing silica gel with CH₂Cl₂ and hexane as a developing solvent, to obtain Compound 44 (2.4 g, yield of 74%), which is a yellow solid. Compound 44 obtained was identified by analysis data.

ESI-LCMS: [M]⁺: C114H53D38BN4. 1564.9795

1H-NMR (CDCl3): δ=7.44 (s, 4H), 7.24 (m, 12H), 7.13 (m, 8H), 6.91 (s, 1H), 1.38 (s, 18H), 1.23 (s, 9H)

### (10) Synthesis of Compound 46

Polycyclic Compound 46 according to one or more embodiments may be synthesized by, for example, steps of Reaction Formula 10.

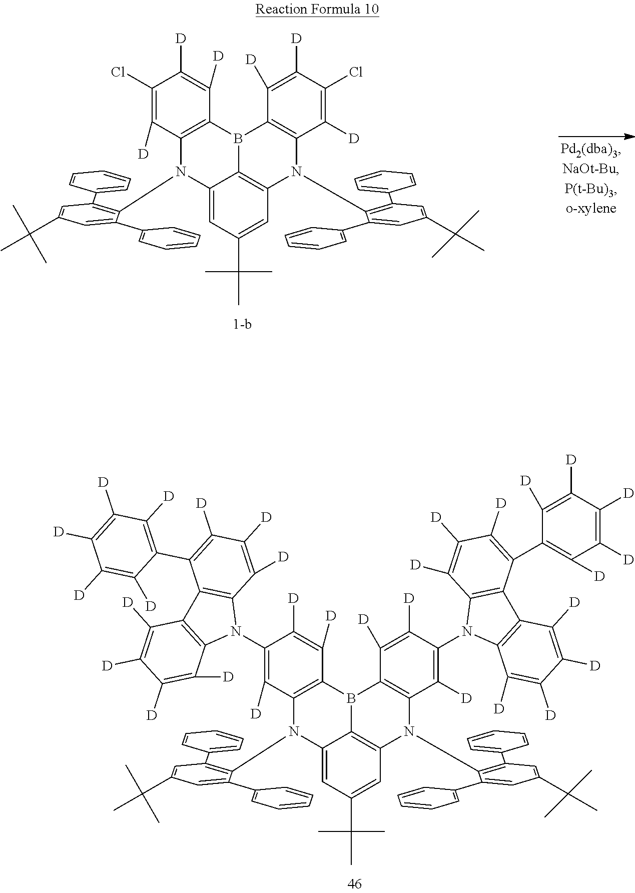

### Synthesis of Compound 48

In an argon atmosphere, Intermediate 1-b (2 g, 2 mmol), 4-(phenyl-d5)-9H-carbazole-1,2,3,5,6,7,8-d7 (1.0 g, 4 mmol), Pd₂(dba)₃ (0.06 g, 0.12 mmol), tris-tert-butyl phosphine (0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄, and then filtered. A solvent was removed from the filtered solution under reduced pressure. Then, the obtained solid was purified and separated by column chromatography utilizing silica gel with CH₂Cl₂ and hexane as a developing solvent to obtain Compound 46 (2.05 g, yield of 73%), which is a yellow solid. Compound 46 obtained was identified through analysis data.

ESI-LCMS: [M]⁺: C102H53D30BN4. 1404.8111

1H-NMR (CDCl3): δ=7.40 (s, 4H), 7.28 (m, 12H), 7.15 (m, 8H), 6.93 (s, 1H), 1.35 (s, 18H), 1.17 (s, 9H)

### (11) Synthesis of Compound 49

Polycyclic Compound 49 according to one or more embodiments may be synthesized by, for example, steps of Reaction Formula 11.

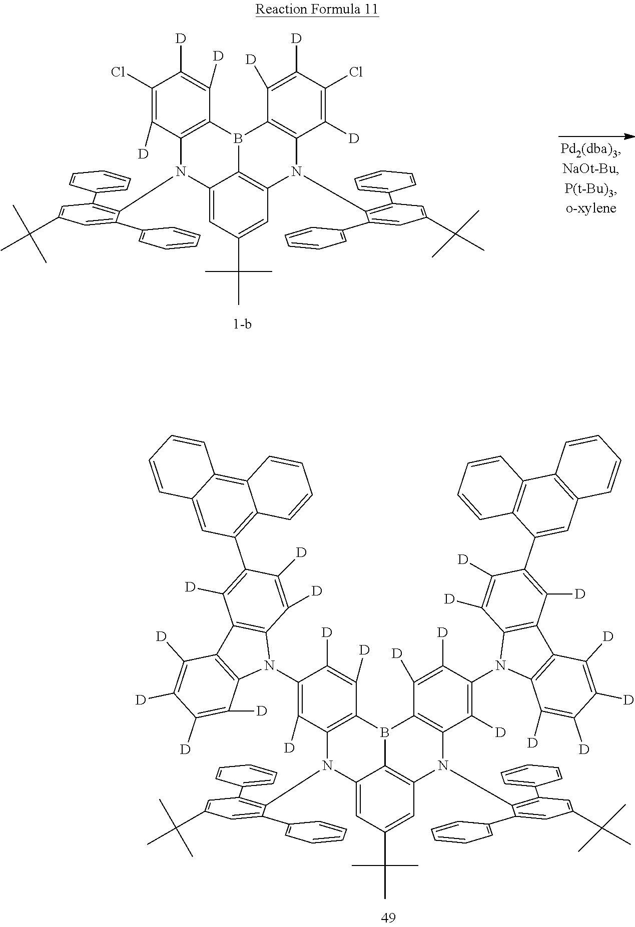 [SMILES: [2H]c1c([2H])c2c(c([2H])c1Cl)N(c1c(-c3ccccc3)cc(C(C)(C)C)cc1-c1ccccc1)c1cc(C(C)(C)C)cc3c1B2c1c([2H])c([2H])c(Cl)c([2H])c1N3c1c(-c2ccccc2)cc(C(C)(C)C)cc1-c1ccccc1 ; [2H]c1c([2H])c(-n2c3c([2H])c([2H])c([2H])c([2H])c3c3c([2H])c(-c4cc5ccccc5c5ccccc45)c([2H])c([2H])c32)c([2H])c2c1B1c3c(cc(C(C)(C)C)cc3N(c3c(-c4ccccc4)cc(C(C)(C)C)cc3-c3ccccc3)c3c([2H])c(-n4c5c([2H])c([2H])c([2H])c([2H])c5c5c([2H])c(-c6cc7ccccc7c7ccccc67)c([2H])c([2H])c54)c([2H])c([2H])c31)N2c1c(-c2ccccc2)cc(C(C)(C)C)cc1-c1ccccc1]

### Synthesis of Compound 49

In an argon atmosphere, Intermediate 1-b (2 g, 2 mmol),), 3-(phenanthren-9-yl)-9H-carbazole-1,2,4,5,6,7,8-d7 (1.4 g, 4 mmol), Pd₂ (dba)₃ (0.06 g, 0.12 mmol), tris-tert-butyl phosphine 0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄, and then filtered. A solvent was removed from the filtered solution under reduced pressure. Then, the obtained solid was purified and separated by column chromatography utilizing silica gel with CH₂Cl₂ and hexane as a developing solvent to obtain Compound 49 (2.45 g, yield of 77%), which is a yellow solid. Compound 49 obtained was identified through analysis data.

ESI-LCMS: [M]⁺: C118H71D20BN4.1594.8687

1H-NMR (CDCl3): δ=9.08 (d, 2H), 8.84 (d, 2H), 8.27 (d, 2H), 8.05 (s, 2H), 7.90 (d, 2H), 7.70 (m, 8H), 7.40 (s, 4H), 7.25 (m, 12H), 7.08 (m, 8H), 6.91 (s, 1H), 1.32 (s, 18H), 1.13 (s, 9H)

### (12) Synthesis of Compound 51

Polycyclic Compound 51 according to one or more embodiments may be synthesized by, for example, steps of Reaction Formula 12.

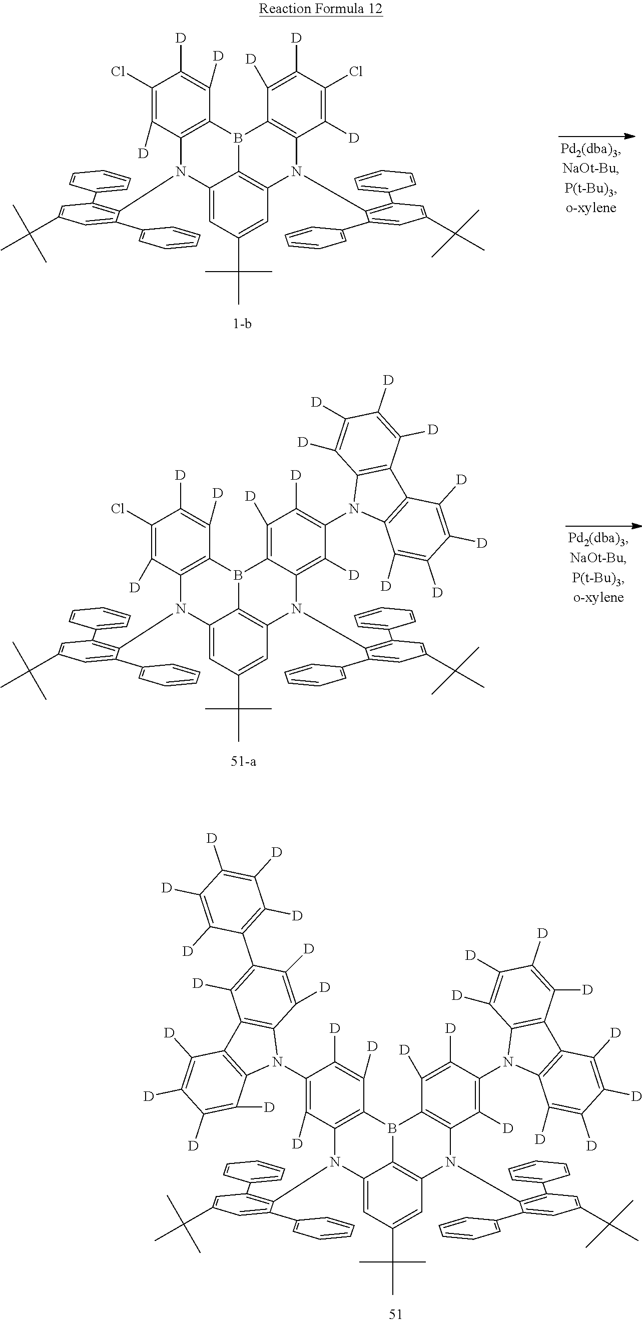

### Synthesis of Intermediate 51-a

In an argon atmosphere, Intermediate 1-b (2 g, 2 mmol), 9H-carbazole-1,2,3,5,6,7,8-d7 (0.35 g, 2 mmol), Pd₂(dba)₃ (0.06 g, 0.12 mmol), tris-tert-butyl phosphine (0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄, and then filtered. A solvent was removed from the filtered solution under reduced pressure. Then, the obtained solid was purified and separated by column chromatography utilizing silica gel with CH₂Cl₂ and hexane as a developing solvent to obtain Compound 51-a (1.43 g, yield of 65%), which is a yellow solid. Compound 51-a obtained was identified through analysis data.

ESI-LCMS: [M]+: C78H53D14BClN3. 1105.6001

### Synthesis of Compound 51

In an argon atmosphere, Intermediate 51-a (1.4 g, 1.2 mmol), 3-(phenyl-d5)-9H-carbazole-1,2,4,5,6,7,8-d7 (0.32 g, 1.2 mmol), Pd₂(dba)₃ (0.06 g, 0.12 mmol), tris-tert-butyl phosphine (0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄, and then filtered. A solvent was removed from the filtered solution under reduced pressure. Then, the obtained solid was purified and separated by column chromatography utilizing silica gel with CH₂Cl₂ and hexane as a developing solvent to obtain Compound 51 (1.2 g, yield of 78%), which is a yellow solid. Compound 51 obtained was identified through analysis data.

ESI-LCMS: [M]+: C96H53D26BN4. 1324.0811

1H-NMR (CDCl3): δ=7.42 (s, 4H), 7.21 (m, 12H), 7.11 (m, 8H), 6.88 (s, 1H), 1.31 (s, 18H), 1.12 (s, 9H)

### (13) Synthesis of Compound 53

Polycyclic Compound 53 according to one or more embodiments may be synthesized by, for example, steps of Reaction Formula 13.

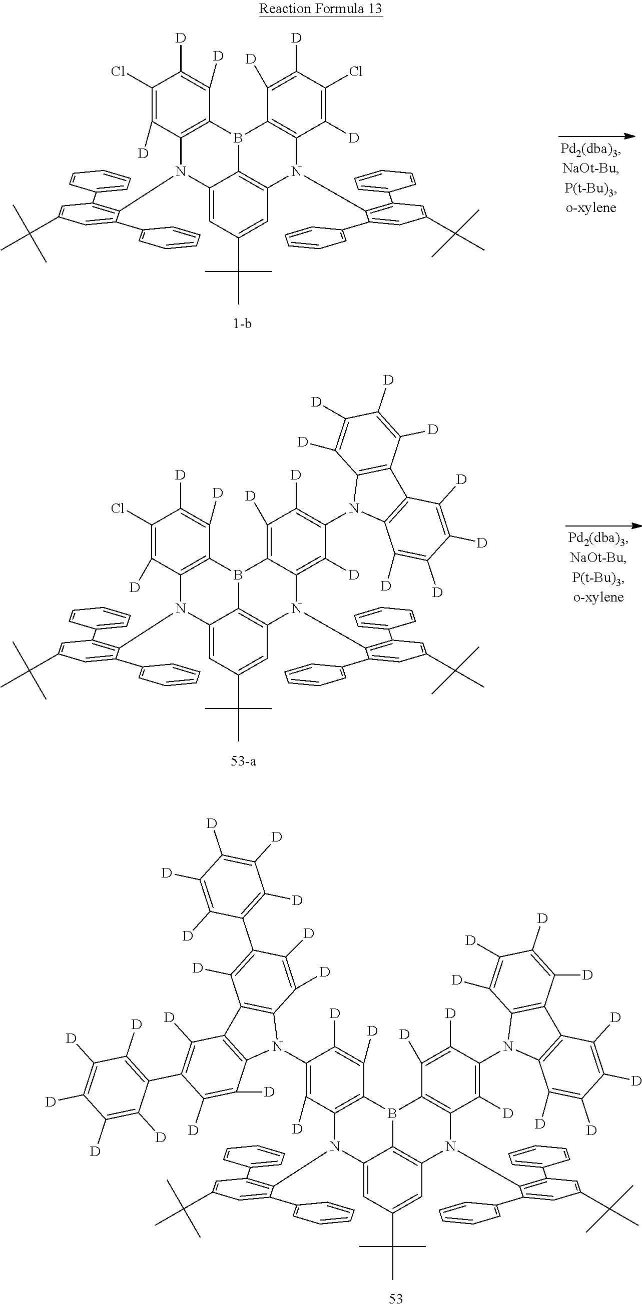

### Synthesis of Intermediate 53-a

In an argon atmosphere, Intermediate 1-b (2 g, 2 mmol), 9H-carbazole-1,2,3,5,6,7,8-d7 (0.35 g, 2 mmol), Pd₂(dba)₃ (0.06 g, 0.12 mmol), tris-tert-butyl phosphine (0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄, and then filtered. A solvent was removed from the filtered solution under reduced pressure. Then, the obtained solid was purified and separated by column chromatography utilizing silica gel with CH₂Cl₂ and hexane as a developing solvent to obtain Compound 53-a (1.43 g, yield of 65%), which is a yellow solid. Compound 53-a obtained was identified through analysis data.

ESI-LCMS: [M]+: C78H53D14BClN3. 1105.6001

### Synthesis of Compound 53

In an argon atmosphere, Intermediate 53-a (1.4 g, 1.2 mmol) 3,6-bis(phenyl-d5)-9H-carbazole-1,2,4,5,7,8-d6 (0.40 g, 1.2 mmol), Pd₂(dba)₃ (0.06 g, 0.12 mmol), tris-tert-butyl phosphine (0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄, and then filtered. A solvent was removed from the filtered solution under reduced pressure. Then, the obtained solid was purified and separated by column chromatography utilizing silica gel with CH₂Cl₂ and hexane as a developing solvent to obtain Compound 53 (1.2 g, yield of 78%), which is a yellow solid. Compound 53 obtained was identified through analysis data.

ESI-LCMS: [M]⁺: C102H53D30BN4. 1404.2186

1H-NMR (CDCl3): δ=7.42 (s, 4H), 7.21 (m, 12H), 7.11 (m, 8H), 6.88 (s, 1H), 1.31 (s, 18H), 1.12 (s, 9H)

### (14) Synthesis of Compound 62

Polycyclic Compound 62 according to one or more embodiments may be synthesized by, for example, steps of Reaction Formula 14.

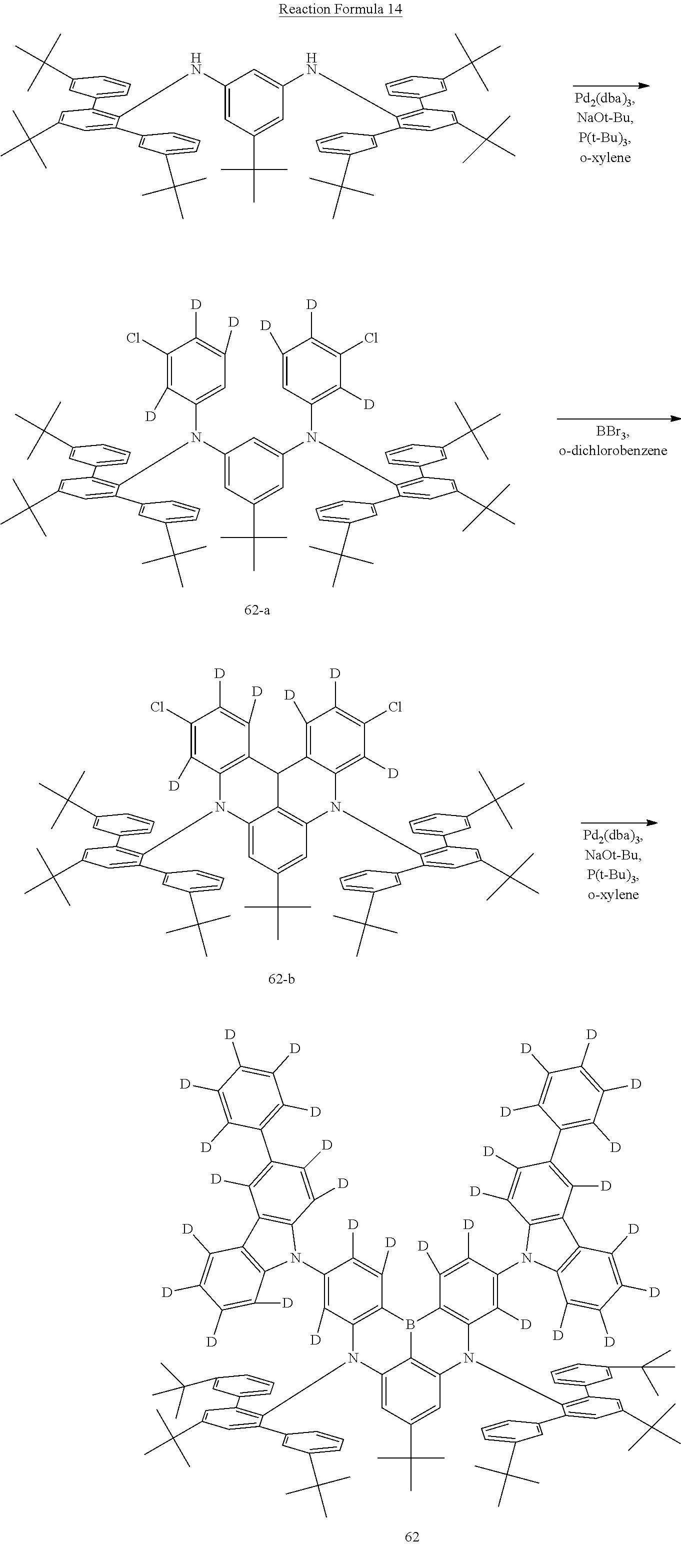

### Synthesis of Intermediate 62-a

In an argon atmosphere, 5-(tert-butyl)-N1,N3-bis(3,3″,5′-tri-tert-butyl-[1,1′:3′,1″-terphenyl]-2′-yl)benzene-1,3-diamine (10 g, 10 mmol), 1-chloro-3-iodobenzene-2,4,5,6-d4 (6.6 g, 27 mmol), Pd₂(dba)₃ (1.6 g, 1.9 mmol), tris-tert-butyl phosphine (1.6 mL, 3.8 mmol), and sodium tert-butoxide (11.5 g, 120 mmol) were put into a 2 L flask, and dissolved in 300 mL of o-xylene, and then a reaction solution was stirred for 12 hours at 140° C. After cooling, an organic layer was collected by adding 1 L of water and 300 mL of ethyl acetate and extracting, then dried over MgSO₄, and then filtered. A solvent was removed from the filtered solution under reduced pressure, and the obtained solid was purified and separated by column chromatography utilizing silica gel with CH₂Cl₂ and hexane as a developing solvent to obtain Intermediate 62-a (8.8 g, yield of 71%), which is a white solid. A mass spectroscopic analysis data of an obtained compound is as follows.

ESI-LCMS: [M]⁺: C82H88D6Cl2N2. 1182.8272

### Synthesis of Intermediate 62-b

In an argon atmosphere, he Intermediate 62-a (8.8 g, 7.4 mmol) was put into a 1 L flask, and dissolved in 100 mL of o-dichlorobenzene, and then BBr₃ (1.5 equiv.) was added. A reaction solution was stirred for 12 hours at 140° C. After cooling, the reaction was quenched by adding triethylamine, and a solvent was removed under reduced pressure. Then, the obtained solid was purified and separated by column chromatography utilizing silica gel with CH₂Cl₂ and hexane as a developing solvent to obtain Intermediate 62-b (2.2 g, yield of 25%), which is a yellow solid. A mass spectroscopic analysis data of an obtained compound is as follows.

ESI-LCMS: [M]⁺: C82H85D6BCl2N2. 1190.7005

### Synthesis of Compound 62

In an argon atmosphere, Intermediate 62-b (2.2 g, 1.8 mmol), 3-(phenyl-d5)-9H-carbazole-1,2,4,5,6,7,8-d7 (1.3 g, 5 mmol), Pd₂(dba)₃ (0.06 g, 0.12 mmol), tris-tert-butyl phosphine (0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄, and then filtered. A solvent was removed from the filtered solution under reduced pressure. Then, the obtained solid was purified and separated by column chromatography utilizing silica gel with CH₂Cl₂ and hexane as a developing solvent to obtain Compound 62 (2.25 g, yield of 75%), which is a yellow solid. Compound 62 obtained was identified through analysis data.

ESI-LCMS: [M]⁺: C118H85D30BN4. 1630.2424

1H-NMR (CDCl3): δ=7.55 (s, 2H), 7.41 (s, 4H), 7.12 (m, 8H), 7.01 (d, 4H), 6.92 (s, 2H), 1.55 (s, 36H), 1.32 (s, 18H), 1.12 (s, 9H)

### (15) Synthesis of Compound 80

Polycyclic compound 80 according to one or more embodiments may be synthesized by, for example, steps of Reaction Formula 15.

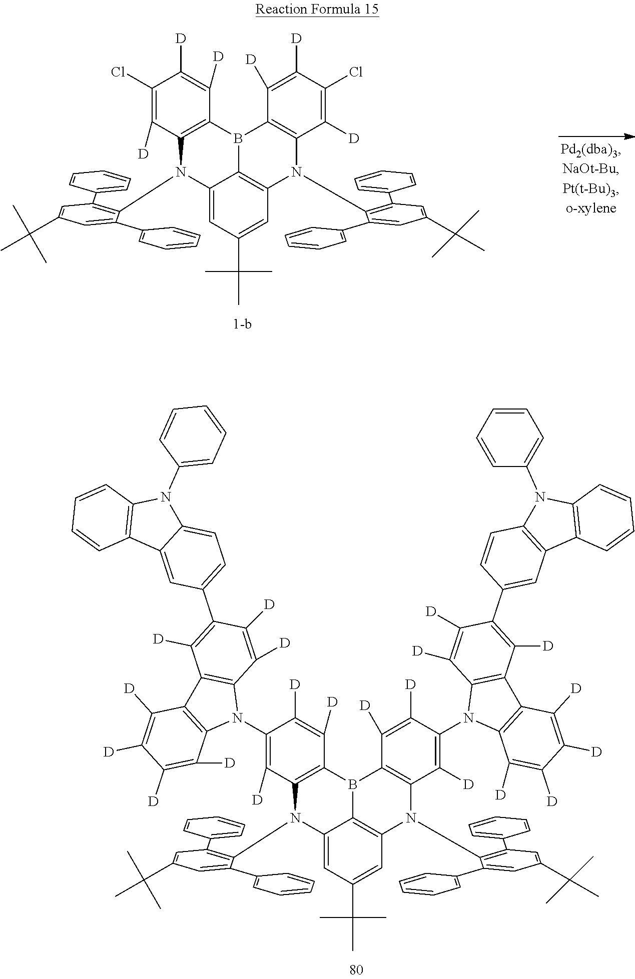

### Synthesis of Compound 80

In an argon atmosphere, Intermediate 1-b (2.2 g, 2.2 mmol), 9-phenyl-9H,9′H-3,3′-bicarbazole-1′,2′,4′,5′,6′,7′,8′-d7 (1.9 g, 5 mmol), Pd₂(dba)₃ (0.06 g, 0.12 mmol), tris-tert-butyl phosphine (0.06 mL, 0.24 mmol), and sodium tert-butoxide (0.5 g, 5.1 mmol) were put into a 1 L flask, and dissolved in 100 mL of o-xylene, and then a reaction solution was stirred for 12 hours at 140° C. After cooling, an organic layer was collected by adding 1 L of water and 300 mL of ethyl acetate and extracting, then dried over MgSO₄, and then filtered. A solvent was removed from the filtered solution under reduced pressure. Then, the obtained solid was purified and separated by column chromatography utilizing silica gel with CH₂Cl₂ and hexane as a developing solvent to obtain Compound 80 (2.8 g, yield of 74%), which is a yellow solid. Compound 80 obtained was identified by analysis data.

ESI-LCMS: [M]+: C126H77D20BN6. 1724.9111

1H-NMR (CDCl3): δ=8.55 (d, 1H), 8.30 (d, 1H), 8.19 (d, 1H), 8.13 (d, 1H), 7.94 (d, 1H), 7.89 (s, 2H), 7.77 (d, 1H), 7.58 (m, 7H), 7.50 (m, 6H), 7.41 (s, 4H), 7.15 (m, 12H), 7.08 (d, 2H), 7.05 (m, 8H), 7.01 (d, 4H), 6.90 (s, 2H), 1.33 (s, 18H), 1.15 (s, 9H)

### 2. Evaluation of Polycyclic Compound

In Table 1, polycyclic compounds utilized in Examples and Comparative Examples are listed.

TABLE 1

| Classification | Compound |
|---|---|
| Example 1 | 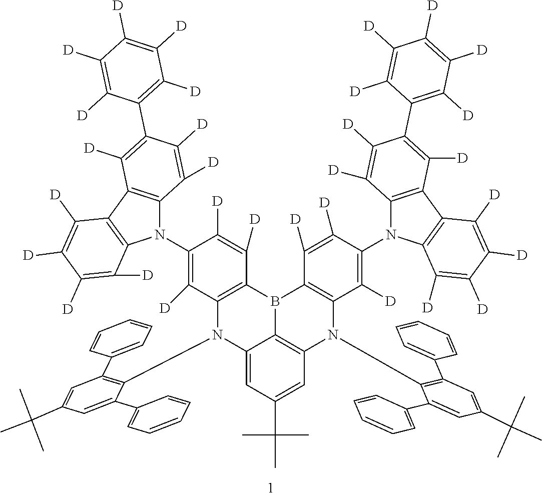 [SMILES: [2H]c1c([2H])c([2H])c(-c2c([2H])c([2H])c3c(c2[2H])c2c([2H])c([2H])c([2H])c([2H])c2n3-c2c([2H])c([2H])c3c(c2[2H])N(c2c(-c4ccccc4)cc(C(C)(C)C)cc2-c2ccccc2)c2cc(C(C)(C)C)cc4c2B3c2c([2H])c([2H])c(-n3c5c([2H])c([2H])c([2H])c([2H])c5c5c([2H])c(-c6c([2H])c([2H])c([2H])c([2H])c6[2H])c([2H])c([2H])c53)c([2H])c2N4c2c(-c3ccccc3)cc(C(C)(C)C)cc2-c2ccccc2)c([2H])c1[2H]] |
| Example 2 | 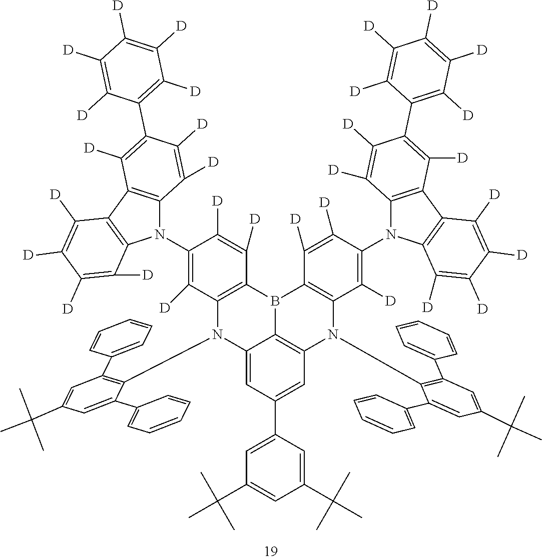 [SMILES: [2H]c1c([2H])c([2H])c(-c2c([2H])c([2H])c3c(c2[2H])c2c([2H])c([2H])c([2H])c([2H])c2n3-c2c([2H])c([2H])c3c(c2[2H])N(c2c(-c4ccccc4)cc(C(C)(C)C)cc2-c2ccccc2)c2cc(-c4cc(C(C)(C)C)cc(C(C)(C)C)c4)cc4c2B3c2c([2H])c([2H])c(-n3c5c([2H])c([2H])c([2H])c([2H])c5c5c([2H])c(-c6c([2H])c([2H])c([2H])c([2H])c6[2H])c([2H])c([2H])c53)c([2H])c2N4c2c(-c3ccccc3)cc(C(C)(C)C)cc2-c2ccccc2)c([2H])c1[2H]] |
| Example 3 | 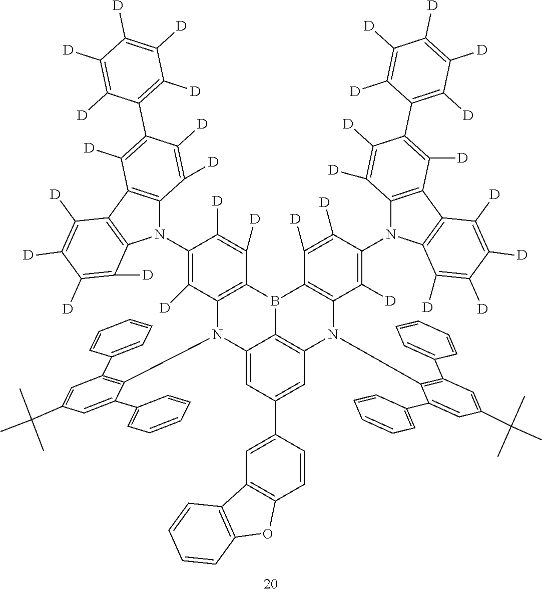 [SMILES: [2H]c1c([2H])c([2H])c(-c2c([2H])c([2H])c3c(c2[2H])c2c([2H])c([2H])c([2H])c([2H])c2n3-c2c([2H])c([2H])c3c(c2[2H])N(c2c(-c4ccccc4)cc(C(C)(C)C)cc2-c2ccccc2)c2cc(-c4ccc5oc6ccccc6c5c4)cc4c2B3c2c([2H])c([2H])c(-n3c5c([2H])c([2H])c([2H])c([2H])c5c5c([2H])c(-c6c([2H])c([2H])c([2H])c([2H])c6[2H])c([2H])c([2H])c53)c([2H])c2N4c2c(-c3ccccc3)cc(C(C)(C)C)cc2-c2ccccc2)c([2H])c1[2H]] |
| Example 4 | 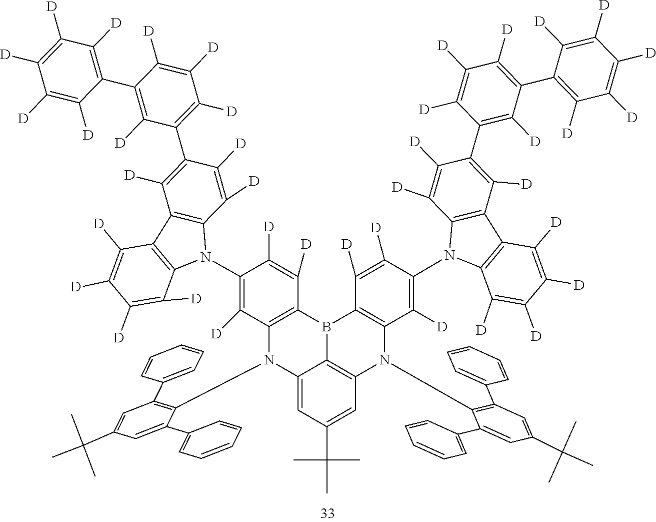 [SMILES: [2H]c1c([2H])c([2H])c(-c2c([2H])c([2H])c([2H])c(-c3c([2H])c([2H])c4c(c3[2H])c3c([2H])c([2H])c([2H])c([2H])c3n4-c3c([2H])c([2H])c4c(c3[2H])N(c3c(-c5ccccc5)cc(C(C)(C)C)cc3-c3ccccc3)c3cc(C(C)(C)C)cc5c3B4c3c([2H])c([2H])c(-n4c6c([2H])c([2H])c([2H])c([2H])c6c6c([2H])c(-c7c([2H])c([2H])c([2H])c(-c8c([2H])c([2H])c([2H])c([2H])c8[2H])c7[2H])c([2H])c([2H])c64)c([2H])c3N5c3c(-c4ccccc4)cc(C(C)(C)C)cc3-c3ccccc3)c2[2H])c([2H])c1[2H]] |
| Example 5 | 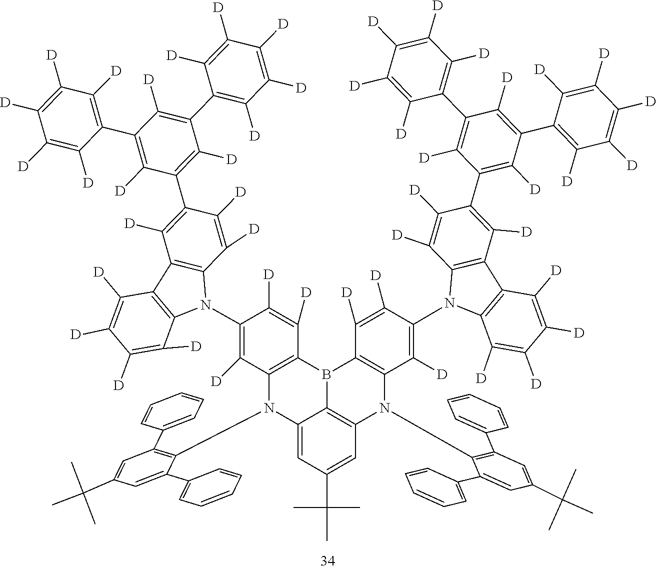 [SMILES: [2H]c1c([2H])c([2H])c(-c2c([2H])c(-c3c([2H])c([2H])c([2H])c([2H])c3[2H])c([2H])c(-c3c([2H])c([2H])c4c(c3[2H])c3c([2H])c([2H])c([2H])c([2H])c3n4-c3c([2H])c([2H])c4c(c3[2H])N(c3c(-c5ccccc5)cc(C(C)(C)C)cc3-c3ccccc3)c3cc(C(C)(C)C)cc5c3B4c3c([2H])c([2H])c(-n4c6c([2H])c([2H])c([2H])c([2H])c6c6c([2H])c(-c7c([2H])c(-c8c([2H])c([2H])c([2H])c([2H])c8[2H])c([2H])c(-c8c([2H])c([2H])c([2H])c([2H])c8[2H])c7[2H])c([2H])c([2H])c64)c([2H])c3N5c3c(-c4ccccc4)cc(C(C)(C)C)cc3-c3ccccc3)c2[2H])c([2H])c1[2H]] |
| Example 6 | 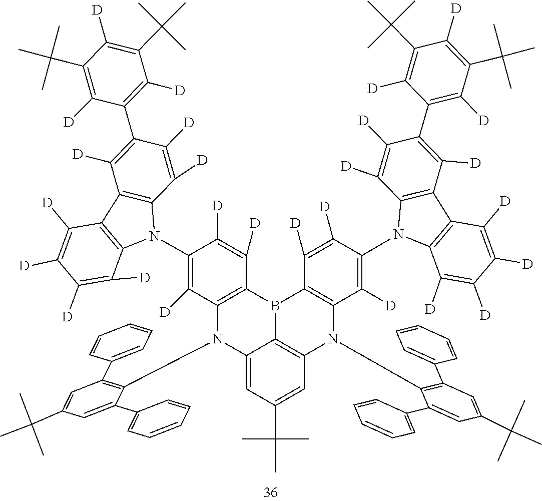 [SMILES: [2H]c1c([2H])c(-n2c3c([2H])c([2H])c([2H])c([2H])c3c3c([2H])c(-c4c([2H])c(C(C)(C)C)c([2H])c(C(C)(C)C)c4[2H])c([2H])c([2H])c32)c([2H])c2c1B1c3c(cc(C(C)(C)C)cc3N(c3c(-c4ccccc4)cc(C(C)(C)C)cc3-c3ccccc3)c3c([2H])c(-n4c5c([2H])c([2H])c([2H])c([2H])c5c5c([2H])c(-c6c([2H])c(C(C)(C)C)c([2H])c(C(C)(C)C)c6[2H])c([2H])c([2H])c54)c([2H])c([2H])c31)N2c1c(-c2ccccc2)cc(C(C)(C)C)cc1-c1ccccc1] |
| Example 7 | 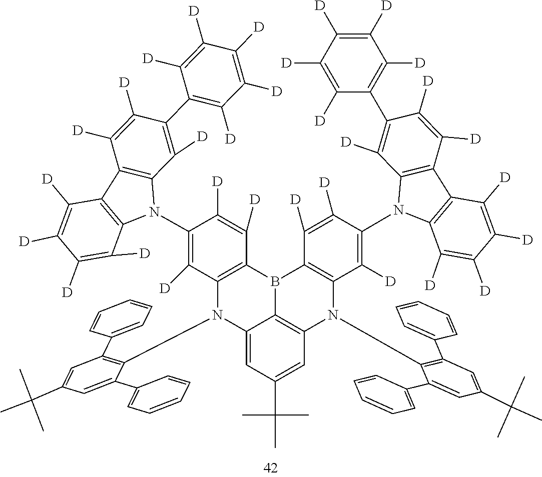 [SMILES: [2H]c1c([2H])c([2H])c(-c2c([2H])c([2H])c3c4c([2H])c([2H])c([2H])c([2H])c4n(-c4c([2H])c([2H])c5c(c4[2H])N(c4c(-c6ccccc6)cc(C(C)(C)C)cc4-c4ccccc4)c4cc(C(C)(C)C)cc6c4B5c4c([2H])c([2H])c(-n5c7c([2H])c([2H])c([2H])c([2H])c7c7c([2H])c([2H])c(-c8c([2H])c([2H])c([2H])c([2H])c8[2H])c([2H])c75)c([2H])c4N6c4c(-c5ccccc5)cc(C(C)(C)C)cc4-c4ccccc4)c3c2[2H])c([2H])c1[2H]] |
| Example 8 | 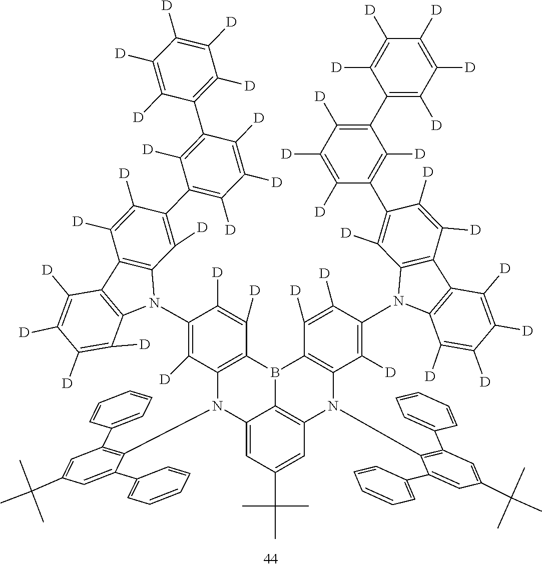 [SMILES: [2H]c1c([2H])c([2H])c(-c2c([2H])c([2H])c([2H])c(-c3c([2H])c([2H])c4c5c([2H])c([2H])c([2H])c([2H])c5n(-c5c([2H])c([2H])c6c(c5[2H])N(c5c(-c7ccccc7)cc(C(C)(C)C)cc5-c5ccccc5)c5cc(C(C)(C)C)cc7c5B6c5c([2H])c([2H])c(-n6c8c([2H])c([2H])c([2H])c([2H])c8c8c([2H])c([2H])c(-c9c([2H])c([2H])c([2H])c(-c%10c([2H])c([2H])c([2H])c([2H])c%10[2H])c9[2H])c([2H])c86)c([2H])c5N7c5c(-c6ccccc6)cc(C(C)(C)C)cc5-c5ccccc5)c4c3[2H])c2[2H])c([2H])c1[2H]] |
| Example 9 | 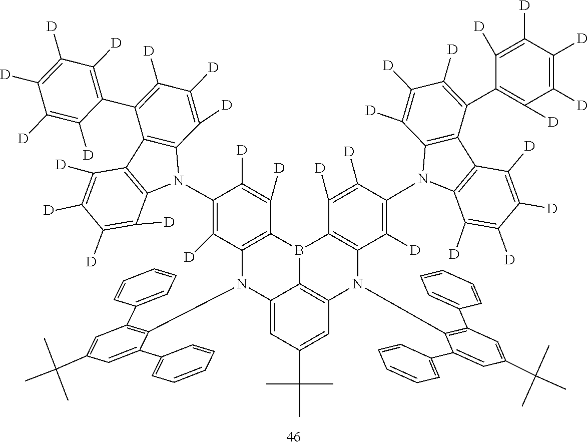 [SMILES: [2H]c1c([2H])c([2H])c(-c2c([2H])c([2H])c([2H])c3c2c2c([2H])c([2H])c([2H])c([2H])c2n3-c2c([2H])c([2H])c3c(c2[2H])N(c2c(-c4ccccc4)cc(C(C)(C)C)cc2-c2ccccc2)c2cc(C(C)(C)C)cc4c2B3c2c([2H])c([2H])c(-n3c5c([2H])c([2H])c([2H])c([2H])c5c5c(-c6c([2H])c([2H])c([2H])c([2H])c6[2H])c([2H])c([2H])c([2H])c53)c([2H])c2N4c2c(-c3ccccc3)cc(C(C)(C)C)cc2-c2ccccc2)c([2H])c1[2H]] |
| Example 10 | 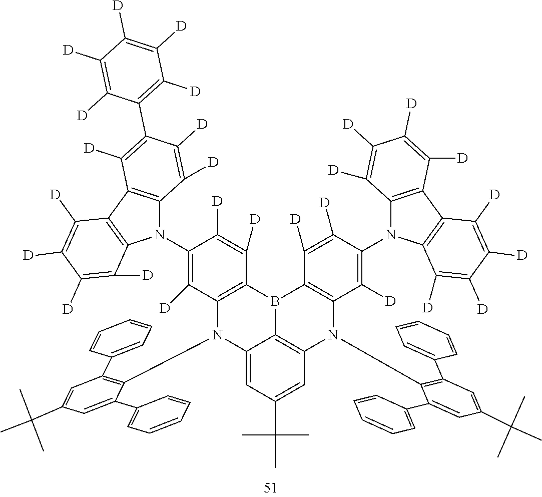 [SMILES: [2H]c1c([2H])c([2H])c(-c2c([2H])c([2H])c3c(c2[2H])c2c([2H])c([2H])c([2H])c([2H])c2n3-c2c([2H])c([2H])c3c(c2[2H])N(c2c(-c4ccccc4)cc(C(C)(C)C)cc2-c2ccccc2)c2cc(C(C)(C)C)cc4c2B3c2c([2H])c([2H])c(-n3c5c([2H])c([2H])c([2H])c([2H])c5c5c([2H])c([2H])c([2H])c([2H])c53)c([2H])c2N4c2c(-c3ccccc3)cc(C(C)(C)C)cc2-c2ccccc2)c([2H])c1[2H]] |
| Example 11 | 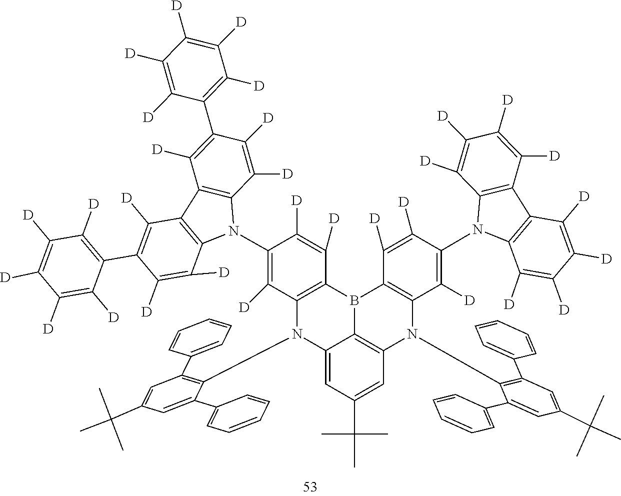 [SMILES: [2H]c1c([2H])c([2H])c(-c2c([2H])c([2H])c3c(c2[2H])c2c([2H])c(-c4c([2H])c([2H])c([2H])c([2H])c4[2H])c([2H])c([2H])c2n3-c2c([2H])c([2H])c3c(c2[2H])N(c2c(-c4ccccc4)cc(C(C)(C)C)cc2-c2ccccc2)c2cc(C(C)(C)C)cc4c2B3c2c([2H])c([2H])c(-n3c5c([2H])c([2H])c([2H])c([2H])c5c5c([2H])c([2H])c([2H])c([2H])c53)c([2H])c2N4c2c(-c3ccccc3)cc(C(C)(C)C)cc2-c2ccccc2)c([2H])c1[2H]] |
| Example 12 | 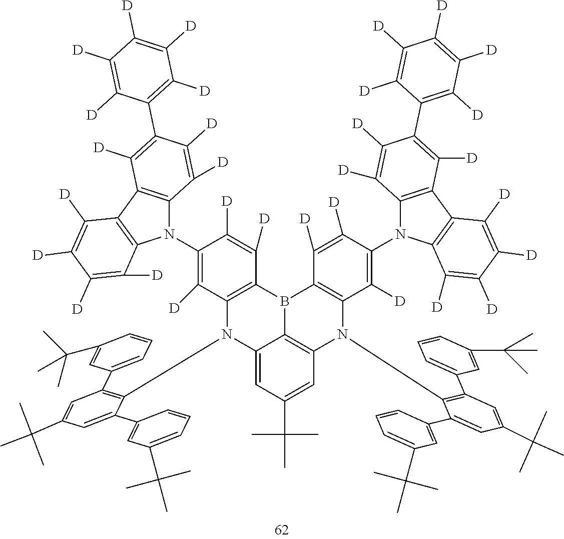 [SMILES: [2H]c1c([2H])c([2H])c(-c2c([2H])c([2H])c3c(c2[2H])c2c([2H])c([2H])c([2H])c([2H])c2n3-c2c([2H])c([2H])c3c(c2[2H])N(c2c(-c4cccc(C(C)(C)C)c4)cc(C(C)(C)C)cc2-c2cccc(C(C)(C)C)c2)c2cc(C(C)(C)C)cc4c2B3c2c([2H])c([2H])c(-n3c5c([2H])c([2H])c([2H])c([2H])c5c5c([2H])c(-c6c([2H])c([2H])c([2H])c([2H])c6[2H])c([2H])c([2H])c53)c([2H])c2N4c2c(-c3cccc(C(C)(C)C)c3)cc(C(C)(C)C)cc2-c2cccc(C(C)(C)C)c2)c([2H])c1[2H]] |
| Example 13 | 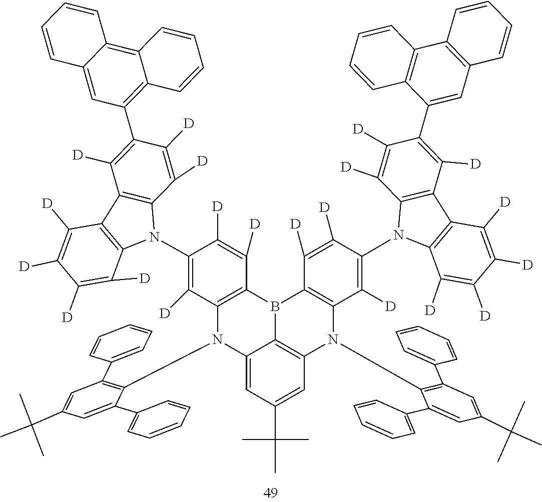 [SMILES: [2H]c1c([2H])c(-n2c3c([2H])c([2H])c([2H])c([2H])c3c3c([2H])c(-c4cc5ccccc5c5ccccc45)c([2H])c([2H])c32)c([2H])c2c1B1c3c(cc(C(C)(C)C)cc3N(c3c(-c4ccccc4)cc(C(C)(C)C)cc3-c3ccccc3)c3c([2H])c(-n4c5c([2H])c([2H])c([2H])c([2H])c5c5c([2H])c(-c6cc7ccccc7c7ccccc67)c([2H])c([2H])c54)c([2H])c([2H])c31)N2c1c(-c2ccccc2)cc(C(C)(C)C)cc1-c1ccccc1] |
| Example 14 | 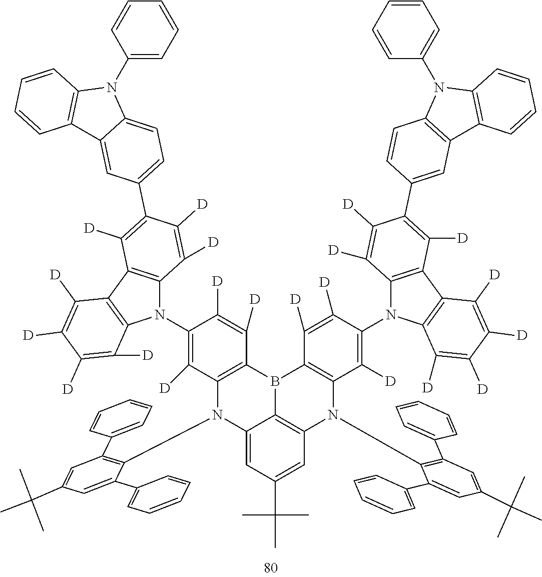 [SMILES: [2H]c1c([2H])c(-n2c3c([2H])c([2H])c([2H])c([2H])c3c3c([2H])c(-c4ccc5c(c4)c4ccccc4n5-c4ccccc4)c([2H])c([2H])c32)c([2H])c2c1B1c3c(cc(C(C)(C)C)cc3N(c3c(-c4ccccc4)cc(C(C)(C)C)cc3-c3ccccc3)c3c([2H])c(-n4c5c([2H])c([2H])c([2H])c([2H])c5c5c([2H])c(-c6ccc7c(c6)c6ccccc6n7-c6ccccc6)c([2H])c([2H])c54)c([2H])c([2H])c31)N2c1c(-c2ccccc2)cc(C(C)(C)C)cc1-c1ccccc1] |
| Example 15 | 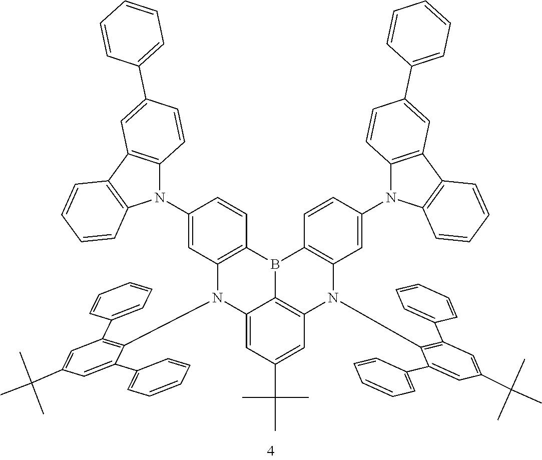 [SMILES: CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cc(C(C)(C)C)cc4-c4ccccc4)c4cc(C(C)(C)C)cc2c43)c(-c2ccccc2)c1] |
| Comparative Example 1 | 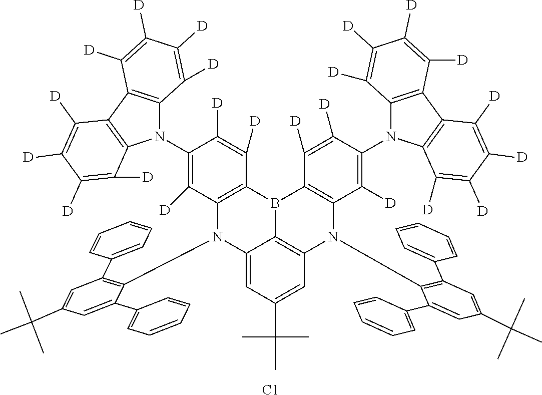 |
| Comparative Example 2 | 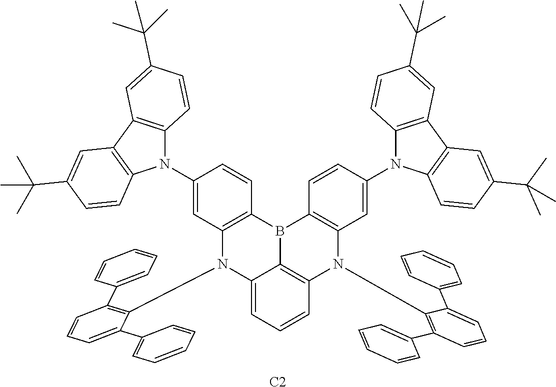 [SMILES: CC(C)(C)c1ccc2c(c1)c1cc(C(C)(C)C)ccc1n2-c1ccc2c(c1)N(c1c(-c3ccccc3)cccc1-c1ccccc1)c1cccc3c1B2c1ccc(-n2c4ccc(C(C)(C)C)cc4c4cc(C(C)(C)C)ccc42)cc1N3c1c(-c2ccccc2)cccc1-c1ccccc1 ; "C2"] |
| Comparative Example 3 | 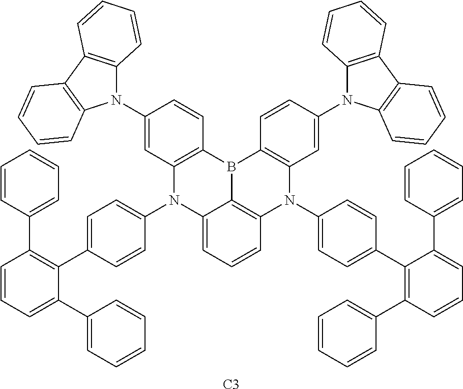 [SMILES: c1ccc(-c2cccc(-c3ccccc3)c2-c2ccc(N3c4cc(-n5c6ccccc6c6ccccc65)ccc4B4c5ccc(-n6c7ccccc7c7ccccc76)cc5N(c5ccc(-c6c(-c7ccccc7)cccc6-c6ccccc6)cc5)c5cccc3c54)cc2)cc1 ; "C3"] |

In Table 2, the evaluation results of material characteristics of polycyclic compounds utilized in Examples and Comparative Examples are listed.

λ_{Abs} among the material characteristics of the polycyclic compound in Table 2 was measured by utilizing the Labsolution UV-Vis software in a state in which a deuterium/tungsten-halogen light source and a silicon photodiode were attached to an UV-1800 UVNisible Scanning Spectrophotometer (made by SHIMADZU) instrument. S1, T1, λₑₘᵢ, and full-width quarter maximum (FWQM) were measured by utilizing the FluorEssence software in a state in which a xenon light source and a monochromator were attached to FluoroMax® Plus spectrometer (made by Horiba) instrument. Stokes-shift exhibits a difference between a maximum wavelength when absorbing energy and a maximum wavelength when emitting energy.

A structure having an exited second stable triplet state was calculated utilizing unrestricted density functional theory (UDFT) calculating method, and corresponding energies were calculated as T2 and T3 values. UDFT calculation was performed with Gaussian 09, which is a commercially available software, and the 6-311 G(d,p) basis function and the B3LYP exchange-correlation functional were utilized.

Measurement of K_{RISC}, which is a RISC speed, was calculated from Eq. k_{RISC}=ϕ_{d}(k_{ISC}·τₚ·τ_{d}·ϕₚ). After depositing a single film utilizing the vacuum deposition method on the glass substrate with a thickness of 40 nm, each factor in the equation was measured utilizing the method. ϕ_{d} and ϕₚ were measured with Quantaurus-QY measurement system (C11347-11, Hamamatsu Photonics). τp and τd were measured by utilizing Quantaurus-Tau fluorescence lifetime measurement system (011367-03, Hamamatsu Photonics).

TABLE 2

| | | | | | ΔE | ΔE | ΔE | | | | | |
|---|---|---|---|---|---|---|---|---|---|---|---|---|
| | | | | | (S₁ − | (T₁ − | (T₂ − | RISC | | | | |
| | S1 | T1 | T2 | T3 | T₂) | T₂) | T₃) | (k_{RISC}) | λ_{Abs} | λₑₘᵢ | Stokes- | FWQM |
| Classification | (eV) | (eV) | (eV) | (eV) | (eV) | (eV) | (eV) | (S⁻¹) | (nm) | (nm) | shift | (nm) |
| Example 1 | 2.70 | 2.58 | 2.99 | 3.03 | 0.29 | 0.41 | 0.04 | 9.7 × 10⁴ | 447 | 459 | 12 | 35 |
| Example 2 | 2.67 | 2.57 | 2.95 | 2.98 | 0.28 | 0.38 | 0.03 | 9.9 × 10⁴ | 451 | 463 | 12 | 31 |
| Example 3 | 2.68 | 2.58 | 2.97 | 3.00 | 0.29 | 0.39 | 0.03 | 9.6 × 10⁴ | 448 | 460 | 12 | 33 |
| Example 4 | 2.70 | 2.59 | 2.91 | 2.92 | 0.21 | 0.32 | 0.01 | 4.3 × 10⁵ | 447 | 459 | 12 | 34 |
| Example 5 | 2.70 | 2.58 | 2.88 | 2.89 | 0.18 | 0.30 | 0.01 | 5.3 × 10⁵ | 447 | 459 | 12 | 33 |
| Example 6 | 2.70 | 2.58 | 2.99 | 3.03 | 0.29 | 0.41 | 0.04 | 9.6 × 10⁴ | 447 | 459 | 12 | 34 |
| Example 7 | 2.70 | 2.58 | 2.95 | 2.96 | 0.25 | 0.37 | 0.01 | 1.3 × 10⁵ | 447 | 458 | 11 | 33 |
| Example 8 | 2.70 | 2.58 | 2.91 | 2.92 | 0.21 | 0.33 | 0.01 | 4.8 × 10⁵ | 447 | 458 | 11 | 33 |
| Example 9 | 2.70 | 2.59 | 2.97 | 3.01 | 0.27 | 0.38 | 0.04 | 0.8 × 10⁵ | 447 | 459 | 12 | 35 |
| Example 10 | 2.70 | 2.59 | 2.97 | 2.98 | 0.27 | 0.38 | 0.01 | 2.1 × 10⁵ | 446 | 458 | 12 | 35 |
| Example 11 | 2.70 | 2.59 | 2.95 | 2.96 | 0.25 | 0.36 | 0.01 | 2.4 × 10⁵ | 447 | 459 | 12 | 35 |
| Example 12 | 2.70 | 2.58 | 2.99 | 3.03 | 0.29 | 0.41 | 0.04 | 9.5 × 10⁴ | 448 | 459 | 11 | 32 |
| Example 13 | 2.71 | 2.59 | 2.80 | 2.85 | 0.09 | 0.21 | 0.05 | 0.2 × 10^{6 S} | 449 | 460 | 11 | 35 |
| Example 14 | 2.70 | 2.58 | 2.85 | 2.88 | 0.15 | 0.27 | 0.03 | 7.2 × 10⁵ | 450 | 46 | 11 | 34 |
| Example 15 | 2.71 | 2.59 | 2.98 | 3.02 | 0.27 | 0.39 | 0.04 | 2.2 × 10⁵ | 447 | 459 | 12 | 35 |
| Comparative | 2.70 | 2.59 | 3.05 | 3.14 | 0.35 | 0.46 | 0.09 | 1.2 × 10⁴ | 446 | 459 | 13 | 37 |
| Example 1 | | | | | | | | | | | | |
| Comparative | 2.70 | 2.58 | 3.10 | 3.21 | 0.46 | 0.52 | 0.11 | 0.9 × 10⁴ | 440 | 453 | 13 | 39 |
| Example 2 | | | | | | | | | | | | |
| Comparative | 2.70 | 2.59 | 3.08 | 3.18 | 0.38 | 0.49 | 0.10 | 0.3 × 10⁴ | 442 | 457 | 15 | 40 |
| Example 3 | | | | | | | | | | | | |

Referring to results of Table 2, compounds according to Examples exhibited similar levels of T1 energy levels and S1 energy levels to those of compounds according to Comparative Examples. However, in terms of the T2 energy level and the T3 energy level, the compounds according to Examples had relatively low values compared to compounds according to Comparative Examples. As a result, differences (ΔE(S₁−T₂)) in energy levels between the S1 state and the T2 state of the compounds according to Examples are smaller than differences (ΔE(S₁−T₂) in energy levels between the S1 state and the T2 state of the compounds according to Comparative Examples. In some embodiments, the compounds according to Examples are smaller in the difference in energy levels of higher triplet states than compounds according to Comparative Examples. For example, differences (ΔE(T₁−T₂) in energy levels between the T1 state and the T2 state of the compounds according to Examples and differences (ΔE(T₂−T₃) in energy levels between the T2 state and the T3 state of the compounds according to Examples are respectively smaller than differences (ΔE(T₁−T₂) in energy levels between the T1 state and the T2 state of the compounds according to Comparative Examples, and differences (ΔE(T₂−T₃) in energy levels between the T2 state and the T3 state of the compounds according to Comparative Examples.

In case of the compounds according to Examples, it can be seen that RISC speed was faster than those of the compounds according to Comparative Examples. For example, with reference to Table 2, it is considered, without being bound by any particular theory, that the compounds according to Examples had relatively lower energy levels of the higher triplet state than the compounds according to Comparative Examples, and therefore the RISC speed in Examples exhibited improved results than those in Comparative Examples.

In some embodiments, with reference to the results of Table 2, Examples exhibited characteristics of light-absorbing wavelength and light-emitting wavelength similar to those of Comparative Examples. For example, it can be seen that despite some differences in energy levels of the triplet states, the compounds according to Examples exhibit similar light-emitting wavelength characteristics to the compounds according to Comparative Examples.

In some embodiments, full-width at quarter maximum (FWQM) values, which are evaluated values of characteristics of a light-emitting peak, in Examples were relatively smaller than those in Comparative Examples. The FWQM is a width of a light-emitting peak at a quarter point of a maximum value of a light-emitting peak. It can be demonstrated from the results of Table 2 that the compounds according to Examples exhibit relatively low FWQM characteristics according to Comparative Examples, and exhibit excellent or suitable color rendering characteristics, compared to the compounds.

### 3. Manufacturing and Evaluation of Light-Emitting Element

### (1) Manufacturing of Light-Emitting Element

A light-emitting element according to one or more embodiments, including the polycyclic compound according to one or more embodiments, or a light-emitting element including a compound of Comparative Example in an emission layer were manufactured by a method. Light-emitting elements of Examples 1 to 15 were manufactured by utilizing the polycyclic compound according to one or more embodiments as a dopant material in an emission layer. The light-emitting elements according to Comparative Examples 1 to 3 were manufactured by utilizing Comparative Example Compounds C1 to C3 as dopant materials in the emission layer.

The glass substrate (made by Corning, Inc.) on which the ITO electrode of 15 Ω/cm² (1200 Å) was formed as the first electrode was cut to a size of 50 mm×50 mm×0.7 mm, ultrasonically cleaned utilizing isopropyl alcohol and pure water for 5 minutes each, then irradiated with UV light for 30 minutes and cleaned by exposure to ozone, and then mounted on a vacuum deposition device.

NPD was deposited on the first electrode to form a hole injection layer having a thickness of 300 Å, and Compound H-1-19 was deposited on the hole injection layer to form a hole transport layer having a thickness of 200 Å. Next, CzSi was deposited on the hole transport layer to form a light-emitting auxiliary layer having a thickness of 100 Å.

A host mixture, a phosphorescent sensitizer and a dopant were co-deposited on the light-emitting auxiliary layer at a weight ratio of 85:14:1 to form an emission layer having a thickness of 200 Å. The host mixture is provided such that HT33, which is a hole transporting host, and ETH66, which is an electron transporting host, were provided at a weight ratio of 5:5. As the phosphorescent sensitization material, Compound AD-39 was utilized. As the dopant material, Example Compounds or Comparative Example Compounds were utilized.

TSPO1 was deposited on the emission layer to form a hole blocking layer having a thickness of 200 Å, and TPBi was deposited on the hole blocking layer to form an electron transport layer having a thickness of 300 Å. LiF was deposited on the electron transport layer to form an electron injection layer having a thickness of 10 Å, and Al was deposited on the electron injection layer to form a second electrode having a thickness of 3000 Å, thereby manufacturing a light-emitting element.

Compounds utilized in manufacturing of the light-emitting element are as follows:

### Material Utilized in Manufacturing of Light-Emitting Element

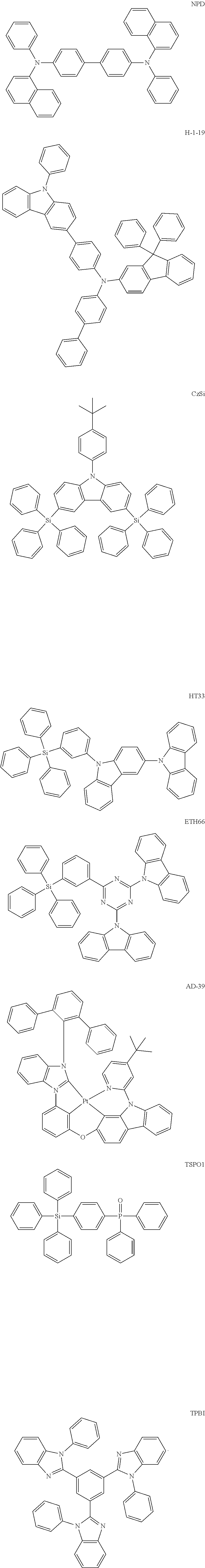

### (2) Evaluation of Light-Emitting Element

Table 3 shows the evaluation results of the light-emitting element according to Examples and Comparative Examples. For the light-emitting elements according to Examples and Comparative Examples, a driving voltage (V) at a current density of about 10 mA/cm², front efficiency (cd/A/y), and a light-emitting wavelength (nm) were measured utilizing Keithley SMU 236 and a luminance meter PR650, and the measurement results were listed. The time taken for luminance to decrease to 95% of an initial luminance was measured as the lifespan, and compared values with a value in the light-emitting element according to Comparative Example 1 were listed as relative element lifespans.

TABLE 3

| | | | Light- | | | |
|---|---|---|---|---|---|---|
| | Driving | Front | emitting | Life- | | |
| Classifica- | voltage | efficiency | wavelength | span | | Q.E |
| tion | (V) | (cd/A/y) | (nm) | (T95) | CIE y | (%) |
| Example 1 | 4.1 | 554.8 | 463 | 1.5 | 0.057 | 53.1 |
| Example 2 | 4.0 | 584.2 | 463 | 1.5 | 0.055 | 58.1 |
| Example 3 | 4.1 | 573.3 | 463 | 1.2 | 0.056 | 55.6 |
| Example 4 | 4.1 | 560.7 | 463 | 1.7 | 0.057 | 54.7 |
| Example 5 | 4.0 | 564.1 | 463 | 1.6 | 0.057 | 54.8 |
| Example 6 | 4.0 | 543.8 | 463 | 1.7 | 0.054 | 52.1 |
| Example 7 | 3.9 | 555.1 | 463 | 1.4 | 0.053 | 53.2 |
| Example 8 | 4.0 | 543.8 | 463 | 1.6 | 0.055 | 51.8 |
| Example 9 | 4.1 | 543.1 | 463 | 1.2 | 0.057 | 50.7 |
| Example 10 | 4.1 | 559.1 | 463 | 1.5 | 0.058 | 53.5 |
| Example 11 | 4.1 | 562.6 | 463 | 1.6 | 0.056 | 54.1 |
| Example 12 | 4.0 | 563.1 | 463 | 1.9 | 0.054 | 54.0 |
| Example 13 | 3.8 | 588.4 | 463 | 2.1 | 0.055 | 57.1 |
| Example 14 | 4.1 | 573.1 | 463 | 1.8 | 0.054 | 55.9 |
| Example 15 | 4.0 | 554.1 | 463 | 1.3 | 0.057 | 53.1 |
| Comparative | 4.1 | 536.1 | 462 | 1 | 0.053 | 47.1 |
| Example 1 | | | | | | |
| Comparative | 4.2 | 489.5 | 457 | 0.4 | 0.049 | 41.0 |
| Example 2 | | | | | | |
| Comparative | 4.4 | 500.4 | 466 | 0.1 | 0.060 | 45.9 |
| Example 3 | | | | | | |

It can be seen from the results of Table that the light-emitting elements according to Examples exhibit similar levels of driving voltage characteristics to those of Comparative Examples. In some embodiments, the light-emitting elements according to Examples exhibited similar characteristics of the light-emitting wavelength and color coordinates (CIE y) to those of Comparative Example 1 containing a Comparative Example Compound C1 having a similar core structure with Example Compounds. For example, it can be seen that Examples exhibit similar light-emitting color characteristics to those of Comparative Example 1.

In some embodiments, Examples exhibit higher front efficiency and higher external quantum efficiency (Q,E) values than Comparative Examples. For example, it is believed that, in case of Examples, because a polycyclic compound having improved material stability, according to one or more embodiments, is included in the emission layer, deterioration of the polycyclic compound is mitigated or reduced, and thus light emission efficiency of the emission layer improved.

In some embodiments, referring to results of Table 3, Examples exhibit excellent or suitable lifespan characteristics as compared with Comparative Examples. The light-emitting elements according to Examples include the polycyclic compound according to one or more embodiments in the emission layer and having lower energy level in the higher triplet state than Comparative compounds according to Comparative Examples, and thus deterioration of the excitons in the Example light-emitting elements may be mitigated or reduced, and the light-emitting elements according to the present embodiments may thereby exhibit a longer lifespan than light-emitting elements according to Comparative Examples.

In the light-emitting element according to one or more embodiments, the emission layer may include the polycyclic compound according to one or more embodiments. The polycyclic compound according to one or more embodiments includes a fused ring of five rings, as a center structure, including two nitrogen atoms, and one boron atom as a ring-forming atom, and two carbazole derivatives and two terphenyl derivative, which are bonded to the fused ring of five rings. In some embodiments, the polycyclic compound according to one or more embodiments has a structure in which at least one selected from among two carbazole derivatives includes at least one aromatic substituent. Accordingly, the polycyclic compound according to one or more embodiments may exhibit characteristics of lowering energy levels of a higher triplet state, the material deterioration due to excitons in triplet states may be mitigated or reduced, and thus excellent or suitable material stability may be exhibited, and the light-emitting element including the polycyclic compound in the emission layer may exhibit a long or suitable lifespan.

In some embodiments, the polycyclic compound according to one or more embodiments may be utilized as a thermally activated delayed fluorescence material. As a result, a light-emitting element including the polycyclic compound according to one or more embodiments may exhibit characteristics of a relatively high or suitable efficiency and a relatively long or suitable lifespan.

A light-emitting element according to one or more embodiments may include the polycyclic compound according to one or more embodiments in an emission layer, thereby exhibiting characteristics of a relatively high efficiency and a relatively long lifespan.

The polycyclic compound according to one or more embodiments may contribute to improving light emission efficiency and achieving a long lifespan of light-emitting element.

A display device according to one or more embodiments may exhibit excellent or suitable display quality.

Hitherto, although the example embodiments of the present disclosure have been described, it is understood that the present disclosure should not be limited to these embodiments, but one or more suitable changes and modifications can be made by one ordinary skilled in the art within the spirit and scope of the present disclosure as hereinafter claimed.

Accordingly, it is understood that the technical scope of the present disclosure should not be limited to the contents set forth in the detailed description of the specification but be defined by the appended claims and their equivalents.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

What is claimed is:

1. A light-emitting element comprising:
a first electrode;
a second electrode on the first electrode; and
an emission layer between the first electrode and the second electrode and comprising a first compound represented by Formula 1: 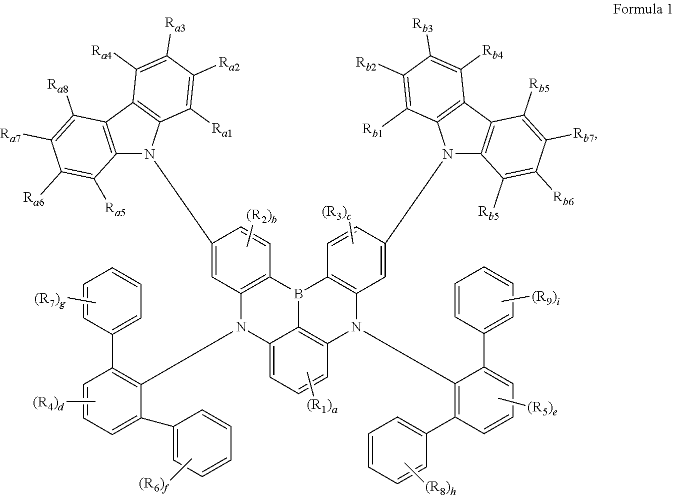
wherein, in Formula 1, at least one selected from among Rₐ₁ to Rₐ₈ and R_{b1} to R_{b8} is a substituted or unsubstituted aryl group having 6 to 60 ring-forming carbon atoms or a substituted or unsubstituted heteroaryl group having 2 to 60 ring-forming carbon atoms,
remaining ones selected from among Rₐ₁ to Rₐ₈, and R_{b1} to R_{b8} are each independently a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, or a substituted or unsubstituted alkenyl group having 2 to 60 carbon atoms,
a to e are each independently an integer of 1 to 3,
f to i are each independently an integer of 1 to 5, and
R₁ to R₉ are each independently a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms.

2. The light-emitting element of claim 1, wherein
the emission layer further comprises at least one of a second compound represented by Formula HT-1, or a third compound represented by Formula ET-1: 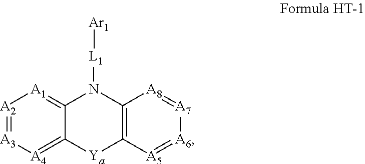
wherein, in Formula HT-1,
A₁ to A₈ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Ar₁ is a substituted or unsubstituted aryl group having 6 to 30 ring-forming carbon atoms or a substituted or unsubstituted heteroaryl group having 2 to 30 ring-forming carbon atoms,
R₅₁ to R₅₅ are each independently, a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or are bonded to an adjacent group to form a ring: 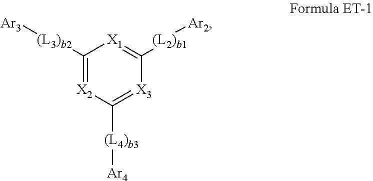
wherein, in Formula ET-1,
at least one among X₁ to X₃ is N, and remaining ones among X₁ to X₃ are CR₅₆,
R₅₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer of 0 to 10,
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L4 are each independently a direct linkage, a substituted or unsubstituted arylene group having 6 to 30 ring-forming carbon atoms, or a substituted or unsubstituted heteroarylene group having 2 to 30 ring-forming carbon atoms.

3. The light-emitting element of claim 2, wherein
the emission layer further comprises a fourth compound represented by Formula D-1: 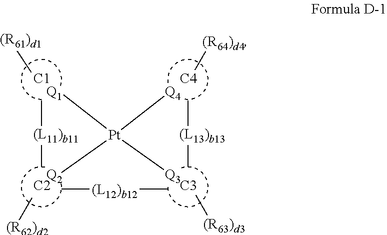
and
wherein, in Formula D-1,
Q₁ to Q₄ are each independently C or N,
C₁ to C₄ are each independently a substituted or unsubstituted hydrocarbon ring having 5 to 30 ring-forming carbon atoms, or a substituted or unsubstituted hetero ring having 2 to 30 ring-forming carbon atoms,
L₁₁ to L₁₃ are each independently a direct linkage, 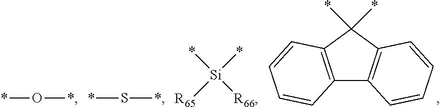
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer of 0 to 4.

4. The light-emitting element of claim 3, wherein
the emission layer comprises the first compound, the second compound, the third compound, and the fourth compound.

5. The light-emitting element of claim 1, wherein
the emission layer is to emit delayed fluorescence.

6. The light-emitting element of claim 1, wherein
the emission layer is to emit blue light.

7. The light-emitting element of claim 1, wherein
Formula 1 is represented by at least one among Formulae 1-1 to 1-4: 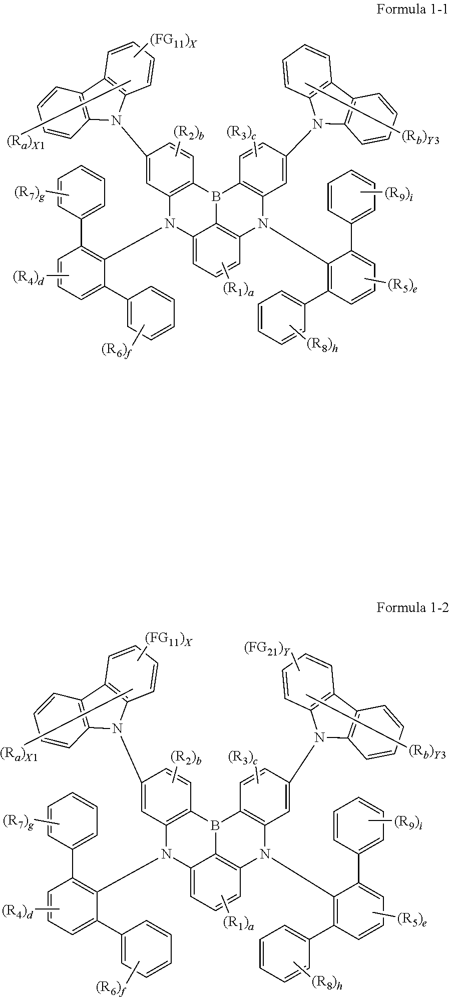 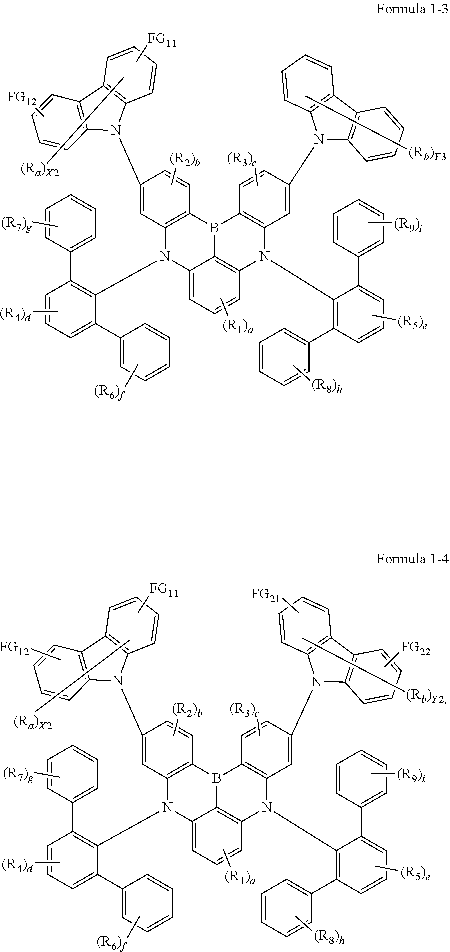
and
wherein, in Formulae 1-1 to 1-4,
FG₁₁, FG₁₂, FG₂₁ and FG₂₂ are each independently a substituted or unsubstituted aryl group having 6 to group having 6 to 60 ring-forming carbon atoms or a substituted or unsubstituted heteroaryl group having 2 to 60 ring-forming carbon atoms,
X and Y are each 1 or 2,
X1 is an integer of 1 to (8-X), Y1 is an integer of 1 to (8-Y),
X2 and Y2 are each independently an integer of 1 to 6,
X3 and Y3 are each independently an integer of 1 to 8,
Rₐ and R_{b} are each independently a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, or a substituted or unsubstituted alkenyl group having 2 to 60 carbon atoms, and
a to i, and R₁ to R₉ are the same as defined in Formula 1.

8. The light-emitting element of claim 7, wherein
in Formulae 1-1 to 1-4,
FG₁₁, FG₁₂, FG₂₁, and FG₂₂ are each independently a substituted or unsubstituted phenyl group, a substituted or unsubstituted biphenyl group, a substituted or unsubstituted terphenyl group, a substituted or unsubstituted naphthyl group, a substituted or unsubstituted phenanthrene group, a substituted or unsubstituted pyrene group, or a substituted or unsubstituted dibenzoheterol group, containing N, O, and/or S as a ring-forming atom.

9. The light-emitting element of claim 1, wherein
Formula 1 is represented by Formula 2: 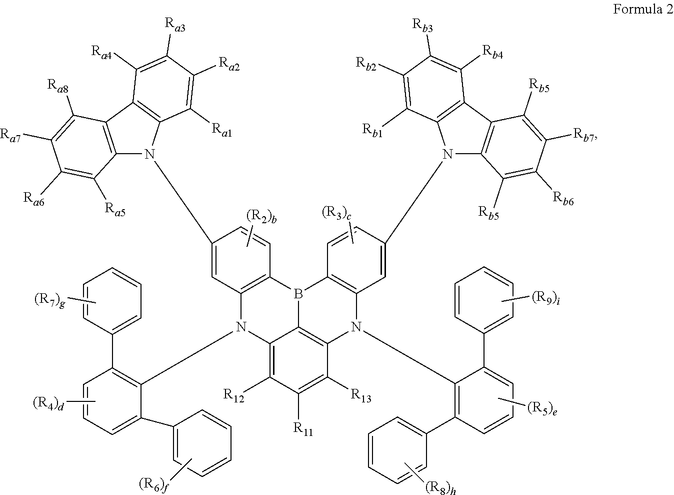
wherein, in Formula 2,
R₁₁ is a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, a substituted or unsubstituted alkenyl group having 2 to 60 carbon atoms, a substituted or unsubstituted aryl group having 6 to group having 6 to 60 ring-forming carbon atoms, or a substituted or unsubstituted heteroaryl group having 2 to 60 ring-forming carbon atoms,
R₁₂ and R₁₃ are each independently a hydrogen atom or a deuterium atom, and
Rₐ₁ to Rₐ₈, R_{b1} to R_{b8}, b to i, and R₂ to R₉ are the same as defined in Formula 1.

10. The light-emitting element of claim 1, wherein,
in Formula 1, at least one selected from among Rₐ₁ to Rₐ₈ and R_{b1} to R_{b8} is a substituted or unsubstituted aryl group having 6 to group having 6 to 60 ring-forming carbon atoms or a substituted or unsubstituted heteroaryl group having 2 to 60 ring-forming carbon atoms, and
remaining ones selected from among Rₐ₁ to Rₐ₈ and R_{b1} to R_{b8} are each independently a hydrogen atom or a deuterium atom.

11. The light-emitting element of claim 1, wherein,
in Formula 1, at least one selected from among Rₐ₁ to Rₐ₈ and R_{b1} to R_{b8} is represented by at least one of FG-a to FG-h: 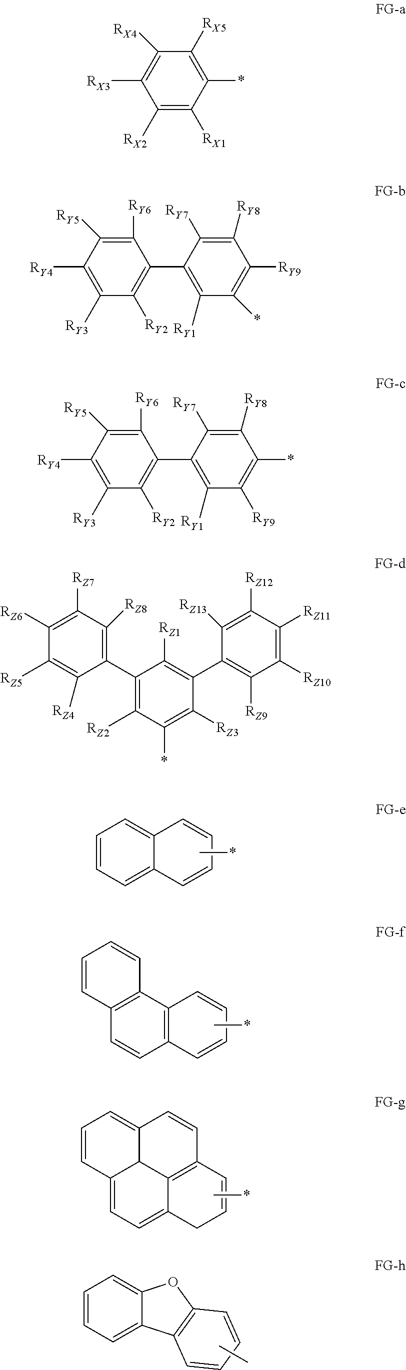
and
wherein, in FG-a to FG-d, R_{X1} to R_{X5}, R_{Y1} to R_{Y9}, and R_{Z1} to R_{Z13} are each independently a hydrogen atom, a deuterium atom, a cyano group, or a t-butyl group, and
in FG-h, Q is O, S, NH, or NPh, and Ph is a phenyl group.

12. The light-emitting element of claim 1, wherein
the first compound is represented by any one of compounds in Compound Group 1: 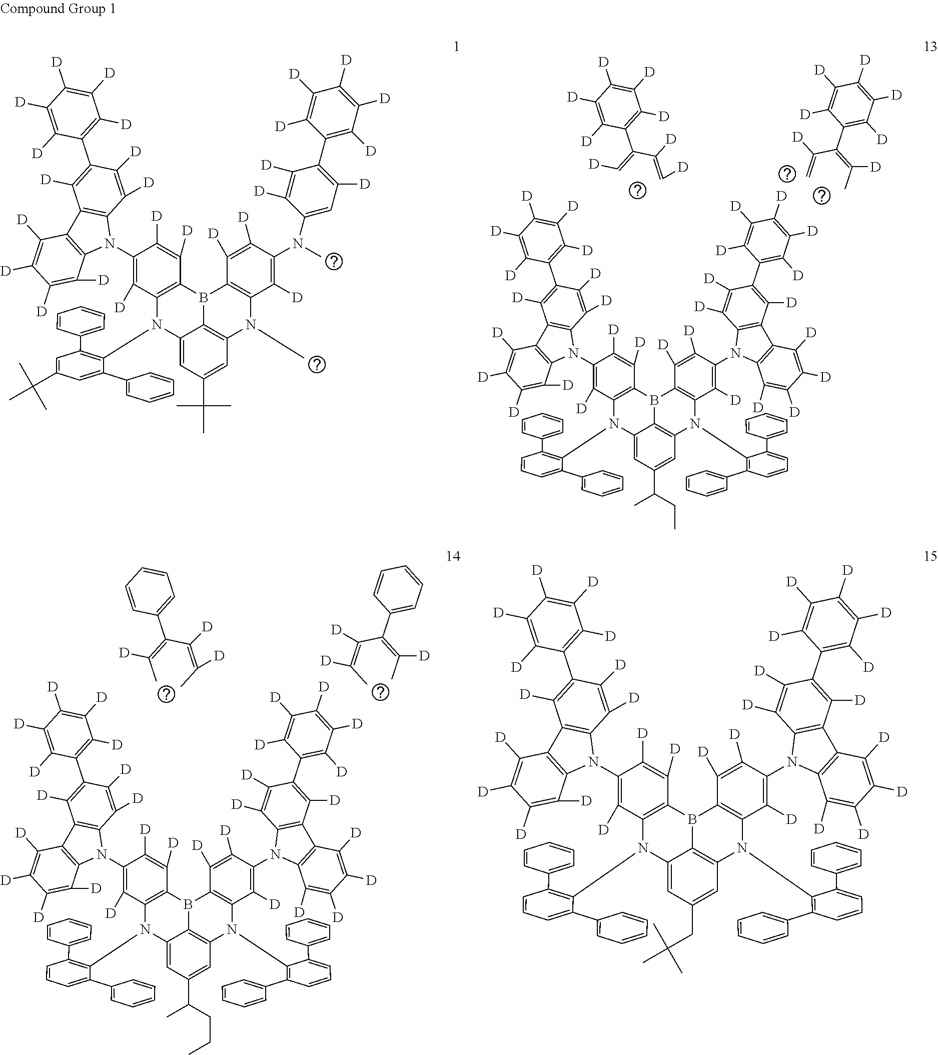 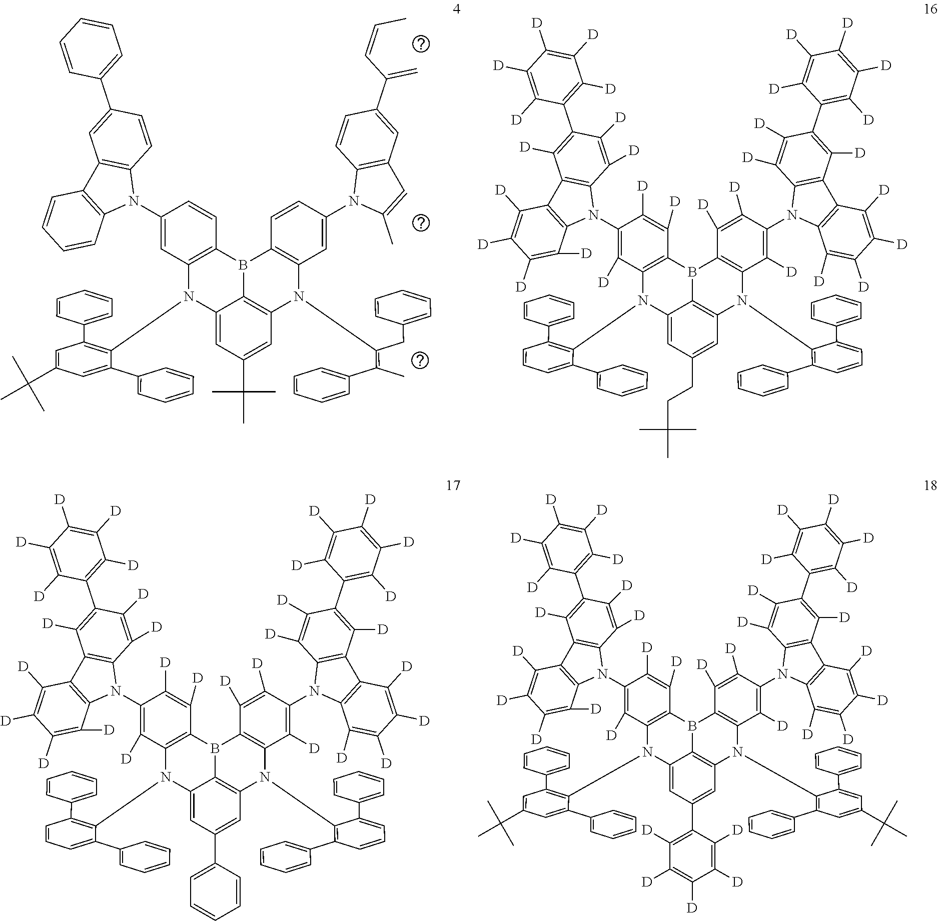 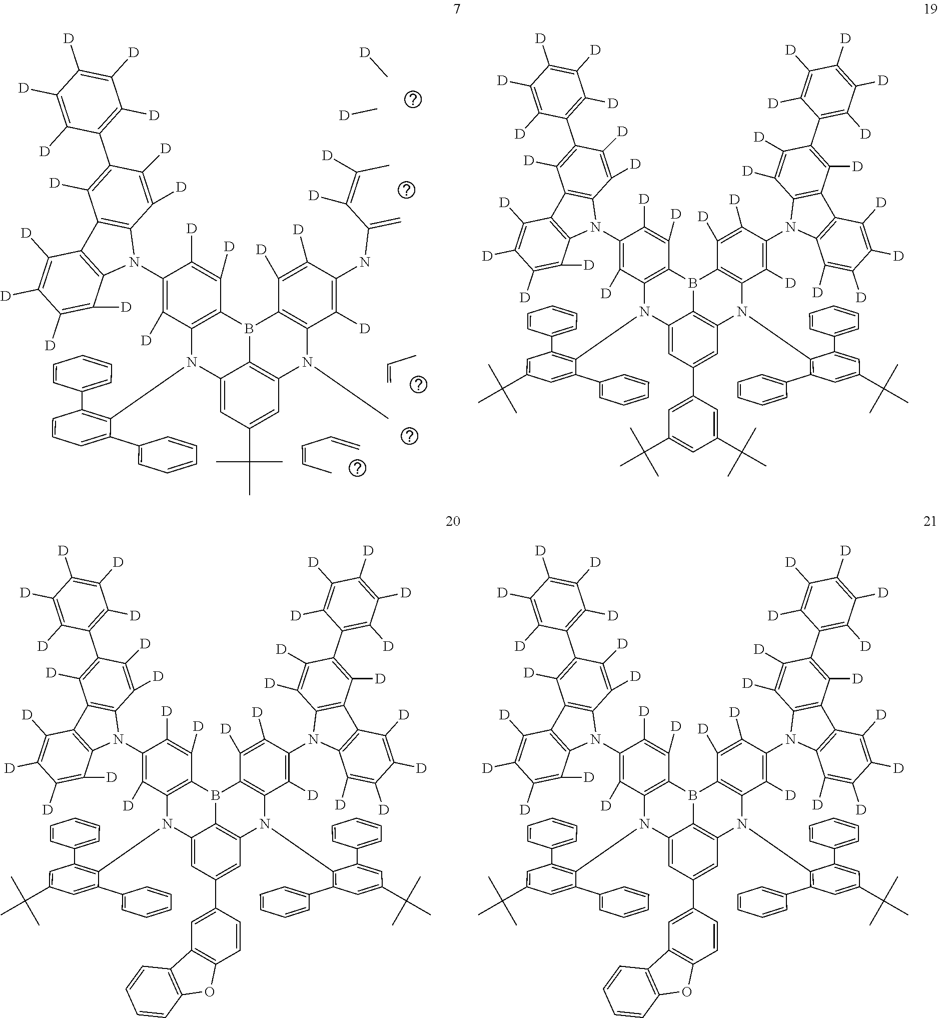 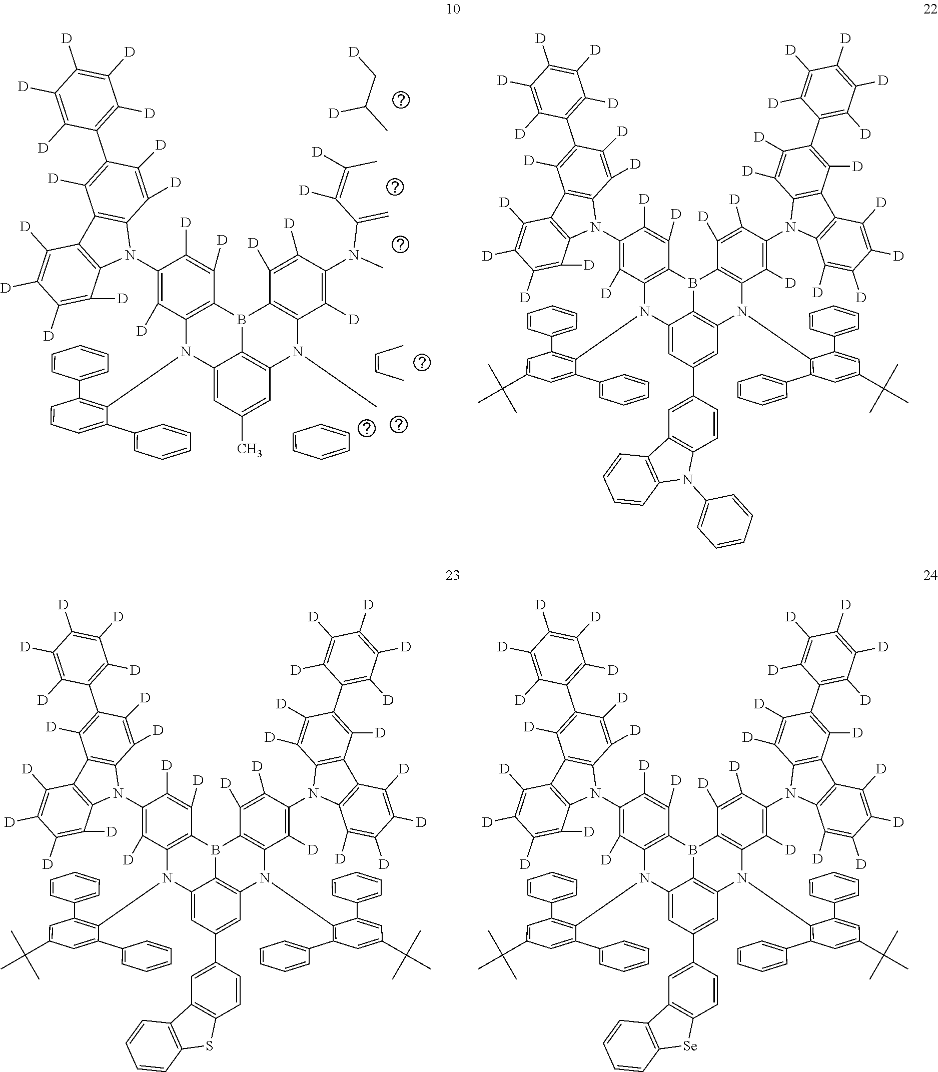 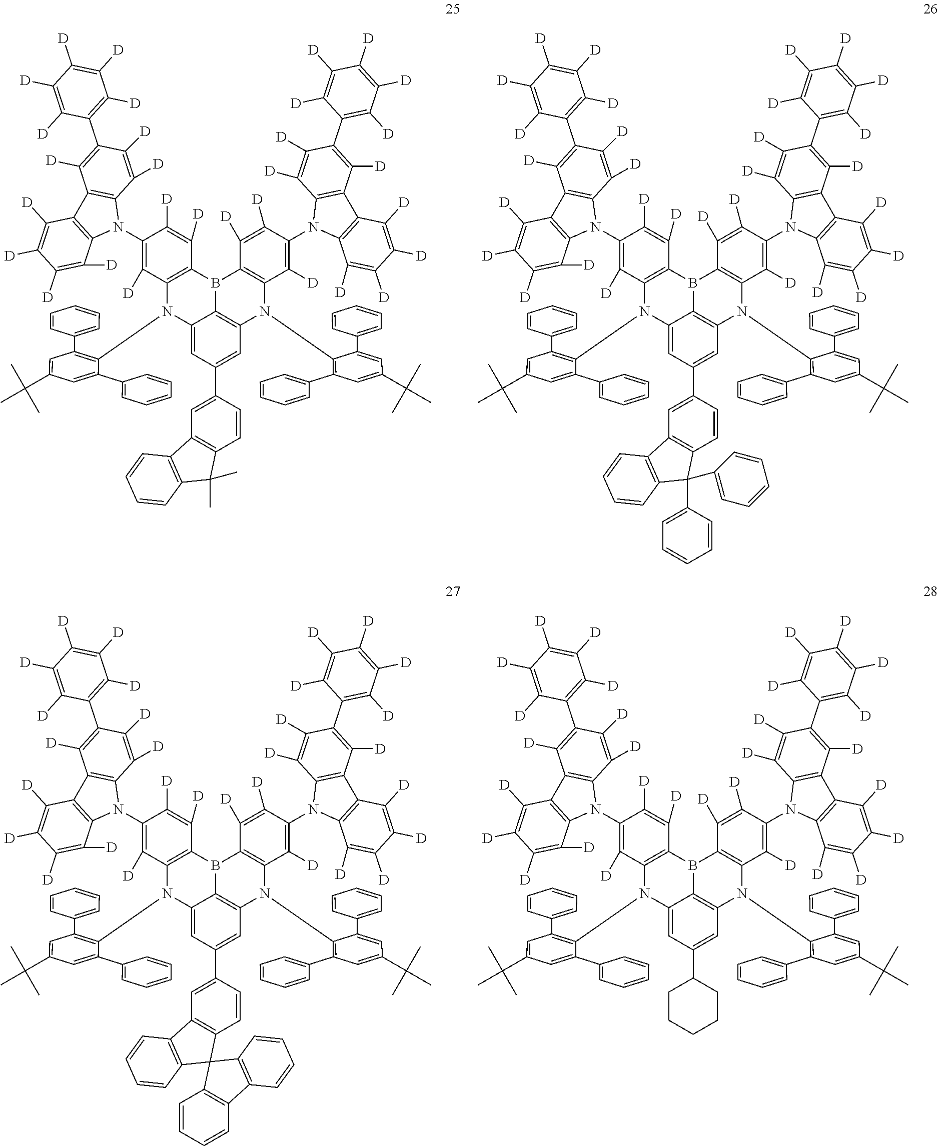 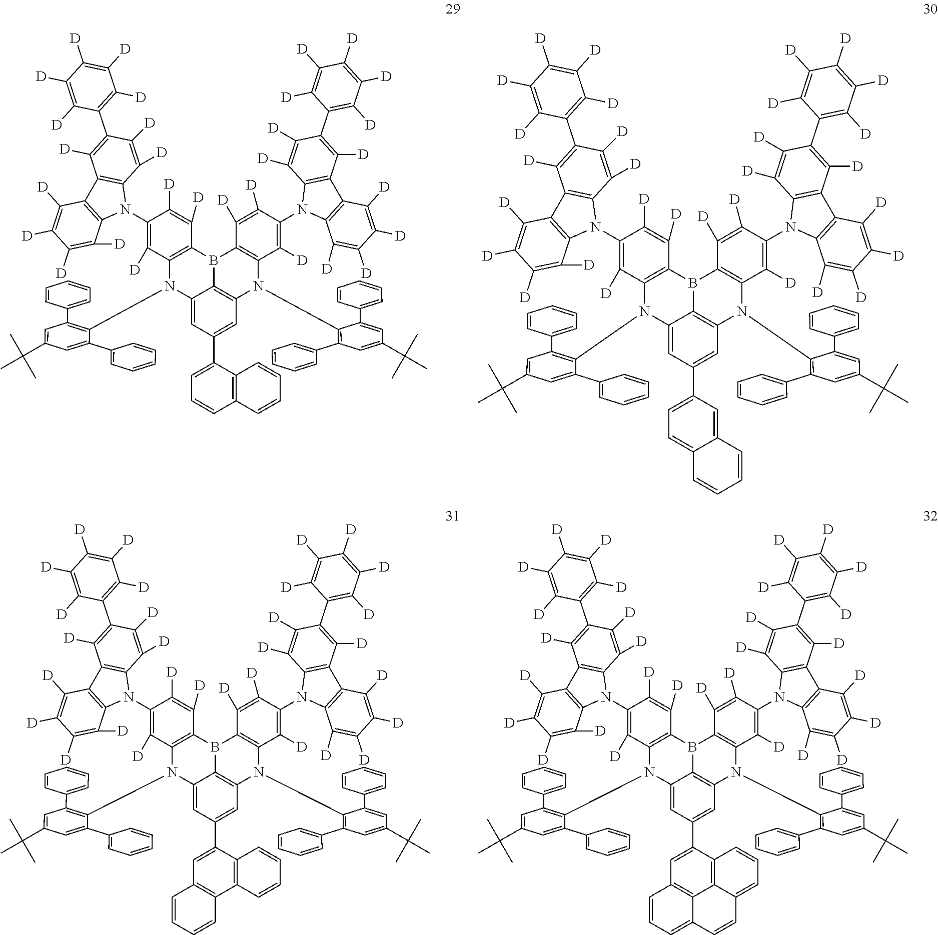 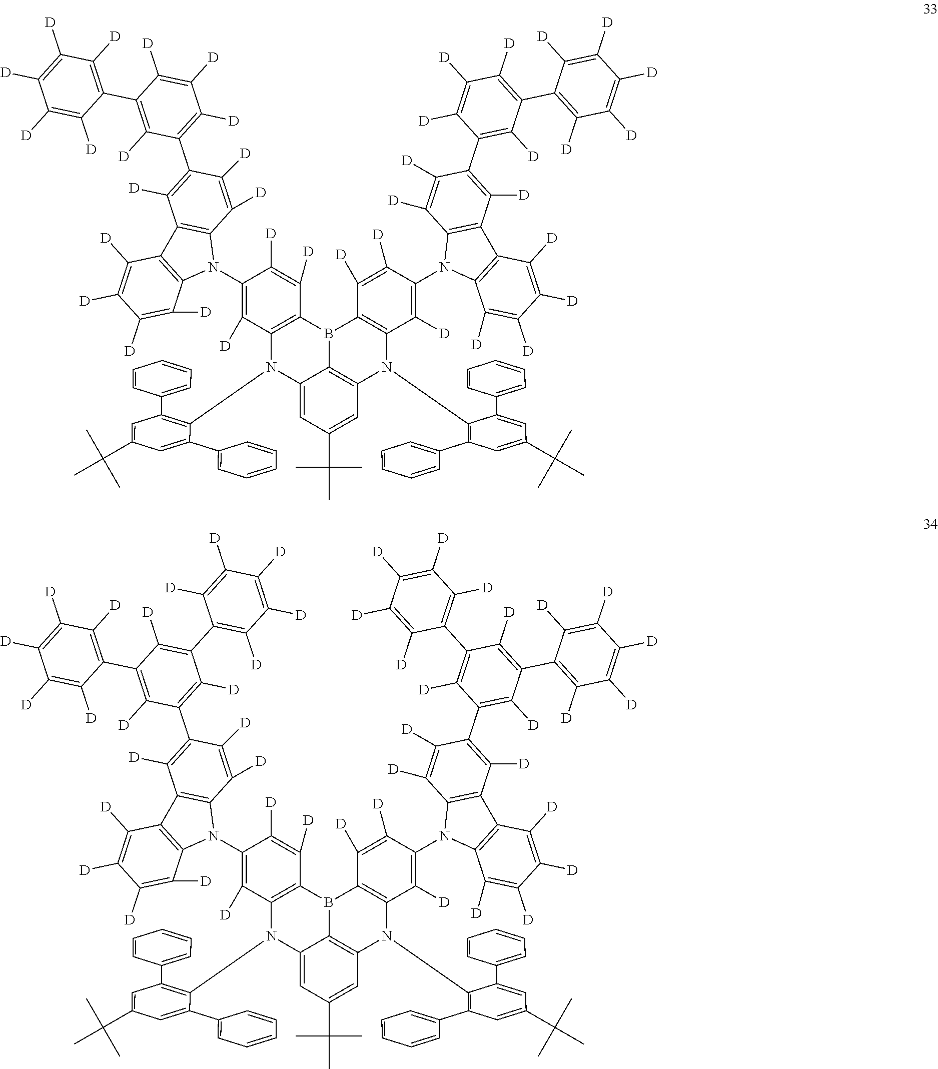 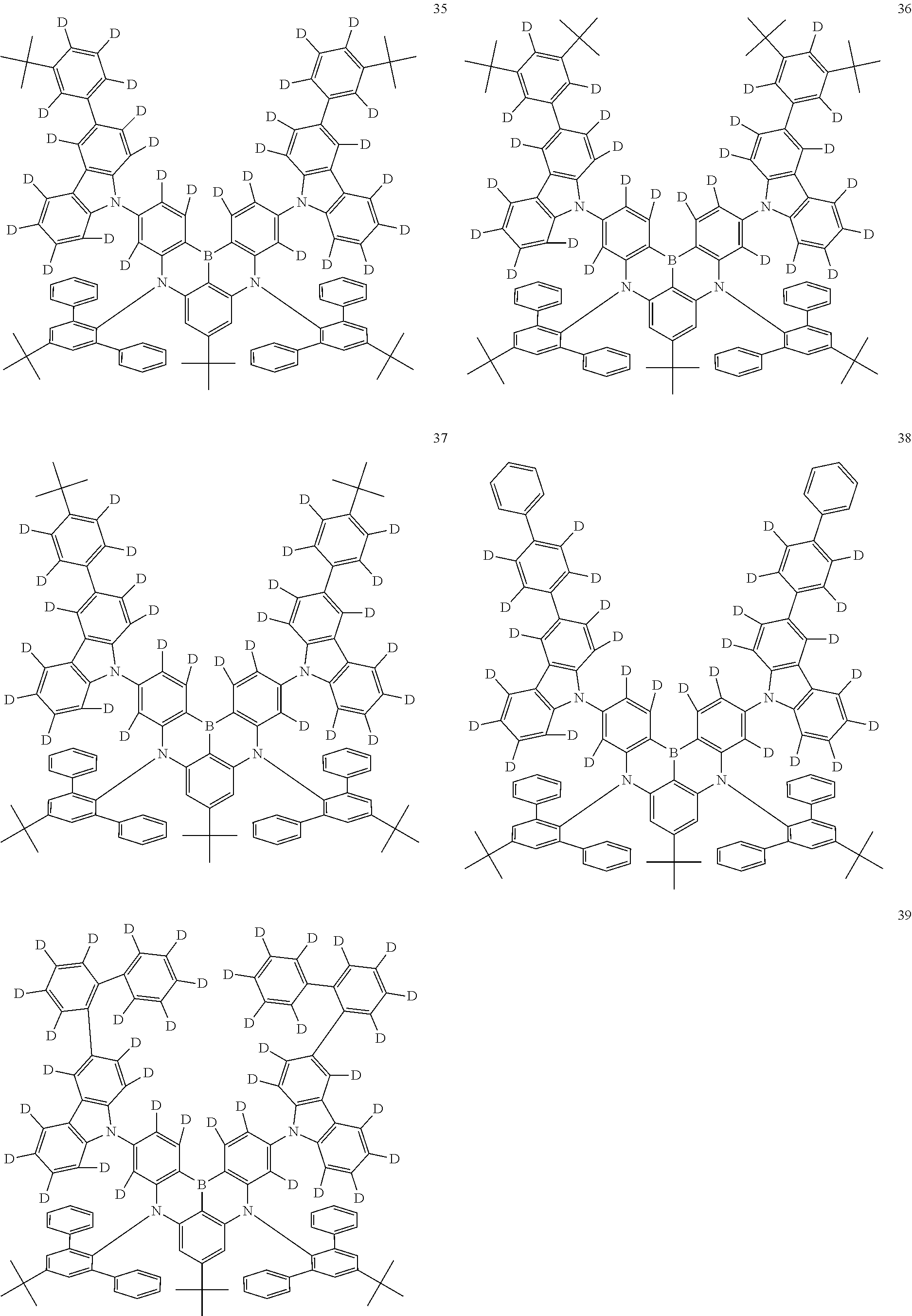 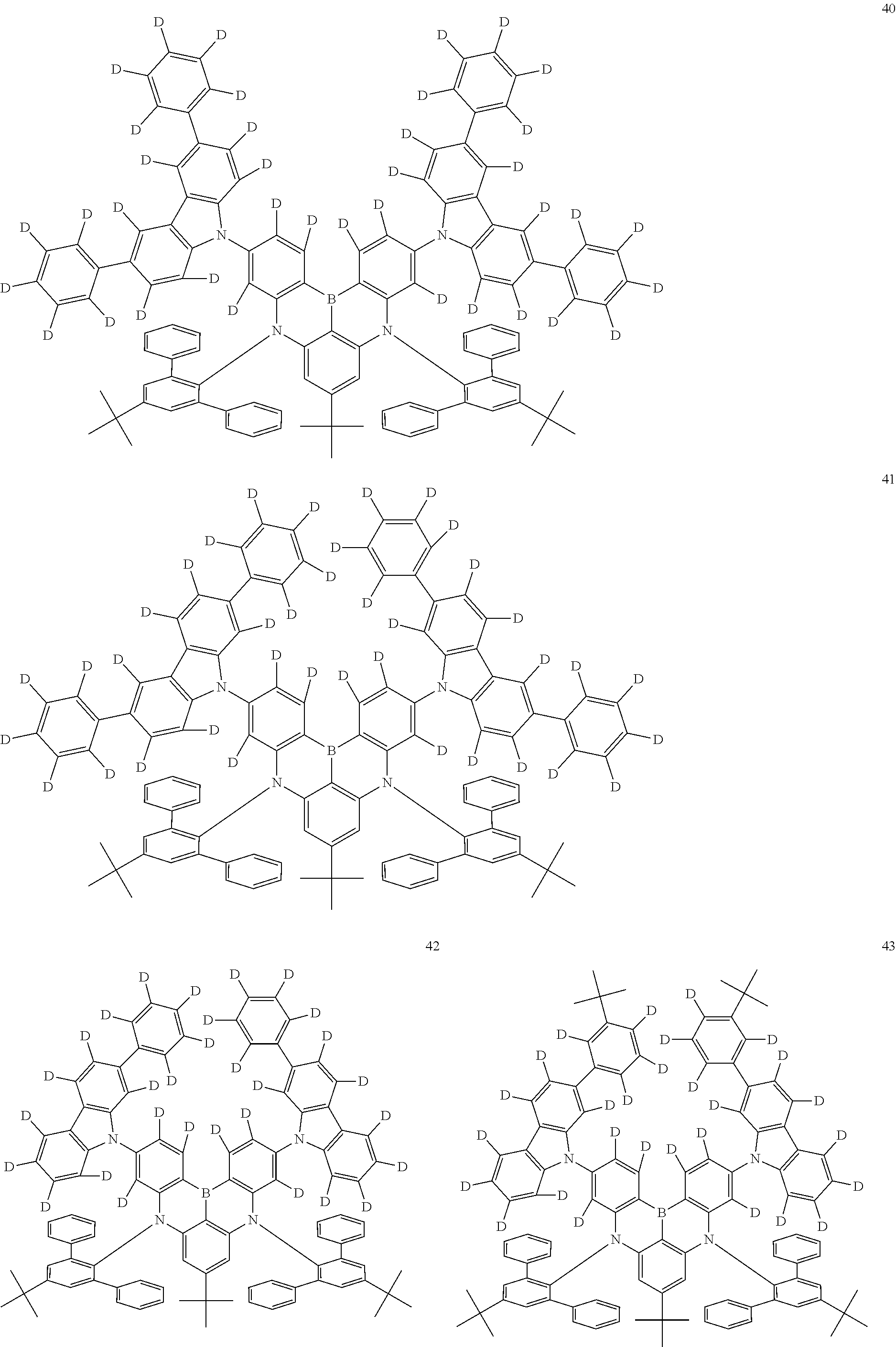 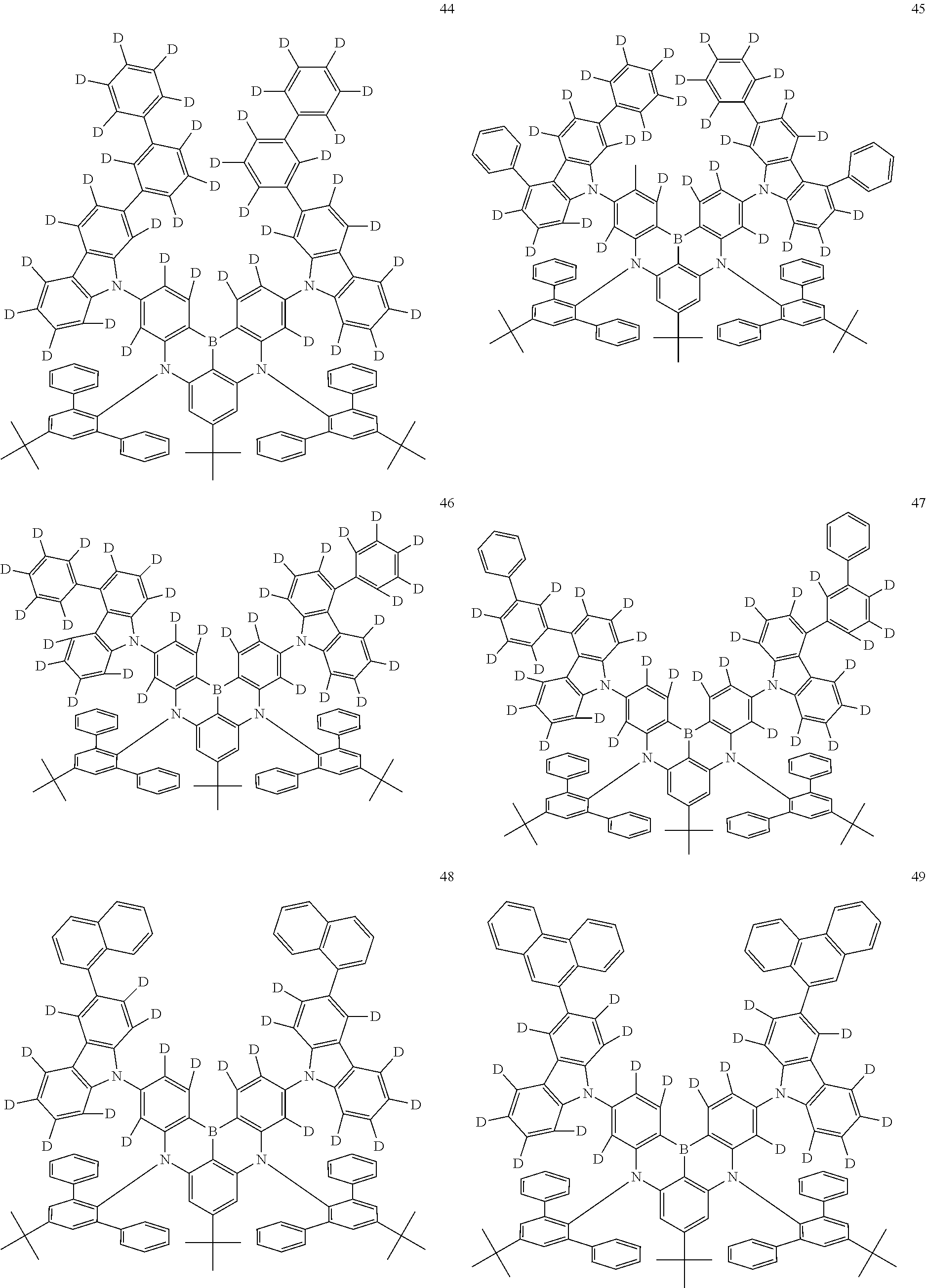 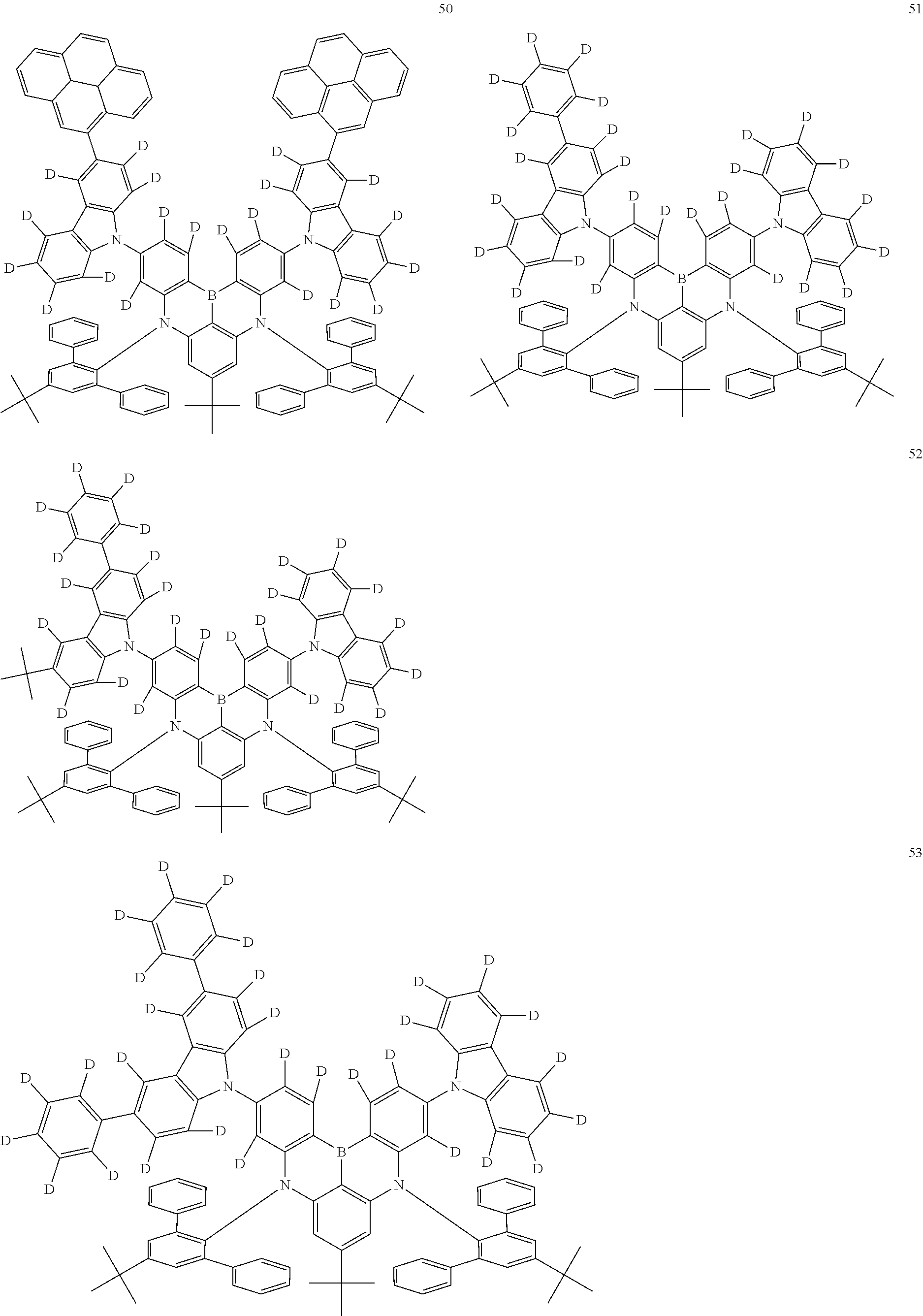 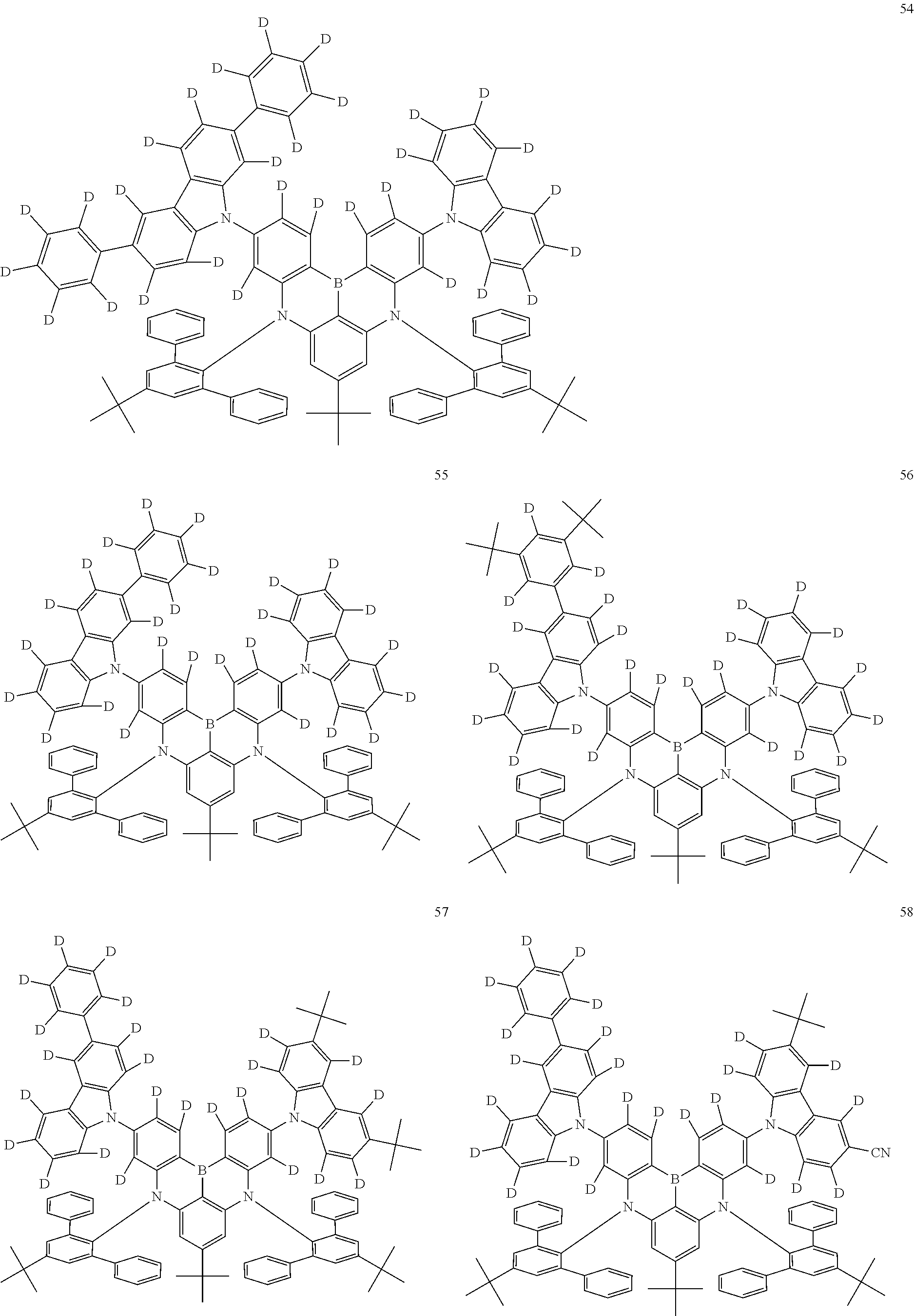 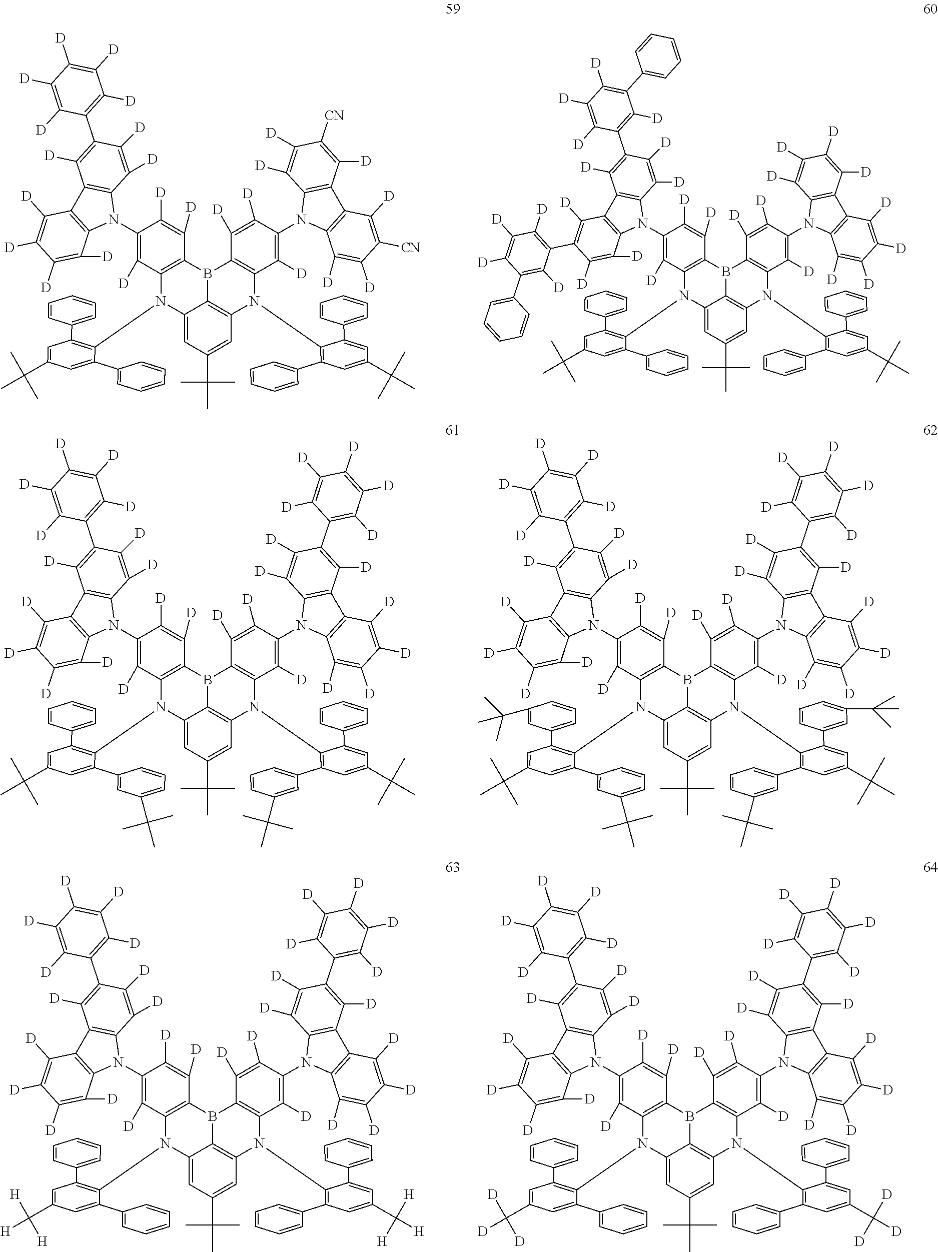 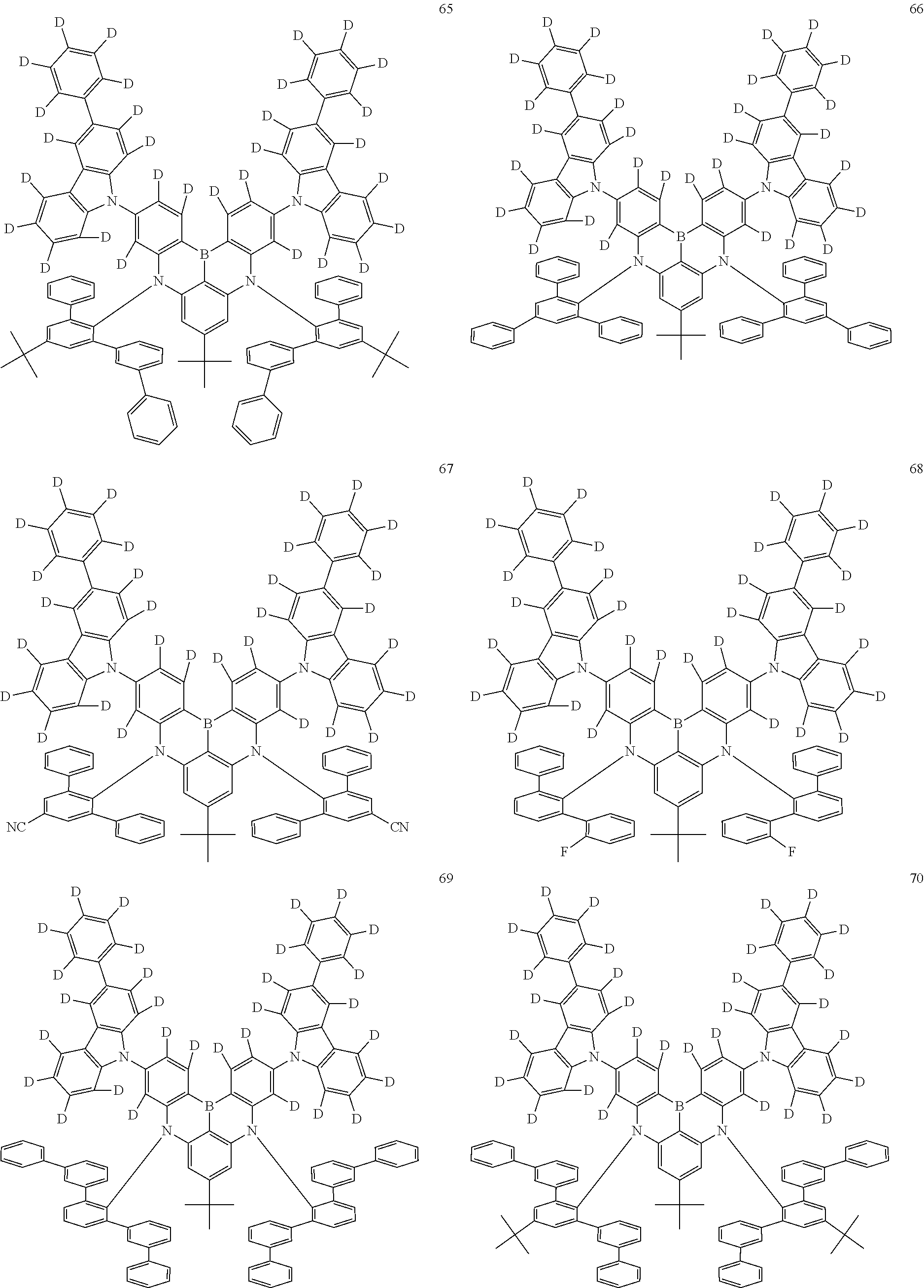 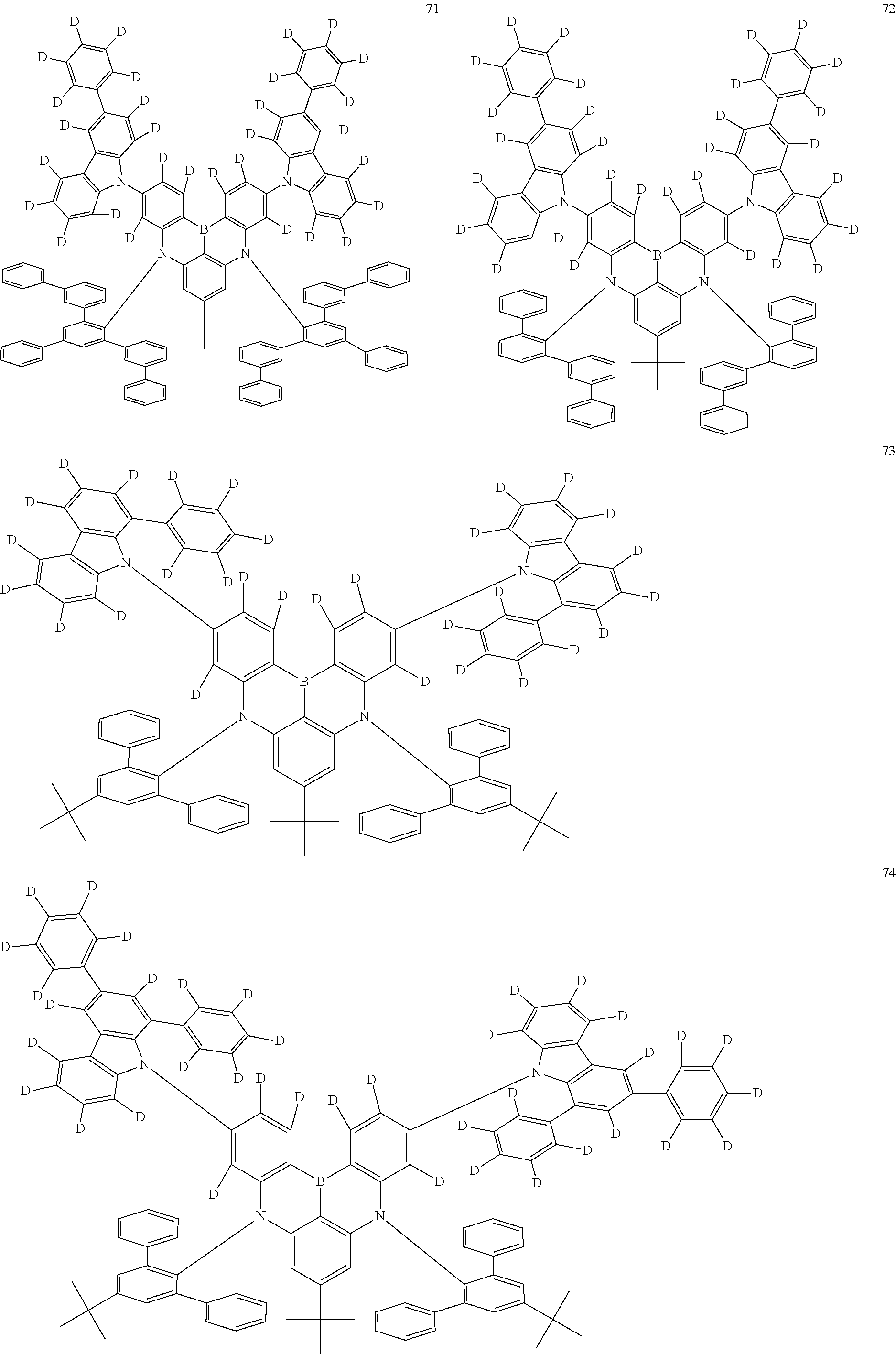 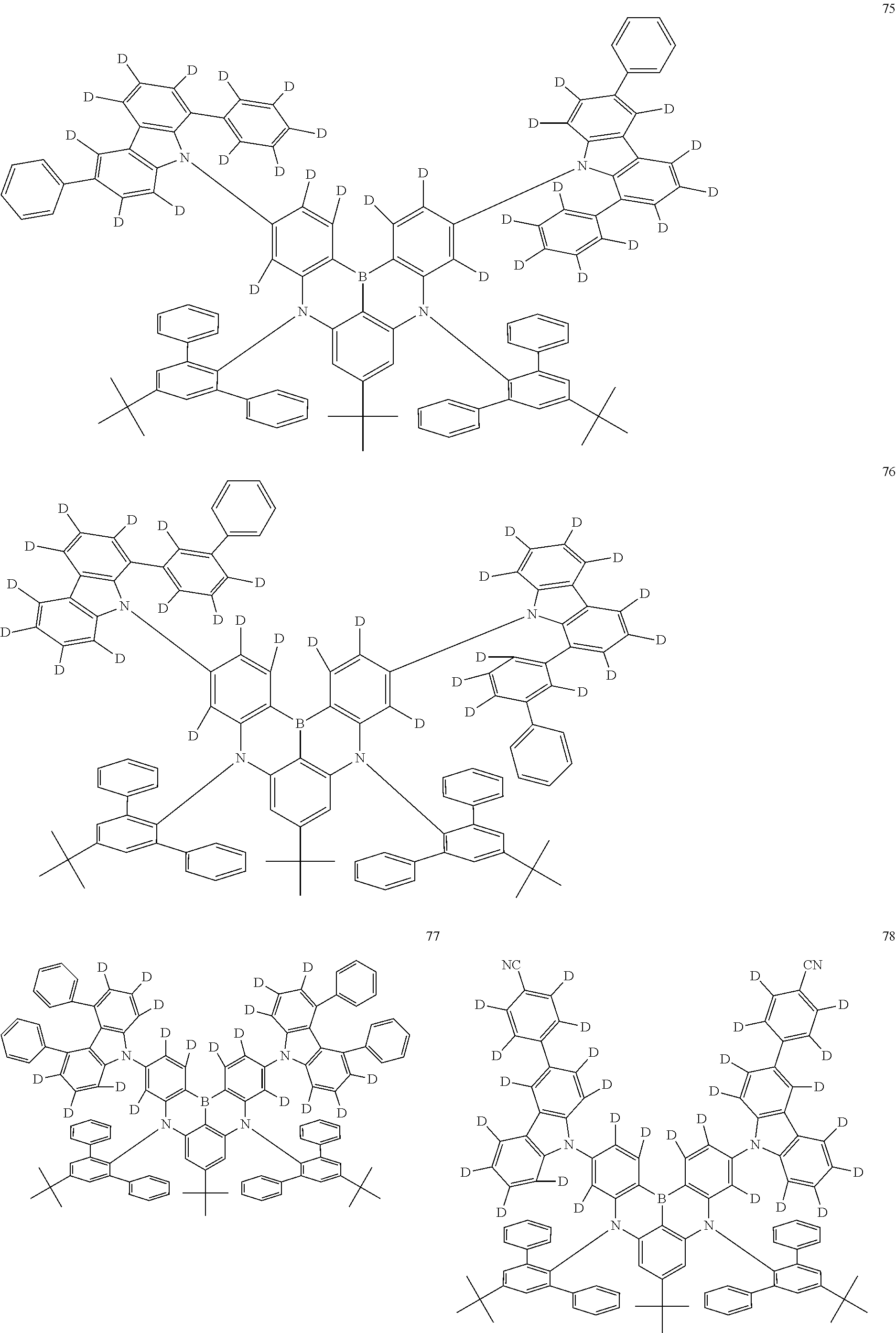 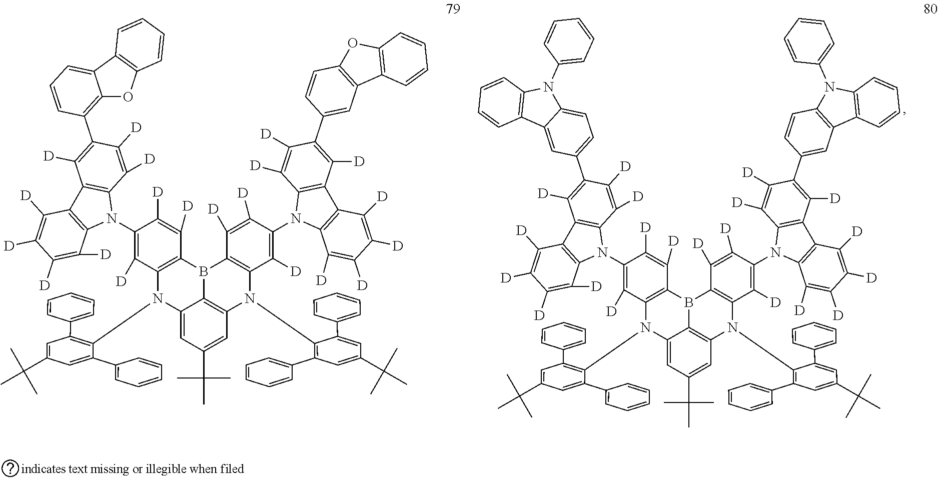
and
where in Compound Group 1, D is a deuterium atom.

13. A polycyclic compound represented by Formula 1: 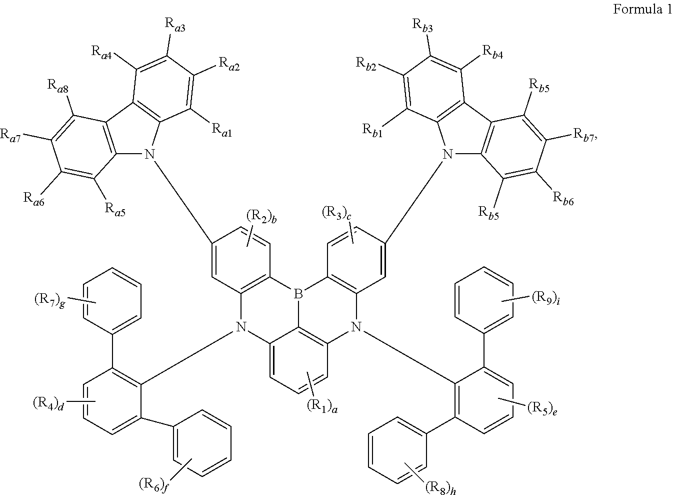
wherein in Formula 1,
at least one selected from among Rₐ₁ to Rₐ₈ and R_{b1} to R_{b8} is a substituted or unsubstituted aryl group having 6 to group having 6 to 60 ring-forming carbon atoms or a substituted or unsubstituted heteroaryl group having 2 to 60 ring-forming carbon atoms,
remaining ones selected from among Rₐ₁ to Rₐ₈ and R_{b1} to R_{b8} are each independently a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, or a substituted or unsubstituted alkenyl group having 2 to 60 carbon atoms,
a to e are each independently an integer of 1 to 3,
f to i are each independently an integer of 1 to 5, and
R₁ to R₉ are each independently a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, a substituted or unsubstituted alkenyl group having 2 to 60 carbon atoms, a substituted or unsubstituted aryl group having 6 to group having 6 to 60 ring-forming carbon atoms, or a substituted or unsubstituted heteroaryl group having 2 to 60 ring-forming carbon atoms.

14. The polycyclic compound of claim 13, wherein
Formula 1 is represented by any one among Formulae 1-1 to 1-4: 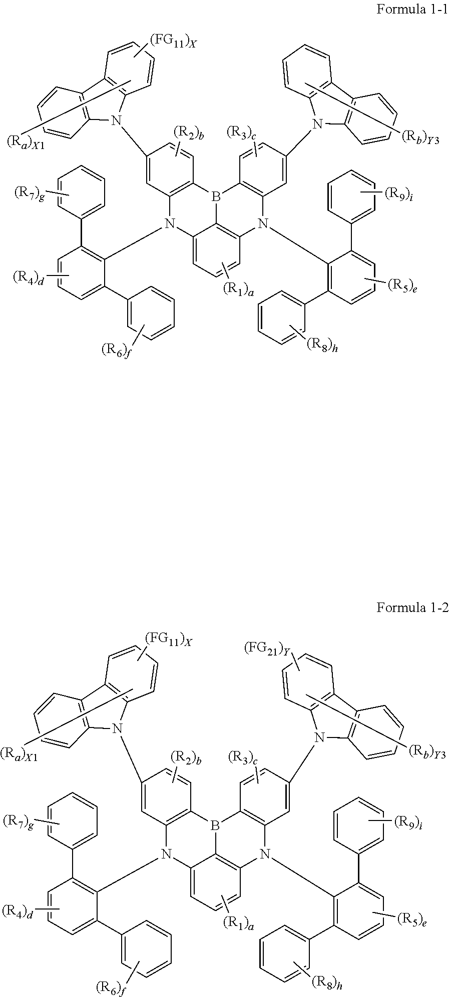 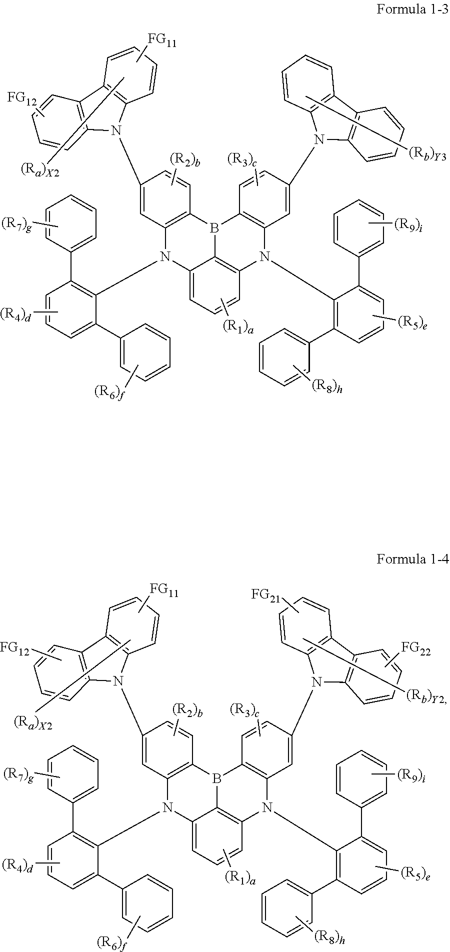
wherein, in Formulae 1-1 to 1-4,
FG₁₁, FG₁₂, FG₂₁ and FG₂₂ are each independently a substituted or unsubstituted aryl group having 6 to 60 ring-forming carbon atoms or a substituted or unsubstituted heteroaryl group having 2 to 60 ring-forming carbon atoms,
X and Y are each 1 or 2,
X1 is an integer of 1 to (8-X), Y1 is an integer of 1 to (8-Y),
X2 and Y2 are each independently an integer of 1 to 6,
X3 and Y3 are each independently an integer of 1 to 8,
Rₐ and R_{b} are each independently a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, or a substituted or unsubstituted alkenyl group having 2 to 60 carbon atoms, and
a to i, and R₁ to R₉ are the same as defined in Formula 1.

15. The polycyclic compound of claim 14, wherein,
in Formulae 1-1 to 1-4,
FG₁₁, FG₁₂, FG₂₁, and FG₂₂ are each independently a substituted or unsubstituted phenyl group, a substituted or unsubstituted biphenyl group, a substituted or unsubstituted terphenyl group, a substituted or unsubstituted naphthyl group, a substituted or unsubstituted phenanthrene group, a substituted or unsubstituted pyrene group, or a substituted or unsubstituted dibenzoheterol group, containing N, O, and/or S as a ring-forming atom.

16. The polycyclic compound of claim 13, wherein
Formula 1 is represented by Formula 2: 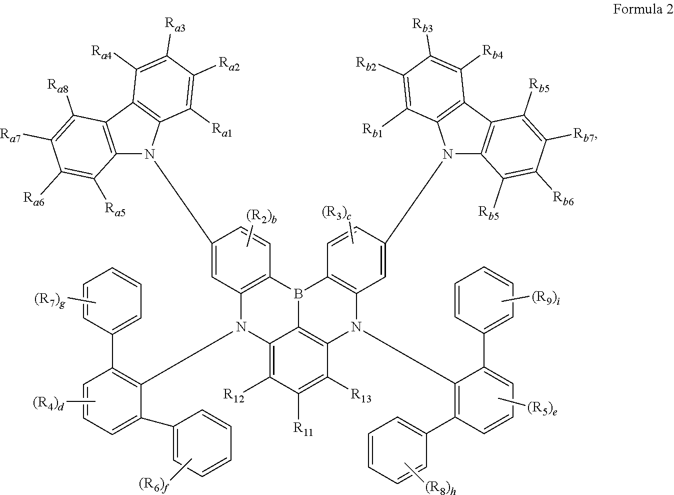
wherein, in Formula 2,
R₁₁ is a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms,
R₁₂ and R₁₃ are each independently a hydrogen atom or a deuterium atom, and
Rₐ₁ to Rₐ₈, R_{b1} to R_{b8}, b to i, and R₂ to R₉ are the same as defined in Formula 1.

17. The polycyclic compound of claim 13, wherein,
in Formula 1, at least one selected from among Rₐ₁ to Rₐ₈ and R_{b1} to R_{b8} is a substituted or unsubstituted aryl group having 6 to 60 ring-forming carbon atoms, or a substituted or unsubstituted heteroaryl group having 2 to 60 ring-forming carbon atoms, and
remaining ones selected from among Rₐ₁ to Rₐ₈ and R_{b1} to R_{b8} are each independently a hydrogen atom or a deuterium atom.

18. The polycyclic compound of claim 13, wherein,
in Formula 1, at least one selected from among Rₐ₁ to Rₐ₈ and R_{b1} to R_{b8} is represented by at least one among FG-a to FG-h: 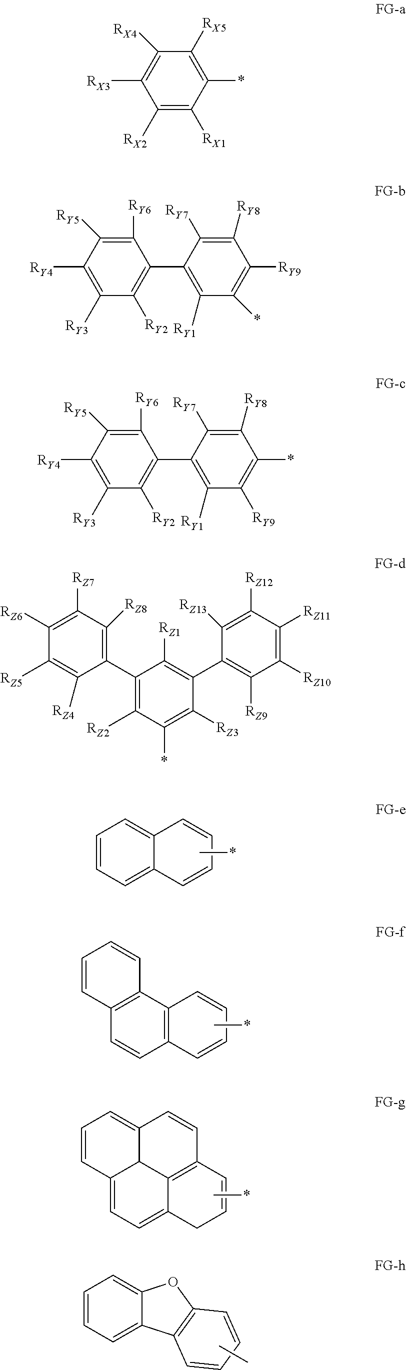
and
wherein, in FG-a to FG-d,
R_{X1} to R_{X5}, R_{Y1} to R_{Y9}, and R_{Z1} to R_{Z13} are each independently a hydrogen atom, a deuterium atom, a cyano group, or a t-butyl group, and
in FG-h, Q is O, S, NH, or NPh, and Ph is a phenyl group.

19. The polycyclic compound of claim 13, wherein,
in Formula 1, at least one hydrogen atom selected from among Rₐ₁ to Rₐ₈, R_{b1} to R_{b8}, and R₁ to R₃ is substituted with a deuterium atom.

20. The polycyclic compound of claim 13, wherein
Formula 1 is represented by any compound in Compound Group 1: 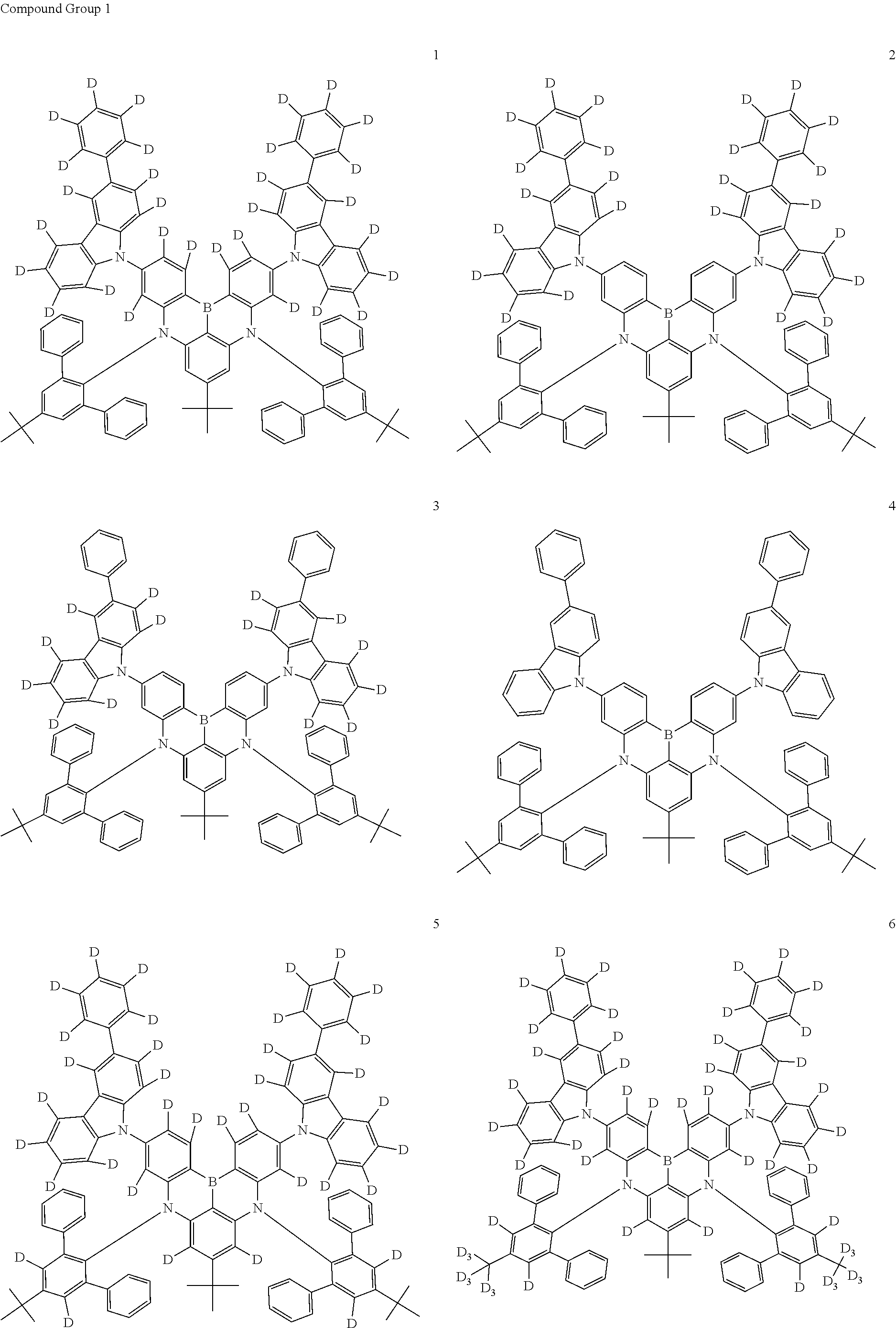 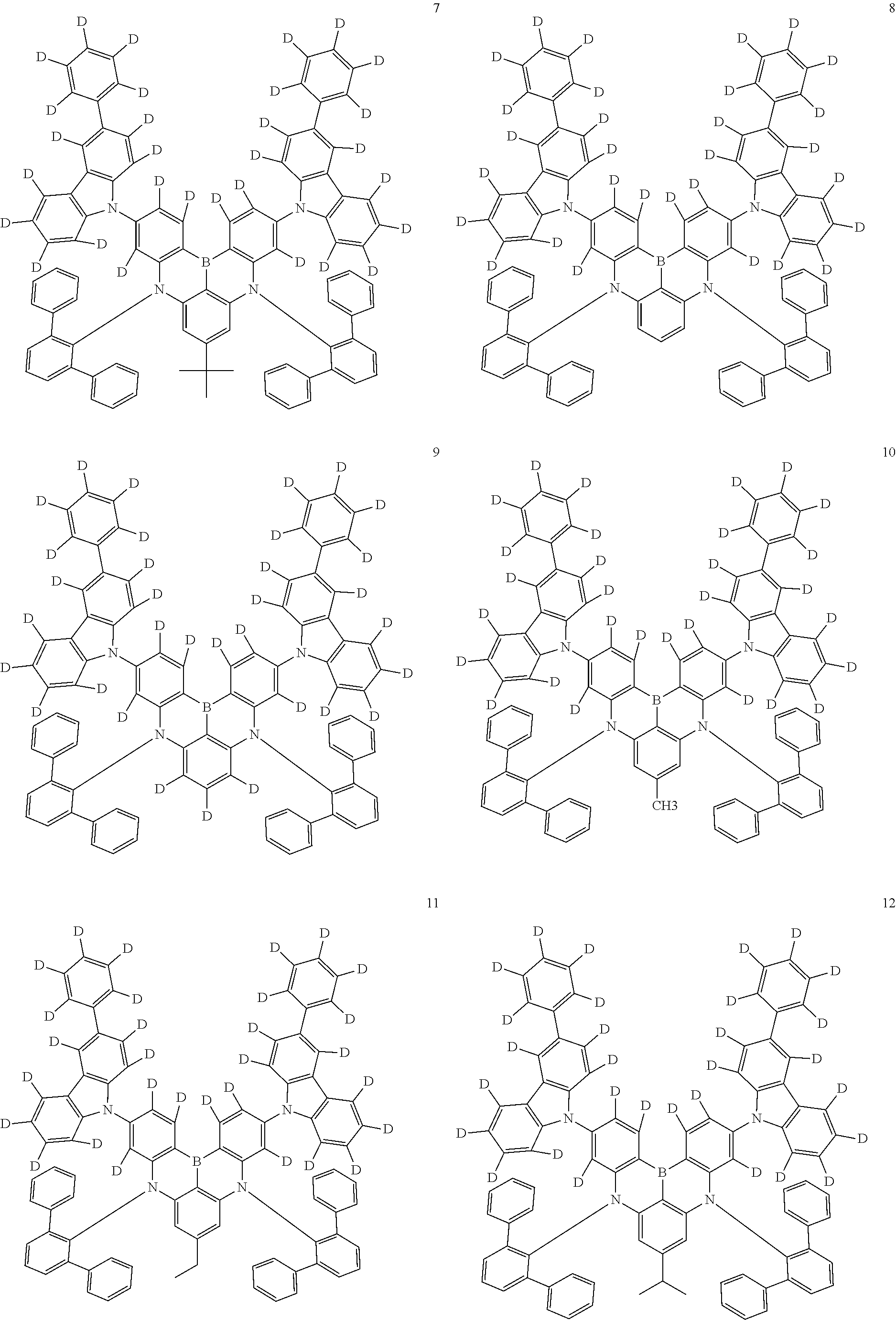 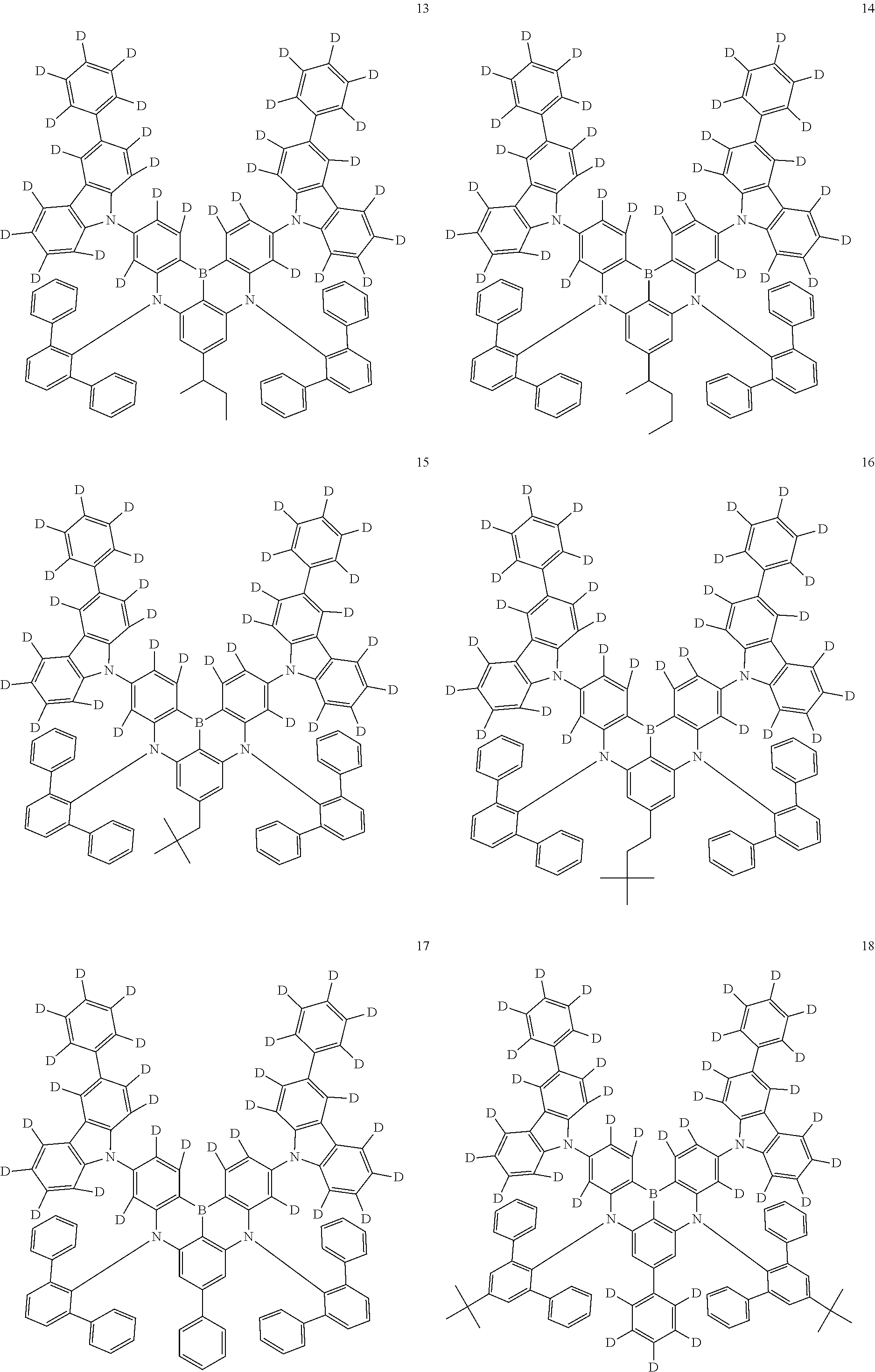 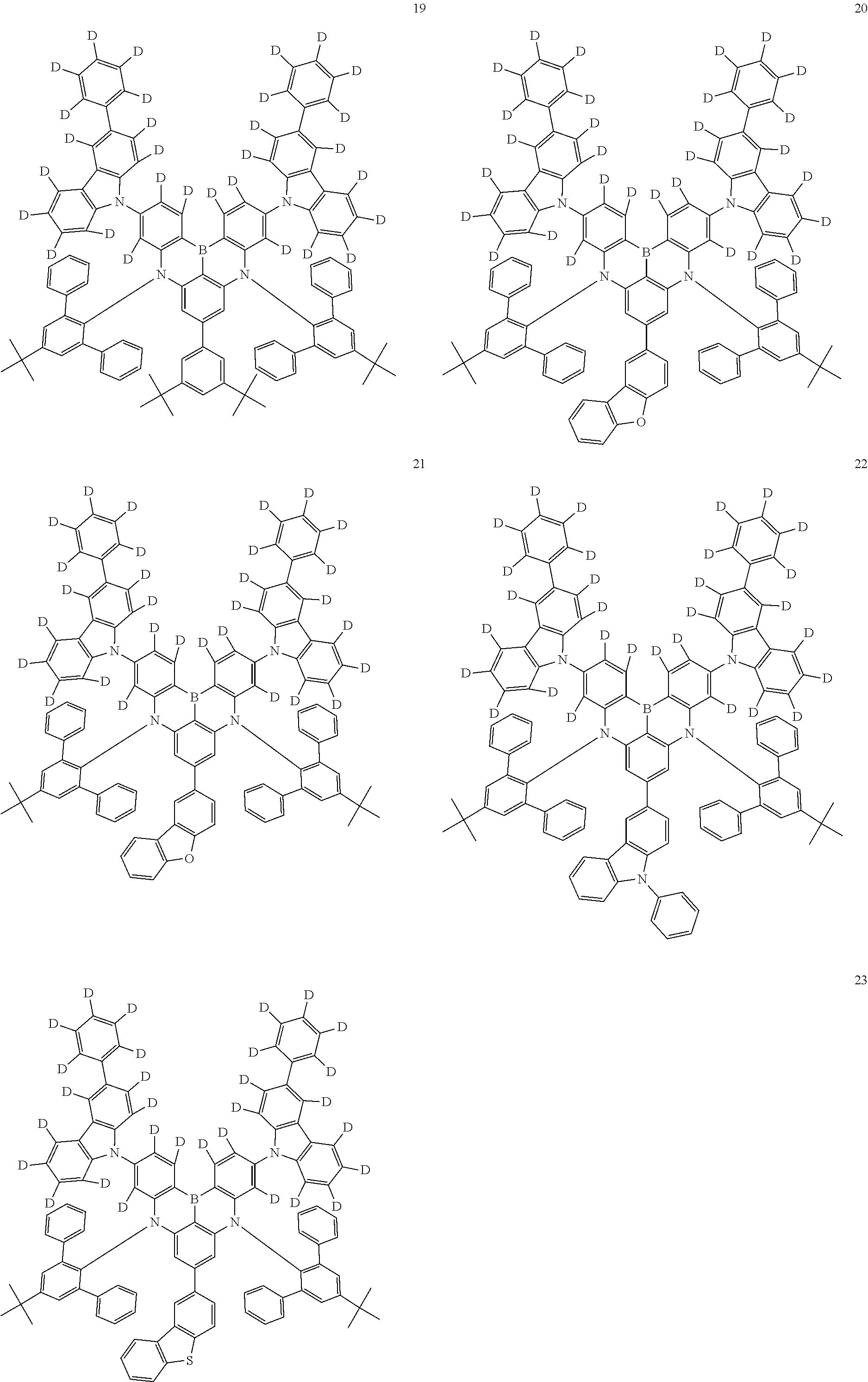 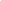 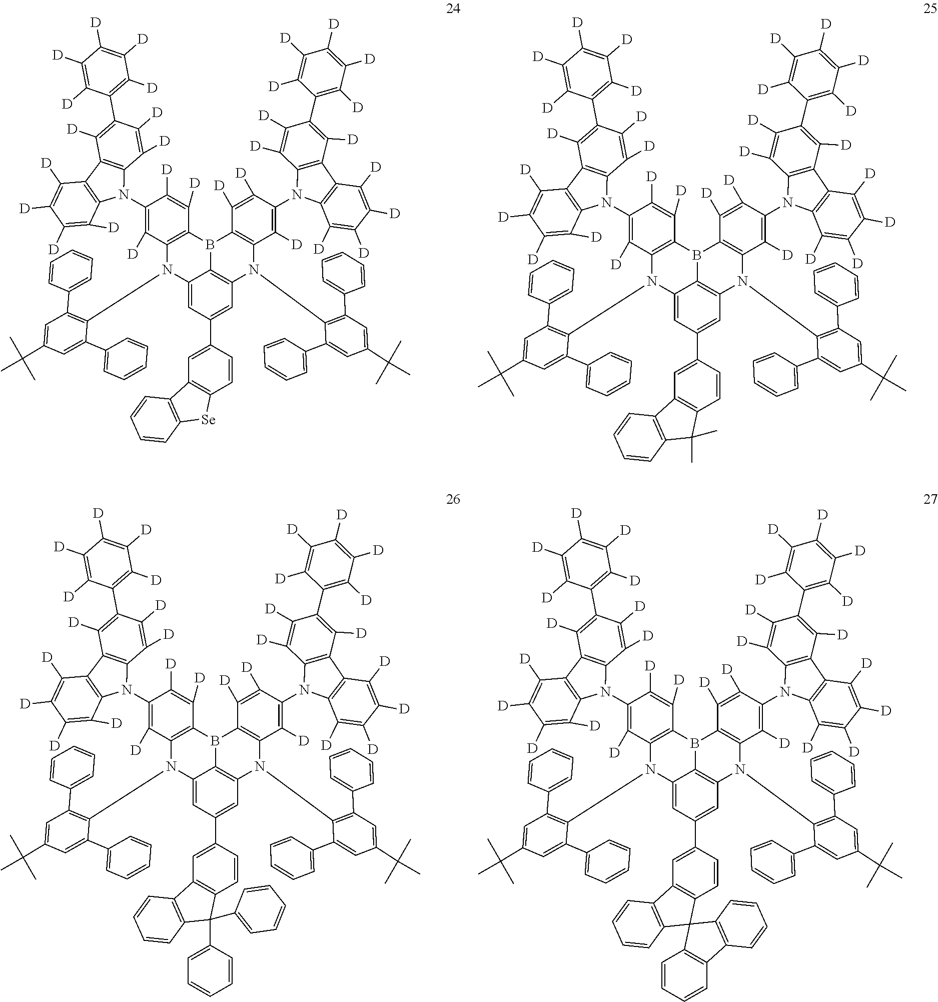 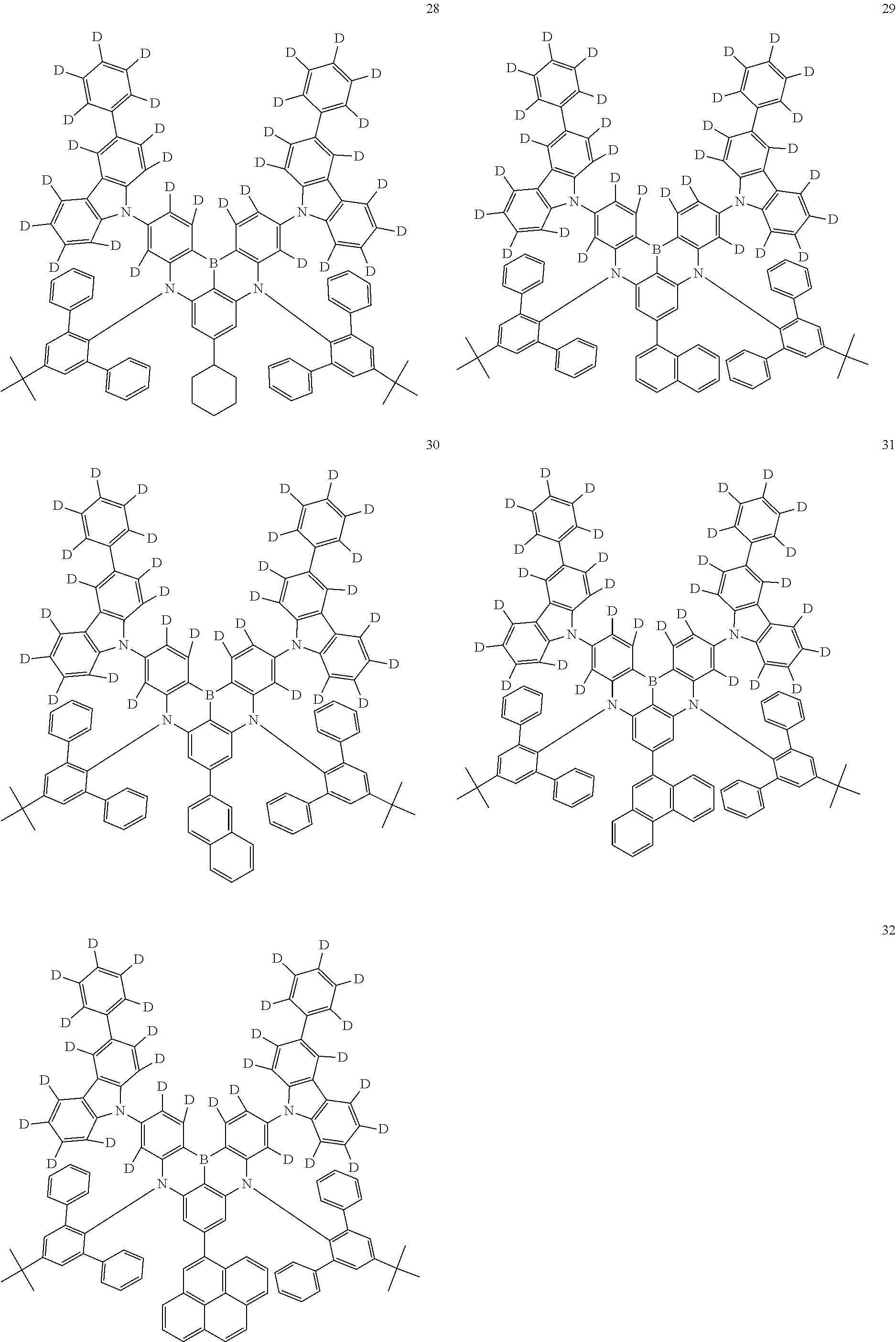 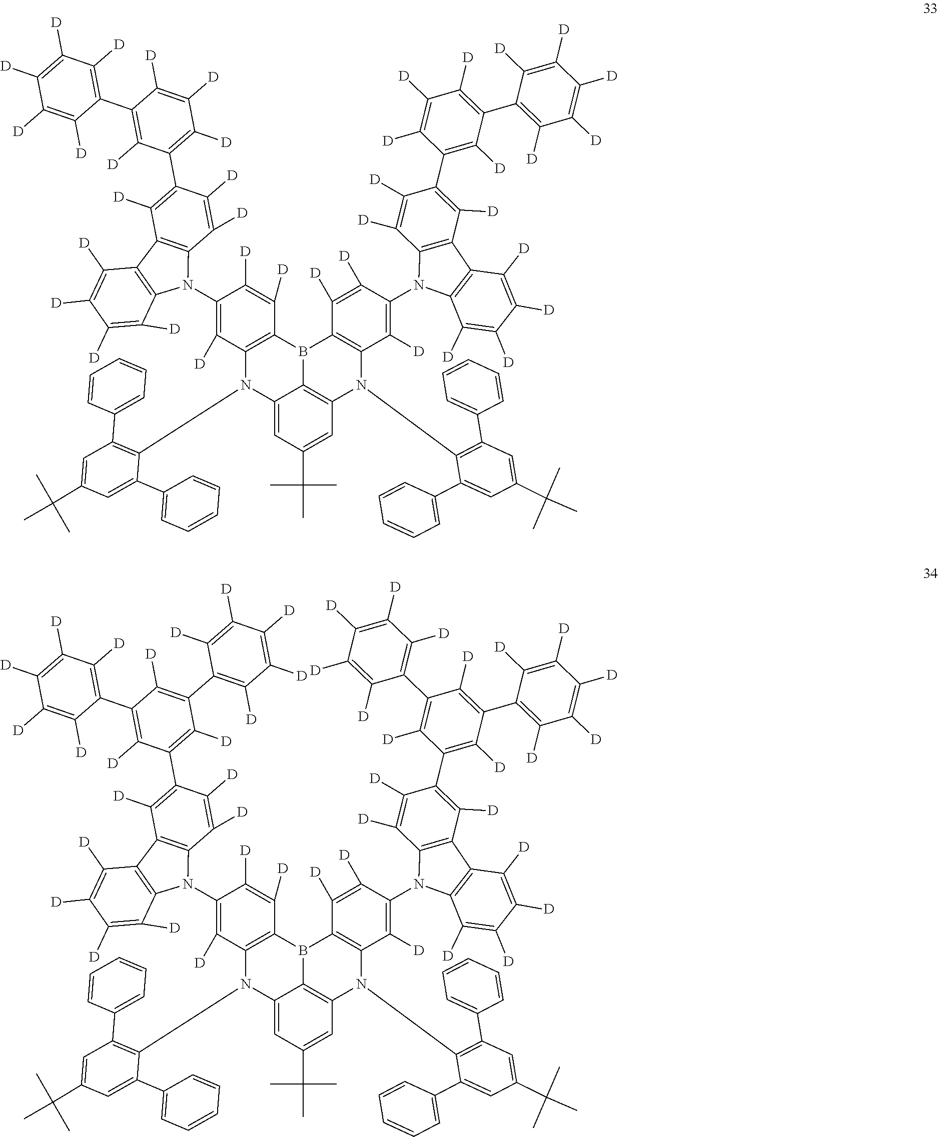 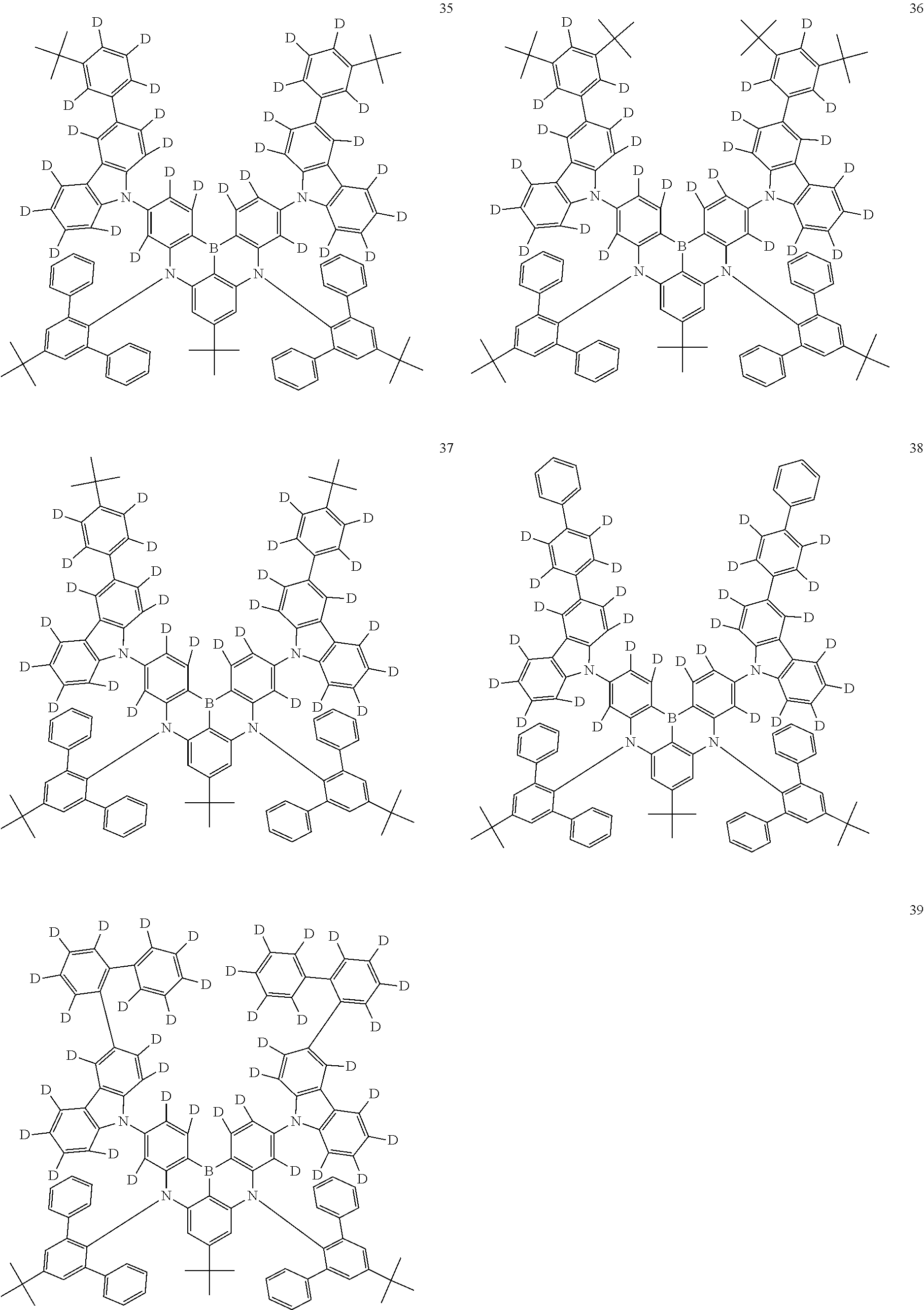 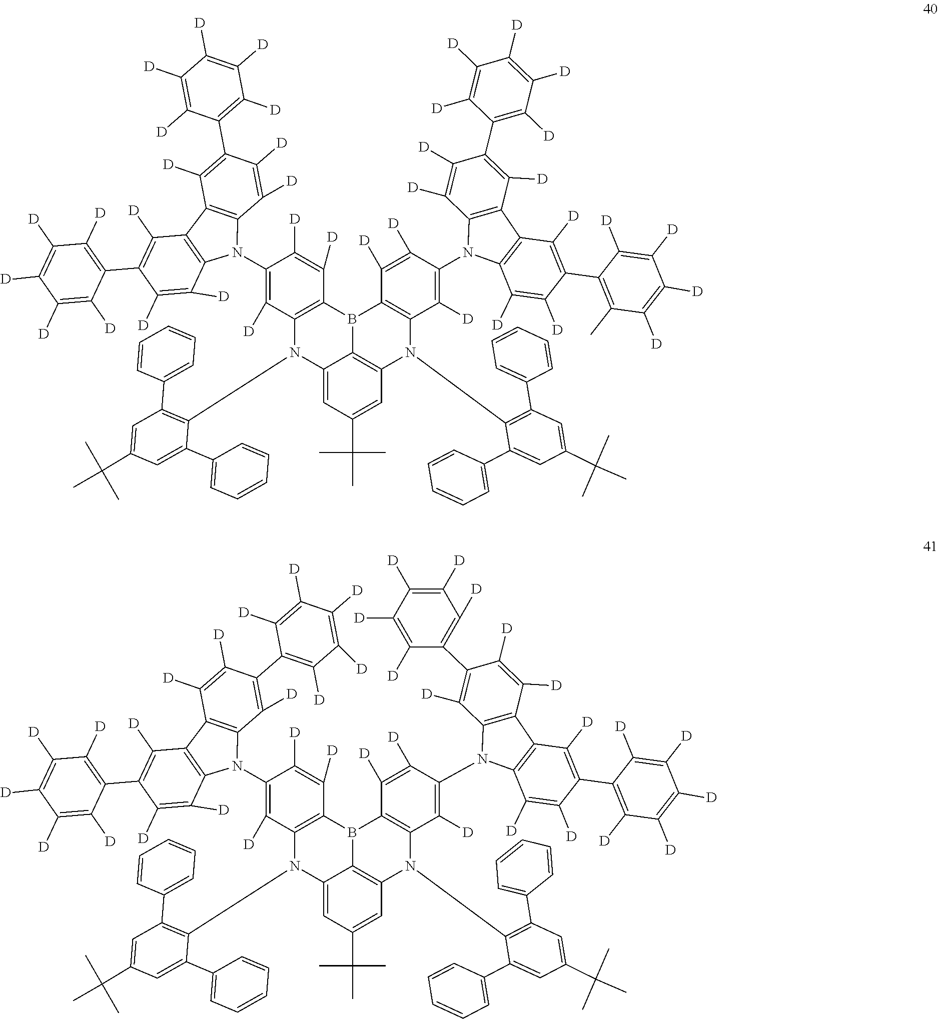 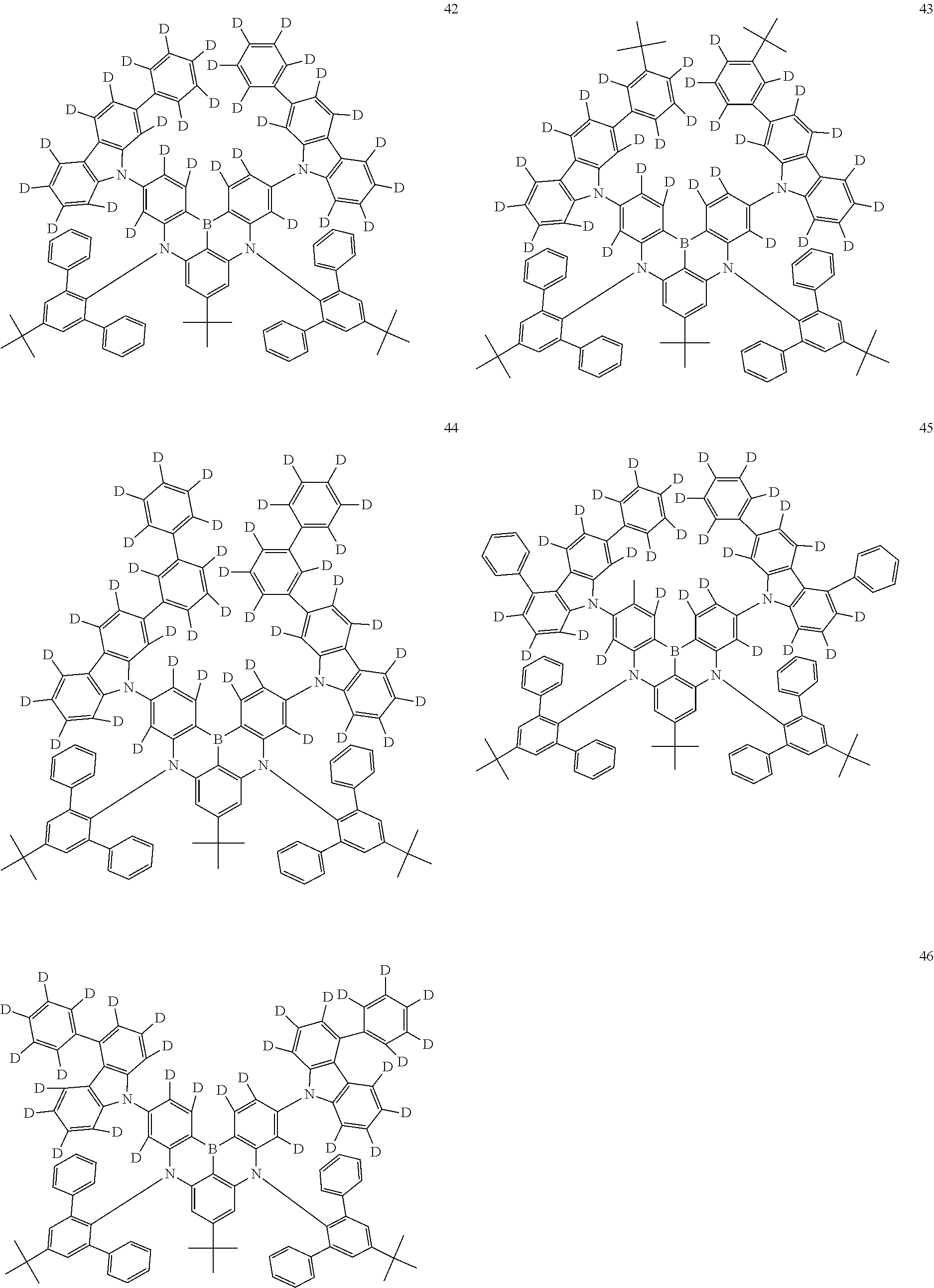 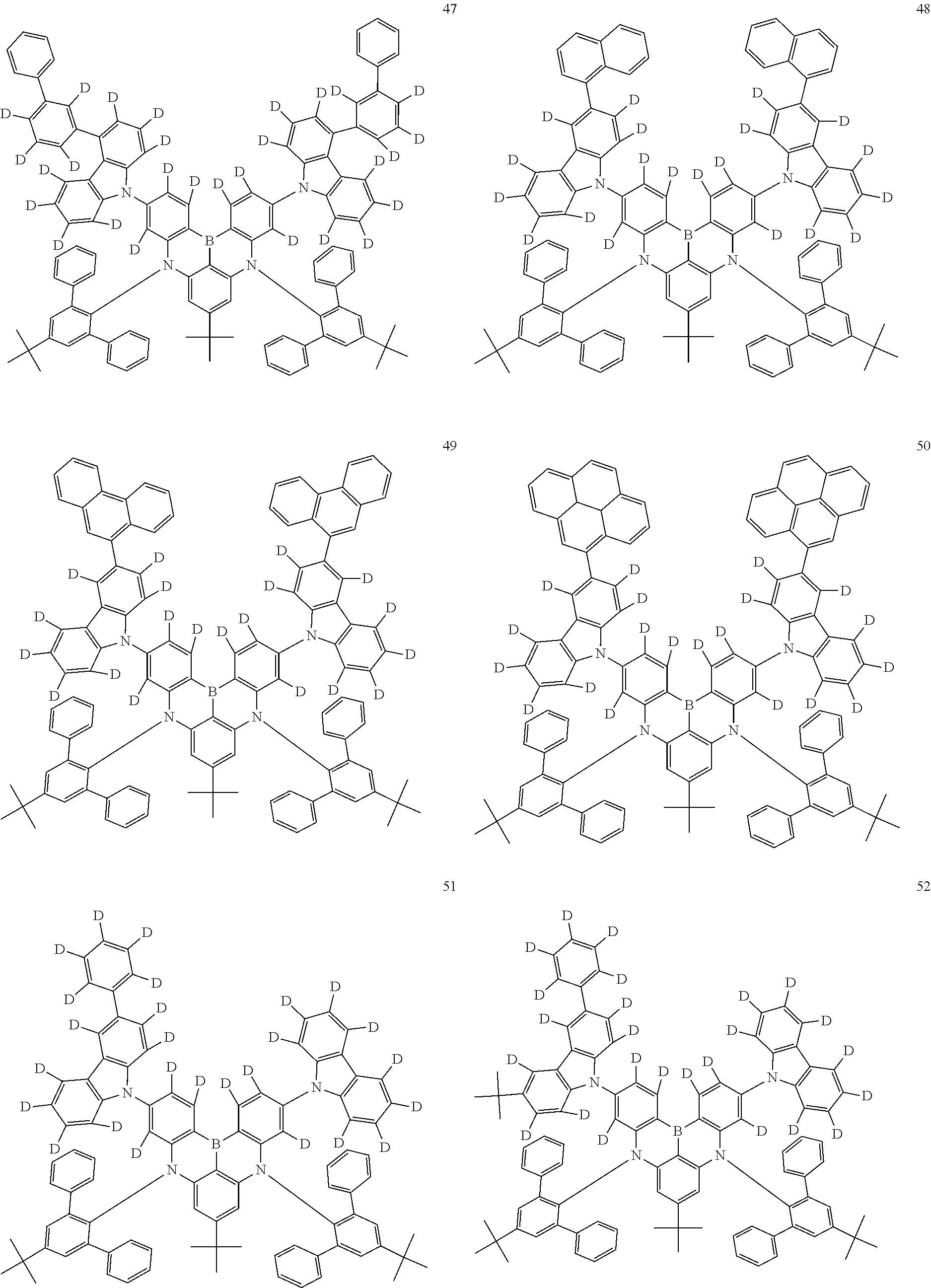 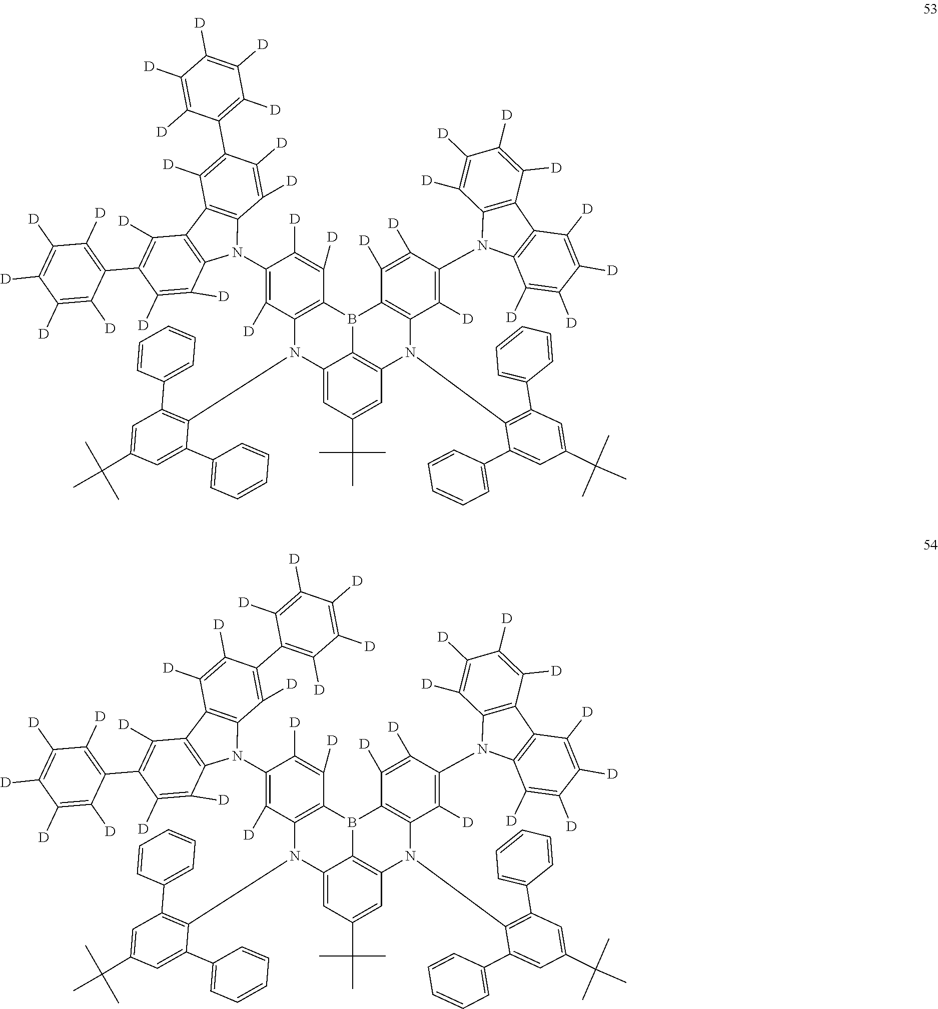 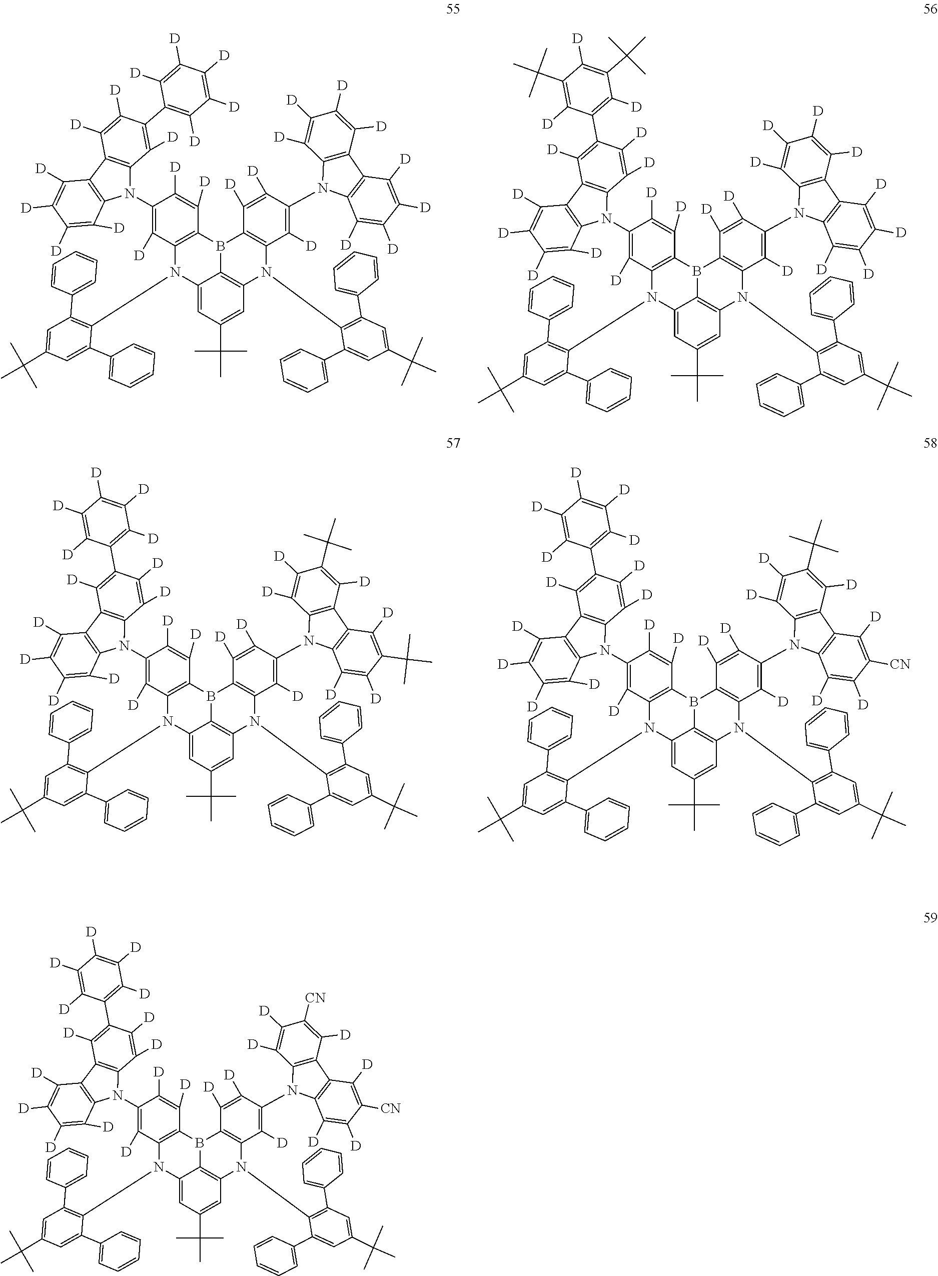 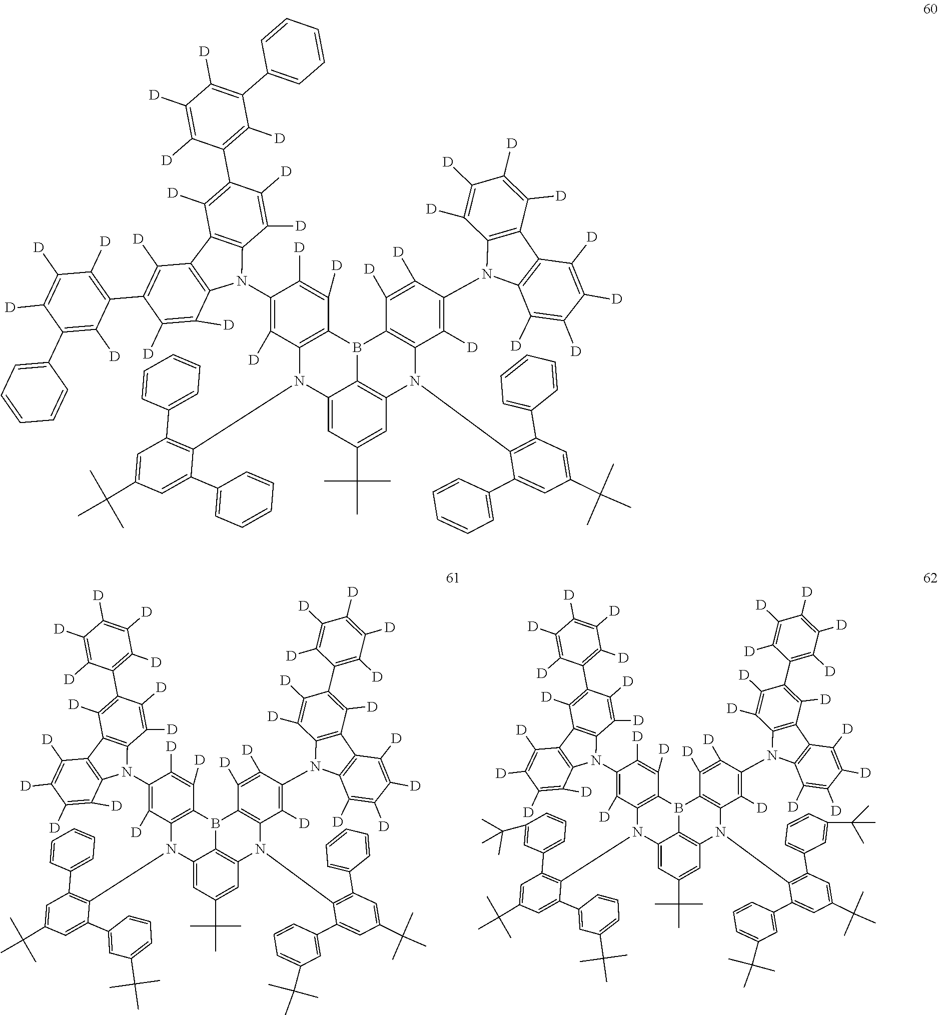 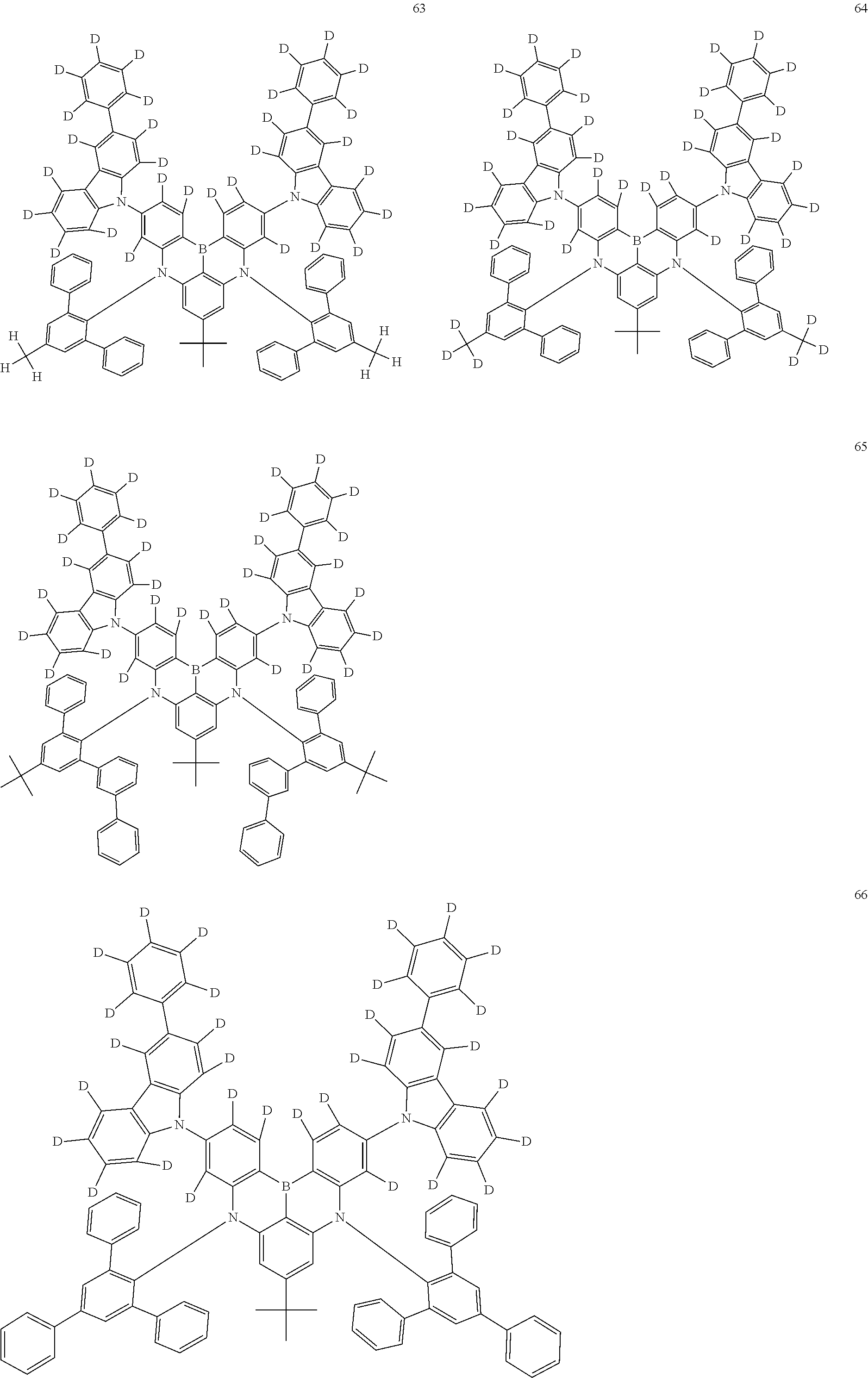 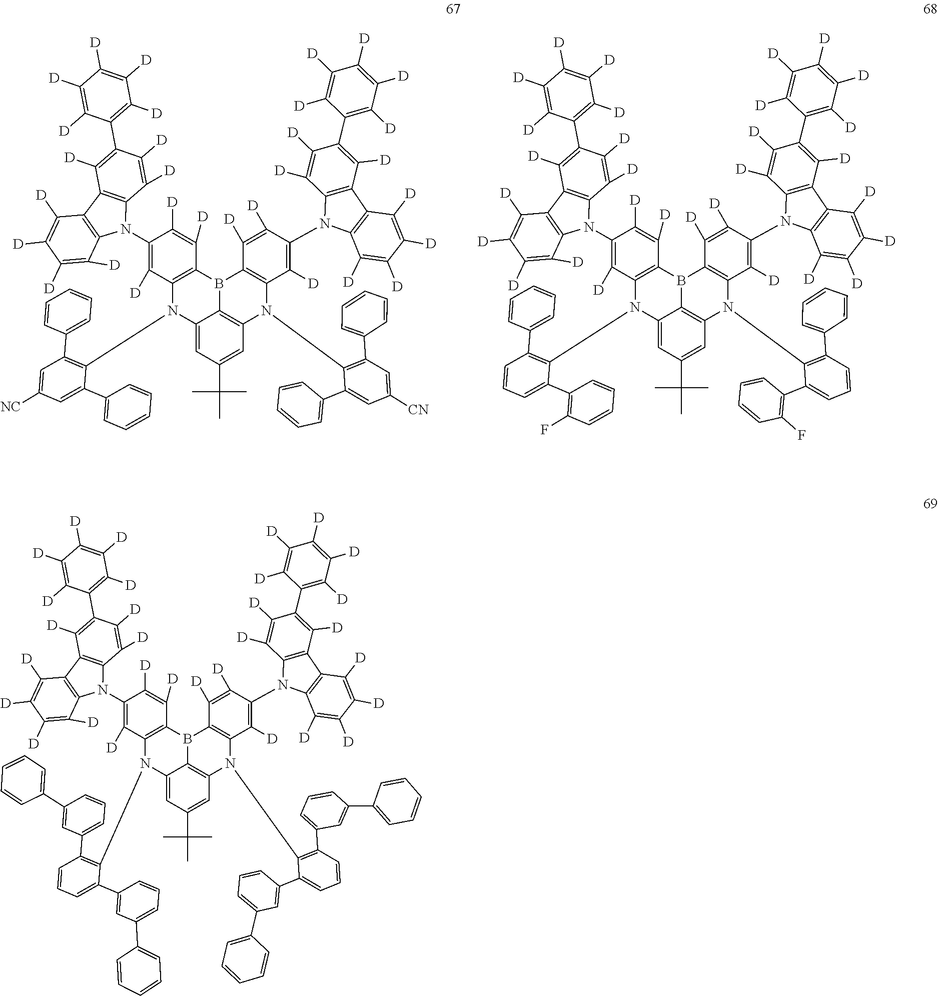 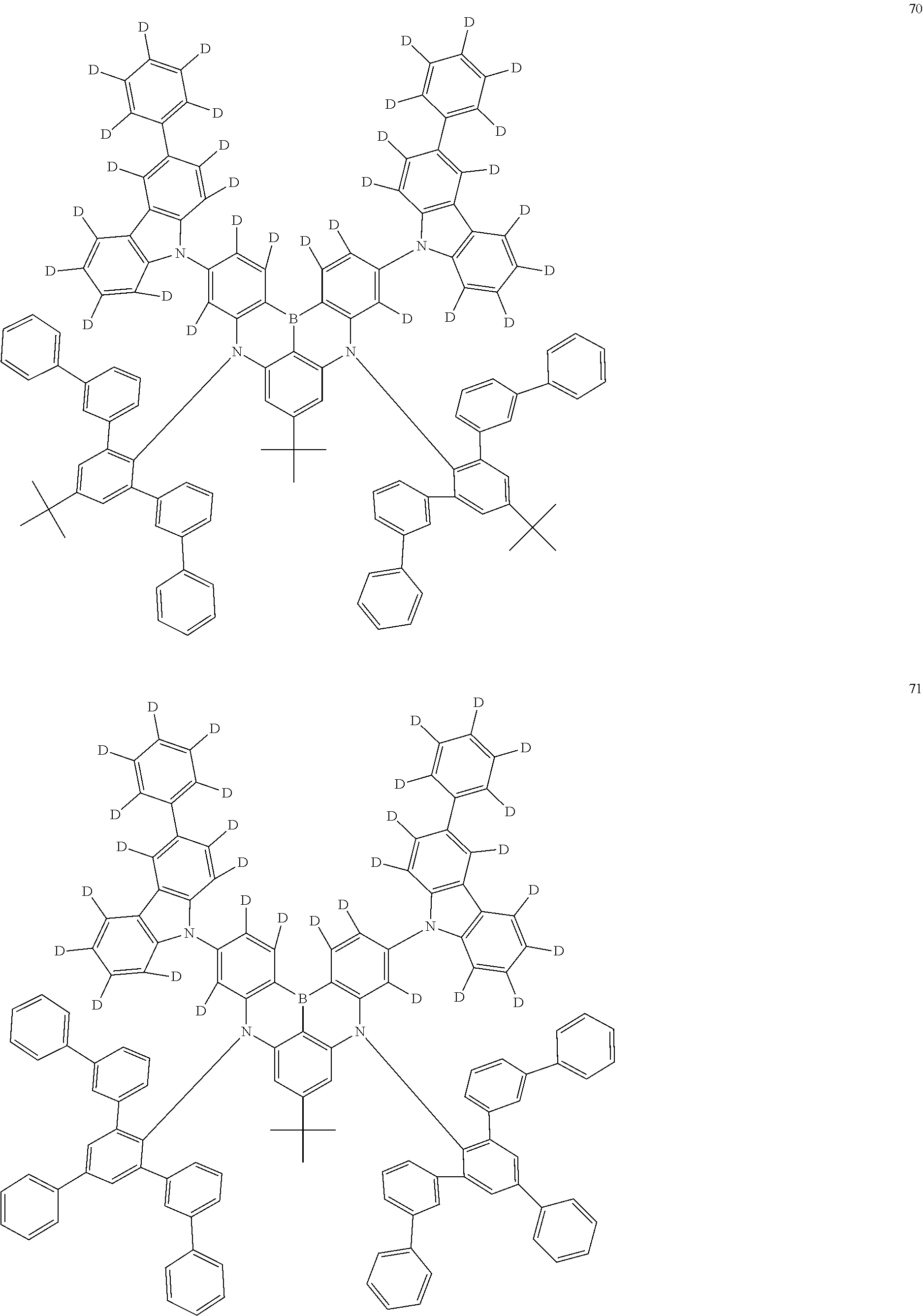 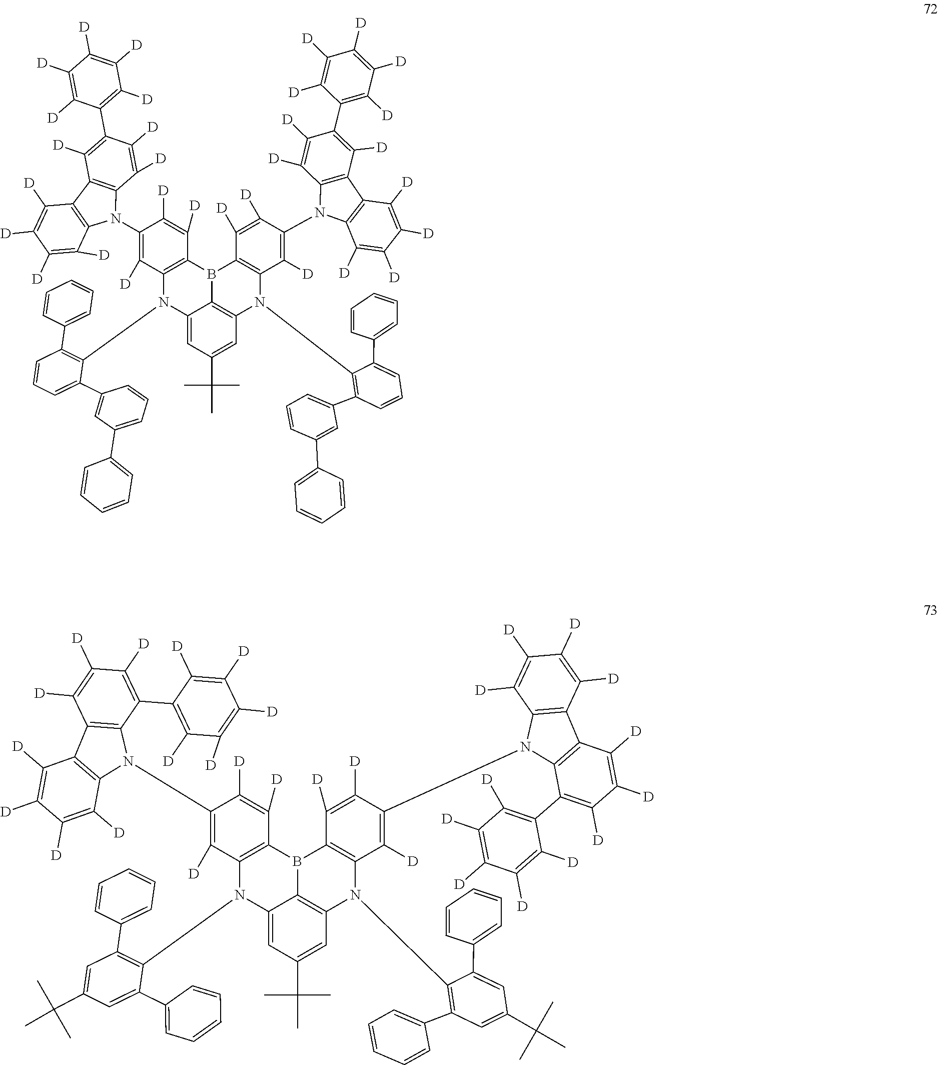 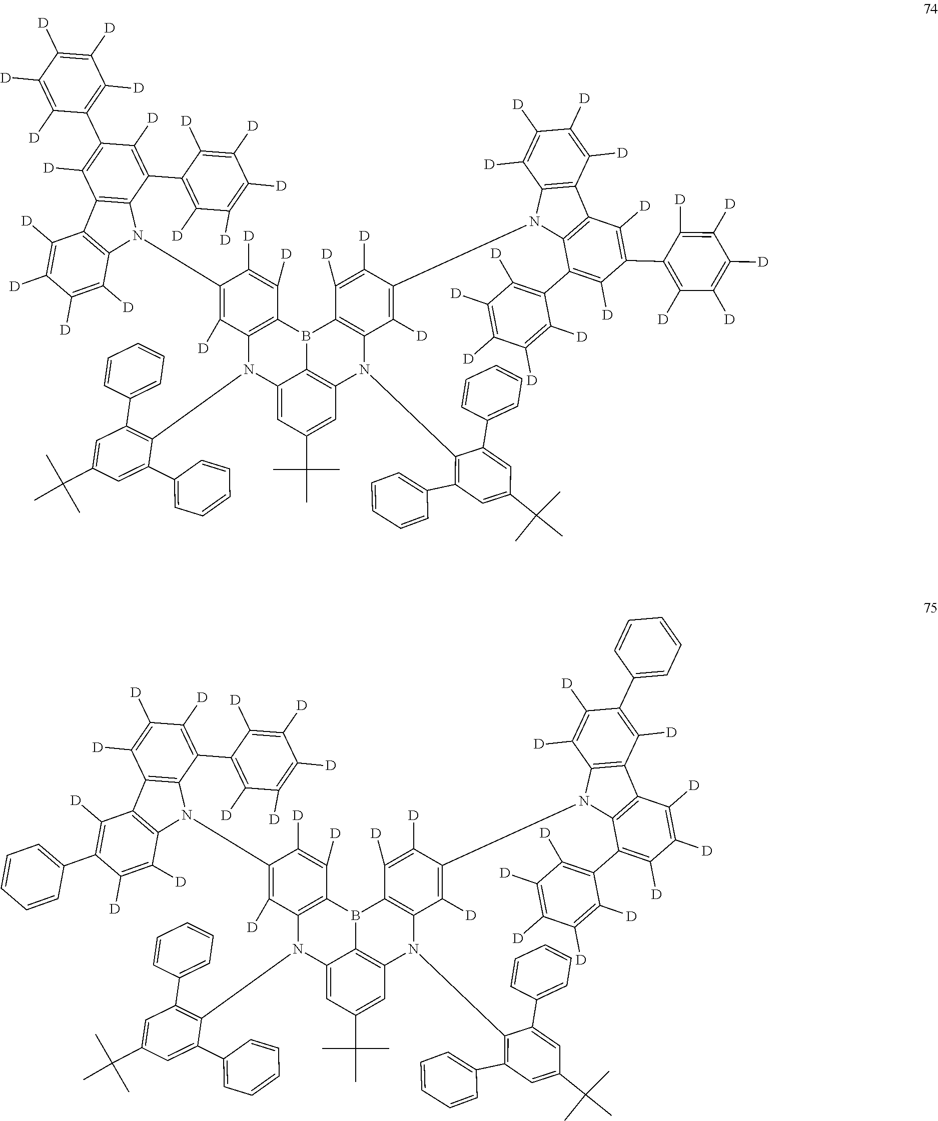 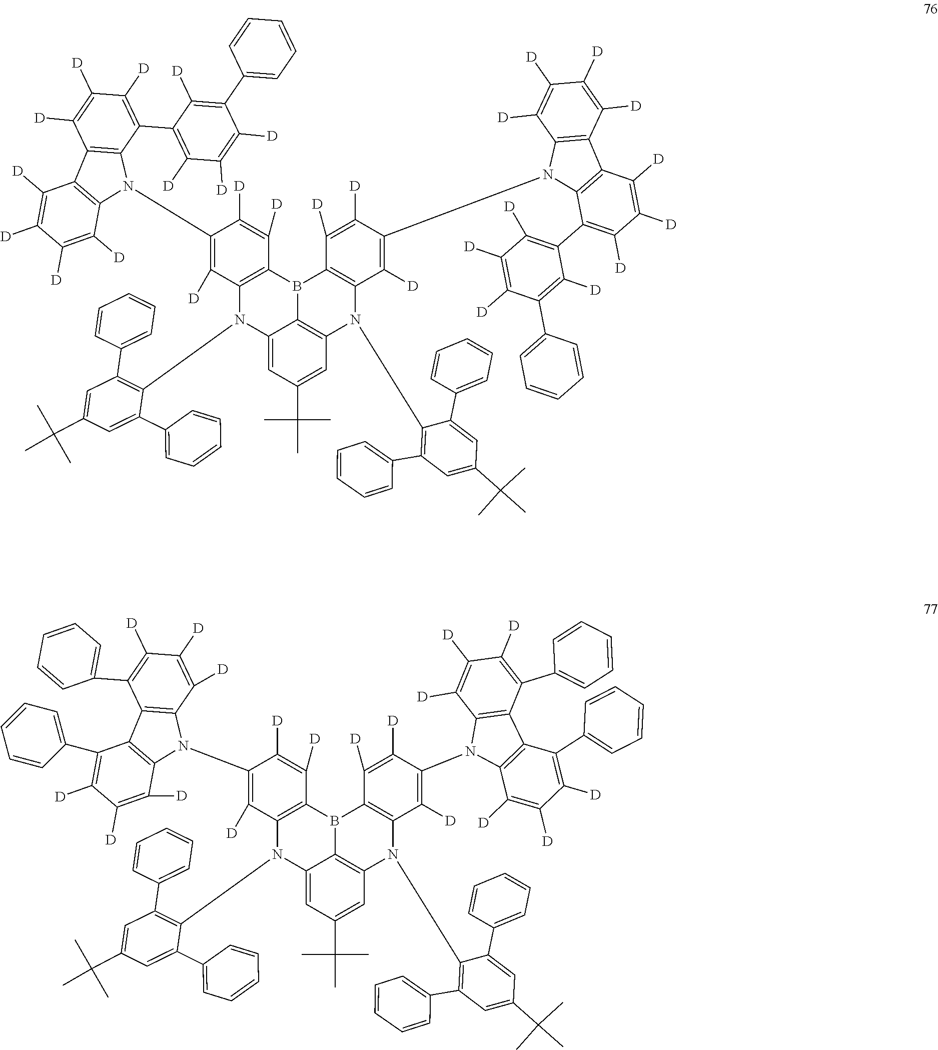 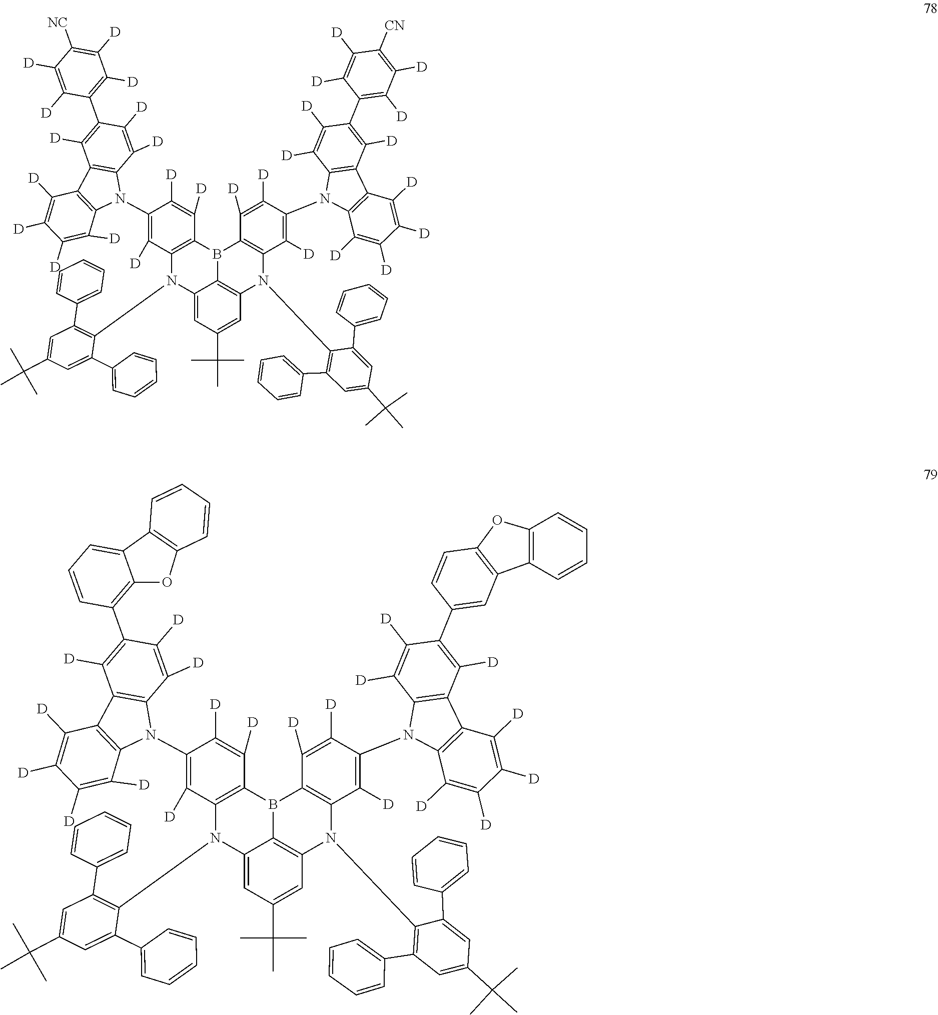 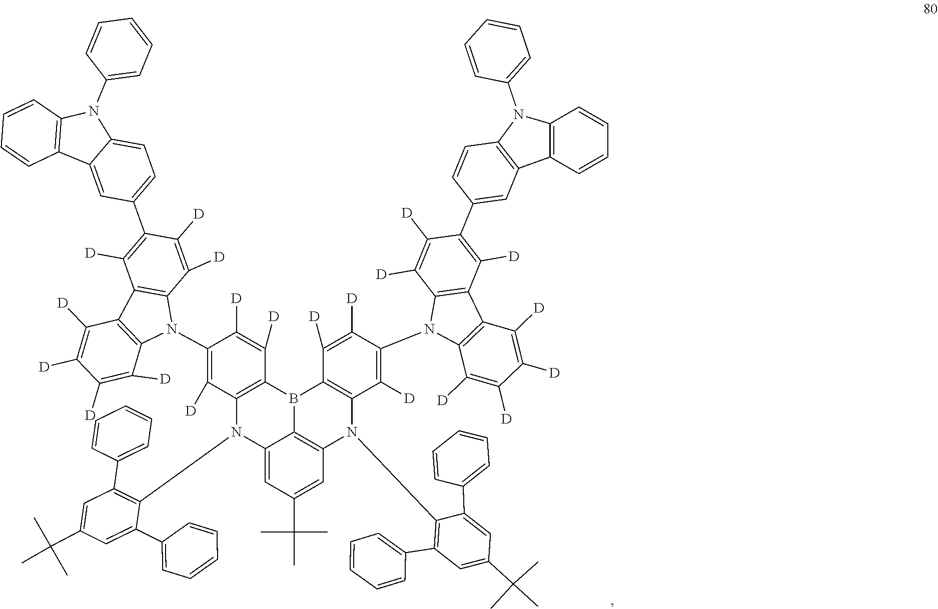 [SMILES: [2H]c1c([2H])c(-n2c3c([2H])c([2H])c([2H])c([2H])c3c3c([2H])c(-c4ccc5c(c4)c4ccccc4n5-c4ccccc4)c([2H])c([2H])c32)c([2H])c2c1B1c3c(cc(C(C)(C)C)cc3N(c3c(-c4ccccc4)cc(C(C)(C)C)cc3-c3ccccc3)c3c([2H])c(-n4c5c([2H])c([2H])c([2H])c([2H])c5c5c([2H])c(-c6ccc7c(c6)c6ccccc6n7-c6ccccc6)c([2H])c([2H])c54)c([2H])c([2H])c31)N2c1c(-c2ccccc2)cc(C(C)(C)C)cc1-c1ccccc1]
wherein in Compound Group 1, D is a deuterium atom.

21. A display device comprising:
a base layer;
a circuit layer on the base layer; and
a display element layer on the circuit layer and comprising a light-emitting element,
wherein the light-emitting element comprises a first electrode, a second electrode on the first electrode, and an emission layer between the first electrode and the second electrode and comprising a polycyclic compound represented by Formula 1: 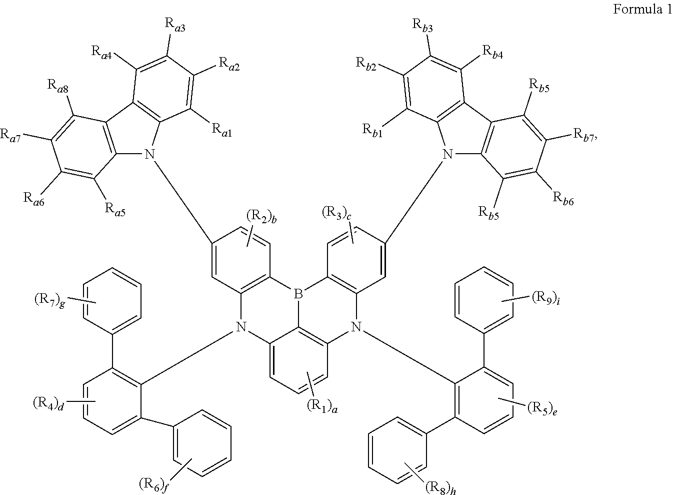
and
wherein, in Formula 1,
at least one selected from among Rₐ₁ to Rₐ₈ and R_{b1} to R_{b8} is a substituted or unsubstituted aryl group having 6 to group having 6 to 60 ring-forming carbon atoms or a substituted or unsubstituted heteroaryl group having 2 to 60 ring-forming carbon atoms,
remaining ones selected from among Rₐ₁ to Rₐ₈ and R_{b1} to R_{b8} are each independently a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, or a substituted or unsubstituted alkenyl group having 2 to 60 carbon atoms,
a to e are each independently an integer of 1 to 3,
f to i are each independently an integer of 1 to 5, and
R₁ to R₉ are each independently a hydrogen atom, a deuterium atom, a halogen atom, a cyano group, a nitro group, a substituted or unsubstituted silyl group, a substituted or unsubstituted amino group, a substituted or unsubstituted alkyl group having 1 to 60 carbon atoms, a substituted or unsubstituted cycloalkyl group having 3 to 60 carbon atoms, a substituted or unsubstituted alkoxy group having 1 to 60 carbon atoms, a substituted or unsubstituted alkenyl group having 2 to 60 carbon atoms, a substituted or unsubstituted aryl group having 6 to group having 6 to 60 ring-forming carbon atoms, or a substituted or unsubstituted heteroaryl group having 2 to 60 ring-forming carbon atoms.

22. The display device of claim 21, wherein
the light-emitting element is to emit blue light.

23. The display device of claim 21, further comprising a light control layer comprising a quantum dot.
